(19) United States
(12) Patent Application Publication
(10) Pub. No.: US 2026/0354007 A1
(43) Pub. Date: Nov. 5, 2026

(54) Composition, Organic Film Comprising Cured Material Prepared by Curing the Composition, and Electroluminescent Device Comprising the Organic Film

(71) Applicants: Samsung Electronics Co., Ltd., Suwon-si (KR); Samsung Display Co., Ltd., Yongin-si (KR)

(72) Inventors: Yusaku KONISHI, Yokohama-shi (JP); Yukika YAMADA, Yokohama-shi (JP); Norihito ISHII, Yokohama-shi (JP); Keigo FURUTA, Yokohama-shi (JP); Hiroko ENDO, Yokohama-shi (JP); Fumiaki KATO, Yokohama-shi (JP); Ji Hyun MIN, Suwon-si (KR); HONG KYU SEO, Suwon-si (KR); Ha il KWON, Suwon-si (KR)

(21) Appl. No.: 19/648,264

(22) Filed: Apr. 15, 2026

(30) Foreign Application Priority Data
Apr. 15, 2025 (JP) 2025-067072
Jan. 12, 2026 (KR) 10-2026-0005460

(51) Int. Cl. H10K 85/10; C08G 61/12; C08K 5/55; C09D 5/24; C09D 7/63; C09D 165/00; H10K 50/115; H10K 50/17

(52) U.S. Cl. CPC H10K 85/115; C08G 61/12; C08G 61/124; C09D 5/24; C09D 7/63; C09D 165/00; H10K 85/151; C08G 2261/122; C08G 2261/124; C08G 2261/1412; C08G 2261/148; C08G 2261/149; C08G 2261/312; C08G 2261/3142; C08G 2261/3241; C08G 2261/334; C08G 2261/95; C08K 5/55; H10K 50/115; H10K 50/17

(57) ABSTRACT

A composition comprising a copolymer including a structural unit represented by Chemical Formula 1, and at least one of Structural unit A represented by Chemical Formula 2 or Structural unit B represented by Chemical Formula 3, each of which is described herein, and a salt compound, the salt compound including a borate anion represented by Chemical Formula 4, which is described herein, and an iodonium cation is provided, in which an energy difference (ΔE) between an ionic potential of the copolymer and an electron affinity of the borate anion is greater than or equal to about 0.75 eV.

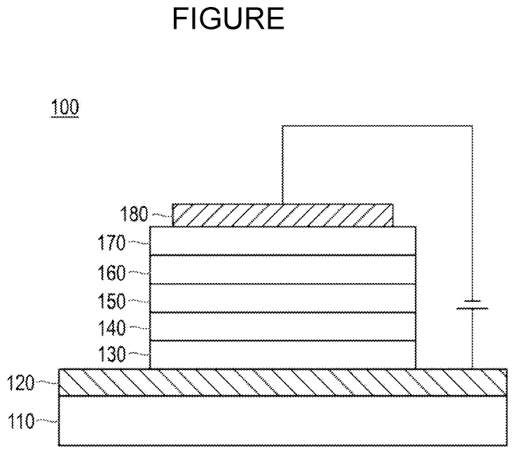

This application claims priority to and the benefit of Japanese Patent Application No. 2025-067072, filed in the Japanese Patent Office on Apr. 15, 2025, and Korean Patent Application No. 10-2026-0005460, filed in the Korean Intellectual Property Office on Jan. 12, 2026, and all the benefits accruing therefrom under 35 U.S.C. § 119, the entire contents of which in their entireties are herein incorporated by reference.

### BACKGROUND

### 1. Field

A composition, an organic film comprising a cured material prepared by curing the composition, and an electroluminescent device including the organic film are disclosed.

### 2. Description of the Related Art

There is a strong interest in quantum dots that cover a wide color for a RGB light source, and research and development of electroluminescence devices having the quantum dots in a light emitting layer (hereinafter, also referred to as a quantum dot electroluminescent device, or QD-LED). Such quantum dots and devices are actively progressing as a display device, e.g., a lighting device having a thin film, and/or that is lightweight or has a relatively low power consumption.

Through the use of specific aging technology, the luminous efficiency and device life of the QD-LED may be drastically improved.

### SUMMARY

We have discovered that the hole injection layer deteriorates by formation of anions during aging (e.g., acrylic acid anions), and as a result, current density degrades (i.e., de-doping), which in turn leads to a rise in driving voltage, luminous efficiency deterioration, life of the device deterioration, etc. Accordingly, device performance improvement by positive aging and device performance deterioration due to the deterioration of hole injection layer by negative aging are in a technical trade-off.

Further, recently, from the perspectives of large-area optimization, manufacturing process efficiency, and cost reduction, there has been a demand for manufacturing QD-LEDs using a coating method. On the other hand, in a laminated structure including a lower layer (for example, a hole injection layer or a hole transport layer) and an upper layer (for example, an emission layer), when forming the lower layer by a coating method, the material for the lower layer is required to have low solubility (orthogonality) with the solvent used to form the upper layer. However, conventional hole injection materials (hole transport materials) did not have such characteristics.

Through our recent efforts to provide a layer having resistance to a solvent used to form an adjacent layer, enhance resistance to positive aging, reduce the driving voltage of electroluminescent devices, improve luminous efficiency, and extend the lifetime of the devices, it was found that one or more of the above technical objectives could be achieved with the presence of a composition comprising a copolymer and a salt compound.

The copolymer includes a structural unit represented by Chemical Formula 1, and at least one structural unit selected from Structural unit A represented by Chemical Formula 2 or Structural unit B represented by Chemical Formula 3, and the salt compound includes a borate anion represented by Chemical Formula 4 and an iodonium cation. In the composition, an energy difference (ΔE) between an ionization potential of the copolymer and an electron affinity of the borate anion is greater than or equal to about 0.75 electron volts (eV), and the ionization potential of the copolymer is deeper than an ionization potential of the iodonium cation:

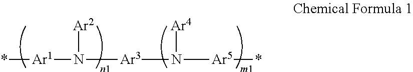

in Chemical Formula 1,
Ar¹, Ar², Ar⁴, and Ar⁵ are, each independently, a substituted or unsubstituted aromatic hydrocarbon ring group, or a substituted or unsubstituted aromatic heterocyclic group,
Ar³ is a substituted or unsubstituted carbazole, a substituted or unsubstituted fluorene, a substituted or unsubstituted benzene, or a substituted or unsubstituted biphenylene group, wherein when Ar³ is a substituted or unsubstituted benzene, or a substituted or unsubstituted biphenylene group, then at least one of Ar¹ or Ar² is not a substituted or unsubstituted benzene, and at least one of Ar⁴ or Ar⁵ is not a substituted or unsubstituted benzene,
n1 is an integer of greater than or equal to 1 and less than or equal to 3,
m1 is an integer of greater than or equal to 1 and less than or equal to 3, and
* is a bonding position to an adjacent atom;

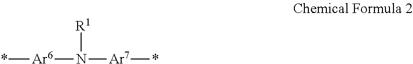

in Chemical Formula 2,
Ar⁶ and Ar⁷ are, each independently, a substituted or unsubstituted aromatic hydrocarbon ring group, or a substituted or unsubstituted aromatic heterocyclic group, and Ar⁶ and Ar⁷ optionally form a ring together,
R¹ is a group represented by chemical formula (2-a), and
* is a bonding position to an adjacent atom,

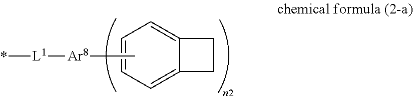

in chemical formula (2-a)
L¹ is a single bond, or a group represented by chemical formula (2-b),
Ar⁸ is a substituted or unsubstituted aromatic hydrocarbon ring group, or a substituted or unsubstituted aromatic heterocyclic group,
wherein when L¹ is a single bond, at least one of Ar⁶, Ar⁷, or Ar⁸ is not a substituted or unsubstituted benzene, or Ar⁸ may form a ring together with at least one of Ar⁶ or Ar⁷,
n2 is an integer of greater than or equal to 2 and less than or equal to 5, and
* is a bonding position to an adjacent atom,

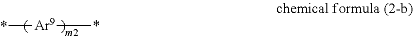

in chemical formula (2-b),
Ar⁹ is a substituted or unsubstituted aromatic hydrocarbon ring group, or a substituted or unsubstituted aromatic heterocyclic group, or Ar⁹ forms a ring together with at least one of Ar⁶ or Ar⁷,
m2 is an integer of greater than or equal to 1 and less than or equal to 5, and when m2 is an integer of greater than or equal to 2, each Ar⁹ is the same or different, and
* is a bonding position to an adjacent atom;

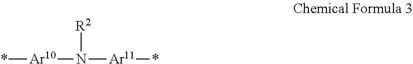

in Chemical Formula 3,
Ar¹⁰ and Ar¹¹ are, each independently, a substituted or unsubstituted aromatic hydrocarbon ring group, or a substituted or unsubstituted aromatic heterocyclic group, and Ar¹⁰ and Ar¹¹ optionally form a ring together,
R² is a group represented by chemical formula (3-a) or chemical formula (3-b), and
* is a bonding position to an adjacent atom;

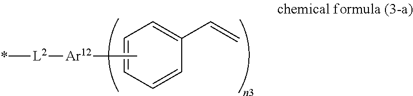

in chemical formula (3-a),
Ar¹² is a substituted or unsubstituted aromatic hydrocarbon ring group, or a substituted or unsubstituted aromatic heterocyclic group,
wherein when L² is a single bond, then Ar¹² optionally forms a ring together with at least one of Ar¹⁰ or Ar¹¹
n3 is an integer of greater than or equal to 2 and less than or equal to 5, and
* is a bonding position to an adjacent atom;

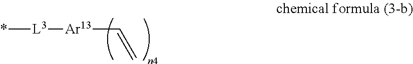

in chemical formula (3-b),
L³ is a single bond, or a group represented by chemical formula (3-c), Ar¹³ is a substituted or unsubstituted aromatic hydrocarbon ring group, or a substituted or unsubstituted aromatic heterocyclic group,
wherein when L³ is a single bond, then Ar¹³ optionally forms a ring together with at least one of Ar¹⁰ or Ar¹¹,
n4 is an integer of greater than or equal to 2 and less than or equal to 5, and
* is a bonding position to an adjacent atom;

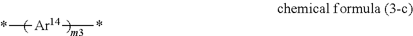

in chemical formula (3-c),
Ar¹⁴ is a substituted or unsubstituted aromatic hydrocarbon ring group, or a substituted or unsubstituted aromatic heterocyclic group, or Ar¹⁴ optionally forms a ring together with at least one of Ar¹⁰ or Ar¹¹,
m3 is an integer of greater than or equal to 1 and less than or equal to 5, and when m3 is an integer of greater than or equal to 2, each Ar¹⁴ is the same or different, and
* is a bonding position to an adjacent atom;

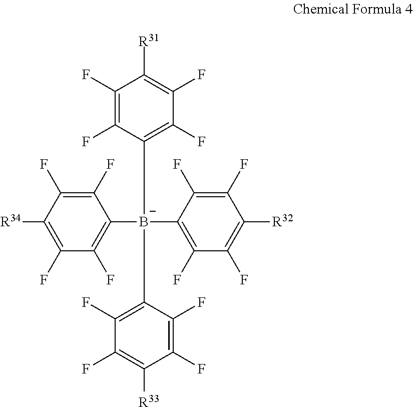

in Chemical Formula 4,
R³¹ to R³⁴ are, each independently, a hydrogen atom, a fluorine atom, or a group represented by chemical formula (4-a),

*-L⁴-(Ar¹⁵)ₙ₆—(X)ₙ₅ chemical formula (4-a)

in chemical formula (4-a),
L⁴ is a single bond, or a group represented by chemical formula (4-b),
Ar¹⁵ is a substituted or unsubstituted aromatic hydrocarbon ring group, or a substituted or unsubstituted aromatic heterocyclic group,
X is a fluorine atom, or a group selected from Group (4-1),
n5 is an integer of greater than or equal to 1 and less than or equal to 5,
n6 is an integer of 0 or 1,
when multiple groups represented by chemical formula (4-a) are present, each L⁴ is the same or different,
when multiple groups represented by chemical formula (4-a) are present, each Ar¹⁵ is the same or different,
when multiple groups represented by chemical formula (4-a) are present, each X is the same or different,
when multiple groups represented by chemical formula (4-a) are present, each n5 is the same or different,
when multiple groups represented by chemical formula (4-a) are present, each n6 is the same or different,
when n5 is an integer of greater than or equal to 2, each X is the same or different, and
* is a bonding position to an adjacent atom,

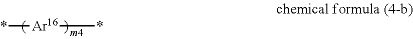

in chemical formula (4-b),
Ar¹⁶ is a substituted or unsubstituted aromatic hydrocarbon ring group, or a substituted or unsubstituted aromatic heterocyclic group,
m4 is an integer of greater than or equal to 1 and less than or equal to 5, and when m4 is greater than or equal to 2, each Ar¹⁶ is the same or different, and
* is a bonding position to an adjacent atom,

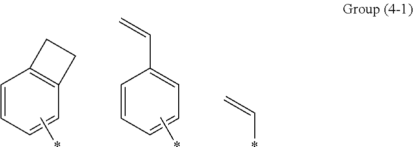

in Group (4-1),
* is a bonding position to an adjacent atom.

According to one or more embodiments, a composition is provided that can improve resistance to a solvent used to form an adjacent layer and resistance to positive aging, reduce the driving voltage, enhance luminous efficiency, and improve the device lifespan of an electroluminescent device.

### BRIEF DESCRIPTION OF DRAWING

The FIGURE is a schematic representation of an electroluminescence device according to one or more embodiments.

### DETAILED DESCRIPTION

A composition according to an aspect includes a copolymer including a structural unit represented by Chemical Formula 1, and at least one structural unit of Structural unit A represented by Chemical Formula 2 or Structural unit B represented by Chemical Formula 3, and a salt compound including a borate anion represented by Chemical Formula 4 and an iodonium cation, wherein in the composition, an energy difference (ΔE) between an ionization potential of the copolymer and an electron affinity of the borate anion is greater than or equal to about 0.75 eV, and the ionization potential of the copolymer is deeper than an ionization potential of the iodonium cation:

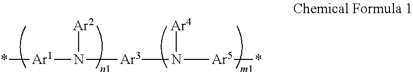

in Chemical Formula 1,
Ar¹, Ar², Ar⁴, and Ar⁵ are, each independently, a substituted or unsubstituted aromatic hydrocarbon ring group, or a substituted or unsubstituted aromatic heterocyclic group,
Ar³ is a substituted or unsubstituted carbazole, a substituted or unsubstituted fluorene, a substituted or unsubstituted benzene, or a substituted or unsubstituted biphenylene group, wherein when Ar³ is a substituted or unsubstituted benzene, or a substituted or unsubstituted biphenylene group, then at least one of Ar¹ or Ar² is not a substituted or unsubstituted benzene, and at least one of Ar⁴ or Ar⁵ is not a substituted or unsubstituted benzene,
n1 is an integer of greater than or equal to 1 and less than or equal to 3,
m1 is an integer of greater than or equal to 1 and less than or equal to 3, and
* is a bonding position to an adjacent atom;

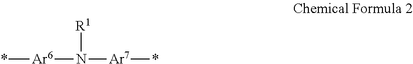

in Chemical Formula 2,
Ar⁶ and Ar⁷ are, each independently, a substituted or unsubstituted aromatic hydrocarbon ring group, or a substituted or unsubstituted aromatic heterocyclic group, and Ar⁶ and Ar⁷ optionally form a ring together,
R¹ is a group represented by chemical formula (2-a), and
* is a bonding position to an adjacent atom,

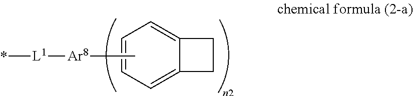

in chemical formula (2-a)
L¹ is a single bond, or a group represented by chemical formula (2-b),
Ar⁸ is a substituted or unsubstituted aromatic hydrocarbon ring group, or a substituted or unsubstituted aromatic heterocyclic group,
wherein when L¹ is a single bond, at least one of Ar⁶, Ar⁷, or Ar⁸ is not a substituted or unsubstituted benzene, or Ar⁸ optionally forms a ring together with at least one of Ar⁶ or Ar⁷
n2 is an integer of greater than or equal to 2 and less than or equal to 5, and
* is a bonding position to an adjacent atom,

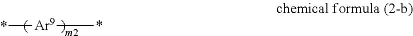

in chemical formula (2-b),
Ar⁹ is a substituted or unsubstituted aromatic hydrocarbon ring group, or a substituted or unsubstituted aromatic heterocyclic group, or Ar⁹ optionally forms a ring together with at least one of Ar⁶ or Ar⁷,
m2 is an integer of greater than or equal to 1 and less than or equal to 5, and when m2 is an integer of greater than or equal to 2, each Ar⁹ is the same or different, and
* is a bonding position to an adjacent atom;

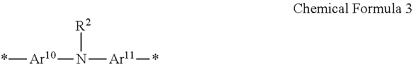

in Chemical Formula 3,
Ar¹⁰ and Ar¹¹ are, each independently, a substituted or unsubstituted aromatic hydrocarbon ring group, or a substituted or unsubstituted aromatic heterocyclic group, and Ar¹⁰ and Ar¹¹ optionally form a ring together,
R² is a group represented by chemical formula (3-a) or chemical formula (3-b), and
* is a bonding position to an adjacent atom;

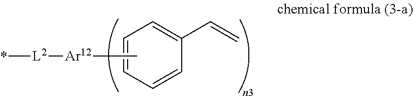

in chemical formula (3-a),
L² is a single bond, or a group represented by chemical formula (3-c),
Ar¹² is a substituted or unsubstituted aromatic hydrocarbon ring group, or a substituted or unsubstituted aromatic heterocyclic group,
wherein when L² is a single bond, Ar¹² optionally forms a ring together with at least one of Ar¹⁰ or Ar¹¹,
n3 is an integer of greater than or equal to 2 and less than or equal to 5, and
* is a bonding position to an adjacent atom;

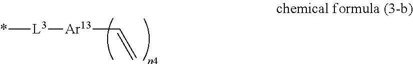

in chemical formula (3-b),
L³ is a single bond, or a group represented by chemical formula (3-c),
Ar¹³ is a substituted or unsubstituted aromatic hydrocarbon ring group, or a substituted or unsubstituted aromatic heterocyclic group,
wherein when L³ is a single bond, Ar¹³ optionally forms a ring together with at least one of Ar¹⁰ or Ar¹¹,
n4 is an integer of greater than or equal to 2 and less than or equal to 5, and
* is a bonding position to an adjacent atom;

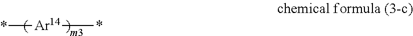

in chemical formula (3-c),
Ar¹⁴ is a substituted or unsubstituted aromatic hydrocarbon ring group, or a substituted or unsubstituted aromatic heterocyclic group, or Ar¹⁴ optionally forms a ring together with at least one of Ar¹⁰ or Ar¹¹,
m3 is an integer of greater than or equal to 1 and less than or equal to 5, and when m3 is an integer of greater than or equal to 2, each Ar¹⁴ is the same or different, and
* is a bonding position;

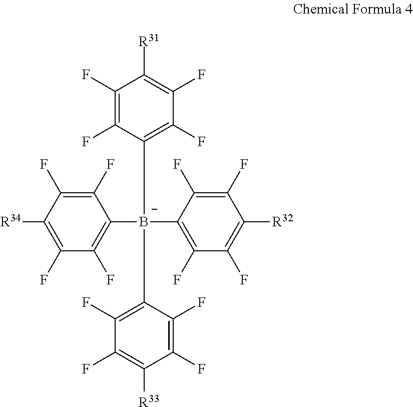

in Chemical Formula 4,
R³¹ to R³⁴ are, each independently, a hydrogen atom, a fluorine atom, or a group represented by chemical formula (4-a),

*-L⁴-(Ar¹⁵)ₙ₆—(X)ₙ₅ chemical formula (4-a)
in chemical formula (4-a),
L⁴ is a single bond, or a group represented by chemical formula (4-b),
Ar¹⁵ is a substituted or unsubstituted aromatic hydrocarbon ring group, or a substituted or unsubstituted aromatic heterocyclic group,
X is a fluorine atom, or a group selected from Group (4-1),
n5 is an integer of greater than or equal to 1 and less than or equal to 5,
n6 is an integer of 0 or 1,
when multiple groups represented by chemical formula (4-a) are present, each L⁴ is the same or different,
when multiple groups represented by chemical formula (4-a) are present, each Ar¹⁵ is the same or different,
when multiple groups represented by chemical formula (4-a) are present, each X is the same or different,
when multiple groups represented by chemical formula (4-a) are present, each n5 is the same or different,
when multiple groups represented by chemical formula (4-a) are present, each n6 is the same or different,
when n5 is an integer of greater than or equal to 2, each X is the same or different, and
* is a bonding position to an adjacent atom,

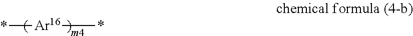

in chemical formula (4-b),
Ar¹⁶ is a substituted or unsubstituted aromatic hydrocarbon ring group, or a substituted or unsubstituted aromatic heterocyclic group,
m4 is an integer of greater than or equal to 1 and less than or equal to 5, and when m4 is greater than or equal to 2, each Ar¹⁶ is the same or different, and
* is a bonding position to an adjacent atom,

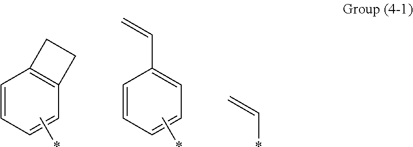

in Group (4-1),
* is a bonding position to an adjacent atom.

In the descriptions below, the polymer including a structural unit represented by Chemical Formula 1, and at least one structural unit represented by Structural unit A represented by Chemical Formula 2 or Structural unit B represented by Chemical Formula 3 may be referred to simply as ‘the copolymer’, or ‘the copolymer according to an embodiment’. Further, the salt compound including the borate anion represented by Chemical Formula 4 and an iodonium cation is referred to simply as ‘the salt compound’, or ‘the salt compound according to an embodiment’.

Without wishing to be bound to theory, in the hole injection layer, it is known that the hole injection characteristics may be improved by forming a charge transfer complex. If the cations and anions do not form a charge transfer complex, there remains a strong possibility that hole injection characteristics may be degraded. Conventional hole injection materials have a relatively small difference between the ionization potential of the hole injection material included in hole injection layer and the electron affinity of borate anion (dopant) than the difference between the ionization potential of the hole injection material and electron affinity of acid anions resulting from positive aging. Accordingly, acid anions resulting from positive aging and borate anion exchange occurs, the formed charge transfer complex collapses, and the cations and acid anions that do not form charge transfer complexes combine. Therefore, the electric conductivity of hole injection layer deteriorates, and the characteristics, for example, driving voltage, luminous efficiency, device lifespan, etc. may deteriorate.

Meanwhile, in a composition according to one or more embodiments, the composition may have a larger difference between the ionization potential of the copolymer, which is a hole injection material, and electron affinity of the borate anion (dopant) included in the salt compound than the difference between the ionization potential of the copolymer and electron affinity of the anions resulting from the positive aging, and the ionization potential of the copolymer is deeper than the ionization potential of the iodonium cation included in the salt compound. Accordingly, and without wishing to be bound to theory, even though positive aging is performed, it is believed that the collapse of charge-transfer complexes of the borate anions of the salt compound and the copolymer may be suppressed, the conductivity of the hole injection layer is maintained, and the degradation of each characteristic (e.g., driving voltage, luminous efficiency, device lifetime, etc.) may be suppressed.

In addition, the copolymer according to one or more embodiments includes a plurality of crosslinking groups in the structural units represented by Chemical Formula 2 or Chemical Formula 3. Accordingly, the cured material obtained by curing the composition according to one or more embodiments has a high density of crosslinking, which results in good resistance to a solvent used to form an adjacent layer.

Hereinafter, the exemplary embodiments will be described in further detail. The embodiments are not limited to the following forms and can be variously modified within the scope of the claims. In addition, the embodiments described in this specification can be combined arbitrarily to form other embodiments. Also, the drawing is exaggerated for the convenience of explanation, and the dimensional ratios of each component in the drawing may differ from reality.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% or ±5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein. In this specification, unless otherwise specifically stated, measurements of handling and physical properties are conducted at room temperature (greater than or equal to 20° C. and less than or equal to 25° C.) and relative humidity between 40% RH and 50% RH.

As used herein, ‘x and y are each independent’ means that x and y may be the same or may be different.

As used herein, a group derived from “compound z” or a group originating from “compound z” means that when “compound z” is made into a cyclic compound, from that ring structure, the hydrogen atoms directly bonded to the ring-forming atoms are removed according to the valence to represent an unsaturated group.

As used herein, the number of ring-forming atoms refers to the number of atoms constituting the corresponding ring itself of the compound (e.g., monocyclic compound, condensed ring compound, crosslinked compound, carbocyclic compound, and heterocyclic compound) having a structure in which atoms are bonded in a ring (e.g., monocycle, condensed ring, ring assembly, etc.). Atoms that do not form a ring (e.g., a hydrogen atom that terminates the bond of the atoms forming a ring) or atoms included in a substituent when the ring is replaced by a substituent are not included in the number of ring-forming atoms. The number of ring-forming atoms described below is assumed to be the same unless otherwise specified.

For example, a benzene ring has 6 ring-forming atoms, a naphthalene ring has 10 ring-forming atoms, a pyridine ring has 6 ring-forming atoms, and a furan ring has 5 ring-forming atoms.

When the benzene ring is substituted with a substituent, for example, an alkyl group, the number of carbon atoms of the alkyl group is not included in the number of ring-forming atoms of the benzene ring. Accordingly, the number of ring-forming atoms of the benzene ring substituted by the alkyl group is 6. In addition, when the naphthalene ring is substituted with an alkyl group as a substituent, for example, the number of atoms of the alkyl group is not included in the number of ring-forming atoms of the naphthalene ring. Accordingly, the number of ring-forming atoms of the naphthalene ring substituted by the alkyl group is 10.

For example, the number of hydrogen atoms bonded to the pyridine ring or the atoms constituting the substituent is not included in the number of ring-forming atoms of the pyridine ring. Accordingly, the number of ring-forming atoms of the pyridine ring to which the hydrogen atom or substituent is bonded is 6.

As used herein, unless specifically defined, the term “substituted” refers to being substituted with an alkyl group, a cycloalkyl group, a hydroxyalkyl group, an alkoxy group, an alkoxyalkyl group, a cycloalkoxy group, an alkenyl group, an alkynyl group, a primary amino group (—NH₂), a secondary amino group (—NH(R¹): R¹ is an alkyl group or an aryl group), a tertiary amino group (—N(R¹)(R²): R¹ and R² are each independently an alkyl group or an aryl group, and in this case, R¹ and R² may form a ring), an aryl group, an aryloxy group, an alkylthio group, a cycloalkylthio group, an arylthio group, an alkoxycarbonyl group, an aryloxycarbonyl group, a hydroxy group (—OH), a carboxylic acid group (—COOH), a thiol group (—SH), a cyano group (—CN), a halogen atom (a fluorine atom, a chlorine atom, a bromine atom, or an iodine atom), or a combination thereof. On the other hand, when a group is substituted, the form of the group which is included in the definition of a substituent does not include a form which has been further substituted with the group as a substituent. For example, when the substituent is an alkyl group, this alkyl group as a substituent is not further substituted with an alkyl group. However, in some cases, this does not apply when a different substituent is introduced. For example, when an alkyl group is substituted with an aromatic hydrocarbon group, the aromatic hydrocarbon group may also be substituted with an alkyl group.

As used herein, the alkyl group as the substituent may be either a linear or branched alkyl group, for example a linear alkyl group having 1 to 20 carbon atoms or a branched alkyl group having 3 to 20 carbon atoms. Specifically, the alkyl group may be a methyl group, an ethyl group, an n-propyl group, an isopropyl group, an n-butyl group, an isobutyl group, a sec-butyl group, a tert-butyl group, an n-pentyl group, an isopentyl group, a tert-pentyl group, a neopentyl group, a 1,2-dimethylpropyl group, an n-hexyl group, an isohexyl group, a 1,3-dimethylbutyl group, a 1-isopropylpropyl group, a 1,2-dimethylbutyl group, an n-heptyl group, a 1,4-dimethylpentyl group, a 3-ethylpentyl group, a 2-methyl-1-isopropylpropyl group, a 1-ethyl-3-methylbutyl group, an n-octyl group, a 2-ethylhexyl group, a 3-methyl-1-isopropylbutyl group, a 2-methyl-1-isopropylbutyl group, a 1-tert-butyl-2-methylpropyl group, an n-nonyl group, a 3,5,5-trimethylhexyl group, an n-decyl group, an isodecyl group, an n-undecyl group, a 1-methyldecyl group, an n-dodecyl group, an n-tridecyl group, an n-tetradecyl group, an n-pentadecyl group, an n-hexadecyl group, an n-heptadecyl group, an n-octadecyl group, an nonadecyl group, an icosyl group, or the like.

As the substituent, the cycloalkyl group may include for example, a cyclopropyl group, a cyclobutyl group, a cyclopentyl group, a cyclohexyl group, or the like.

The hydroxyalkyl group may be, for example, an alkyl group that is substituted with 1 to 3 (e.g., 1 or 2, and for example 1) hydroxy groups (for example, hydroxymethyl group, hydroxyethyl group, or the like).

The alkoxy group as the substituent may be either a linear or branched alkoxy group, but desirably a linear alkoxy group having 1 to 20 carbon atoms or a branched alkoxy group having 3 to 20 carbon atoms. For example, the alkoxy group may be, for example, a methoxy group, an ethoxy group, a propoxy group, an isopropoxy group, a butoxy group, a pentyloxy group, a hexyloxy group, a heptyloxy group, an octyloxy group, a nonyloxy group, a decyloxy group, an undecyloxy group, a dodecyloxy group, a tridecyloxy group, a tetradecyloxy group, a pentadecyloxy group, a hexadecyloxy group, a heptadecyloxy group, an octadecyloxy group, a 2-ethylhexyloxy group, a 3-ethylpentyloxy group, or the like.

The cycloalkoxy group as a substituent may be, for example, a cyclopropyloxy group, a cyclobutyloxy group, a cyclopentyloxy group, a cyclohexyloxy group, or the like.

The alkenyl group as a substituent may include, for example, a vinyl group, an allyl group, a 1-propenyl group, an isopropenyl group, a 1-butenyl group, a 2-butenyl group, a 3-butenyl group, a 1-pentenyl group, a 2-pentenyl group, a 3-pentenyl group, a 1-hexenyl group, a 2-hexenyl group, a 3-hexenyl group, a 1-heptenyl group, a 2-heptenyl group, a 5-heptenyl group, a 1-octenyl group, a 3-octenyl group, a 5-octenyl group, or the like.

The alkynyl group as a substituent may include, for example, an acetylenyl group, a 1-propynyl group, a 2-propynyl group, a 1-butynyl group, a 2-butynyl group, a 3-butynyl group, a 1-pentetyl group, a 2-pentetyl group, a 3-pentetyl group, 1-hexynyl group, a 2-hexynyl group, a 3-hexynyl group, a 1-heptinyl group, a 2-heptinyl group, a 5-heptinyl group, a 1-octynyl group, a 3-octynyl group, a 5-octynyl group, or the like.

The secondary amino groups as a substituent may include, for example, an alkylamino group having 1 to 10 carbon atoms such as a methylamino group, an ethylamino group, an n-propylamino group, an n-butylamino group, an isobutylamino group, or the like, and a monoarylamino group such as a monophenylamino group, a mononaphthylamino group, or the like.

The tertiary amino group as a substituent may include, for example, a dialkylamino group having 2 to 20 carbon atoms, such as a dimethylamino group, a diethylamino group, a di-n-propylamino group, a di-n-butylamino group, a methylethylamino group, or the like, and a diarylamino group, such as a diphenylamino group, a dinaphthylamino group, or the like.

Examples of an aryl group as a substituent may include, for example, an aryl group having 6 to 30 carbon atoms. For example, the aryl group may include a phenyl group, a naphthyl group, a biphenyl group, a fluorenyl group, an anthryl group, a pyrenyl group, an azulenyl group, an acenaphthyl group, a terphenyl group, a phenanthryl group, or the like.

Examples of the aryloxy group as a substituent may include a phenoxy group, a naphthyloxy group, or the like.

Examples of the alkylthio group as a substituent may include a methylthio group, an ethylthio group, a propylthio group, a pentylthio group, a hexylthio group, an octylthio group, a dodecylthio group, or the like.

Examples of the cycloalkylthio group as a substituent may include a cyclopentylthio group, a cyclohexylthio group, or the like.

Examples of the arylthio group as a substituent may include a phenylthio group, a naphthylthio group, or the like.

Examples of the alkoxycarbonyl group as a substituent may include a methoxycarbonyl group, an ethoxycarbonyl group, a butoxycarbonyl group, an octyloxycarbonyl group, a dodecyloxycarbonyl group, or the like.

Examples of aryloxycarbonyl group as a substituent may include a phenyloxycarbonyl group, a naphthyloxycarbonyl group, or the like.

As used herein, unless otherwise stated, a substituent may include positional isomers. For example, a naphthyl group may be a 1-naphthyl group and/or a 2-naphthyl group, and a biphenyl group may be at least one of (1,1′-biphenyl)-2-yl, (1,1′-biphenyl)-3-yl, or (1,1′-biphenyl)-4-yl.

As used herein, the term “carbon number” for a group that may have substituents means the number of carbons not including the carbons of the substituents, unless otherwise specifically stated.

In chemical formulas used herein, unless otherwise defined, if a chemical bond is not shown at a position where a chemical bond should be indicated, it means that a hydrogen atom is bonded at that position.

As used herein, ‘the substituent is a hydrogen atom’ means that it is unsubstituted.

As used herein, the symbols accompanied by ‘*’ (asterisk) in the text or in chemical formulas indicate a bonding site with another atom.

### Copolymer

The copolymer according to one or more embodiments includes a structural unit represented by Chemical Formula 1, and at least one structural unit of Structural unit A represented by Chemical Formula 2 or Structural unit B represented by Chemical Formula 3.

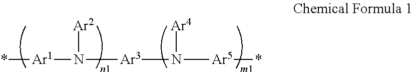

in Chemical Formula 1,
Ar¹, Ar², Ar⁴, and Ar⁵ are, each independently, a substituted or unsubstituted aromatic hydrocarbon ring group, or a substituted or unsubstituted aromatic heterocyclic group,
Ar³ is a substituted or unsubstituted carbazole, a substituted or unsubstituted fluorene, a substituted or unsubstituted benzene, or a substituted or unsubstituted biphenylene group, wherein when Ar³ is a substituted or unsubstituted benzene, or a substituted or unsubstituted biphenylene group, then at least one of Ar¹ or Ar² is not a substituted or unsubstituted benzene, and at least one of Ar⁴ or Ar⁵ is not a substituted or unsubstituted benzene,
n1 is an integer of greater than or equal to 1 and less than or equal to 3,
m1 is an integer of greater than or equal to 1 and less than or equal to 3, and
* is a bonding position to an adjacent atom;

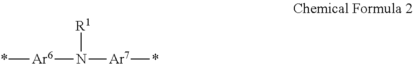

in Chemical Formula 2,
Ar⁶ and Ar⁷ are, each independently, a substituted or unsubstituted aromatic hydrocarbon ring group, or a substituted or unsubstituted aromatic heterocyclic group, and Ar⁶ and Ar⁷ optionally form a ring together,
R¹ is a group represented by chemical formula (2-a), and
* is a bonding position to an adjacent atom,

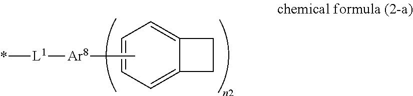

in chemical formula (2-a)
L¹ is a single bond, or a group represented by chemical formula (2-b),
Ar⁸ is a substituted or unsubstituted aromatic hydrocarbon ring group, or a substituted or unsubstituted aromatic heterocyclic group,
wherein when L¹ is a single bond, at least one of Ar⁶, Ar⁷, or Ar⁸ is not a substituted or unsubstituted benzene, and Ar⁸ optionally forms a ring together with at least one of Ar⁶ or Ar⁷
n2 is an integer of greater than or equal to 2 and less than or equal to 5, and
* is a bonding position to an adjacent atom,

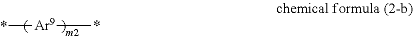

in chemical formula (2-b),
Ar⁹ is a substituted or unsubstituted aromatic hydrocarbon ring group, or a substituted or unsubstituted aromatic heterocyclic group, and wherein Ar⁹ optionally forms a ring together with at least one of Ar⁶ or Ar⁷,
m2 is an integer of greater than or equal to 1 and less than or equal to 5,
when m2 is an integer of greater than or equal to 2, each Ar⁹ is the same or different,
* is a bonding position to an adjacent atom;

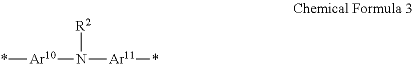

in Chemical Formula 3,
Ar¹⁰ and Ar¹¹ are, each independently, a substituted or unsubstituted aromatic hydrocarbon ring group, or a substituted or unsubstituted aromatic heterocyclic group, and Ar¹⁰ and Ar¹¹ optionally form a ring together,
R² is a group represented by chemical formula (3-a) or chemical formula (3-b), and
* is a bonding position to an adjacent atom;

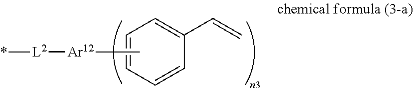

in chemical formula (3-a),
Ar¹² is a substituted or unsubstituted aromatic hydrocarbon ring group, or a substituted or unsubstituted aromatic heterocyclic group,
wherein when L² is a single bond, Ar¹² optionally forms a ring together with at least one of Ar¹⁰ or Ar¹¹,
n3 is an integer of greater than or equal to 2 and less than or equal to 5, and
* is a bonding position to an adjacent atom;

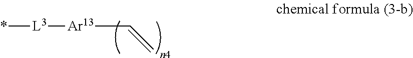

in chemical formula (3-b),
L³ is a single bond, or a group represented by chemical formula (3-c),
Ar¹³ is a substituted or unsubstituted aromatic hydrocarbon ring group, or a substituted or unsubstituted aromatic heterocyclic group,
wherein when L³ is a single bond, Ar¹³ optionally forms a ring together with at least one of Ar¹⁰ or Ar¹¹,
n4 is an integer of greater than or equal to 2 and less than or equal to 5, and
* is a bonding position to an adjacent atom;

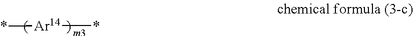

in chemical formula (3-c),
Ar¹⁴ is a substituted or unsubstituted aromatic hydrocarbon ring group, or a substituted or unsubstituted aromatic heterocyclic group, or wherein Ar¹⁴ forms a ring together with at least one of Ar¹⁰ or Ar¹¹,
m3 is an integer of greater than or equal to 1 and less than or equal to 5, and when m3 is an integer of greater than or equal to 2, each Ar¹⁴ is the same or different, and
* is a bonding position to an adjacent atom;

The structural unit represented by Chemical Formula 1 of the copolymer may be included alone, or in a combination of two or more types of structural units.

When the copolymer includes two or more types of the structural units represented by Chemical Formula 1, the two or more types of the structural units may be arranged in block form, in random form, in alternating form, or in periodic form.

In Chemical Formula 1, Ar¹, Ar², Ar⁴, and Ar⁵ are, each independently, a substituted or unsubstituted aromatic hydrocarbon ring group, or a substituted or unsubstituted aromatic heterocyclic group.

An aromatic hydrocarbon ring group may represent a group derived from a hydrocarbon ring that is aromatic in whole or in part. If there are two or more aromatic hydrocarbon rings, which are partially or entirely aromatic, these rings may be bonded to each other by a single bond, or condensed. The number of ring-forming atoms of the aromatic hydrocarbon group may be greater than or equal to 6 and less than or equal to 14. Non-limiting examples of the aromatic hydrocarbon group may include a benzene ring group, a biphenyl ring group, a naphthalene ring group, a fluorene ring group, an anthracene ring group, a phenanthrene ring group, a perylene ring group, a tetracene ring group, a pyrene ring group, a benzopyrene ring group, a chrysene ring group, a triphenylene ring group, an acenaphthene ring group, a fluoranthene ring group, or the like.

An aromatic heterocyclic group represents a group derived from a heterocycle having aromaticity. As used herein, a heterocycle having aromaticity represents, in part or in whole, a heterocycle having aromaticity. When a part of a heterocycle having aromaticity possesses aromaticity, the aromaticity may originate from the heterocyclic portion of the ring or from the hydrocarbon portion of the ring. An heterocycle having aromaticity may include a ring with aromaticity, not particularly limited, but for example, having one or more heteroatoms (for example, nitrogen atom (N), oxygen atom (O), phosphorus atom (P), sulfur atom(S), silicon atom (Si), or the like) as ring-forming atoms, while the remaining ring-forming atoms are carbon atoms (C). Also, there are cases where a carbon atom forming a ring structure are part of a ketone group (C═O), thione group (C═S), or C═NH group, or where a sulfur atom forming a ring structure are part of a sulfinyl group (S═O) or sulfonyl group (O═S═O), meaning that an atom forming a ring structure may be bonded to an atom outside the ring through a double bond. In this case, as used herein, an atom outside the ring that forms a double bond with an atom constituting the ring structure is considered a part of a heterocycle having aromaticity. In addition, when an atom outside the ring that forms a double bond is bonded to a hydrogen atom through a single bond, the hydrogen atom is also considered part of a heterocycle having aromaticity.

Non-limiting examples of aromatic heterocycles may include, for example, a pyridine ring, a pyrazine ring, a pyridazine ring, a pyrimidine ring, a triazine ring, a quinoline ring, an isoquinoline ring, a quinoxaline ring, a quinazoline ring, a naphthyridine ring, an acridine ring, a phenazine ring, a benzoquinoline ring, a benzoisoquinoline ring, a phenanthridine ring, a phenanthroline ring, a benzoquinone ring, a coumarin ring, an anthraquinone ring, a fluorenone ring, a furan ring, a thiophene ring, a benzofuran ring, a benzothiophene ring, a dibenzofuran ring, a dibenzothiophene ring, a pyrrole ring, an indole ring, a carbazole ring, an indolocarbazole ring, an imidazole ring, a benzimidazole ring, a pyrazole ring, an indazole ring, an oxazole ring, an isoxazole ring, a benzoxazole ring, a benzoisoxazole ring, a thiazole ring, an isothiazole ring, a benzothiazole ring, a benzoisothiazole ring, an imidazolinone ring, a benzimidazolinone ring, an imidazopyridine ring, an imidazopyrimidine ring, an imidazophenanthrene ring, a benzimiazophenanthrine ring, an azadibenzofuran ring, an azacarbazole ring, an azadibenzothiophene ring, a diazadibenzofuran ring, a diazacarbazole ring, a diazadibenzothiophene ring, a xanthone ring, a thioxanthone ring, or the like, or a combination thereof.

When an aromatic heterocyclic group contains two or more heterocycles having aromaticity, these rings may be bonded to each other through a single bond or may be fused together. Also, when a monovalent aromatic heterocyclic group contains two or more heterocycles having aromaticity, an atom may serve as a ring-forming atom for any of these rings.

The number of ring-forming atoms in an aromatic heterocyclic group (the total of ring-forming carbon atoms and ring-forming heteroatoms) is not particularly limited, but it may be greater than or equal to 3 and less than or equal to 30. For example, the number of ring-forming atoms in an aromatic heterocyclic group may be, from the same perspective, greater than or equal to 5 and less than or equal to 20, or, for example, greater than or equal to 6 and less than or equal to 14. The number of ring-forming heteroatoms in an aromatic heterocyclic ring is not particularly limited, but may be greater than or equal to 1 and less than or equal to 10. Further, from the same perspective, the number of ring-forming heteroatoms in an aromatic heterocyclic ring may be greater than or equal to 1 and less than or equal to 5, or, for example, greater than or equal to 1 and less than or equal to 3. As mentioned above, a ring-forming atom refers to an atom that directly forms the ring structure. Accordingly, in the case where there is an atom outside the ring that forms a double bond with an atom constituting the ring structure, the aforementioned atom is not included among the ring-forming atoms.

Among the above-mentioned aromatic heterocycle groups, from the perspective of further enhancing the effects of one or more embodiments, Ar¹, Ar², Ar⁴, and Ar⁵ may, each independently, be a dibenzofuran ring group or a dibenzothiophene ring group.

In Chemical Formula 1, Ar³ is a substituted or unsubstituted carbazole ring group, a substituted or unsubstituted fluorene ring group, a substituted or unsubstituted benzene group, or a substituted or unsubstituted biphenylene group. In this case, when Ar³ is a substituted or unsubstituted benzene group, or a substituted or unsubstituted biphenylene group, then Ar¹ is not a substituted or unsubstituted benzene ring group, Ar² is not a substituted or unsubstituted benzene ring group, Ar⁴ is not a substituted or unsubstituted benzene ring group, and Ar⁵ is not a substituted or unsubstituted benzene ring group.

In one or more embodiments, the structural unit represented by Chemical Formula 1 may be selected from Group (1-1) to Group (1-3):

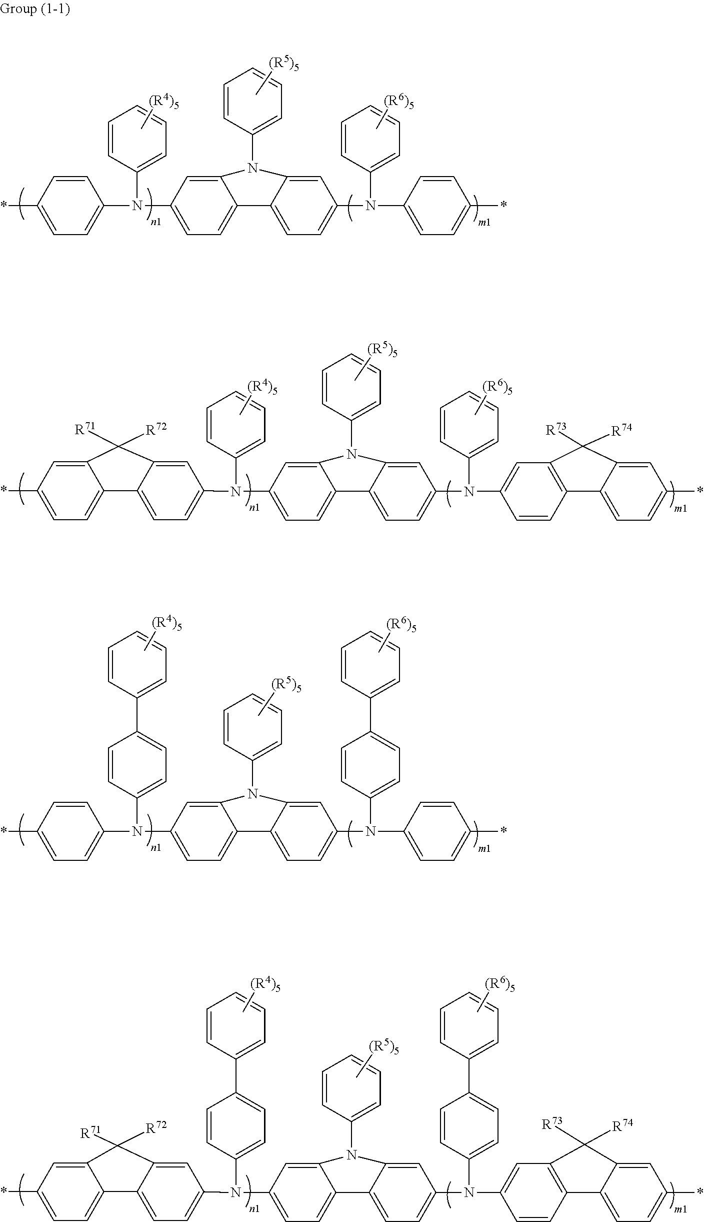

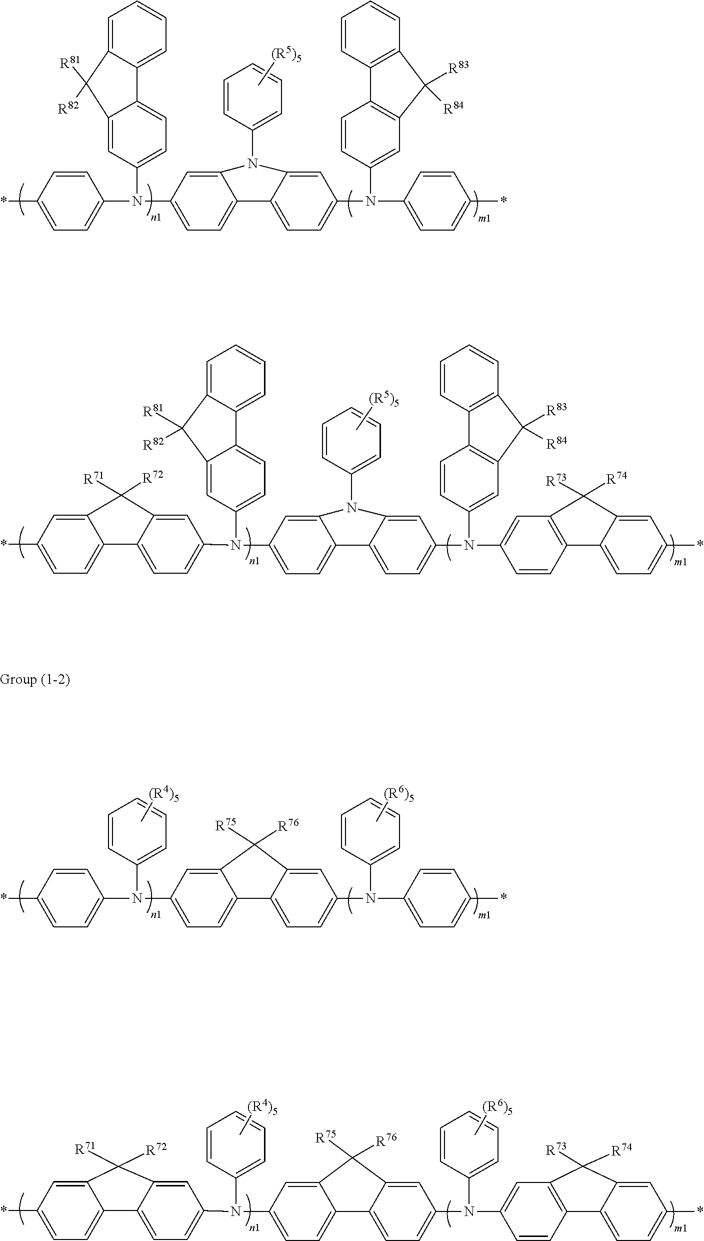

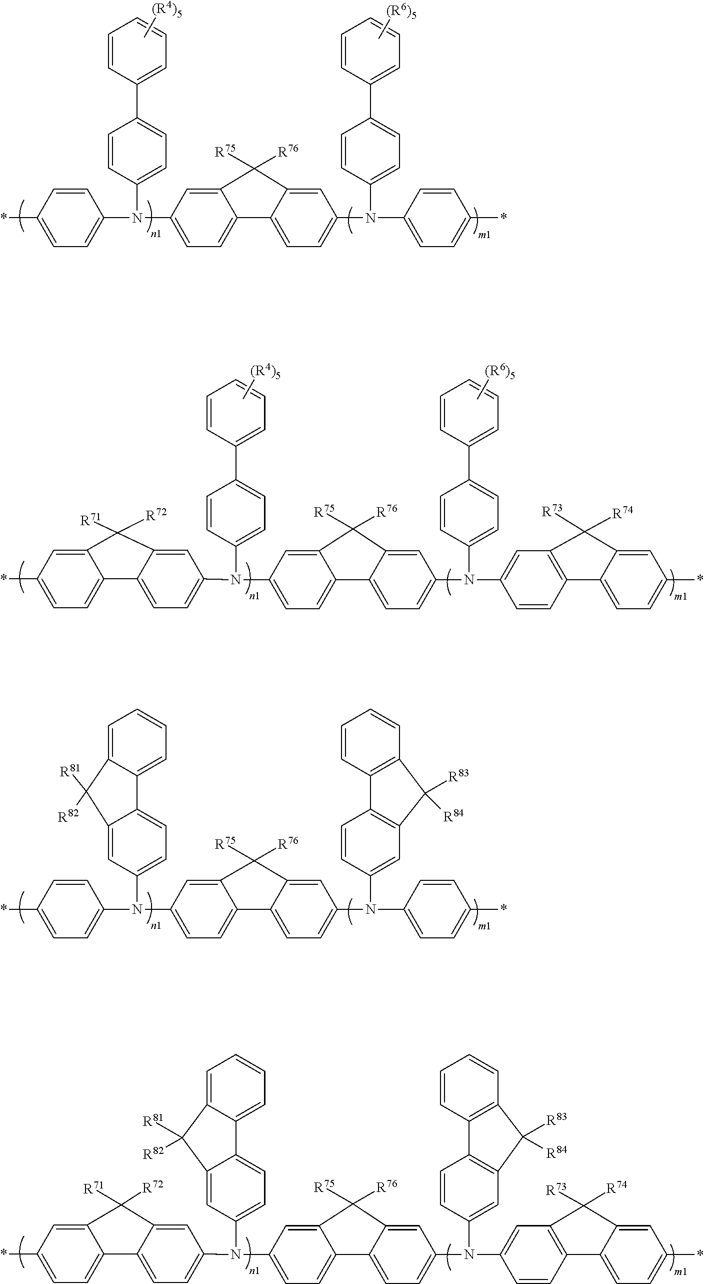

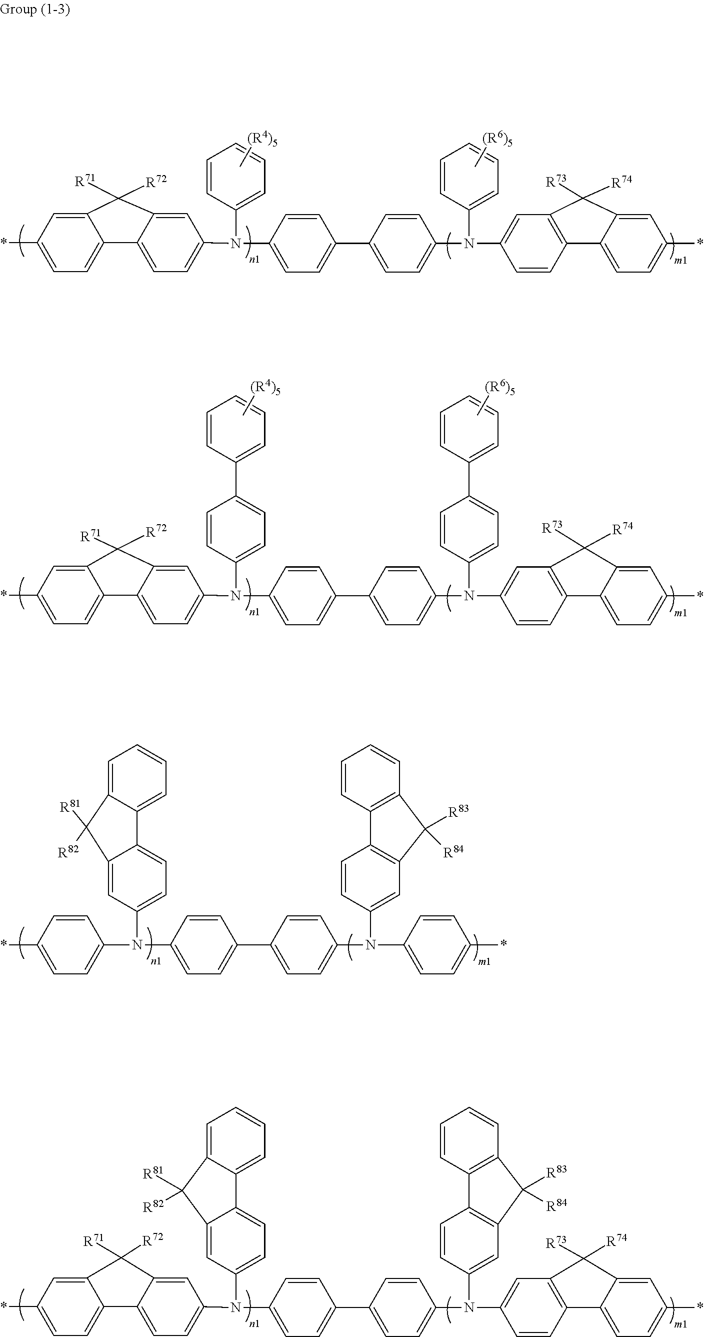

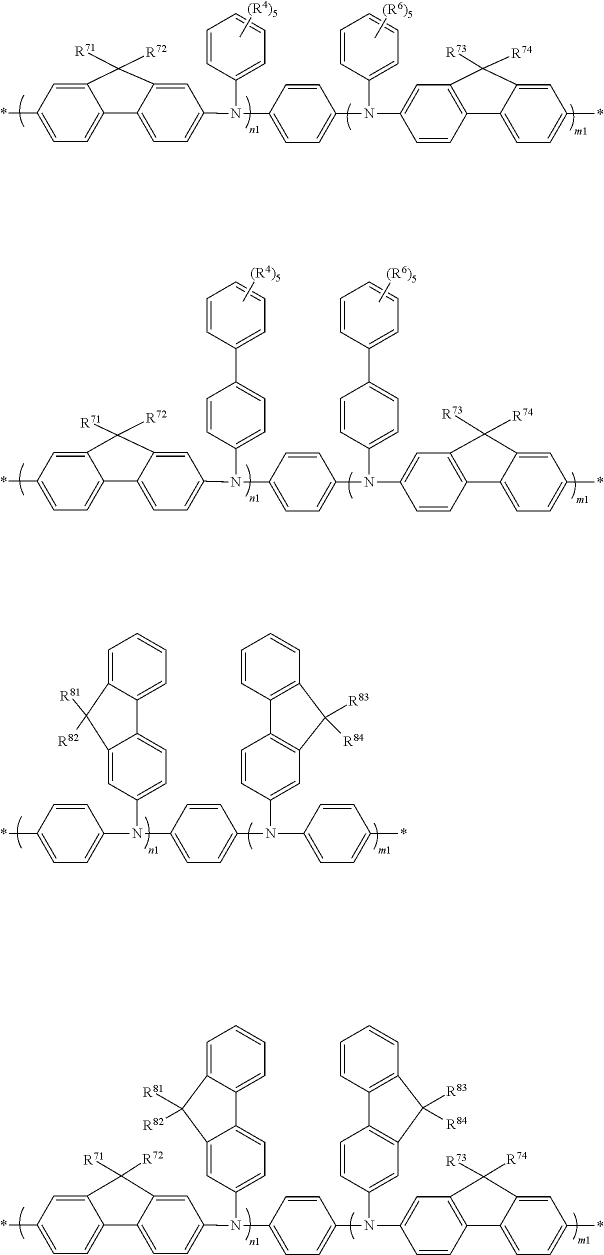

In Group (1-1) to Group (1-3),
R⁴ to R⁶, R⁷¹ to R⁷⁶, and R⁸¹ to R⁸⁴, may, each independently, be a hydrogen atom, or a hydrocarbon group having 1 to 20 carbon atoms,
each n1 may represent an integer of greater than or equal to 1 and less than or equal to 3,
each m1 may represent an integer of greater than or equal to 1 and less than or equal to 3, and
* is a bonding position to an adjacent atom.

Examples of the hydrocarbon groups used for R⁴ to R⁶, R⁷¹ to R⁷⁶, or R⁸¹ to R⁸⁴, may include an alkyl group, a cycloalkyl group, an alkenyl group, an alkynyl group, or an aryl group. Examples of these hydrocarbon groups are the same as those exemplified in the substituents described herein.

The copolymer further includes at least one structural unit of Structural unit A represented by Chemical Formula 2, or Structural unit B represented by Chemical Formula 3, in addition to the structural unit represented by Chemical Formula 1:

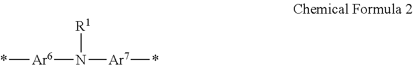

in Chemical Formula 2,
Ar⁶ and Ar⁷ are, each independently, a substituted or unsubstituted aromatic hydrocarbon ring group, or a substitution or unsubstituted aromatic heterocyclic group, and Ar⁶ and Ar⁷ optionally form a ring together,
R¹ is a group represented by chemical formula (2-a), and
* is a bonding position to an adjacent atom;

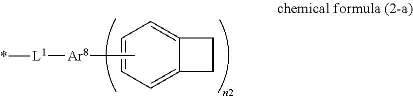

in chemical formula (2-a),
L¹ is a single bond, or a group represented by chemical formula (2-b),
Ar⁸ is a substituted or unsubstituted aromatic hydrocarbon ring group, or a substituted or unsubstituted aromatic heterocyclic group,
wherein when L¹ is a single bond, at least one of Ar⁶, Ar⁷ or Ar⁸ is not a substituted or unsubstituted benzene ring, and Ar⁸ optionally forms a ring together with at least one of Ar⁶ or Ar⁷,
n2 is an integer of greater than or equal to 2 and less than or equal to 5, and
* is a bonding position to an adjacent atom;

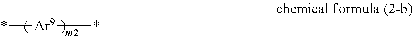

in chemical formula (2-b),
Ar⁹ is a substituted or unsubstituted aromatic hydrocarbon ring group, or a substituted or unsubstituted aromatic heterocyclic group, or Ar⁹ optionally forms a ring with at least one of Ar⁶ or Ar⁷,
m2 is an integer of greater than or equal to 1 and less than or equal to 5, and when m2 is an integer of greater than or equal to 2, each Ar⁹ is the same or different,
* is a bonding position to an adjacent atom,

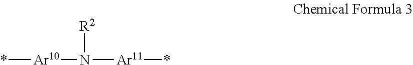

in Chemical Formula 3,
Ar¹⁰ and Ar¹¹ are, each independently, a substituted or unsubstituted aromatic hydrocarbon ring group, or a substitution or unsubstituted aromatic heterocyclic group, and Ar¹⁰ and Ar¹¹ optionally form a ring together,
R² is a group represented by chemical formula (3-a) or chemical formula (3-b), and
* is a bonding position to an adjacent atom;

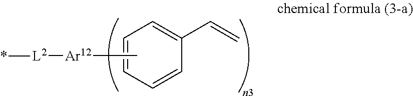

in chemical formula (3-a),
L² is a single bond, or a group represented by chemical formula (3-c),
Ar¹² is a substituted or unsubstituted aromatic hydrocarbon ring group, or a substituted or unsubstituted aromatic heterocyclic group, and
wherein when L² is a single bond, Ar¹² optionally forms a ring together with at least one of Ar¹⁰ or Ar¹¹,
n3 is an integer of greater than or equal to 2 and less than or equal to 5, and
* is a bonding position to an adjacent atom;

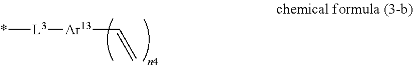

in chemical formula (3-b),
L³ is a single bond, or a group represented by chemical formula (3-c),
Ar¹³ is a substituted or unsubstituted aromatic hydrocarbon ring group, or a substituted or unsubstituted aromatic heterocyclic group,
wherein when L³ is a single bond, Ar¹³ optionally forms a ring together with at least one of Ar¹⁰ or Ar¹¹,
n4 is an integer of greater than or equal to 2 and less than or equal to 5, and
* is a bonding position to an adjacent atom;

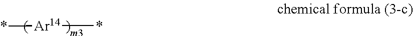

in chemical formula (3-c),
Ar¹⁴ is a substituted or unsubstituted aromatic hydrocarbon ring group, or a substituted or unsubstituted aromatic heterocyclic group, or Ar¹⁴ optionally forms a ring with at least one of Ar¹⁰ or Ar¹¹,
m3 is an integer of greater than or equal to 1 and less than or equal to 5, wherein when m3 is an integer of greater than or equal to 2, each Ar¹⁴ is the same or different, and
* is a bonding position to an adjacent atom.

The definitions and examples of aromatic hydrocarbon ring group and aromatic heterocyclic group of Ar⁶ and Ar⁷ of Chemical Formula 2, Ar⁸ of chemical formula (2-a), Ar⁹ of chemical formula (2-b), Ar¹⁰ and Ar¹¹ of Chemical Formula 3, Ar¹² of chemical formula (3-a), Ar¹³ of chemical formula (3-b), and Ar¹⁴ of chemical formula (3-c) are the same as those described in Chemical Formula 1.

When L¹ of chemical formula (2-a) is a single bond, at least one of Ar⁶, Ar⁷ and Ar⁸ is not a substituted or unsubstituted benzene ring.

The Structural unit A represented by Chemical Formula 2 may be included alone, or in a combination of two or more types of structural units. Further, the Structural unit B represented by Chemical Formula 3 may be included alone, or in a combination of two or more types of structural units.

When the copolymer includes two or more types of the Structural units A represented by Chemical Formula 2, the two or more types of the Structural units A may be arranged in block form, in random form, in alternating form, or in periodic form. In the same manner, when the copolymer includes two or more types of the Structural units B represented by Chemical Formula 3, the two or more types of the Structural units B may be arranged in block form, in random form, in alternating form, or in periodic form. Further, when the copolymer includes both the Structural unit A and Structural unit B represented by Chemical Formula 2 and Chemical Formula 3, respectively, the Structural unit A and Structural unit B may be arranged in block form, in random form, in alternating form, or in periodic form.

Further, the structural unit represented by Chemical Formula 1, and at least one structural unit of Structural unit A and Structural unit B may be arranged in block form, in random form, in alternating form, or in periodic form.

The Structural unit A represented by Chemical Formula 2 may be selected from Group 2, and embodiments are not limited thereto:

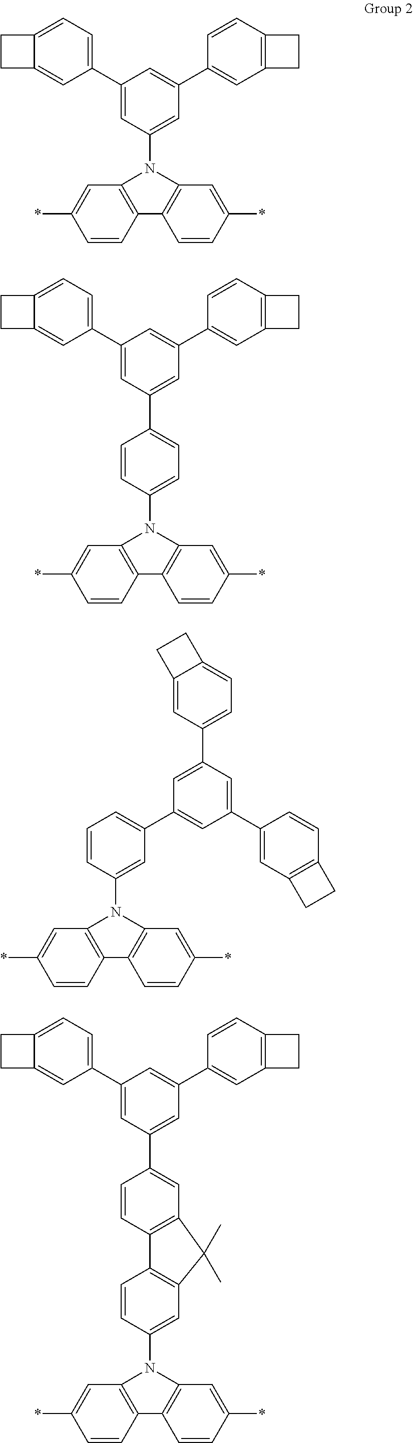

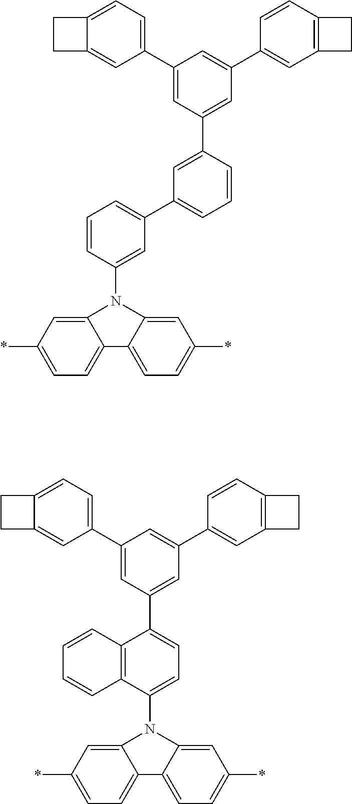

The Structural unit B represented by Chemical Formula 3 may be selected from Group 3, and embodiments are not limited thereto:

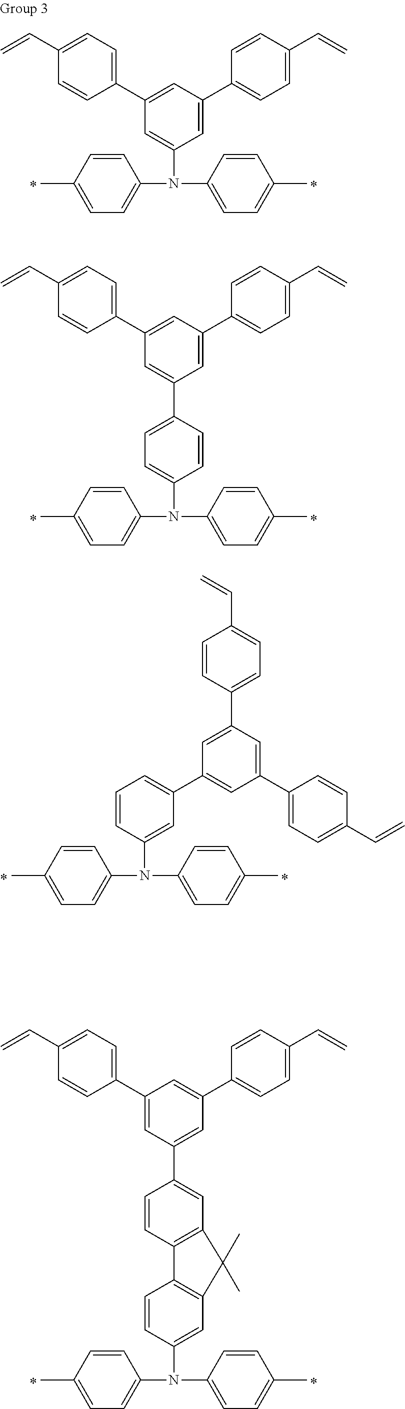

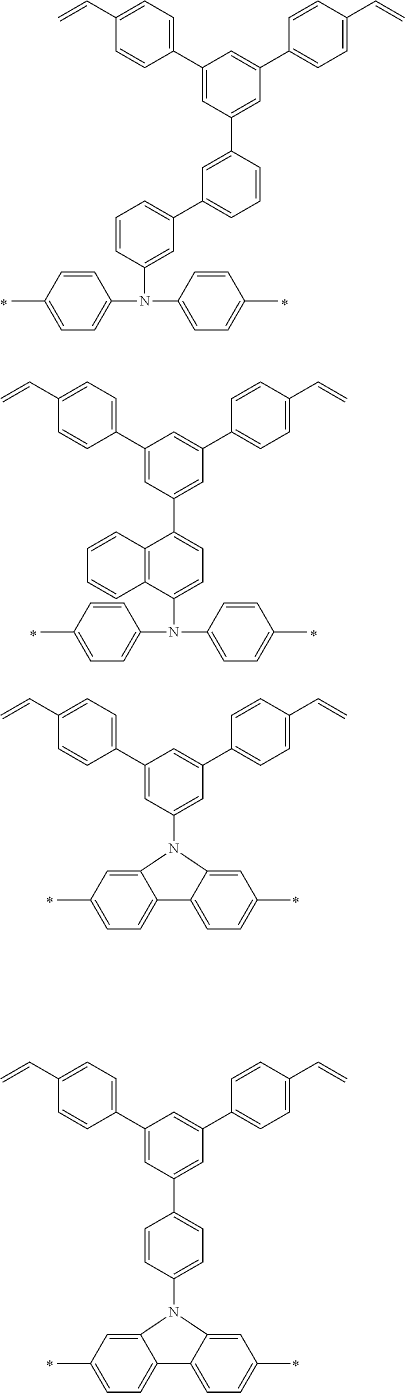

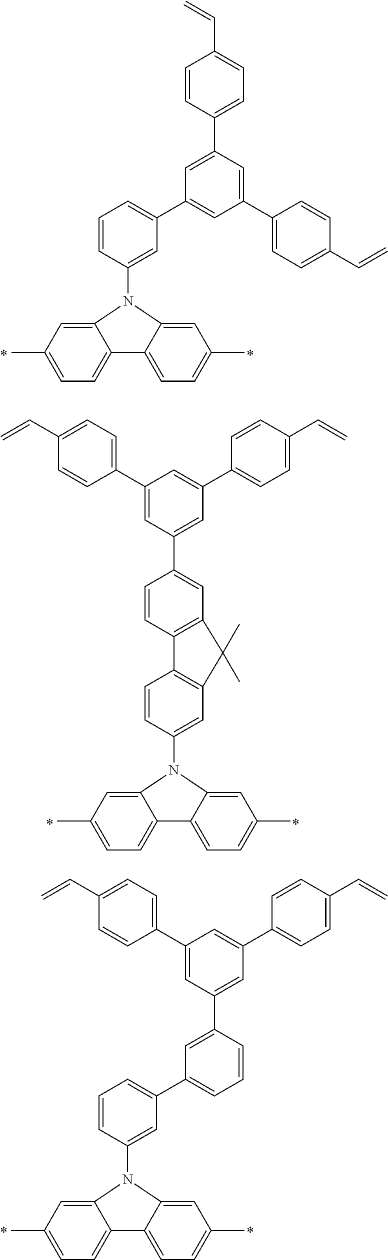

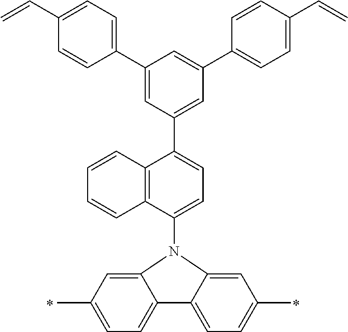

A mole ratio of the structural unit represented by Chemical Formula 1 may be greater than or equal to about 20 mole % and less than or equal to about 99 mole %, for example, greater than or equal to about 50 mole % and less than or equal to about 95 mole %, based on a total number of moles of the structural unit represented by Chemical Formula 1, Structural unit A represented by Chemical Formula 2, and Structural unit B represented by Chemical Formula 3 in the copolymer.

A mole ratio of the at least one of Structural unit A represented by Chemical Formula 2 or Structural unit B represented by Chemical Formula 3 may be greater than or equal to about 1 mole % and less than or equal to about 80 mole %, for example, greater than or equal to about 5 mole % and less than or equal to about 50 mole %, based on a total number of moles of the structural unit represented by Chemical Formula 1, Structural unit A represented by Chemical Formula 2, and Structural unit B represented by Chemical Formula 3 in the copolymer.

Examples of the copolymer of one or more embodiments may be represented below, but embodiments are not limited thereto.

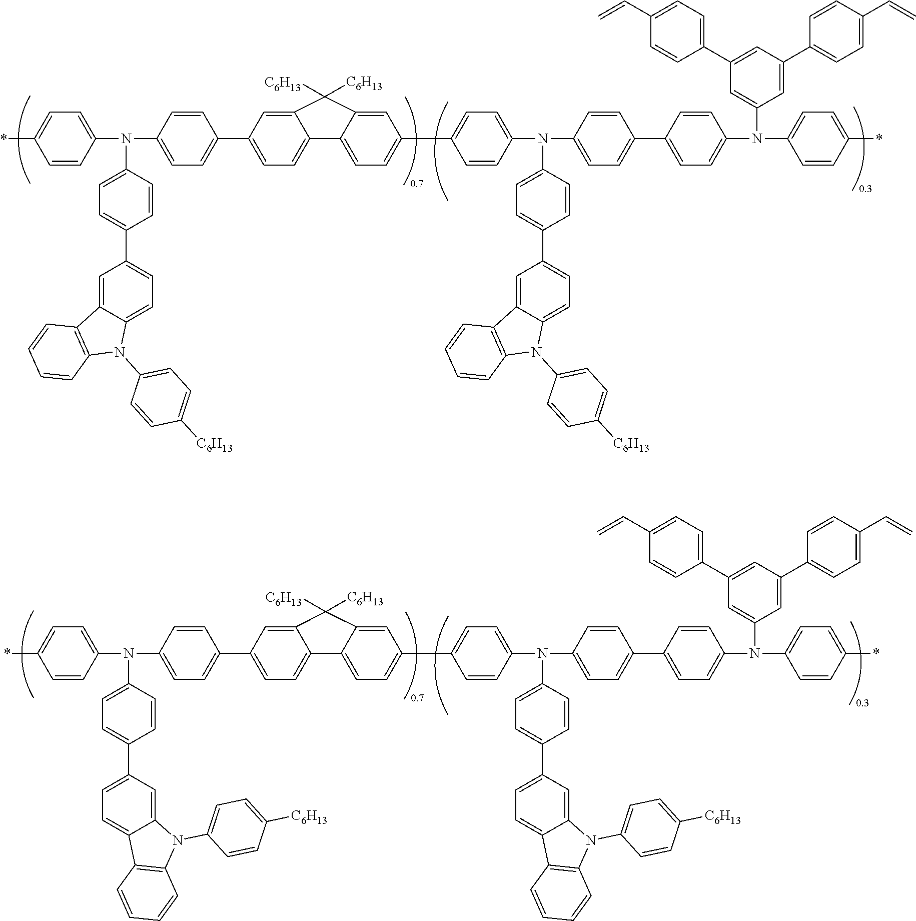

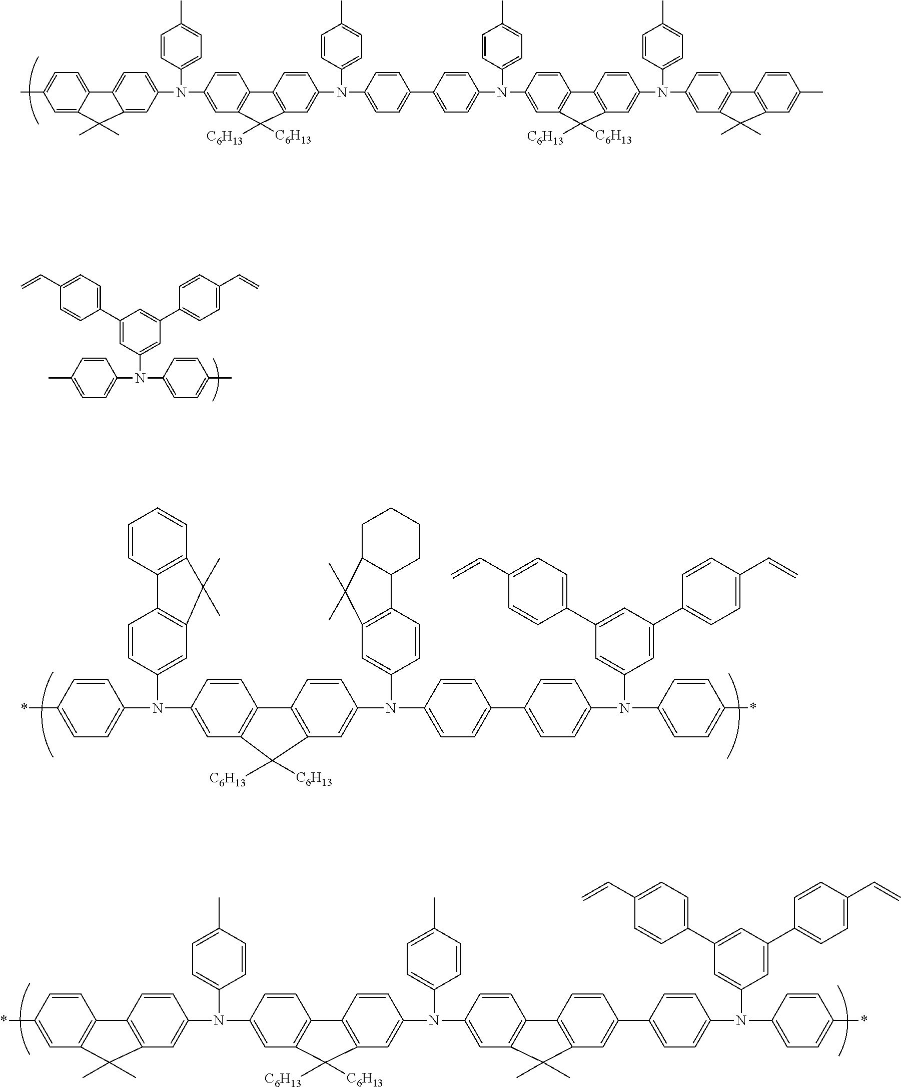

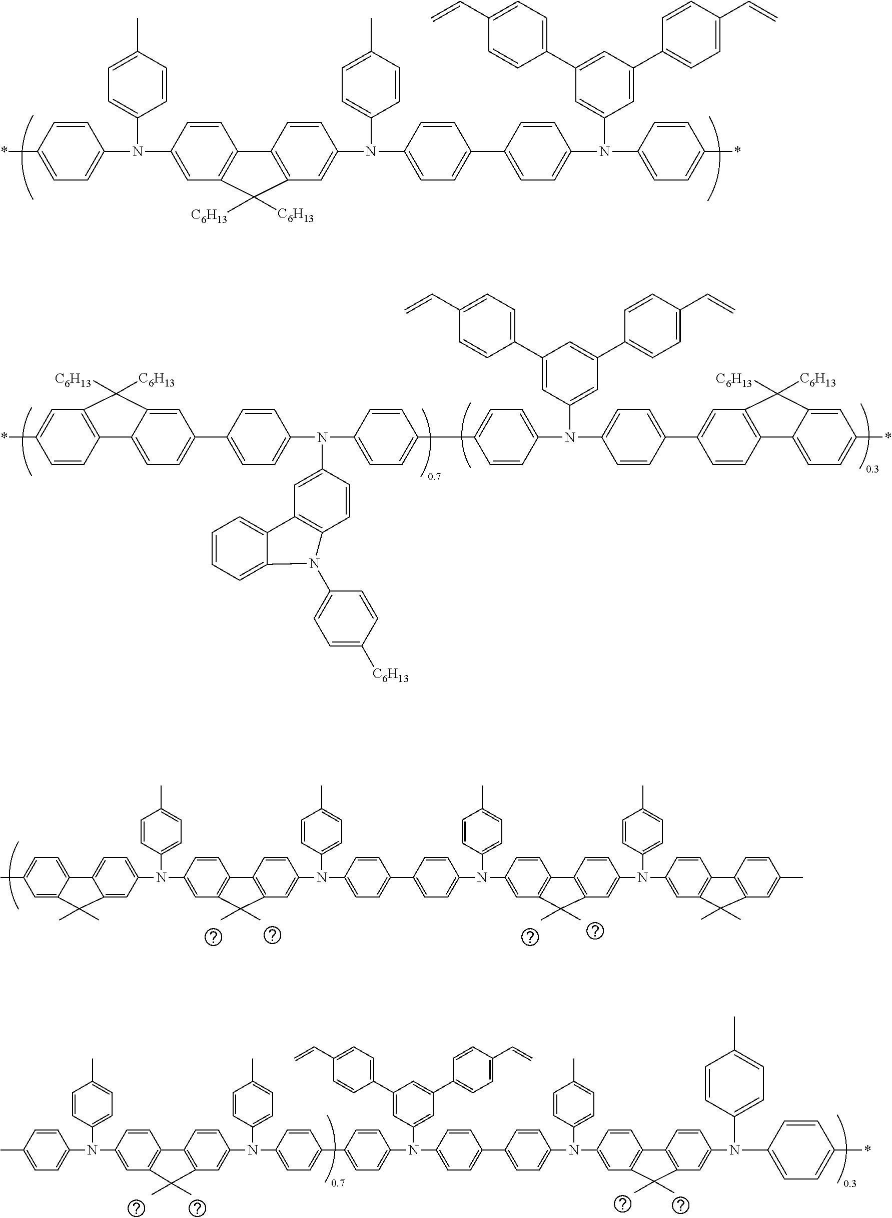

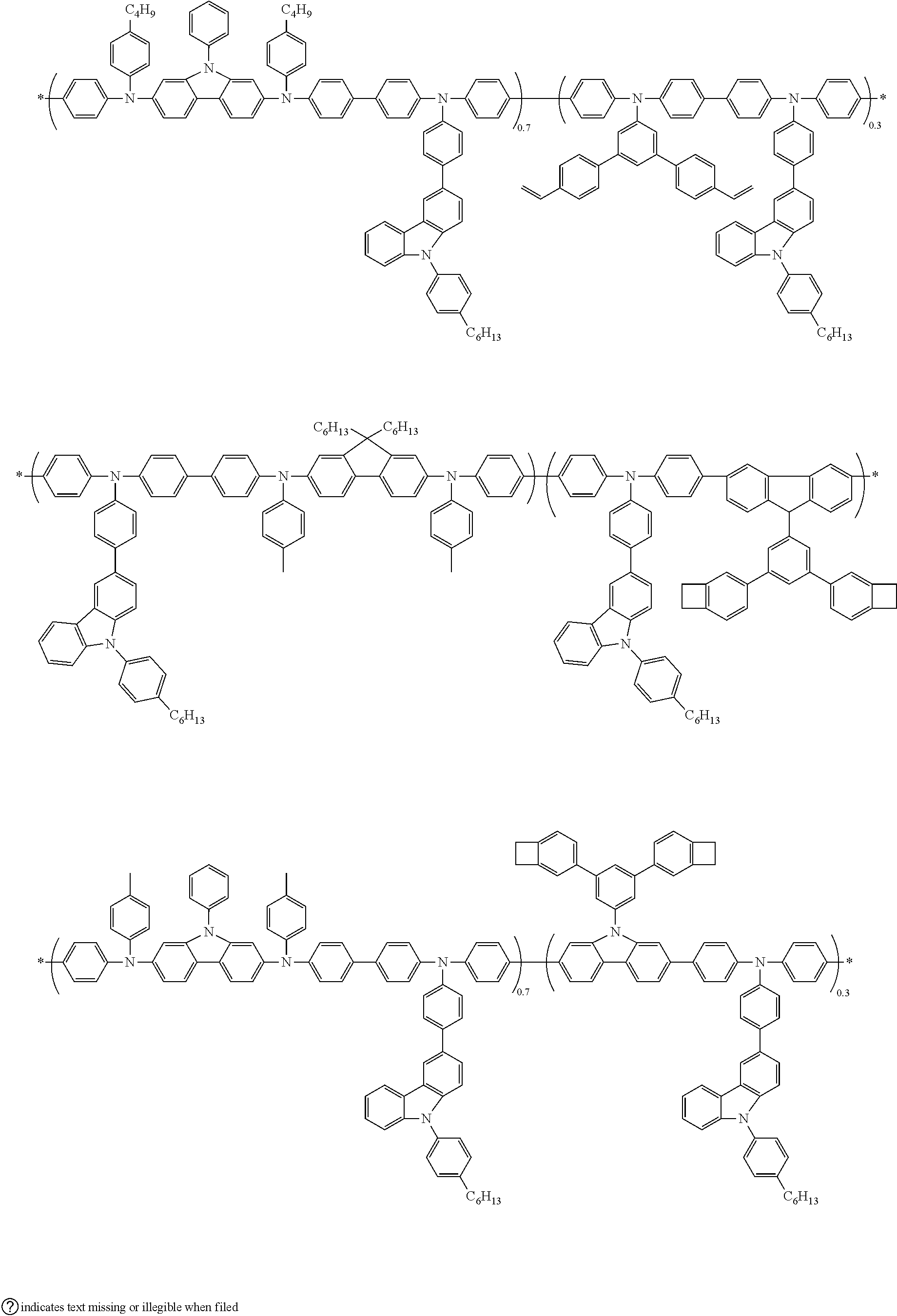

In the above chemical formulae, each * is a bonding position to an adjacent atom.

A weight average molecular weight (Mw) of the copolymer according to one or more embodiments is not particularly limited, as long as an effect of the objectives of an embodiment is achieved. The weight average molecular weight (Mw) of the copolymer may be, for example, greater than or equal to about 8,000 Dalton (Da) and less than or equal to about 500,000 Da, for example, greater than or equal to about 12,000 Da and less than or equal to about 400,000 Da, greater than or equal to about 15,000 Da and less than or equal to about 300,000 Da, greater than or equal to about 18,000 Da and less than or equal to about 200,000 Da, or, for example, greater than or equal to about 20,000 Da and less than or equal to about 100,000 Da. Within the above range of weight average molecular weight of the copolymer, a layer (e.g., a hole injection layer, hole transporting layer, etc.) having homogenous thickness may be prepared with a coating solution containing the copolymer by adjusting viscosity of the coating solution.

A number average molecular weight (Mn) of the copolymer according to one or more embodiments is not particularly limited, as long as an effect of the objectives of an embodiment is achieved. The number average molecular weight of the copolymer may be, for example, greater than or equal to about 3,000 Da and less than or equal to about 250,000 Da, for example, greater than or equal to about 4,000 Da and less than or equal to about 200,000 Da, greater than or equal to about 5,000 Da and less than or equal to about 150,000 Da, greater than or equal to about 6,000 Da and less than or equal to about 100,000 Da, or, for example, greater than or equal to about 8,000 Da and less than or equal to about 100,000 Da. Within the above range of number average molecular weight of the copolymer, a layer (e.g., a hole injection layer, hole transporting layer, etc.) having homogenous thickness may be prepared with a coating solution containing the copolymer by adjusting viscosity of the coating solution.

Further, a polydispersity (Mw/Mn) of the copolymer may be, for example, greater than or equal to about 1.2 and less than or equal to about 6.0, for example, greater than or equal to about 1.2 and less than or equal to about 4.0, or, for example, greater than or equal to about 1.5 and less than or equal to about 3.5.

As used herein, the measurement of number average molecular weight (Mn) and weight average molecular weight (Mw) is not particularly limited, and may be carried out using a known method or by appropriately modifying a known method. As used herein, the number average molecular weight and weight average molecular weight adopt the values measured by the following method. In addition, the polydispersity (Mw/Mn) of the copolymer can be calculated by dividing the weight average molecular weight by the number average molecular weight measured by the following method.

### (Measurement of Number Average Molecular Weight (Mn) and Weight Average Molecular Weight (Mw))

The number average molecular weight (Mn) and weight average molecular weight (Mw) of a copolymer was measured by SEC (Size Exclusion Chromatography) using polystyrene as a standard material under the following conditions:

### (SEC Measurement Condition)

Analysis equipment (SEC): Shimadzu Corporation, Prominence (registered trademark)
Column: Polymer Laboratories, PLgel MIXED-B
Column temperature: 40° C.
Flow rate: 1.0 mL/min
Injection amount of sample solution: 20 μL (concentration of copolymer: about 0.05 weight %)
Eluent: tetrahydrofuran (THF)
Detector (UV-VIS detector): Shimadzu Corporation
Standard sample: polystyrene.

The terminal end of the main chain of the copolymer according to one or more embodiments is not particularly limited and is appropriately defined depending on the type of raw material used, but is usually a hydrogen atom.

The copolymer according to one or more embodiments may be used alone, or in a combination of two or more types of copolymers. Further, the copolymer according to one or more embodiments may be synthesized by using a known synthesis method. For example, the copolymer of one or more embodiments may be synthesized by a person of an ordinary skill in the art by referring to the examples to be described herein. For example, in the method described in the examples, the copolymer may be synthesized by changing raw materials or reaction conditions, adding or omitting some steps, or appropriately combining known synthesis methods.

The method for confirming the structure of a monomer or a copolymer according to one or more embodiments is not particularly limited. The structure of the monomer or the copolymer may be confirmed, for example, by known methods (for example, NMR, LC-MS, etc.).

Ionization potential of the copolymer, in terms of the difference from the electron affinity of the borate anion being within a specific range and from the perspective of further improving resistance to positive aging, for example, may be greater than or equal to about 4.60 eV and less than or equal to about 5.70 eV. For example, ionization potential of the copolymer may be greater than or equal to about 4.70 eV and less than or equal to about 5.60 eV, for example, greater than or equal to about 4.80 eV and less than or equal to about 5.50 eV. The ionization potential may be controlled by the adjustment of the HOMO level of the copolymer through the introduction of electron-donating groups. In addition, the ionization potential may be calculated from molecular orbital calculations, and can, for example, be calculated by the method described in the examples.

An amount of the copolymer in a composition according to an embodiment may be greater than or equal to about 30 wt % and less than or equal to about 99 wt %, for example, greater than or equal to about 50 wt % and less than or equal to about 95 wt %, or, for example, greater than or equal to about 70 wt % and less than or equal to about 90 wt %, each based on the total weight of the composition.

### Salt Compound

The composition according to an aspect also includes a salt compound including a borate anion represented by Chemical Formula 4 and an iodonium cation:

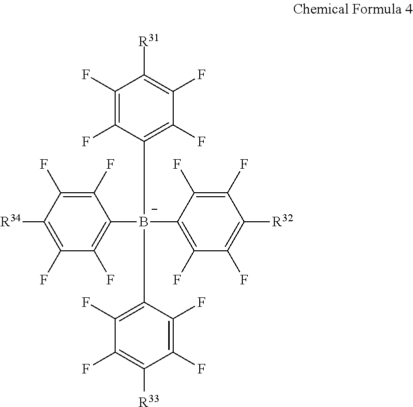

in Chemical Formula 4,
R³¹ to R³⁴ are, each independently, a hydrogen atom, a fluorine atom, or a group represented by chemical formula (4-a):

*-L⁴-(Ar¹⁵)ₙ₆—(X)ₙ₅ chemical formula (4-a)
in chemical formula (4-a),
L⁴ is a single bond, or a group represented by the chemical formula (4-b),
Ar¹⁵ is a substituted or unsubstituted aromatic hydrocarbon ring group, or substituted or unsubstituted aromatic heterocyclic group,
X is a fluorine atom, or a group represented in Group (4-1),
n5 is an integer of greater than or equal to 1 and less than or equal to 5, and
n6 is an integer of 0 or 1, wherein,
when multiple groups represented by chemical formula (4-a) are present, each L⁴ is the same or different,
when multiple groups represented by chemical formula (4-a) are present, each Ar¹⁵ is the same or different,
when multiple groups represented by chemical formula (4-a) are present, each X is the same or different,
when multiple groups represented by chemical formula (4-a) are present, each n5 is the same or different,
when multiple groups represented by chemical formula (4-a) are present, each n6 is the same or different,
when n5 is an integer of greater than or equal to 2, each X is the same or different, and
* is a bonding position to an adjacent atom,

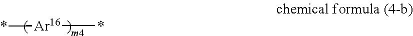

in chemical formula (4-b),
Ar¹⁶ is a substituted or unsubstituted aromatic hydrocarbon ring group, or a substituted or unsubstituted aromatic heterocyclic group,
m4 is an integer of greater than or equal to 1 and less than or equal to 5, and when m4 is an integer of greater than or equal to 2, each Ar¹⁶ is the same or different, and
* is a bonding position to an adjacent atom,

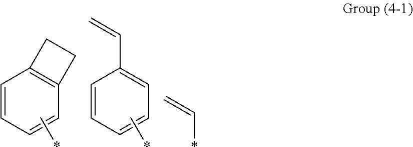

in Group (4-1),
* is a bonding position to an adjacent atom.

The aromatic hydrocarbon group and aromatic heterocyclic group of Ar¹⁵ of chemical formula (4-a) and Ar¹⁶ of chemical formula (4-b) are the same as those described in the descriptions regarding Chemical Formula 1, and thus, explanations in detail are omitted herein.

At least one of R³¹ to R³⁴ in Chemical Formula 4 may be a group represented by chemical formula (4-a) in terms of further improving resistance to a solvent.

R³¹ to R³⁴ in Chemical Formula 4 may, each independently, be a hydrogen atom, a fluorine atom, or a group represented by chemical formula (4-a). Among them, R³¹ to R³⁴ in Chemical Formula 4 may, each independently, be a fluorine atom, or a group represented by chemical formula (4-a).

In chemical formula (4-a), L⁴ is a single bond, or a group represented by chemical formula (4-b). When multiple groups resented by chemical formula (4-a) are present, each L⁴ is the same or different.

In chemical formula (4-b), Ar¹⁶ is a substituted or unsubstituted aromatic hydrocarbon group or a substituted or unsubstituted aromatic heterocyclic group. Among them, Ar¹⁶ may be a substituted or unsubstituted benzene ring group, or for example, a benzene ring group substituted by a fluorine atom. The aromatic hydrocarbon ring group may be, for example, any one of benzene ring group or a fluorene ring group, or for example, may be a benzene ring group, but embodiments are not limited thereto.

In chemical formula (4-b), m4 is an integer of greater than or equal to 1 and less than or equal to 5. In an embodiment, m4 may be an integer of 1 or 2, or for example, may be 1.

In chemical formula (4-a), Ar¹⁵ is a substituted or unsubstituted aromatic hydrocarbon ring group, or a substituted or unsubstituted aromatic heterocyclic group. When multiple groups represented by chemical formula (4-a) are present, each Ar¹⁵ is the same or different. Among them, Ar¹⁵ may be, for example, a substituted or unsubstituted benzene ring group, or, for example, a benzene ring group substituted by a fluorine atom. The aromatic hydrocarbon ring group may be, for example, any one of benzene ring group or a fluorene ring group, or for example, may be a benzene ring group.

In chemical formula (4-a), X is a fluorine atom, or a group represented in Group (4-1). When multiple groups represented by chemical formula (4-a) are present, each X is the same or different. Among them, in terms of the resistance to positive aging, X may be the group represented in Group (4-1). When n5 is greater than or equal to 2, each X may be the same or different.

In chemical formula (4-a), n5 is an integer of greater than or equal to 1 and less than or equal to 5. When multiple groups represented by chemical formula (4-a) are present, each n5 may be the same or different. In one or more embodiments, n5 may be an integer of 1 or 2, or for example, may be 1.

In chemical formula (4-a), n6 is an integer of 0 or 1. When multiple groups represented by chemical formula (4-a) are present, each n6 may be the same or different. In one or more embodiments, n6 may be an integer of 0 or 1, for example, n6 may be 0, or may be 1.

In chemical formula (4-a), when L⁴ is a single bond and n6 is an integer of 0, n5 may be an integer of 1, and X may be directly connected to the carbon atom of the benzene ring of Chemical Formula 4.

The borate anion may include at least one anion selected from those below, but embodiments are not limited thereto:

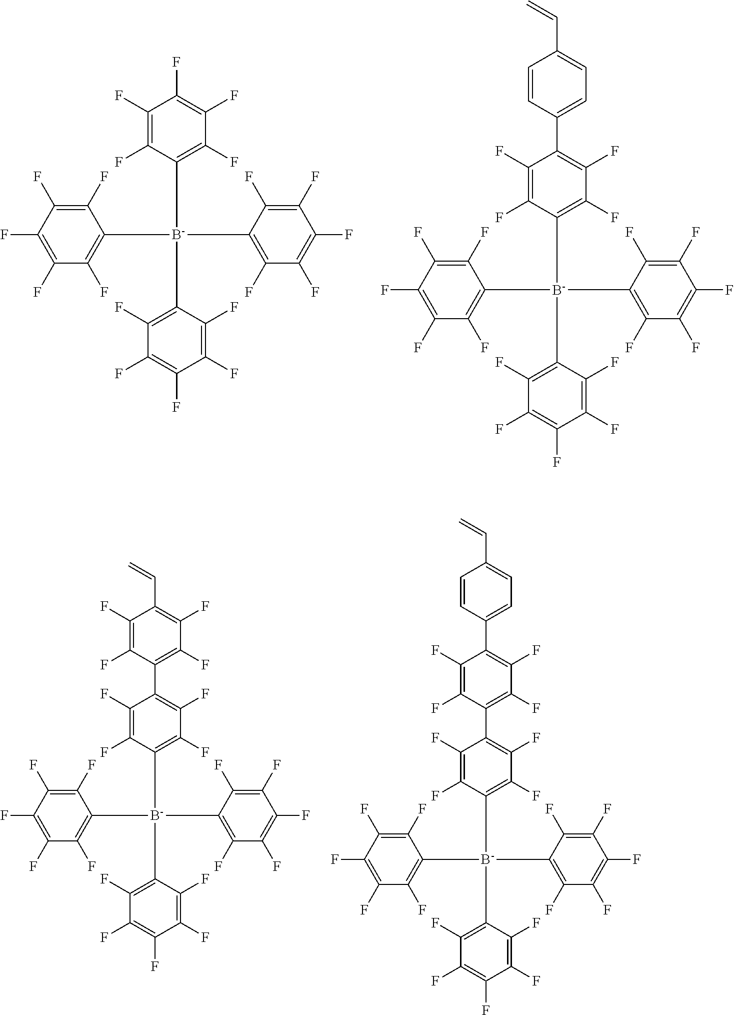 [SMILES: Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F ; C=Cc1ccc(-c2c(F)c(F)c([B-](c3c(F)c(F)c(F)c(F)c3F)(c3c(F)c(F)c(F)c(F)c3F)c3c(F)c(F)c(F)c(F)c3F)c(F)c2F)cc1 ; C=Cc1c(F)c(F)c(-c2c(F)c(F)c([B-](c3c(F)c(F)c(F)c(F)c3F)(c3c(F)c(F)c(F)c(F)c3F)c3c(F)c(F)c(F)c(F)c3F)c(F)c2F)c(F)c1F ; C=Cc1ccc(-c2c(F)c(F)c(-c3c(F)c(F)c([B-](c4c(F)c(F)c(F)c(F)c4F)(c4c(F)c(F)c(F)c(F)c4F)c4c(F)c(F)c(F)c(F)c4F)c(F)c3F)c(F)c2F)cc1]

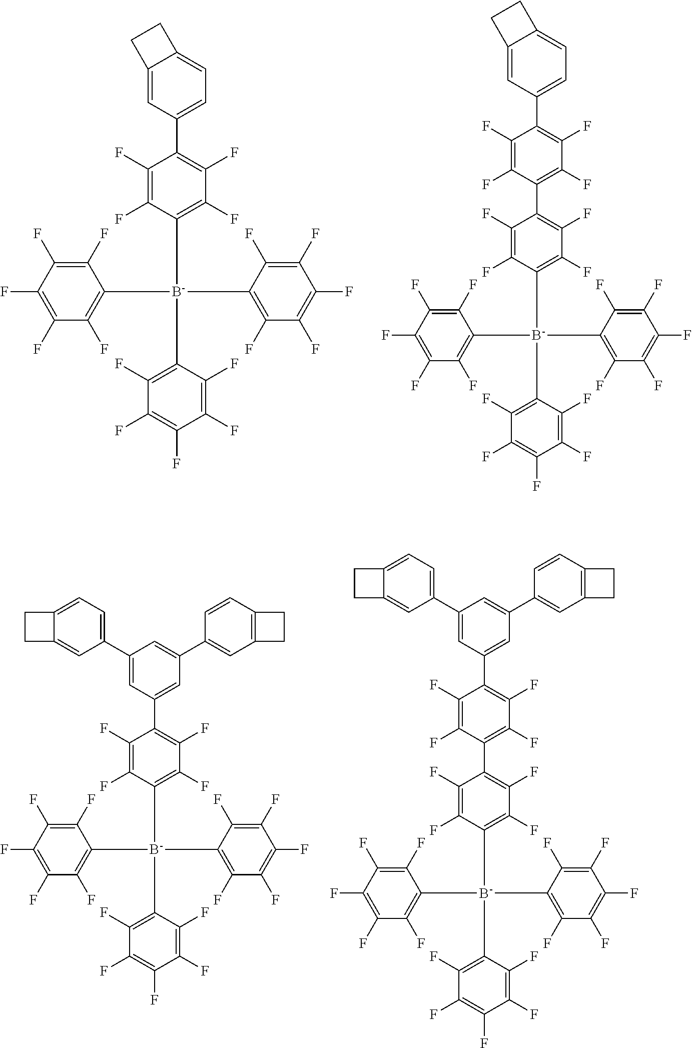

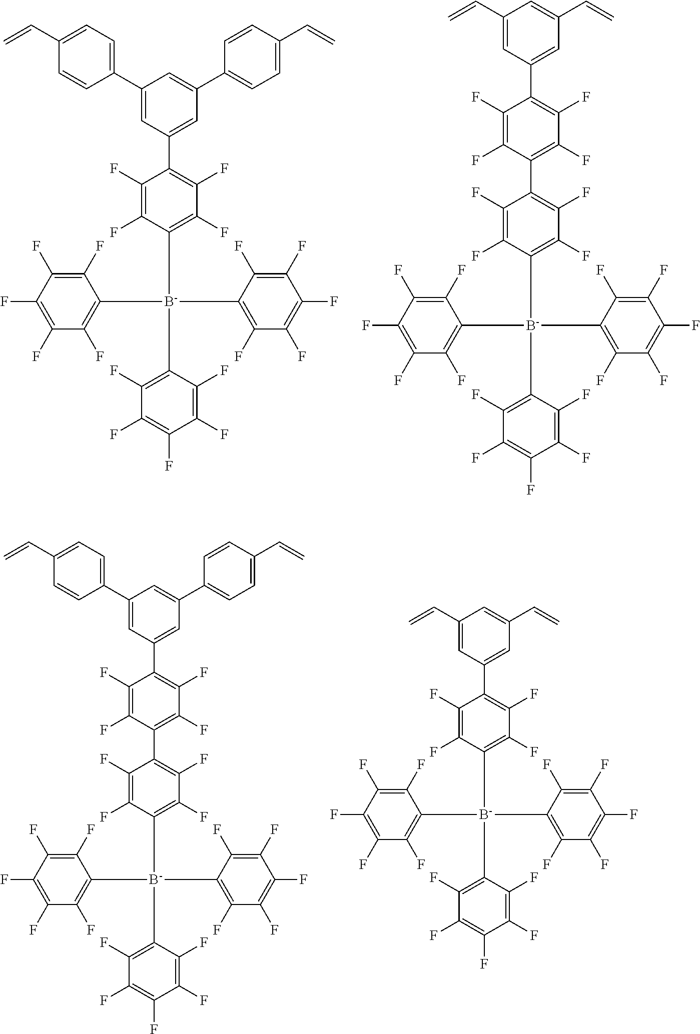

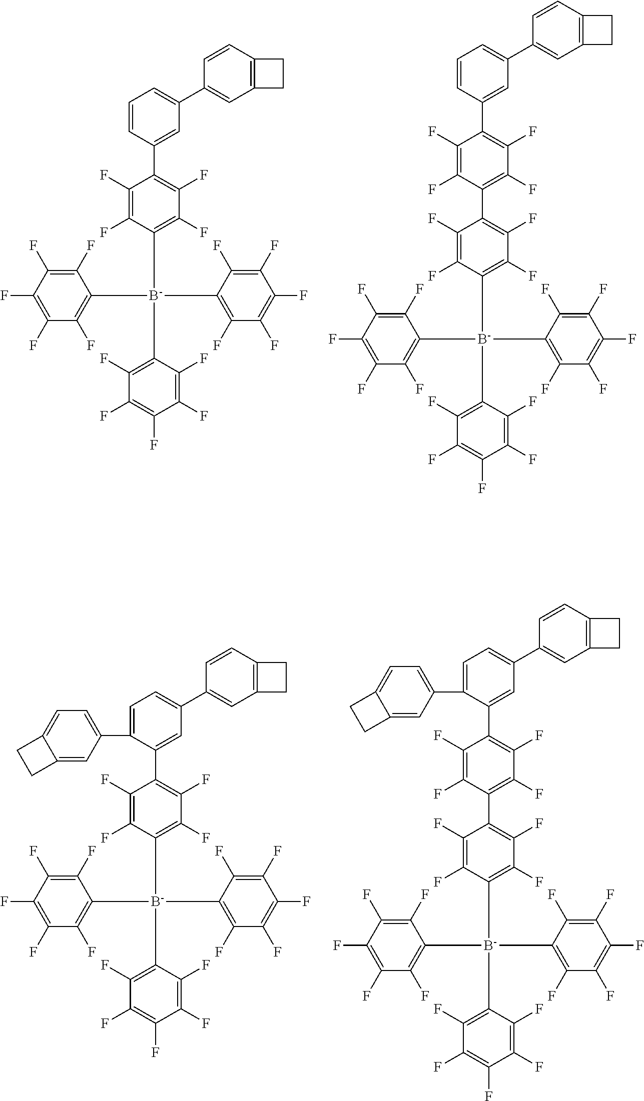

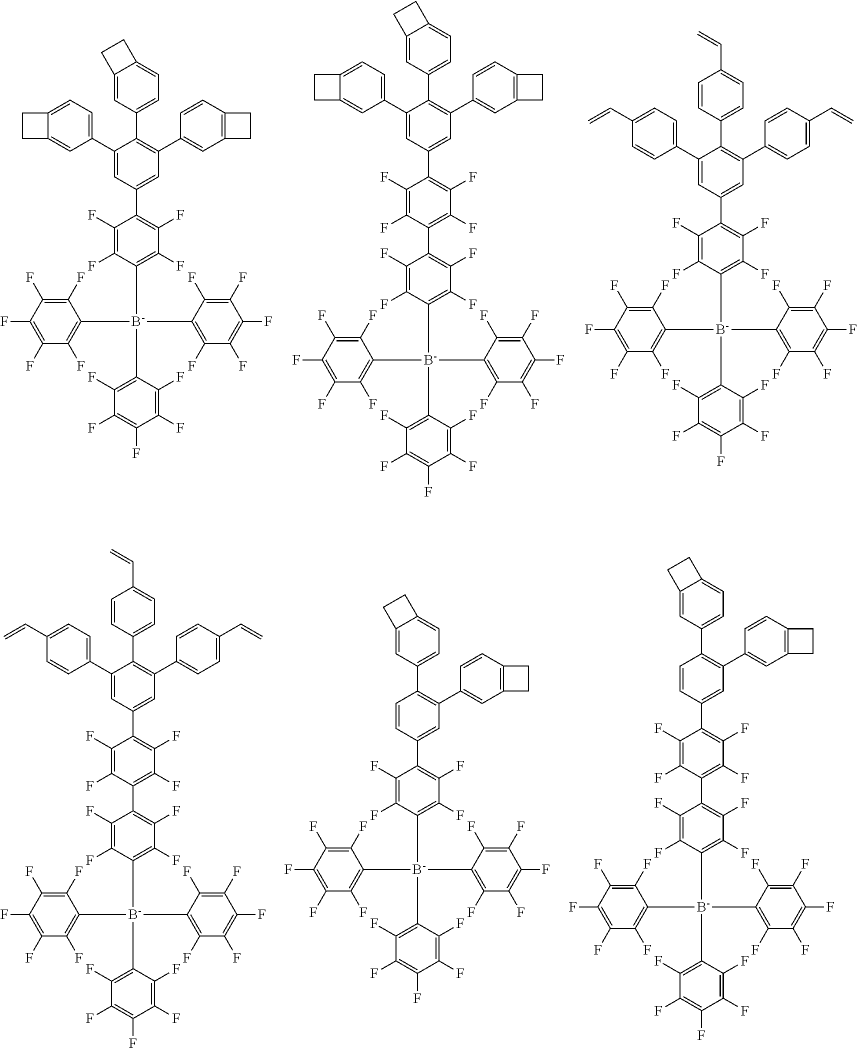

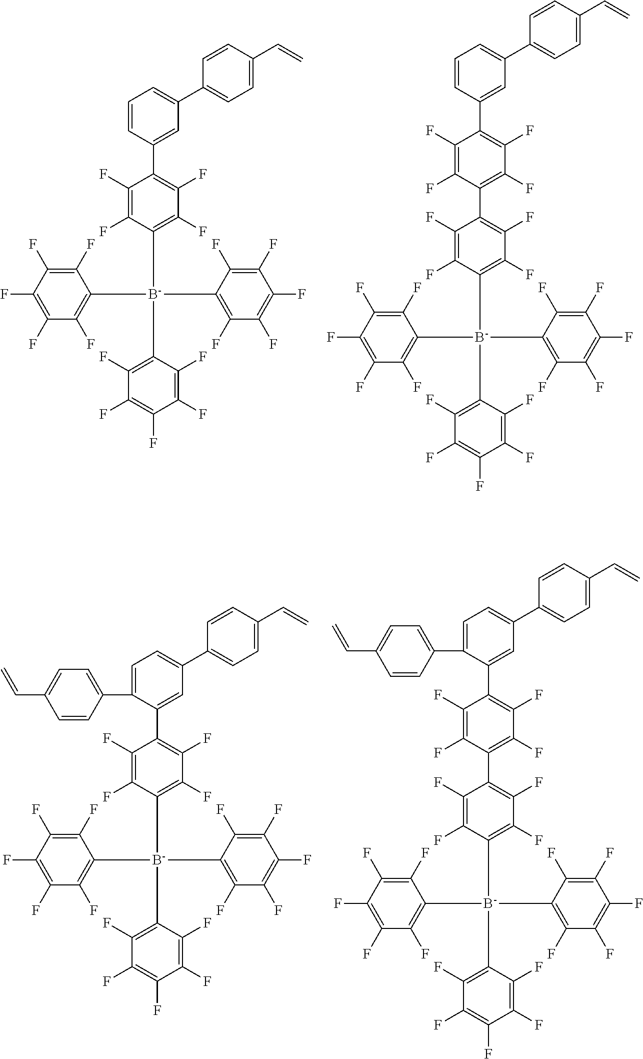

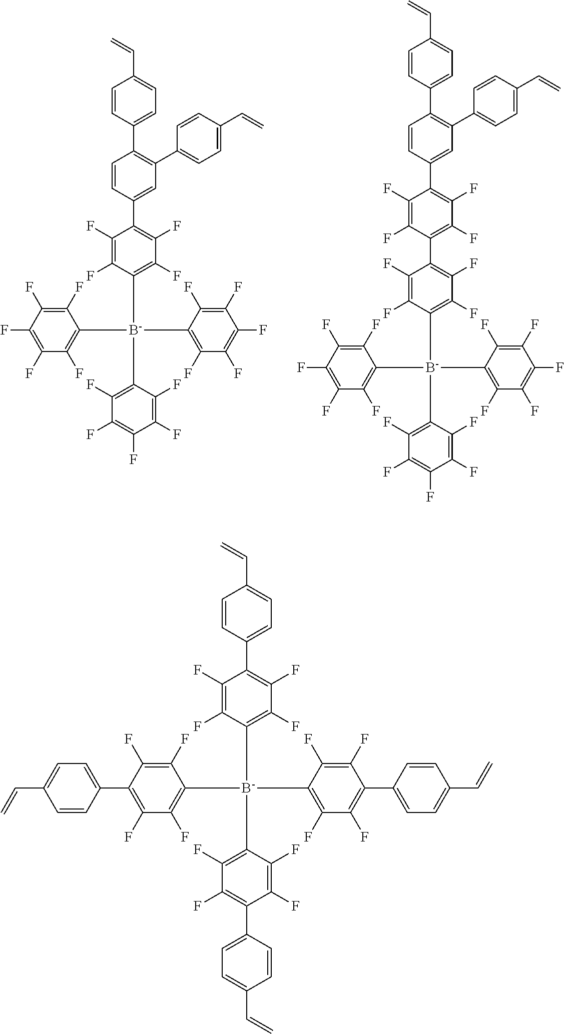 [SMILES: C=Cc1ccc(-c2ccc(-c3c(F)c(F)c([B-](c4c(F)c(F)c(F)c(F)c4F)(c4c(F)c(F)c(F)c(F)c4F)c4c(F)c(F)c(F)c(F)c4F)c(F)c3F)cc2-c2ccc(C=C)cc2)cc1 ; C=Cc1ccc(-c2ccc(-c3c(F)c(F)c(-c4c(F)c(F)c([B-](c5c(F)c(F)c(F)c(F)c5F)(c5c(F)c(F)c(F)c(F)c5F)c5c(F)c(F)c(F)c(F)c5F)c(F)c4F)c(F)c3F)cc2-c2ccc(C=C)cc2)cc1 ; C=Cc1ccc(-c2c(F)c(F)c([B-](c3c(F)c(F)c(-c4ccc(C=C)cc4)c(F)c3F)(c3c(F)c(F)c(-c4ccc(C=C)cc4)c(F)c3F)c3c(F)c(F)c(-c4ccc(C=C)cc4)c(F)c3F)c(F)c2F)cc1]

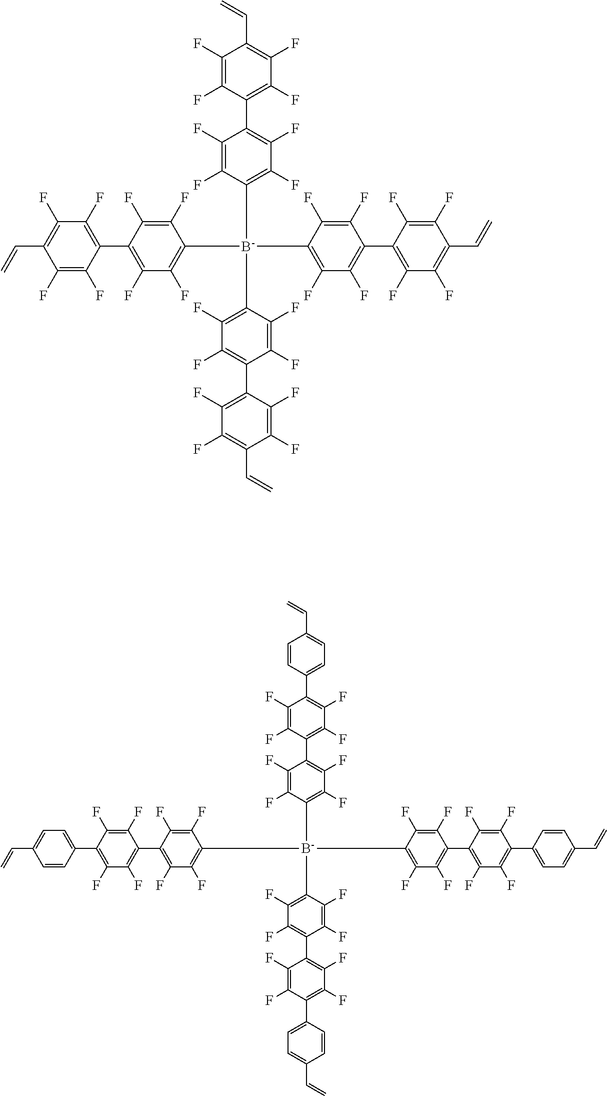

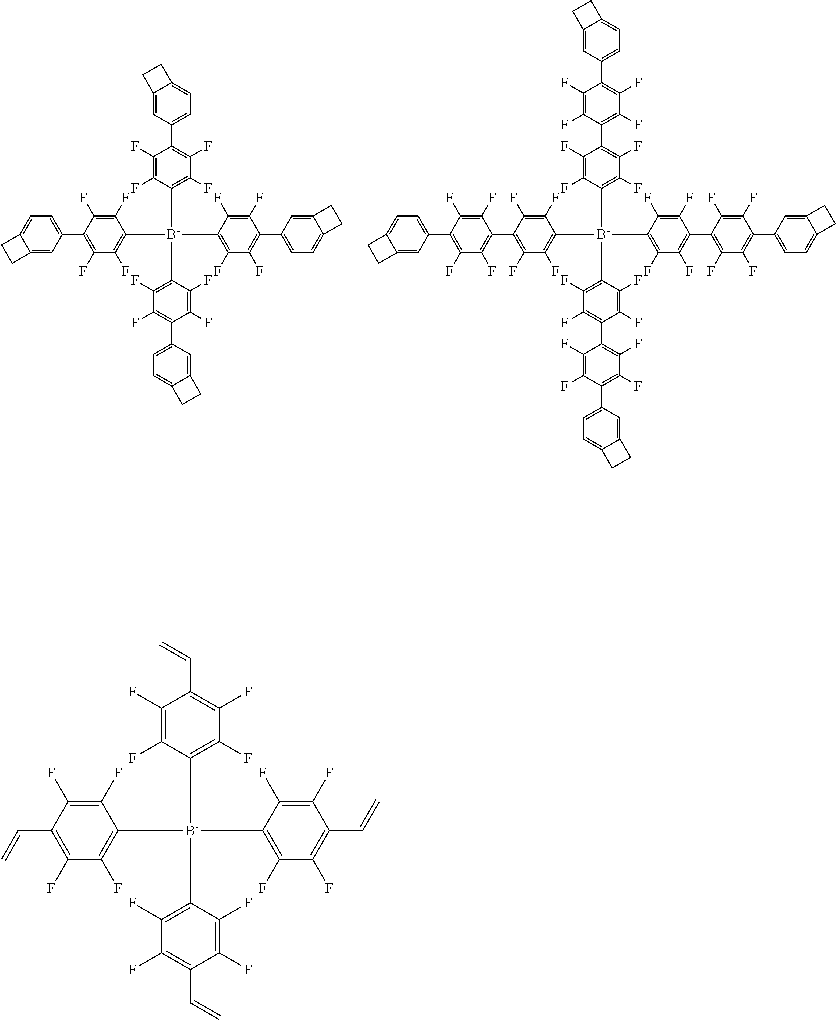 [SMILES: Fc1c(F)c([B-](c2c(F)c(F)c(-c3ccc4c(c3)CC4)c(F)c2F)(c2c(F)c(F)c(-c3ccc4c(c3)CC4)c(F)c2F)c2c(F)c(F)c(-c3ccc4c(c3)CC4)c(F)c2F)c(F)c(F)c1-c1ccc2c(c1)CC2 ; Fc1c(F)c(-c2c(F)c(F)c([B-](c3c(F)c(F)c(-c4c(F)c(F)c(-c5ccc6c(c5)CC6)c(F)c4F)c(F)c3F)(c3c(F)c(F)c(-c4c(F)c(F)c(-c5ccc6c(c5)CC6)c(F)c4F)c(F)c3F)c3c(F)c(F)c(-c4c(F)c(F)c(-c5ccc6c(c5)CC6)c(F)c4F)c(F)c3F)c(F)c2F)c(F)c(F)c1-c1ccc2c(c1)CC2 ; C=Cc1c(F)c(F)c([B-](c2c(F)c(F)c(C=C)c(F)c2F)(c2c(F)c(F)c(C=C)c(F)c2F)c2c(F)c(F)c(C=C)c(F)c2F)c(F)c1F]

The borate anion may be included alone, or in combination of two or more types.

Among the borate anions, for example, the borate anion may be represented by one or more of the anions shown below.

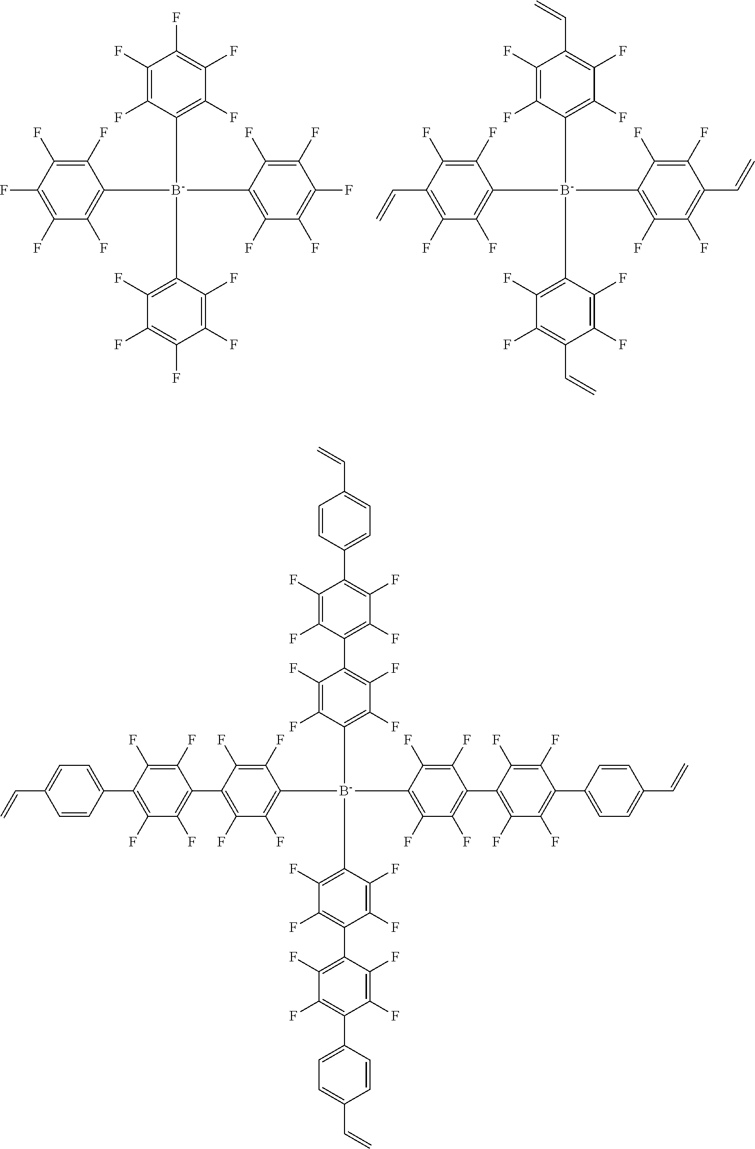 [SMILES: Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F ; C=Cc1c(F)c(F)c([B-](c2c(F)c(F)c(C=C)c(F)c2F)(c2c(F)c(F)c(C=C)c(F)c2F)c2c(F)c(F)c(C=C)c(F)c2F)c(F)c1F ; C=Cc1ccc(-c2c(F)c(F)c(-c3c(F)c(F)c([B-](c4c(F)c(F)c(-c5c(F)c(F)c(-c6ccc(C=C)cc6)c(F)c5F)c(F)c4F)(c4c(F)c(F)c(-c5c(F)c(F)c(-c6ccc(C=C)cc6)c(F)c5F)c(F)c4F)c4c(F)c(F)c(-c5c(F)c(F)c(-c6ccc(C=C)cc6)c(F)c5F)c(F)c4F)c(F)c3F)c(F)c2F)cc1]

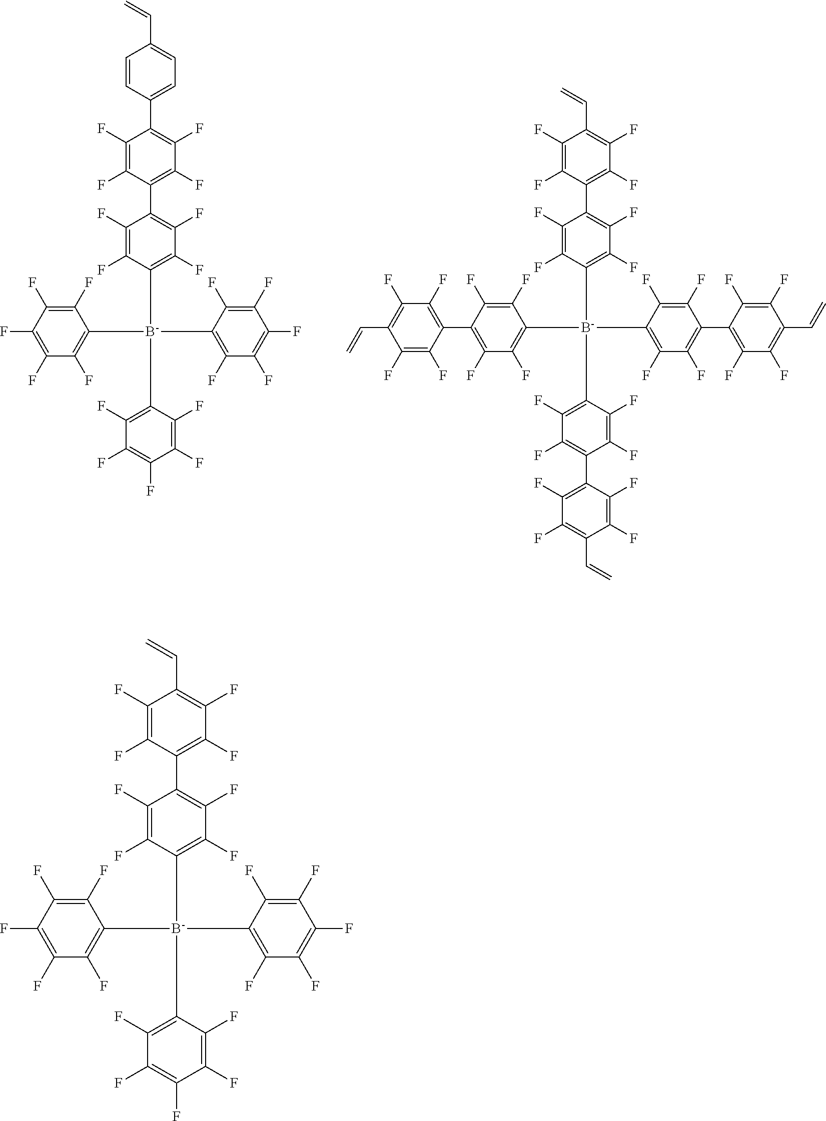 [SMILES: C=Cc1ccc(-c2c(F)c(F)c(-c3c(F)c(F)c([B-](c4c(F)c(F)c(F)c(F)c4F)(c4c(F)c(F)c(F)c(F)c4F)c4c(F)c(F)c(F)c(F)c4F)c(F)c3F)c(F)c2F)cc1 ; C=Cc1c(F)c(F)c(-c2c(F)c(F)c([B-](c3c(F)c(F)c(-c4c(F)c(F)c(C=C)c(F)c4F)c(F)c3F)(c3c(F)c(F)c(-c4c(F)c(F)c(C=C)c(F)c4F)c(F)c3F)c3c(F)c(F)c(-c4c(F)c(F)c(C=C)c(F)c4F)c(F)c3F)c(F)c2F)c(F)c1F ; C=Cc1c(F)c(F)c(-c2c(F)c(F)c([B-](c3c(F)c(F)c(F)c(F)c3F)(c3c(F)c(F)c(F)c(F)c3F)c3c(F)c(F)c(F)c(F)c3F)c(F)c2F)c(F)c1F]

The electron affinity of the borate anion according to one or more embodiments may be, in terms of difference from the electron affinity of the copolymer being in a specific range and from the perspective of further improving resistance to positive aging, for example, greater than or equal to about 5.50 eV and less than or equal to about 6.50 eV, for example, greater than or equal to about 5.60 eV and less than or equal to about 6.40 eV, or for example, greater than or equal to about 5.70 eV and less than or equal to about 6.30 eV.

The electron affinity may be controlled by adjusting the LUMO energy level of the borate anion through the introduction of electron-withdrawing groups. In addition, the electron affinity may be calculated from molecular orbital calculations, and, for example, may be calculated by the method described in the examples.

In an embodiment, the energy difference (ΔE) between the ionization potential of the copolymer and the electron affinity of the borate anion may be greater than or equal to about 0.75 eV, and the ionization potential of the copolymer may be at a deeper level than the ionization potential of the iodonium cation of the salt compound. If the energy difference (ΔE) is less than about 0.75 eV, anion exchange of the acid occurring due to positive aging and the borate anion occurs, and the charge transfer complex does not form to lose conductivity of the electroluminescent device. Also, if the ionization potential of the copolymer is shallower than or equal to the ionization potential of the iodonium cation, then, doping does not occur and the charge transfer complex may not be formed. The energy difference (ΔE) may be greater than or equal to about 0.80 eV, for example, greater than or equal to about 0.83 eV. The larger energy difference (ΔE) is the better, but usually may be less than or equal to about 1.50 eV.

The salt compound according to one or more embodiments includes the borate anion, and iodonium cation that is a counter ion of the borate anion.

Examples of the iodonium cation may include, for example, a difuryliodonium cation, a dithienyliodonium cation, a bis(4,5-dimethyl-2-furyl) iodonium cation, a bis(5-chloro-2-thienyl) iodonium cation, a bis(5-cyano-2-furyl) iodonium cation, a bis(5-nitro-2-thienyl) iodonium cation, a bis(5-acetyl-2-furyl) iodonium cation, a bis(5-carboxy-2-thienyl) iodonium cation, a bis(5-methoxycarbonyl-2-furyl) iodonium cation, a bis(5-phenyl-2-furyl) iodonium cation, a bis(5-(p-methoxyphenyl)-2-thienyl) iodonium cation, a bis(5-vinyl-2-furyl) iodonium cation, a bis(5-ethynyl-2-thienyl) iodonium cation, a bis(5-cyclohexyl-2-furyl) iodonium cation, a bis(5-hydroxy-2-thienyl) iodonium cation, a bis(5-phenoxy-2-furyl) iodonium cation, a bis(5-mercapto-2-thienyl) iodonium cation, a bis(5-butylthio-2-thienyl) iodonium cation, a bis(5-phenylthio-2-thienyl) iodonium cation, a diphenyliodonium cation, a bis(p-tolyl) iodonium cation, a bis(p-octylphenyl) iodonium cation, a bis(p-octadecylphenyl) iodonium cation, a bis(p-octyloxyphenyl) iodonium cation, a bis(p-octadecyloxyphenyl) iodonium cation, a phenyl(p-octadecyloxyphenyl) iodonium cation, a 4-isopropyl-4′-methyldiphenyliodonium cation, a (4-isobutylphenyl)-p-tolyliodonium cation, a bis(1-naphthyl) iodonium cation, a bis(4-phenylsulfanylphenyl) iodonium cation, a phenyl(6-benzoyl-9-ethyl-9H-carbazol-3-yl) iodonium cation, a (7-methoxy-2-oxo-2H-chromen-3-yl)-4′-isopropylphenyliodonium cation, or the like, or a combination thereof, but embodiments are not limited thereto.

The iodonium cation may be included alone, or may be used in combination of two or more types.

Among the iodonium cations, a diphenyliodonium cation, a 4-isopropyl-4′-methyldiphenyliodonium cation, a bis(p-tolyl) iodonium cation, and a (4-isobutylphenyl) (4′-tolyl) iodonium cation may be used.

As long as the ionization potential of the copolymer is deeper than that of the iodonium cation, the value of the ionization potential of the iodonium cation is not specifically limited. The ionization potential of the iodonium cation may be, for example, greater than or equal to about 4.00 eV and less than or equal to about 4.95 eV, for example, greater than or equal to about 4.10 eV and less than or equal to about 4.90 eV, or for example, greater than or equal to about 4.20 eV and less than or equal to about 4.85 eV. The ionization potential of the iodonium cation may be calculated from the molecular orbital calculations, or, for example, may be calculated by the method described in the examples.

The salt compound according to an embodiment may further include another cation, in addition to the iodonium cation. The other cations may include, for example, an onium cation, such as, for example, a sulfonium cation, a sulfoxonium cation, a phosphonium cation, or the like, or a combination thereof.

Examples of the sulfonium cation may include, for example, dimethylphenylsulfonium cation, dimethyl(o-fluorophenyl) sulfonium cation, dimethyl (m-chlorophenyl) sulfonium cation, dimethyl (p-bromophenyl) sulfonium cation, dimethyl(p-cyanophenyl) sulfonium cation, dimethyl (m-nitrophenyl) sulfonium cation, dimethyl(2,4,6-tribromophenyl) sulfonium cation, dimethyl (pentafluorophenyl) sulfonium cation, dimethyl(p-(trifluoromethyl)phenyl) sulfonium cation, dimethyl (p-hydroxyphenyl) sulfonium cation, dimethyl(p-mercaptophenyl) sulfonium cation, dimethyl(p-methylsulfinylphenyl) sulfonium cation, dimethyl(p-methylsulfonylphenyl) sulfonium cation, dimethyl(o-acetylphenyl) sulfonium cation, dimethyl(o-benzoylphenyl) sulfonium cation, dimethyl (p-methylphenyl) sulfonium cation, dimethyl(p-isopropylphenyl) sulfonium cation, dimethyl(p-octadecylphenyl) sulfonium cation, dimethyl(p-cyclohexylphenyl) sulfonium cation, dimethyl(p-methoxyphenyl) sulfonium cation, dimethyl (o-methoxycarbonylphenyl) sulfonium cation, dimethyl(p-phenylsulfanylphenyl) sulfonium cation, (7-methoxy-2-oxo-2H-chromen-4-yl) dimethylsulfonium cation, (4-methoxynaphthalen-1-yl)dimethylsulfonium cation, dimethyl(p-isopropoxycarbonylphenyl) sulfonium cation, dimethyl(2-naphthyl) sulfonium cation, dimethyl(9-anthryl) sulfonium cation, diethylphenylsulfonium cation, methylethylphenylsulfonium cation, methyldiphenylsulfonium cation, triphenylsulfonium cation, diisopropylphenylsulfonium cation, diphenyl (4-phenylsulfanyl-phenyl) sulfonium cation, 4,4′-bis(diphenylsulfonium) diphenylsulfide cation, 4,4′-bis[di[(4-(2-hydroxy-ethoxy)-phenyl)] sulfonium diphenylsulfide cation, 4,4′-bis(diphenylsulfonium) biphenylene cation, diphenyl(o-fluorophenyl) sulfonium cation, diphenyl(m-chlorophenyl) sulfonium cation, diphenyl(p-bromophenyl) sulfonium cation, diphenyl(p-cyanophenyl) sulfonium cation, diphenyl(m-nitrophenyl) sulfonium cation, diphenyl(2,4,6-tribromophenyl) sulfonium cation, diphenyl(pentafluorophenyl) sulfonium cation, diphenyl(p-(trifluoromethyl)phenyl) sulfonium cation, diphenyl(p-hydroxyphenyl) sulfonium cation, diphenyl(p-mercaptophenyl) sulfonium cation, diphenyl(p-methylsulfinylphenyl) sulfonium cation, diphenyl(p-methylsulfonylphenyl) sulfonium cation, diphenyl(o-acetylphenyl) sulfonium cation, diphenyl(o-benzoylphenyl) sulfonium cation, diphenyl(p-methylphenyl) sulfonium cation, diphenyl(p-isopropylphenyl) sulfonium cation, diphenyl(p-octadecylphenyl) sulfonium cation, diphenyl(p-cyclohexylphenyl) sulfonium cation, diphenyl(p-methoxyphenyl) sulfonium cation, diphenyl(o-methoxycarbonylphenyl) sulfonium cation, diphenyl(p-phenylsulfanylphenyl) sulfonium cation, (7-methoxy-2-oxo-2H-chromen-4-yl)diphenylsulfonium cation, (4-methoxynaphthalen-1-yl)diphenylsulfonium cation, diphenyl (p-isopropoxycarbonylphenyl) sulfonium cation, diphenyl(2-naphthyl) sulfonium cation, diphenyl (9-anthryl) sulfonium cation, ethyldiphenylsulfonium cation, methylethyl(o-tolyl) sulfonium cation, methyldi(p-tolyl) sulfonium cation, tri(p-tolyl) sulfonium cation, diisopropyl (4-phenylsulfanylphenyl) sulfonium cation, diphenyl(2-thienyl) sulfonium cation, diphenyl(2-furyl) sulfonium cation, diphenyl (9-ethyl-9Hcarbazol-3-yl) sulfonium cation, or the like, but embodiments are not limited thereto.

Examples of the sulfoxonium cation include, for example, dimethylphenylsulfoxonium cation, dimethyl(o-fluorophenyl) sulfoxonium cation, dimethyl(m-chlorophenyl) sulfoxonium cation, dimethyl(p-bromophenyl) sulfoxonium cation, dimethyl(p-cyanophenyl) sulfoxonium cation, dimethyl(m-nitrophenyl) sulfoxonium cation, dimethyl(2,4,6-tribromophenyl) sulfoxonium cation, dimethyl(pentafluorophenyl) sulfoxonium cation, dimethyl(p-(trifluoromethyl)phenyl) sulfoxonium cation, dimethyl(p-hydroxyphenyl) sulfoxonium cation, dimethyl (p-mercaptophenyl) sulfoxonium cation, sulfoxonium cation, dimethyl(p-methylsulfonylphenyl) dimethyl(p-methylsulfinylphenyl) sulfoxonium cation, dimethyl(o-acetylphenyl) sulfoxonium cation, dimethyl(o-benzoylphenyl) sulfoxonium cation, dimethyl(p-methylphenyl) sulfoxonium cation, dimethyl(p-isopropylphenyl) sulfoxonium cation, dimethyl(p-octadecylphenyl) sulfoxonium cation, dimethyl(p-cyclohexylphenyl) sulfoxonium cation, dimethyl(p-methoxyphenyl) sulfoxonium cation, dimethyl(o-methoxycarbonylphenyl) sulfoxonium cation, dimethyl(p-phenylsulfanylphenyl) sulfoxonium cation, (7-methoxy-2-oxo-2H-chromen-4-yl) dimethylsulfoxonium cation, (4-methoxynaphthalen-1-yl)dimethylsulfoxonium cation, dimethyl (p-isopropoxycarbonylphenyl) sulfoxonium cation, dimethyl(2-naphthyl) sulfoxonium cation, dimethyl(9-anthryl) sulfoxonium cation, diethylphenyl sulfoxonium cation, methylethylphenyl sulfoxonium cation, methyldiphenyl sulfoxonium cation, triphenyl sulfoxonium cation, diisopropylphenyl sulfoxonium cation, diphenyl(4-phenylsulfanyl-phenyl)-sulfoxonium cation, 4,4′-bis(diphenyl sulfoxonium) diphenyl sulfide, 4,4′-bis[di[(4-(2-hydroxy-ethoxy)-phenyl)] sulfoxonium]diphenyl sulfide, 4,4′-bis(diphenylsulfoxonium) biphenylene, diphenyl(o-fluorophenyl) sulfoxonium cation, diphenyl(m-chlorophenyl) sulfoxonium cation, diphenyl(p-bromophenyl) sulfoxonium cation, diphenyl(p-cyanophenyl) sulfoxonium cation, diphenyl(m-nitrophenyl) sulfoxonium cation, diphenyl(2,4,6-tribromophenyl) sulfoxonium cation, diphenyl(pentafluorophenyl) sulfoxonium cation, diphenyl(p-(trifluoromethyl)phenyl) sulfoxonium cation, diphenyl(p-hydroxyphenyl) sulfoxonium cation, diphenyl(p-mercaptophenyl) sulfoxonium cation, diphenyl(p-methylsulfinylphenyl) sulfoxonium cation, diphenyl(p-methylsulfonylphenyl) sulfoxonium cation, diphenyl(o-acetylphenyl) sulfoxonium cation, diphenyl(o-benzoylphenyl) sulfoxonium cation, diphenyl(p-methylphenyl) sulfoxonium cation, diphenyl(p-isopropylphenyl) sulfoxonium cation, diphenyl(p-octadecylphenyl) sulfoxonium cation, diphenyl(p-cyclohexylphenyl) sulfoxonium cation, diphenyl(p-methoxyphenyl) sulfoxonium cation, diphenyl(o-methoxycarbonylphenyl) sulfoxonium cation, diphenyl(p-phenylsulfanylphenyl) sulfoxonium cation, (7-methoxy-2-oxo-2H-chromen-4-yl) diphenylsulfoxonium cation, (4-methoxynaphthalen-1-yl)diphenylsulfoxonium cation, diphenyl (p-isopropoxycarbonylphenyl) sulfoxonium cation, diphenyl(2-naphthyl) sulfoxonium cation, diphenyl (9-anthryl) sulfoxonium cation, ethyldiphenylsulfoxonium cation, methylethyl(o-tolyl) sulfoxonium cation, methyl di(p-tolyl) sulfoxonium cation, tri(p-tolyl) sulfoxonium cation, diisopropyl(4-phenylsulfanylphenyl) sulfoxonium cation, diphenyl(2-thienyl) sulfoxonium cation, diphenyl(2-furyl) sulfoxonium cation, diphenyl (9-ethyl-9Hcarbazol-3-yl) sulfoxonium cation, or the like, but embodiments are not limited thereto.

Examples of phosphonium cation may include, for example, trimethylphenylphosphonium cation, triethylphenylphosphonium cation, tetraphenylphosphonium cation, triphenyl(p-fluorophenyl) phosphonium cation, triphenyl(o-chlorophenyl) phosphonium cation, triphenyl(m-bromophenyl) phosphonium cation, triphenyl(p-cyanophenyl) phosphonium cation, triphenyl(m-nitrophenyl) phosphonium cation, triphenyl(p-phenylsulfanylphenyl) phosphonium cation, (7-methoxy-2-oxo-2H-chromen-4-yl) triphenylphosphonium cation, triphenyl(o-hydroxyphenyl) phosphonium cation, triphenyl(o-acetylphenyl) phosphonium cation, triphenyl(m-benzoylphenyl) phosphonium cation, triphenyl(p-methylphenyl) phosphonium cation, triphenyl(p-isopropoxyphenyl) phosphonium cation, triphenyl(o-methoxycarbonylphenyl) phosphonium cation, triphenyl(1-naphthyl) phosphonium cation, triphenyl(9-anthryl) phosphonium cation, triphenyl(2-thienyl) phosphonium cation, triphenyl(2-furyl) phosphonium cation, triphenyl (9-ethyl-9Hcarbazol-3-yl) phosphonium cation, or the like, but embodiments are not limited thereto.

The other cations may be used alone or in combination of two or more types.

The salt compound according to one or more embodiments may include a compound represented below in terms of further improving the effects of the embodiment, but is not limited thereto.

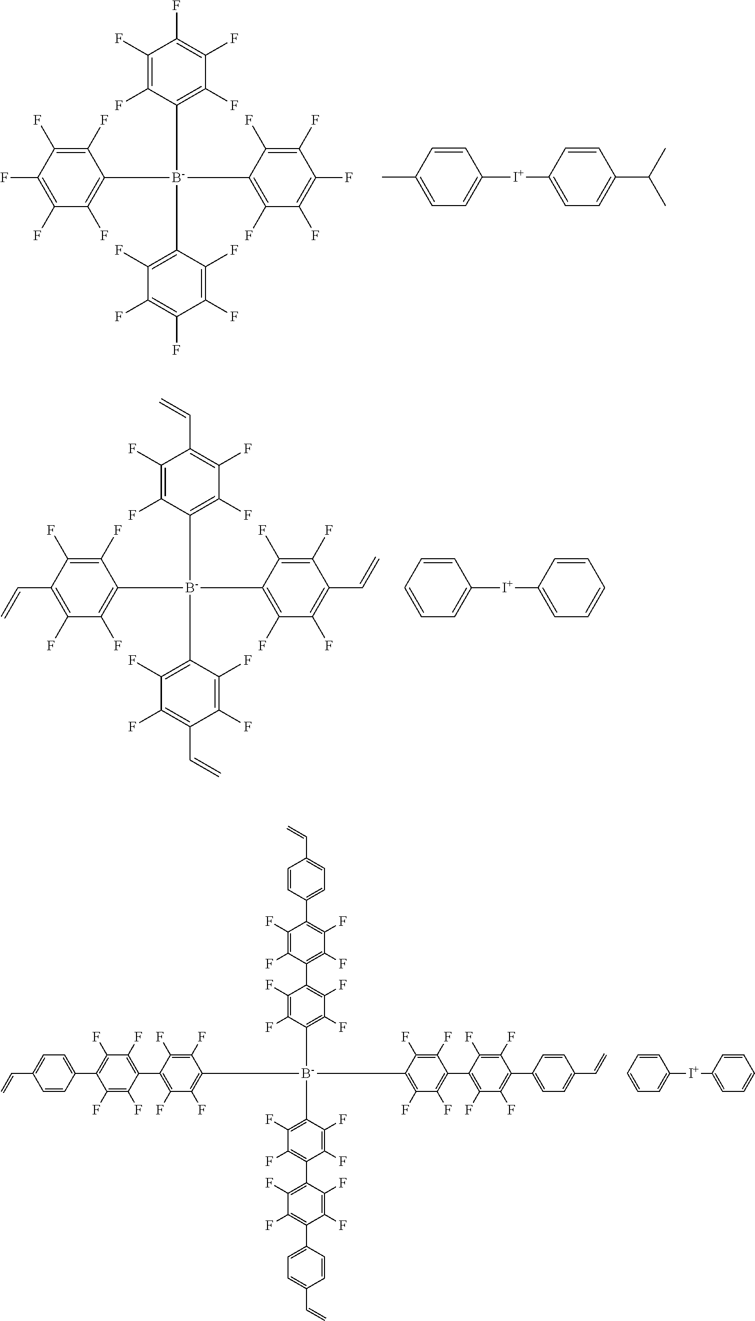

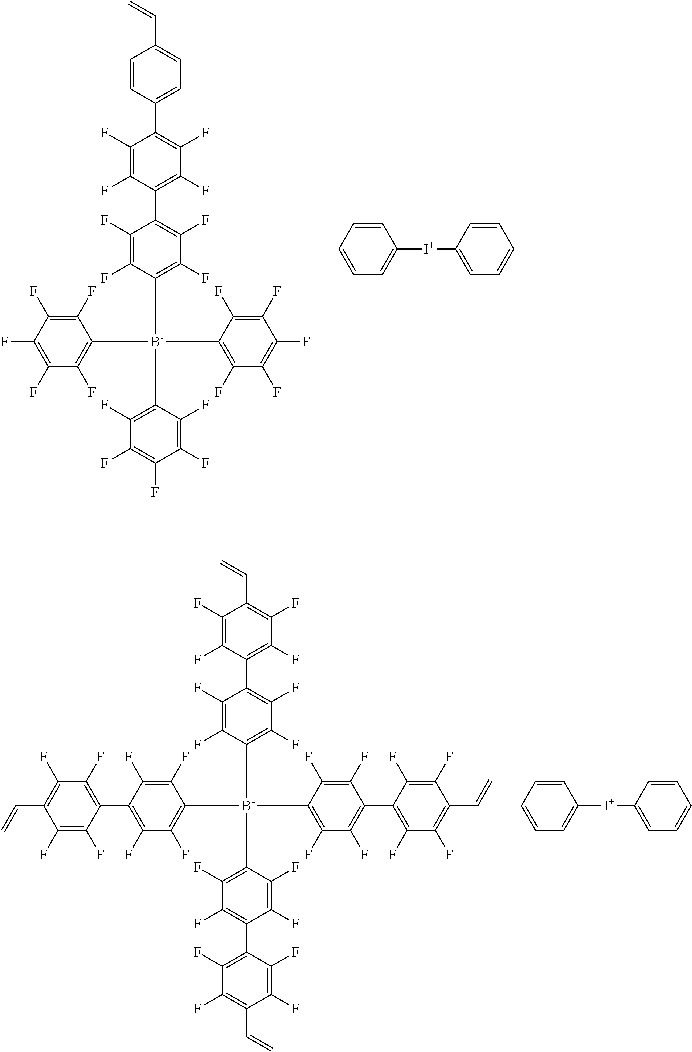 [SMILES: C=Cc1ccc(-c2c(F)c(F)c(-c3c(F)c(F)c([B-](c4c(F)c(F)c(F)c(F)c4F)(c4c(F)c(F)c(F)c(F)c4F)c4c(F)c(F)c(F)c(F)c4F)c(F)c3F)c(F)c2F)cc1 ; c1ccc([I+]c2ccccc2)cc1 ; C=Cc1c(F)c(F)c(-c2c(F)c(F)c([B-](c3c(F)c(F)c(-c4c(F)c(F)c(C=C)c(F)c4F)c(F)c3F)(c3c(F)c(F)c(-c4c(F)c(F)c(C=C)c(F)c4F)c(F)c3F)c3c(F)c(F)c(-c4c(F)c(F)c(C=C)c(F)c4F)c(F)c3F)c(F)c2F)c(F)c1F ; c1ccc([I+]c2ccccc2)cc1]

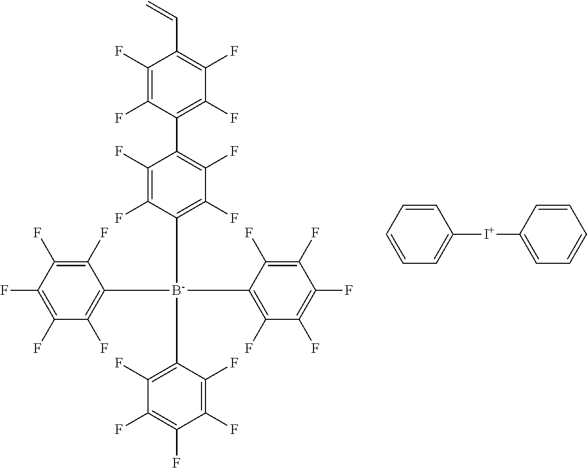 [SMILES: C=Cc1c(F)c(F)c(-c2c(F)c(F)c([B-](c3c(F)c(F)c(F)c(F)c3F)(c3c(F)c(F)c(F)c(F)c3F)c3c(F)c(F)c(F)c(F)c3F)c(F)c2F)c(F)c1F ; c1ccc([I+]c2ccccc2)cc1]

The salt compound may be used alone or in combination of two or more types. The salt compound may be a commercially available product or may be a synthetic product. The method of synthesizing the salt compound is not particularly limited, for example, the salt compound may be synthesized based on the knowledge of known synthesis methods. For instance, it can be synthesized using the method described in the embodiments or according to the method described in the examples. For example, in the method described in the examples, it can be synthesized by changing raw materials or reaction conditions, adding or omitting some steps, or appropriately combining known synthesis methods.

An amount of the salt compound in the composition according to one or more embodiments may be greater than or equal to about 1 wt % and less than or equal to about 70 wt %, for example, greater than or equal to about 5 wt % and less than or equal to about 50 wt %, or for example, greater than or equal to about 10 wt % and less than or equal to about 30 wt %, based on a total weight of the copolymer and the salt compound according to one or more embodiments.

### Solvent

The composition according to one or more embodiments may further include a solvent, in addition to the copolymer and the salt compound.

The solvent may be, for example, in particular not limited to, one that has a boiling point of greater than or equal to about 100° C. and less than or equal to about 350° C. at atmospheric pressure (101.3 kPa, 1 atm). The boiling point of the solvent at atmospheric pressure may be, for example, greater than or equal to about 150° C. and less than or equal to about 320° C., or for example, greater than or equal to about 180° C. and less than or equal to about 300° C. If the boiling point of the solvent at atmospheric pressure is within the above range, the film-forming properties and processability in wet film-forming methods, such as the inkjet method, may be improved. Solvents with a boiling point at atmospheric pressure of greater than or equal to about 100° C. and less than or equal to about 350° C. are not particularly limited, and commonly known solvents may be appropriately employed. Below, solvents with a boiling point at atmospheric pressure of greater than or equal to about 100° C. and less than or equal to about 350° C. are given as examples, but embodiments are not limited thereto.

A hydrocarbon solvent may include octane, nonane, decane, undecane, dodecane, or the like, and is not limited thereto.

An aromatic hydrocarbon solvent may include toluene, xylene, ethylbenzene, n-propylbenzene, isopropylbenzene, mesitylene, n-butylbenzene, sec-butylbenzene, 1-phenylpentane, 2-phenylpentane, 3-phenylpentane, phenylcyclopentane, phenylcyclohexane, 2-ethylbiphenyl, 3-ethylbiphenyl, or the like, and is not limited thereto.

An ether solvent may include 1,4-dioxane, 1,2-diethoxyethane, diethyleneglycoldimethylether, diethyleneglycoldiethylether, anisole, ethoxybenzene, 3-methylanisole, m-dimethoxybenzene, or the like, and is not limited thereto.

A ketone solvent may include 2-hexanone, 3-hexanone, cyclohexanone, 2-heptanone, 3-heptanone, 4-heptanone, cycloheptanone, or the like, and is not limited thereto.

An ester solvent may include butyl acetate, butyl propionate, butyl butyrate, propylene carbonate, methyl benzoate, ethyl benzoate, propyl benzoate, butyl benzoate, or the like, and is not limited thereto.

A nitrile solvent may include benzonitrile, 3-methylbenzonitrile, or the like, and is not limited thereto.

An amide solvent may include N,N-dimethylformamide, N,N-dimethylacetamide, N-methyl-2-pyrrolidone, or the like, and is not limited thereto.

The solvent may be used alone, or in combination of two or more types.

An amount of the solvent in the composition according to one or more embodiments is not particularly limited. For example, solid concentration (total concentration of the copolymer and salt compound) of the composition may be, from the viewpoint of easy application, for example, greater than or equal to about 0.1% by weight (0.1 wt %) and less than or equal to about 10 wt %, or for example, greater than or equal to about 0.5 wt % and less than or equal to about 5 wt %.

The method of preparing the composition according to an embodiment is not particularly limited. For example, a method of sequentially adding and mixing copolymer and a salt compound in a solvent; a method of adding and mixing a copolymer and a salt compound in a solvent at once; a method of separately preparing a solution of the copolymer and a solution of the salt compound and then mixing them, and the like. The temperature and mixing time during mixing are also not particularly limited.

### Electroluminescent Device

Hereinafter, an electroluminescence device according to an embodiment will be described in detail with reference to the FIGURE. The FIGURE is a schematic representation showing an electroluminescence device according to one or more embodiments. As used herein, “electroluminescence device” may be abbreviated as “EL device.”

As shown in the FIGURE, the EL device 100 according to one or more embodiments comprises a substrate 110, a first electrode 120 on the substrate 110, a hole injection layer 130 on the first electrode 120, a hole transport layer 140 on the hole injection layer 130, an emitting layer 150 on the hole transport layer 140, an electron transport layer 160 on the emitting layer 150, an electron injection layer 170 on the electron transport layer 160, and a second electrode 180 on the electron injection layer 170.

The substrate 110 may be a substrate used as a general EL device. For example, the substrate 110 may be a semiconductor substrate such as, for example, a glass substrate, a silicon substrate, or a transparent plastic substrate.

The first electrode 120 is formed on the substrate 110. The first electrode 120 may, for example, provide holes and may be an anode, and may be formed by a metal, an alloy, a conductive compound, or the like having a large work function. For example, the first electrode 120 may be formed as a transparent electrode using indium tin oxide (In₂O₃—SnO₂: ITO), indium zinc oxide (In₂O₃—ZnO), tin oxide (SnO₂), or zinc oxide (ZnO), or the like, which has excellent transparency and conductivity. Additionally, the first electrode 120 may be formed as a reflective electrode by laminating magnesium (Mg), silver (Ag), aluminum (Al), or the like on the transparent conductive film. Additionally, after forming the first electrode 120 on the substrate 110, if necessary, cleaning and UV-ozone treatment may be performed.

The hole injection layer 130 may be formed on the first electrode 120. The hole injection layer 130 may be a layer that facilitates the injection of holes from the first electrode 120, and specifically, may be formed to have a thickness (dry film thickness; the same applies hereinafter) of, for example, about 10 nanometers (nm) to about 1000 nm, or for example, about 20 nm to about 50 nm.

According to one or more embodiments, the hole injection layer 130 may include a cured material formed by curing the composition according to one or more embodiments (a cured material obtained by curing the composition according to an embodiment, a cured material of the composition according to an embodiment). Hereinafter, the cured material formed by curing the composition according to one or more embodiments (a cured material obtained by curing the composition according to an embodiment, a cured material of the composition according to an embodiment) will be simply referred to as the “cured material according to an embodiment”.

According to one or more embodiments, the hole injection layer 130 may include a cured material according to an embodiment and a carboxyl-containing compound used in the positive aging described below.

The pre-cured film containing a composition according to one or more embodiments may be formed by a coating method. For example, it can be formed using a solution coating method, such as, for example, spin coating, casting, micro gravure coating, gravure coating, bar coating, roll coating, wire bar coating, dip coating, spray coating, screen printing, flexographic printing, offset printing, inkjet printing, or the like.

Subsequently, the film formed by the coating method is cured. The curing method is not particularly limited, and may be thermal curing. Thermal curing can be carried out in an air atmosphere or in an inert gas atmosphere. The temperature for thermal curing is not particularly limited, but, for example, may be greater than or equal to about 80° C., greater than or equal to about 100° C., greater than or equal to about 130° C., greater than or equal to about 150° C., or greater than or equal to about 200° C. In addition, the temperature for thermal curing may, for example, be less than or equal to about 250° C., less than or equal to about 230° C., less than or equal to about 200° C., less than or equal to about 180° C., or less than or equal to about 150° C. The heat-curing time is not particularly limited and may, for example, be about 5 minutes or more, about 10 minutes or more, about 15 minutes or more, about 20 minutes or more, or about 30 minutes or more. Further, the heat-curing time may, for example, be about 70 minutes or less, about 60 minutes or less, about 50 minutes or less, about 30 minutes or less, or about 20 minutes or less. In this way, a cured product according to one or more embodiments may be obtained. Also, in this way, a layer containing the cured product according to one or more embodiments may be obtained.

In addition to the cured product according to one or more embodiments (and, if necessary, a carboxyl-containing compound), or when any layer other than the hole injection layer 130 of the EL device 100 contains the cured product according to one or more embodiments (and, if necessary, a carboxyl-containing compound), the hole injection layer 130 may be formed to include a known hole injection material. The hole injection layer 130 may be formed using a known hole injection material. The known hole injection materials for forming the hole injection layer 130 may include, for example, at least one of poly(ether ketone)-containing triphenylamine 4-isopropyl-4′-methyldiphenyliodonium tetrakis(pentafluorophenyl)borate (PPBI), N,N′-diphenyl-N,N′-bis-[4-(phenyl-m-tolyl-amino)-phenyl]-biphenyl-4,4′-diamine (DNTPD), copper phthalocyanine, 4,4′,4″-tris(3-methylphenylphenylamino)triphenylamine (m-MTDATA), N,N′-di(1-naphthyl)-N,N′-diphenylbenzidine (NPB), 4,4′,4″-tris(diphenylamino)triphenylamine (TDATA), 4,4′,4″-tris(N,N-2-naphthylphenylamino)triphenylamine (2-TNATA), polyaniline/dodecylbenzenesulphonic acid, poly(3,4-ethylenedioxythiophene)/poly(4-styrenesulfonate): PEDOT/PSS, or polyaniline/10-camphorsulfonic acid, but embodiments are not limited thereto.

The hole transport layer 140 may be formed on the hole injection layer 130. The hole transport layer 140 may be a layer having a function of transporting holes, and may be formed with a thickness of, for example, about 10 nm to about 150 nm, for example, about 20 nm to about 50 nm. The hole transport layer 140 may be formed by a solution coating method using a composition according to one or more embodiments. According to this method, the durability (luminescence life-span) of the EL device 100 may be extended. Additionally, it is possible to improve the current efficiency of the EL device 100 and to reduce the driving voltage. In addition, since the hole transport layer may be formed by a solution coating method, a large-area film may be efficiently formed.

In one or more embodiments, the hole transport layer 140 may include a cured material according to one or more embodiments. According to one or more embodiments, the hole transport layer 140 may include a cured material according to an embodiment and a carboxyl-containing compound used for positive aging as described herein. Specific examples of the coating method and curing method are the same as those described for the hole injection layer 130.

In addition to the cured product according to one or more embodiments (and, if necessary, a carboxyl group-containing compound), or when any layer other than the hole transport layer 140 of the EL device 100 includes the cured product according to one or more embodiments (and, if necessary, a carboxyl group-containing compound), the hole transport layer 140 may be formed to include a known hole transport material. The known hole transport materials may include, for example, at least one of a carbazole derivative such as 1,1-bis[(di-4-tolylamino)phenyl]cyclohexane (TAPC), N-phenylcarbazole and polyvinylcarbazole, N,N′-bis(3-methylphenyl)-N,N′-diphenyl-[1,1-biphenyl]-4,4′-diamine (TPD), 4,4′,4″-tris(N-carbazolyl)triphenylamine (TCTA), N,N′-di(1-naphthyl)-N,N′-diphenylbenzidine (NPB), or the like, but embodiments are not limited thereto.

The light emitting layer 150 may be formed on the hole transport layer 140. The light emitting layer 150 may be a layer that emits light by fluorescence, phosphorescence, or the like, and may be formed using a vacuum deposition method, a spin coating method, an inkjet printing method, or the like. The light emitting layer 150 may be formed with a thickness of, for example, greater than or equal to about 10 nm and less than or equal to about 60 nm, or for example, greater than or equal to about 20 nm and less than or equal to about 50 nm. As the light emitting material of the light emitting layer 150, any known light emitting material may be used. However, the light emitting material included in the light emitting layer 150 may be a light emitting material capable of light emission from triplet excitons (i.e., phosphorescence). In this case, the driving life-span of the EL device 100 may be further improved.

The light emitting layer 150 is not particularly limited and may have a known configuration. For example, the light emitting layer includes at least one of semiconductor nanocrystal particles and/or an organometallic complex. That is, in one or more embodiments, an organic layer may have a light emitting layer including at least one of semiconductor nanocrystal particles or an organometallic complex. In one or more embodiments, the organic layer may include a light emitting layer that includes semiconductor nanocrystal particles. When the light emitting layer includes semiconductor nanocrystal particles, the EL device may be a quantum dot electroluminescence device (QLED), a quantum dot light emitting device, or a quantum dot light emitting diode. In addition, when the light emitting layer includes an organometallic complex, the EL device may be an organic light emitting device (OLED).

In the form of a light emitting layer including semiconductor nanocrystal particles (QLED), the light emitting layer may be a single layer or multiple layers of a plurality of semiconductor nanocrystal particles (quantum dots). Here, semiconductor nanocrystal particles (quantum dots) are particles of a certain size that have a quantum confinement effect. The diameter of semiconductor nanocrystal particles (quantum dots) is not particularly limited, but may be about 1 nm to about 10 nm.

The semiconductor nanocrystal particles (quantum dots) arranged in the light emitting layer may be synthesized by a wet chemical process, an organometallic chemical vapor deposition process, a molecular beam epitaxy process, or other similar processes. Among these, the wet chemical process is a method of growing particles by adding precursor materials to an organic solvent.

In a wet chemical process, when a crystal grows, an organic solvent is naturally distributed to the surface of the quantum dot crystal and acts as a dispersant, thereby controlling growth of the crystal. Accordingly, in wet chemical processes, the growth of semiconductor nanocrystal particles may be controlled easily and at a lower cost compared to vapor deposition methods such as metal organic chemical vapor deposition (MOCVD) or molecular beam epitaxy (MBE).

Semiconductor nanocrystal particles (quantum dots) may vary the energy band gap by controlling their size, whereby light of various wavelengths may be obtained from the light emitting layer (quantum dot light emitting layer). Therefore, by using multiple quantum dots of different sizes, it is possible to create a display that emits (or emits light) light of multiple wavelengths. The size of the quantum dots may be selected to emit red, green, and/or blue light, enabling color displays to be constructed. Additionally, the size of the quantum dots may be combined to emit white light with various colors.

As the semiconductor nanocrystal particles (quantum dots), a semiconductor material selected from a Group II-VI semiconductor compound; a Group III-V semiconductor compound; a Group IV-VI group semiconductor compound; a Group IV element or compound; or a combination thereof may be used.

The Group II-VI semiconductor compound is not particularly limited, and examples thereof may include a binary compound selected from CdSe, CdTe, ZnS, ZnSe, ZnTe, ZnO, HgS, HgSe, HgTe, or the like, or a combination thereof; a ternary compound selected from CdSeS, CdSeTe, CdSTe, ZnSeS, ZnTeSe, ZnSTe, HgSeS, HgSeTe, HgSTe, CdZnS, CdZnSe, CdZnTe, CdHgS, CdHgSe, CdHgTe, HgZnS, HgZnSe, HgZnTe, or the like, or a combination thereof; a quaternary compound selected from CdZnSeS, CdZnSeTe, CdZnSTe, CdHgSeS, CdHgSeTe, CdHgSTe, HgZnSeS, HgZnSeTe, HgZnSTe, or the like, or a combination thereof; or a combination thereof.

The Group III-V semiconductor compound is not particularly limited, and examples thereof may include a binary compound selected from GaN, GaP, GaAs, GaSb, AlN, AlP, AlAs, AlSb, InN, InP, InAs, InSb, or the like, or a combination thereof; a ternary compound selected from GaNP, GaNAs, GaNSb, GaPAs, GaPSb, AlNP, AlNAs, AlNSb, AlPAs, AlPSb, InNP, InNAs, InNSb, InPAs, InPSb, GaAlNP, or the like, or a combination thereof; a quaternary compound selected from GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or the like, or a combination thereof; or a combination thereof.

The Group IV-VI semiconductor compound is not particularly limited, and examples thereof may include a binary compound selected from SnS, SnSe, SnTe, PbS, PbSe, PbTe, or the like, or a combination thereof; a ternary compound selected from SnSeS, SnSeTe, SnSTe, PbSeS, PbSeTe, PbSTe, SnPbS, SnPbSe, SnPbTe, or the like, or a combination thereof; a quaternary compound selected from SnPbSSe, SnPbSeTe, SnPbSTe, or the like, or a combination thereof; or a combination thereof.

The Group IV element or compound is not particularly limited, and examples thereof may include a single elemental selected from Si, Ge, or a combination thereof; or a binary elemental compound selected from SiC, SiGe, or a combination thereof.

The semiconductor nanocrystal particles (quantum dots) may have a homogeneous single structure or a core-shell dual structure. The core and the shell may include different materials. The material constituting each core and shell may be composed of different semiconductor compounds. However, the energy bandgap of the shell material may be larger than the energy bandgap of the core material. For example, the structures may be ZnTeSe/ZnSe/ZnS, InP/ZnSe/ZnS, CdSe/ZnS, InP/ZnS, or the like, but embodiments are not limited thereto.

For example, a process of producing a quantum dot having a core (CdSe)/shell (ZnS) structure is described. First, a core (CdSe) precursor material such as (CH₃)₂Cd (dimethylcadmium) and TOPSe (trioctylphosphine selenide) are injected into an organic solvent using TOPO (trioctylphosphine oxide) as a surfactant to form a crystal. At this time, after maintaining the crystal at a high temperature for a certain period of time so that it grows to a certain size, a precursor material for the shell (ZnS) is injected to form a shell on the surface of the already formed core. This allows the production of TOPO-capped CdSe/ZnS quantum dots.

Further, in the form of a light emitting layer including an organometallic complex (OLED), the light emitting layer 150 may include, as a host material, for example, at least one of 6,9-diphenyl-9′-(5′-phenyl-[1,1′:3′,1″-terphenyl]-3-yl)3,3′-bi[9H-carbazole], 3,9-diphenyl-5-(3-(4-phenyl-6-(5′-phenyl-[1,1′:3′,1″-terphenyl]-3-yl)-1,3,5-triazine-2-yl)phenyl)-9H-carbazole, 9,9′-diphenyl-3,3′-bi[9H-carbazole], tris(8-quinolinato)aluminum (Alq3), 4,4′-bis(carbazol-9-yl)biphenyl (CBP), poly(n-vinyl carbazole) (PVK), 9,10-di(naphthalene-2-yl)anthracene (ADN), 4,4′,4″-tris(N-carbazolyl)triphenylamine (TCTA), 1,3,5-tris(N-phenyl-benzimidazol-2-yl)benzene (TPBI), 3-tert-butyl-9,10-di(naphth-2-yl)anthracene (TBADN), distyrylarylene (DSA), 4,4′-bis(9-carbazole)-2,2′-dimethyl-biphenyl (dmCBP), or the like, but embodiments are not limited thereto.

In addition, the light-emitting layer 150 may include, as dopant materials, for example, at least one of perylene and its derivatives, rubrene and its derivatives, coumarin and its derivatives, 4-dicyanomethylene-2-(p-dimethylaminostyryl)-6-methyl-4H-pyran (DCM) and its derivatives, bis[2-(4,6-difluorophenyl)pyridinate]picolinate iridium(III) (Flrpic), bis(1-phenylisoquinoline)(acetylacetonate)iridium(III)(Ir(piq)₂(acac)), tris(2-phenylpyridine)iridium(III)(Ir(ppy)₃), iridium (Ir) complexes, such as, for example, tris(2-(3-p-xylol)phenyl)pyridine iridium(III) and other, osmium (Os) complexes, platinum complexes, or the like, or a combination thereof. Among these, for example, the light emitting material may be a light emitting organometallic complex compound.

The method for forming the light emitting layer is not particularly limited. The light emitting layer may be formed by coating a coating solution including at least one of semiconductor nanocrystal particles or an organometallic complex (solution coating method). At this time, as a solvent constituting the coating solution, a solvent that does not dissolve the material in the hole transport layer, such as, for example, a hole transport material, may be selected.

The electron transport layer 160 may be formed on the light emitting layer 150. The electron transport layer 160 may be a layer that has the function of transporting electrons and may be formed by using a vacuum deposition method, spin coating method, inkjet method, or the like. The electron transport layer 160 may be formed to have a thickness of, for example, greater than or equal to about 15 nm and less than or equal to about 50 nm.

The electron transport layer 160 may be formed of a known electron transport material. Examples of known electron transport materials may include at least one of (8-quinolinolato) lithium (lithium quinolate, Liq), tris(8-quinolinolato)aluminium (Alq₃), or a compound having a nitrogen-containing aromatic ring. Examples of the compound having a nitrogen-containing aromatic ring may include a compound including a pyridine ring, such as, for example, 1,3,5-tri[(3-pyridyl)-phen-3-yl]benzene, a compound including a triazine ring, such as, for example, 2,4,6-tris(3′-(pyridin-3-yl)biphenyl-3-yl)-1,3,5-triazine, a compound including an imidazole ring, such as, for example, 2-(4-(N-phenylbenzoimidazolyl-1-yl-phenyl)-9,10-dinaphthylanthracene or 1,3,5-tris(N-phenyl-benzimidazol-2-yl)benzene (TPBI), or the like. The electron transport material may be used alone or as a mixture of two or more types.

The electron injection layer 170 may be formed on the electron transport layer 160. The electron injection layer 170 may be a layer that has the function of facilitating the injection of electrons from the second electrode 180. The electron injection layer 170 may be formed by using a vacuum deposition method or the like. The electron injection layer 170 may be formed to have a thickness of, for example, greater than or equal to about 0.1 nm and less than or equal to about 5 nm, or for example, greater than or equal to about 0.3 nm and less than or equal to about 2 nm. Any known material may be used as a material for forming the electron injection layer 170. For example, the electron injection layer 170 may be formed by a lithium compound such as, for example, (8-quinolinato) lithium (lithium quinolate, Liq) or lithium fluoride (LiF), sodium chloride (NaCl), cesium fluoride (CsF), lithium oxide (Li₂O), or barium oxide (BaO), but embodiments are not limited thereto.

The second electrode 180 may be formed on the electron injection layer 170. The second electrode 180 may be formed by using a vacuum deposition method or the like. The second electrode 180 may provide electrons, and, for example, be a cathode, and may be formed by a metal, an alloy, or a conductive compound having a small work function. For example, the second electrode 180 may be formed as a reflective electrode using a metal, such as, for example, lithium (Li), magnesium (Mg), aluminum (Al), silver (Ag), calcium (Ca), or a combination thereof; or an alloy, such as, for example, aluminum-lithium (Al—Li), magnesium-indium (Mg—In), magnesium-silver (Mg—Ag), or a combination thereof. The second electrode 180 may be formed with a thickness of, for example, from about 10 nm to about 200 nm, for example, from about 50 nm to about 150 nm. Alternatively, the second electrode 180 may be formed as a transparent electrode by a thin film of a metal material having a thickness of 20 nm or less, as a transparent conductive film, such as, for example, indium tin oxide (In₂O₃—SnO₂) or indium zinc oxide (In₂O₃—ZnO).

Regarding the film-forming method of layers other than organic films containing a cured product (and a carboxyl group-containing compound if necessary) according to one or more embodiments, it is not particularly limited. The layers other than the organic film containing a cured product (and a carboxyl group-containing compound if necessary) according to one or more embodiments may, for example, be formed by vacuum deposition or by a solution coating method.

### Positive Aging, and Carboxyl-Containing Compound

As stated, a unique technology of QD-LED is the positive aging caused by an acid compound, and by the positive aging, the luminous efficiency and device lifespan of QD-LEDs may be improved. An electroluminescent device (for example, a QD-LED) according to one or more embodiments may include an organic layer containing a cured material according to one or more embodiments. Thus, even when positive aging is performed using an acid compound, the reduction of driving voltage, and the improvement effects on durability (luminous lifetime) and luminous efficiency (current efficiency) of the device may be achieved. Therefore, the electroluminescent device according to one or more embodiments (for example, QD-LED) may have excellent performance.

Acidic compound used in the positive aging may include, for example, a carboxyl-containing compound, a sulfinic acid-containing compound, a sulfonic acid-containing compound, or the like. Among these, for instance, a carboxyl-containing compound may be used.

The carboxyl-containing compound may include at least one selected from, for example, acetic acid, propionic acid, butyric acid, valeric acid, caproic acid, malonic acid, succinic acid, glutaric acid, adipic acid, pimelic acid, (meth)acrylic acid, poly(meth)acrylic acid, benzoic acid, hexahydrobenzoic acid, terephthalic acid, 1,4-cyclohexanedicarboxylic acid, citric acid, malic acid, 3-isopropylmalic acid, itaconic acid, or citraconic acid, but embodiments are not limited thereto.

The method of positive aging is not particularly limited, for example, after fabricating a QD-LED, a resin containing an acid compound or a solution containing an acid compound (for example, a solution using alcohol as a solvent), is mounted or applied onto the first electrode or the second electrode of the QD-LED, and then irradiated with an active energy beam to form an acid compound layer. Thereafter, positive aging may be performed under a heat-treatment condition. At this time, the acid compound may be a compound containing a carboxyl group.

As a solvent used in a solution containing the acid compound, in addition to the solvent described herein, an alcohol solvent, for example, ethanol, n-propanol, isopropanol, butanol, methyl cellosolve, ethylene glycol monobutyl ether, or propylene glycol monomethyl ether may also be used. The aforementioned solvents may be used alone, or in combination of two or more different solvents. The concentration of the solution containing the acid compound may not be particularly limited, for example, of about 0.5% by weight or more and about 30% by weight or less, for instance, about 1% by weight or more and about 20% by weight or less.

The active energy rays used may include ultraviolet (UV) rays, such as, for example, the g-line (wavelength 436 nm), h-line (wavelength 405 nm), i-line (wavelength 365 nm), or the like. Additionally, wavelengths of less than or equal to about 300 nm, such as, for example, KrF rays (wavelength 248 nm), ArF rays (wavelength 193 nm), or the like may also be used. The cumulative luminous flux of the active energy rays may be, for example, greater than or equal to about 5 mJ/cm² and less than or equal to about 20 mJ/cm².

The thickness of the carboxyl-containing compound layer is not particularly limited, for example, the thickness may be greater than or equal to about 10 nm, greater than or equal to about 30 nm, greater than or equal to about 50 nm, greater than or equal to about 70 nm, greater than or equal to about 90 nm, greater than or equal to about 100 nm, greater than or equal to about 120 nm, greater than or equal to about 140 nm, greater than or equal to about 160 nm, greater than or equal to about 180 nm, greater than or equal to about 200 nm, greater than or equal to about 250 nm, greater than or equal to about 300 nm, greater than or equal to about 350 nm, greater than or equal to about 400 nm, greater than or equal to about 450 nm, greater than or equal to about 500 nm, greater than or equal to about 550 nm, greater than or equal to about 600 nm, greater than or equal to about 650 nm, greater than or equal to about 700 nm, greater than or equal to about 750 nm, greater than or equal to about 800 nm, greater than or equal to about 850 nm, greater than or equal to about 900 nm, greater than or equal to about 950 nm, greater than or equal to about 1 μm, or greater than or equal to about 1.5 μm. In addition, the thickness of the carboxyl-containing compound layer may be, for example, less than or equal to about 100 μm, less than or equal to about 90 μm, less than or equal to about 80 μm, less than or equal to about 70 μm, less than or equal to about 60 μm, less than or equal to about 50 μm, less than or equal to about 40 μm, less than or equal to about 30 μm, less than or equal to about 20 μm, less than or equal to about 10 μm, less than or equal to about 9 μm, less than or equal to about 8 μm, less than or equal to about 7 μm, less than or equal to about 6 μm, less than or equal to about 5 μm, less than or equal to about 4 μm, less than or equal to about 3 μm, less than or equal to about 2 μm, or less than or equal to about 1 μm.

The QD-LED device, in which this carboxyl-containing compound layer has been formed, may be maintained at a predetermined temperature for a predetermined period to perform positive aging. The period of positive aging may, for example, be about 12 hours or more, about 20 hours or more, about 24 hours or more, about 2 days or more, or about 3 days or more. In addition, the period of positive aging may, for example, be about 30 days or less, about 20 days or less, about 10 days or less, or about 7 days or less, and these examples are not limiting.

The temperature for positive aging may be, for example, greater than or equal to about 30° C., greater than or equal to about 35° C., greater than or equal to about 40° C., greater than or equal to about 50° C., greater than or equal to about 55° C., greater than or equal to about 60° C., or greater than or equal to about 65° C.

After performing positive aging, the cured material and the carboxyl-containing compound according to one or more embodiments may be included in any one of the layers (organic layers) arranged between, for example, the first electrode 120 and the second electrode 180. That is, according to one or more embodiments, an organic layer (hereinafter also referred to as “the organic layer according to an embodiment”) including a cured product and a carboxyl group-containing compound according to one or more embodiments may be provided. According to another embodiment, an electroluminescent device is provided, the electroluminescent device including a first electrode layer that supplies holes, a second electrode layer that supplies electrons, and at least one organic layer provided between the first electrode layer and the second electrode layer, wherein at least one layer of the at least one organic layer includes an organic film including a cured product and a carboxyl group-containing compound according to one or more embodiments.

According to one or more embodiments, the cured product and the carboxyl-containing compound may be included in the hole injection layer 130 as a hole injection material, in the hole transport layer 140 as a hole transport material, or in the light-emitting layer 150 as a light-emitting material (host). For example, the cured product and the carboxyl-containing compound according to one or more embodiments may be included in the hole injection layer 130 as a hole injection material, or in the hole transport layer 140 as a hole transport material. For example, a cured material according to one or more embodiments and a carboxyl-containing compound may be included in the hole injection layer 130 as a hole injection material. That is, in one or more embodiments, at least one layer selected from the hole transport layer, the hole injection layer, or the light emitting layer may include an organic film according to one or more embodiments described herein. In one or more embodiments, at least one layer selected from the hole transport layer or the hole injection layer may include an organic film according to one or more embodiments described herein. In one or more embodiments, the hole injection layer may include an organic film according to an embodiment.

The cured material of the copolymer according to one or more embodiments may have a good resistance to a solvent used in a coating solution for forming an adjacent layer to a hole injection layer, and/or a hole transport layer. The solvent used for forming the adjacent layer may include, for example, cyclohexane, hexane, octane, decane, tetradecane, hexadecane, indane, butanol, octanol, cyclohexylbenzene, dodecylbenzene, o-dichlorobenzene, or the like, but embodiments are not limited thereto. Therefore, the cured material of the copolymer according to an embodiment may have good resistance to the solvents.

As used herein, evaluation of resistance to a solvent of a cured material of a copolymer may be performed based on the retention rate calculated by the method as described herein.

### Resistance to Solvent (Retention Rate)

Resistance to a solvent of a cured material of a copolymer is evaluated by the method as described herein. That is, a copolymer is dissolved in xylene, i.e., a solvent, at a concentration of 1 wt % to prepare a copolymer coating solution. Next, the coating solution of the copolymer is coated onto a quartz substrate using a spin coating method and dried (cured) at 230° C. for 30 minutes to form a film with a dry thickness of 25 nm. Then, an absorption spectrum of the formed film (the film before solvent immersion) is measured by using a UV-visible spectrophotometer (manufactured by Kabushiki Kaisha Shimadzu Seisakusho (Shimadzu Corporation), UV-1800). The wavelength of the peak at the longest wavelength side of the absorption spectrum is used as the reference wavelength.

Subsequently, the same film on a quartz substrate (the film before solvent immersion) is immersed in cyclohexylbenzene (CHB), a solvent, for 20 minutes, removed from the solvent, and dried (cured) at 230° C. for 30 minutes. The absorption spectrum of the dried film (the film after solvent immersion) is measured by using the ultraviolet-visible spectrophotometer in the same manner as above. For this absorption spectrum, the ratio of the intensity at the reference wavelength of the absorption spectrum after solvent immersion to the intensity at the reference wavelength of the absorption spectrum before solvent immersion {(‘Intensity at the reference wavelength of the absorption spectrum after solvent immersion’/‘Intensity at the reference wavelength of the absorption spectrum before solvent immersion’)×100(%)} is defined as the retention rate (%), and evaluated.

For example, the retention rate obtained above may be greater than or equal to about 80%, or, for example, may be greater than or equal to about 90%. When the retention rate is greater than or equal to about 80%, it may be considered equivalent to the cured product of the copolymer not dissolving in a solvent used for forming an adjacent layer, e.g., having high solvent resistance. If the retention rate is less than about 80%, mixing may occur between the hole injection layer or the hole transport layer and the adjacent layer, which may lead to a deterioration in performance of the electroluminescent device.

In summary, as an example of an electroluminescent device according to one or more embodiments, the EL device 100 according to one or more embodiments has been described. The EL device 100 according to one or more embodiments may include an organic layer (for example, a hole transport layer or a hole injection layer) that includes a cured material according to one or more embodiments and a carboxyl group-containing compound. As a result, the EL device may exhibit excellent positive aging resistance, improved durability (luminous lifespan), and good luminous efficiency (current efficiency), leading to an EL device with reduced driving voltage. Further, the EL device 100 according to one or more embodiments may have good resistance to a solvent used for forming an adjacent layer.

The laminated structure of the EL device 100 according to one or more embodiments is not limited to the above example. The EL device 100 according to one or more embodiments may be formed with another known laminated structure. For example, in the EL device 100, one or more of the hole injection layer 130, the hole transport layer 140, the electron transport layer 160, and/or the electron injection layer 170 may be omitted, and additionally, other layers may be provided. Furthermore, each layer of the EL device 100 may be formed as a single layer or as multiple layers.

For example, the EL device 100 may further include a hole blocking layer disposed between the hole transport layer 140 and the light emitting layer 150 to prevent excitons or holes from diffusing into the electron transport layer 160. The hole blocking layer may be formed, for example, from oxadiazole derivatives, triazole derivatives, phenanthroline derivatives, or the like.

In addition, a composition according to one or more embodiments may be applied to electroluminescent devices other than the QD-LED or OLED. Other electroluminescent devices to which the composition according to one or more embodiment can be applied are not particularly limited, but for example, may include organic-inorganic perovskite light-emitting devices, or the like.

Although the aspects and features have been described in detail according to one or more embodiments, these are descriptive and exemplary, not limiting, and it is clear that the scope of the embodiments should be interpreted according to the attached claims.

The above detailed description includes the following exemplary embodiments.

1. A composition including:
a copolymer including a structural unit represented by Chemical Formula 1, and at least one structural unit of Structural unit A represented by Chemical Formula 2 or Structural unit B represented by Chemical Formula 3, and
a salt compound including a borate anion represented by Chemical Formula 4, and an iodonium cation,
wherein an energy difference (ΔE) between an ionization potential of the copolymer and an electron affinity of the borate anion is greater than or equal to about 0.75 eV, and the ionization potential of the copolymer is deeper than an ionization potential of the iodonium cation:

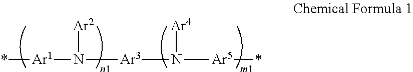

wherein in Chemical Formula 1,
Ar¹, Ar², Ar⁴, and Ar⁵ are, each independently, a substituted or unsubstituted aromatic hydrocarbon ring group, or a substituted or unsubstituted aromatic heterocyclic group,
Ar³ is a substituted or unsubstituted carbazole, a substituted or unsubstituted fluorene, a substituted or unsubstituted benzene, or a substituted or unsubstituted biphenylene group,
wherein when Ar³ is a substituted or unsubstituted benzene, or a substituted or unsubstituted biphenylene group, then at least one of Ar¹ or Ar² is not a substituted or unsubstituted benzene, and at least one of Ar⁴ or Ar⁵ is not a substituted or unsubstituted benzene,
n1 is an integer of greater than or equal to 1 and less than or equal to 3,
m1 is an integer of greater than or equal to 1 and less than or equal to 3, and
* is a bonding position to an adjacent atom;

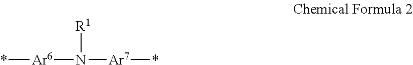

wherein in Chemical Formula 2,
Ar⁶ and Ar⁷ are, each independently, a substituted or unsubstituted aromatic hydrocarbon ring group, or a substituted or unsubstituted aromatic heterocyclic group, and Ar⁶ and Ar⁷ optionally form a ring together,
R¹ is a group represented by chemical formula (2-a),

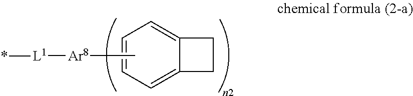

wherein in chemical formula (2-a),
L¹ is a single bond, or a group represented by chemical formula (2-b),
Ar⁸ is a substituted or unsubstituted aromatic hydrocarbon ring group, or a substituted or unsubstituted aromatic heterocyclic group,
wherein, when L¹ is a single bond, then at least one of Ar⁶, Ar⁷ or Ar⁸ is not a substituted or unsubstituted a benzene group, or Ar⁸ optionally forms a ring together with at least one of Ar⁶ or Ar⁷,
n2 is an integer of greater than or equal to 2 and less than or equal to 5, and
* is a bonding position to an adjacent atom,

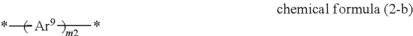

wherein in chemical formula (2-b),
Ar⁹ is a substituted or unsubstituted aromatic hydrocarbon ring group, or a substituted or unsubstituted aromatic heterocyclic group, or Ar⁹ optionally forms a ring together with at least one of Ar⁶ or Ar⁷,
m2 is an integer of greater than or equal to 2 and less than or equal to 5, wherein when m2 is an integer of greater than or equal to 2, each Ar⁹ is the same or different, and
* is a bonding position to an adjacent atom,

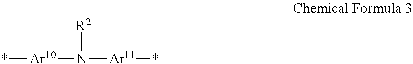

wherein in Chemical Formula 3,
Ar¹⁰ and Ar¹¹ are, each independently, a substituted or unsubstituted aromatic hydrocarbon ring group, or a substituted or unsubstituted aromatic heterocyclic group, and Ar¹⁰ and Ar¹¹ optionally form a ring together,
R² is a group represented by chemical formula (3-a) or chemical formula (3-b), and
* is a bonding position to an adjacent atom,

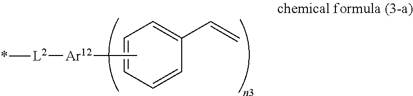

wherein in chemical formula (3-a),
L² is a single bond, or a group represented by chemical formula (3-c),
Ar¹² is a substituted or unsubstituted aromatic hydrocarbon ring group, or a substituted or unsubstituted aromatic heterocyclic group,
wherein, when L² is a single bond, Ar¹² optionally forms a ring together with at least one of Ar¹⁰ or Ar¹¹,
n3 is an integer of greater than or equal to 2 and less than or equal to 5, and
* is a bonding position to an adjacent atom;

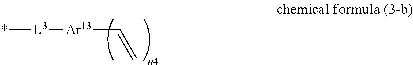

wherein in chemical formula (3-b),
L³ is a single bond, or a group represented by chemical formula (3-c),
Ar¹³ is a substituted or unsubstituted aromatic hydrocarbon ring group, or a substituted or unsubstituted aromatic heterocyclic group,
wherein, when L³ is a single bond, Ar¹³ optionally forms a ring together with at least one of Ar¹⁰ or Ar¹¹,
n4 is an integer of greater than or equal to 2 and less than or equal to 5, and
* is a bonding position to an adjacent atom;

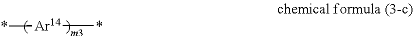

wherein in chemical formula (3-c),
Ar¹⁴ is a substituted or unsubstituted aromatic hydrocarbon ring group, or a substituted or unsubstituted aromatic heterocyclic group, or Ar¹⁴ optionally forms a ring together with at least one of Ar¹⁰ or Ar¹¹
m3 is an integer of greater than or equal to 1 and less than or equal to 5, and when m3 is an integer of greater than or equal to 2, each Ar¹⁴ is the same or different, and
* is a bonding position to an adjacent atom;

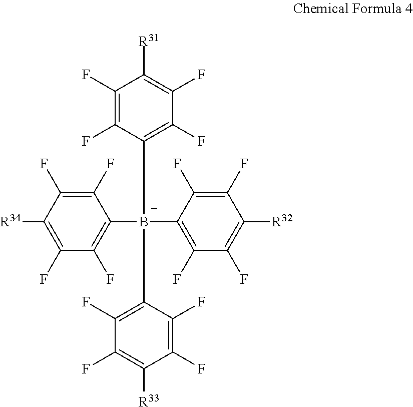

wherein in Chemical Formula 4,
R³¹ to R³⁴ are, each independently a hydrogen atom, a fluorine atom, or a group represented by chemical formula (4-a):

*-L⁴-(Ar¹⁵)ₙ₆—(X)ₙ₅ chemical formula (4-a)
wherein in chemical formula (4-a),
L⁴ is a single bond, or a group represented by chemical formula (4-b),
Ar¹⁵ is a substituted or unsubstituted aromatic hydrocarbon ring group, or a substituted or unsubstituted aromatic heterocyclic group,
X is a fluorine atom, or a group selected from Group (4-1),
n5 is an integer of greater than or equal to 1 and less than or equal to 5,
n6 is an integer of 0 or 1, wherein,
when multiple groups represented by chemical formula (4-a) are present, each L⁴ is the same or different,
when multiple groups represented by chemical formula (4-a) are present, each Ar¹⁵ is the same or different,
when multiple groups represented by chemical formula (4-a) are present, each X is the same or different,
when multiple groups represented by chemical formula (4-a) are present, each n5 is the same or different,
when multiple groups represented by chemical formula (4-a) are present, each n6 is the same or different,
when n5 is an integer of greater than or equal to 2, each X is the same or different, and
* is a bonding position to an adjacent atom,

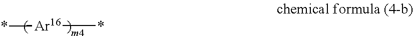

wherein in chemical formula (4-b),
Ar¹⁶ is a substituted or unsubstituted aromatic hydrocarbon ring group, or a substituted or unsubstituted aromatic heterocyclic group,
m4 is an integer of greater than or equal to 1 and less than or equal to 5, and when m4 is greater than or equal to 2, each Ar¹⁶ is the same or different, and
* is a bonding position to an adjacent atom,

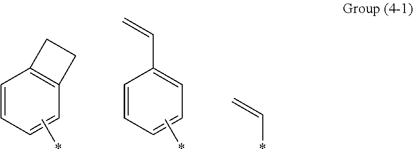

in Group (4-1),
* is a bonding position to an adjacent atom.

2. The composition according to item 1, wherein the borate anion is selected from the groups represented below:

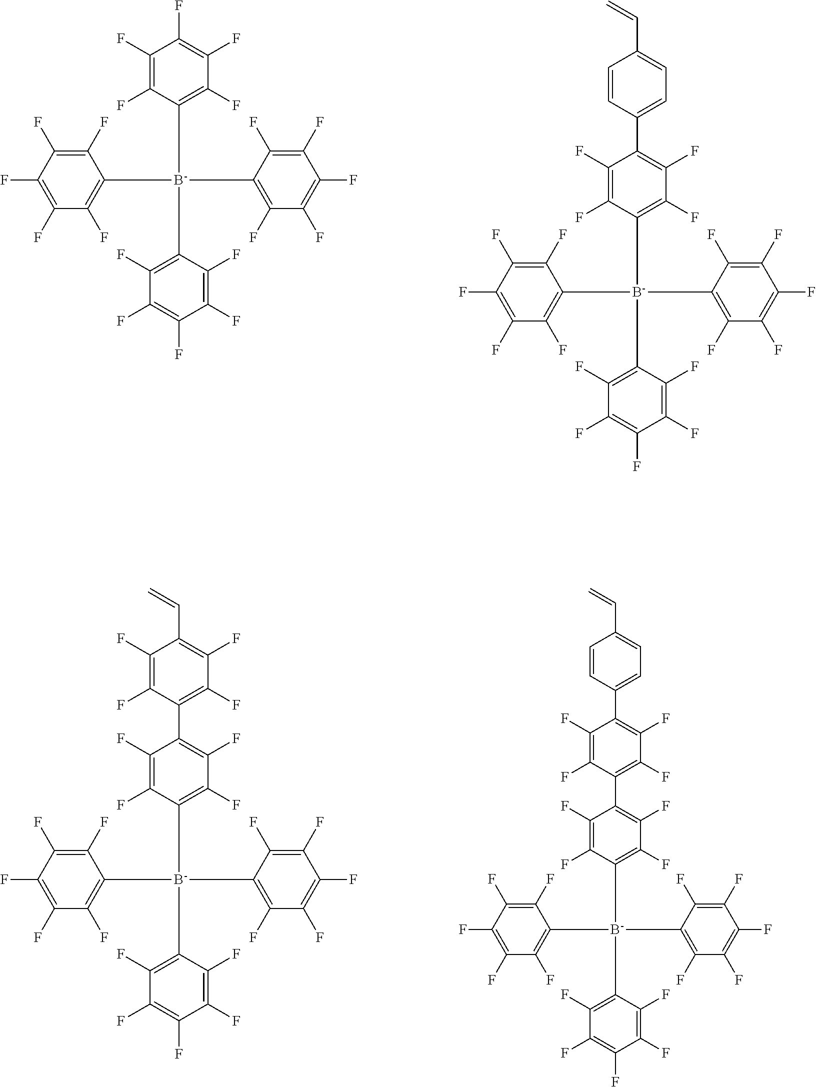 [SMILES: Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F ; C=Cc1ccc(-c2c(F)c(F)c([B-](c3c(F)c(F)c(F)c(F)c3F)(c3c(F)c(F)c(F)c(F)c3F)c3c(F)c(F)c(F)c(F)c3F)c(F)c2F)cc1 ; C=Cc1c(F)c(F)c(-c2c(F)c(F)c([B-](c3c(F)c(F)c(F)c(F)c3F)(c3c(F)c(F)c(F)c(F)c3F)c3c(F)c(F)c(F)c(F)c3F)c(F)c2F)c(F)c1F ; C=Cc1ccc(-c2c(F)c(F)c(-c3c(F)c(F)c([B-](c4c(F)c(F)c(F)c(F)c4F)(c4c(F)c(F)c(F)c(F)c4F)c4c(F)c(F)c(F)c(F)c4F)c(F)c3F)c(F)c2F)cc1]

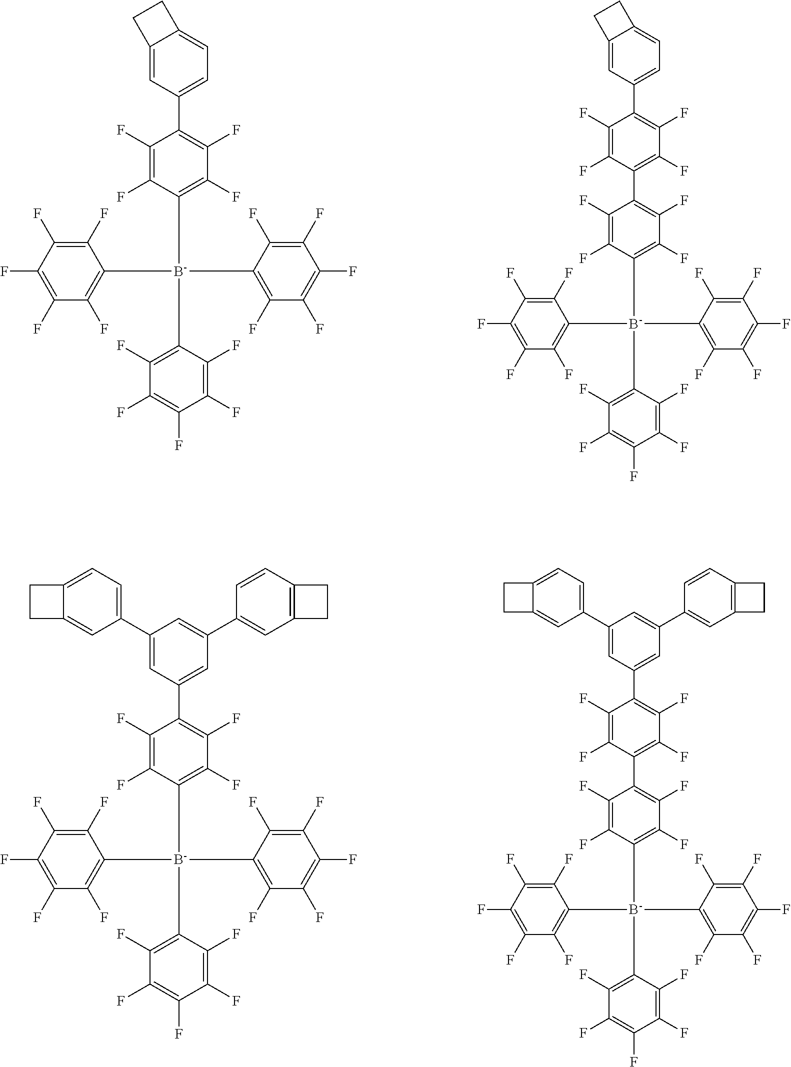

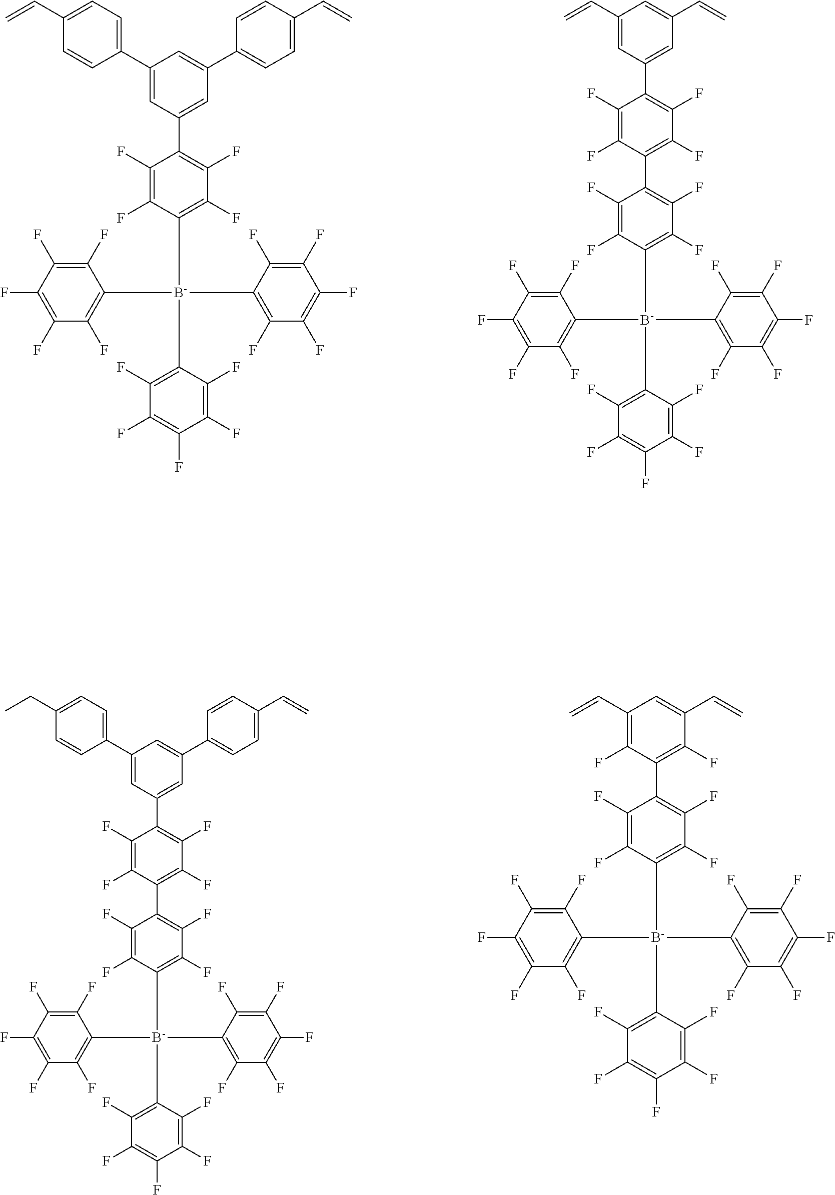

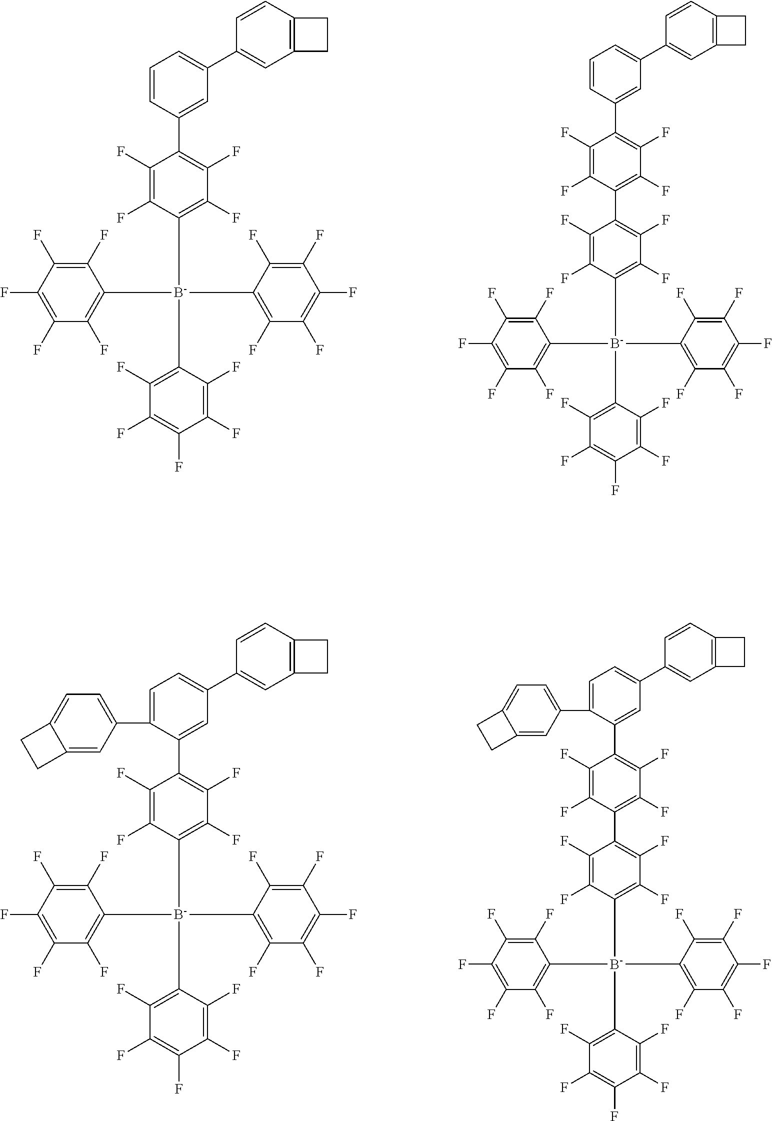

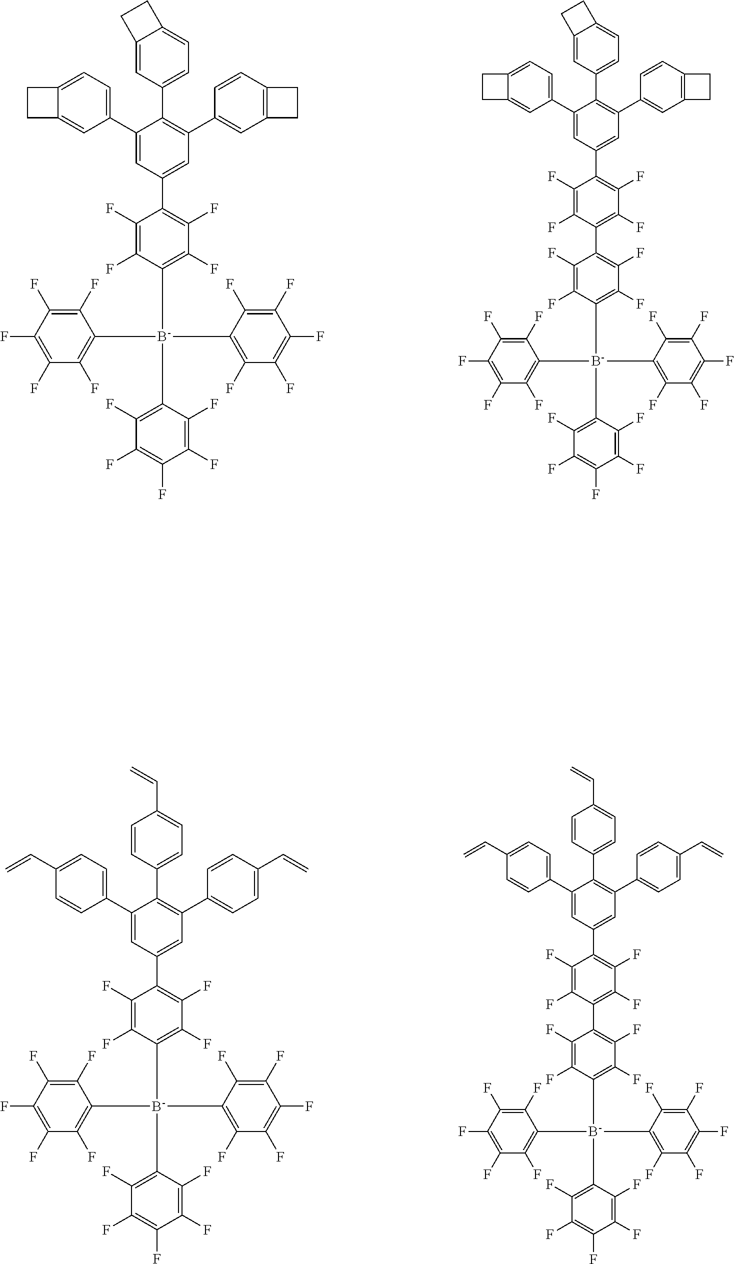

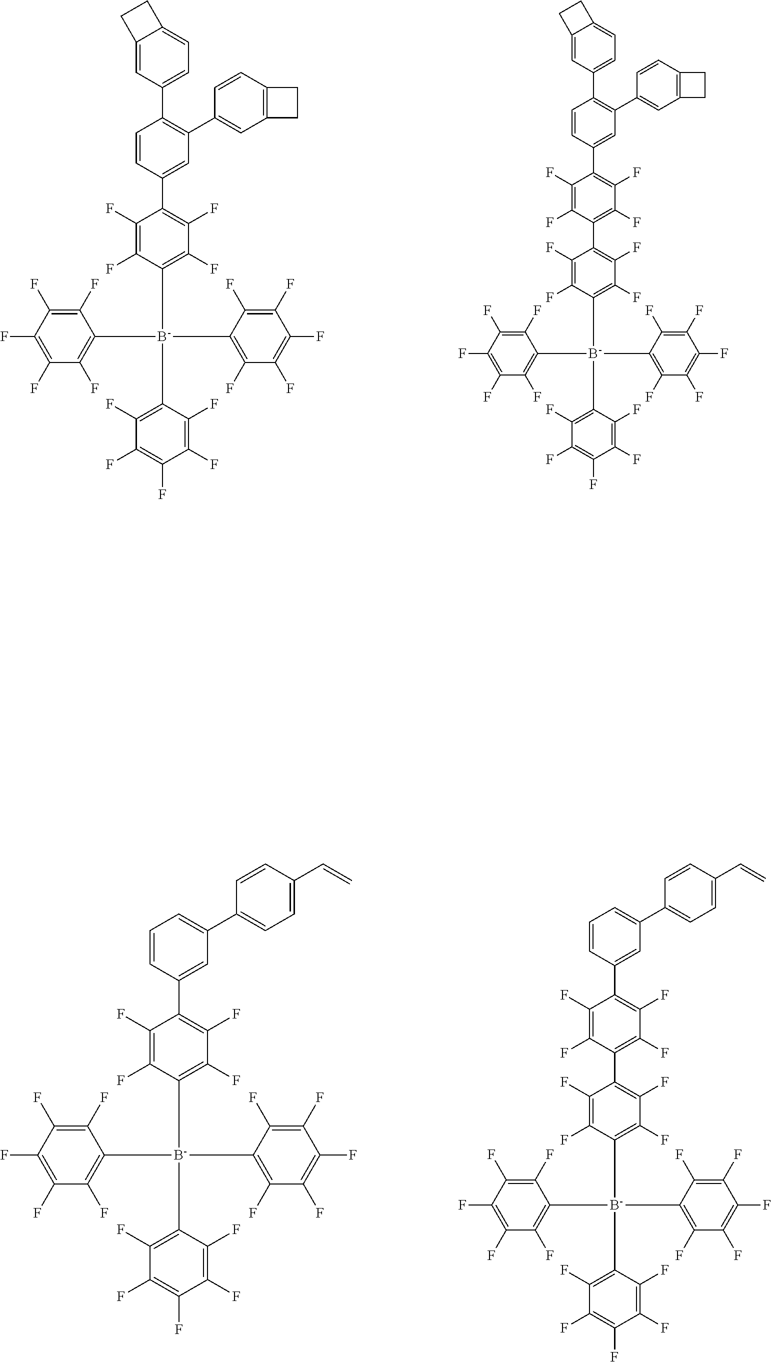

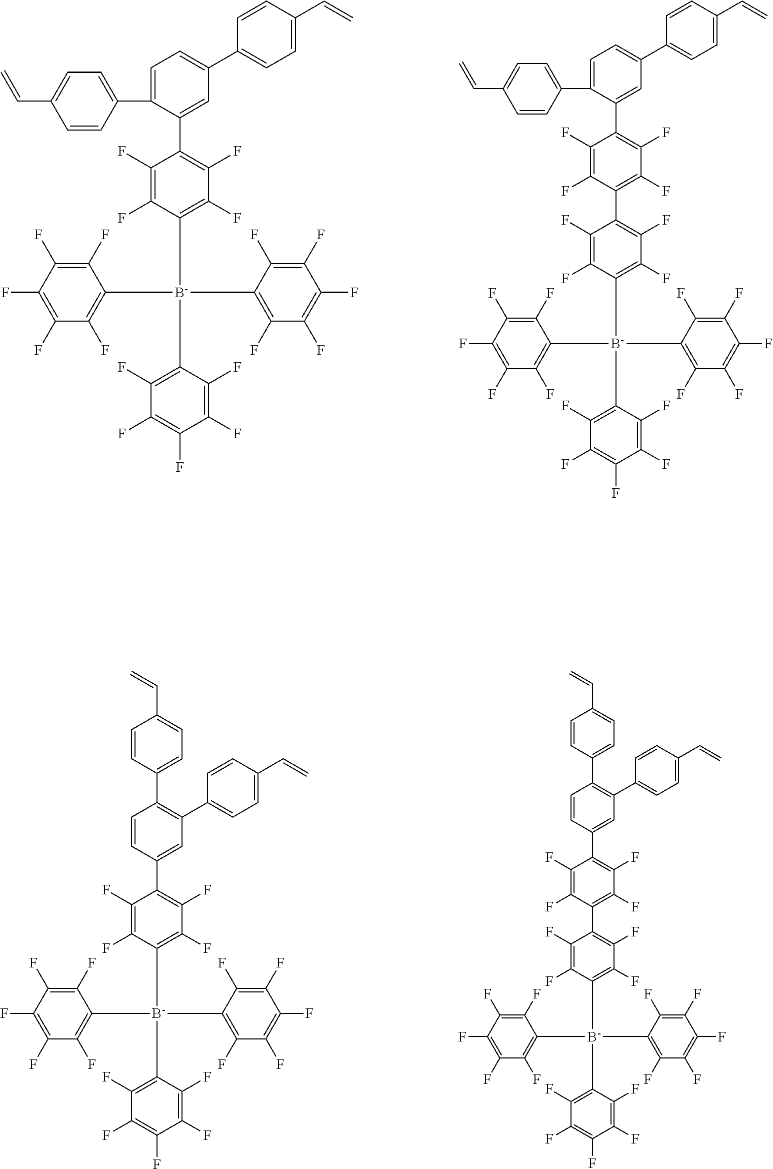

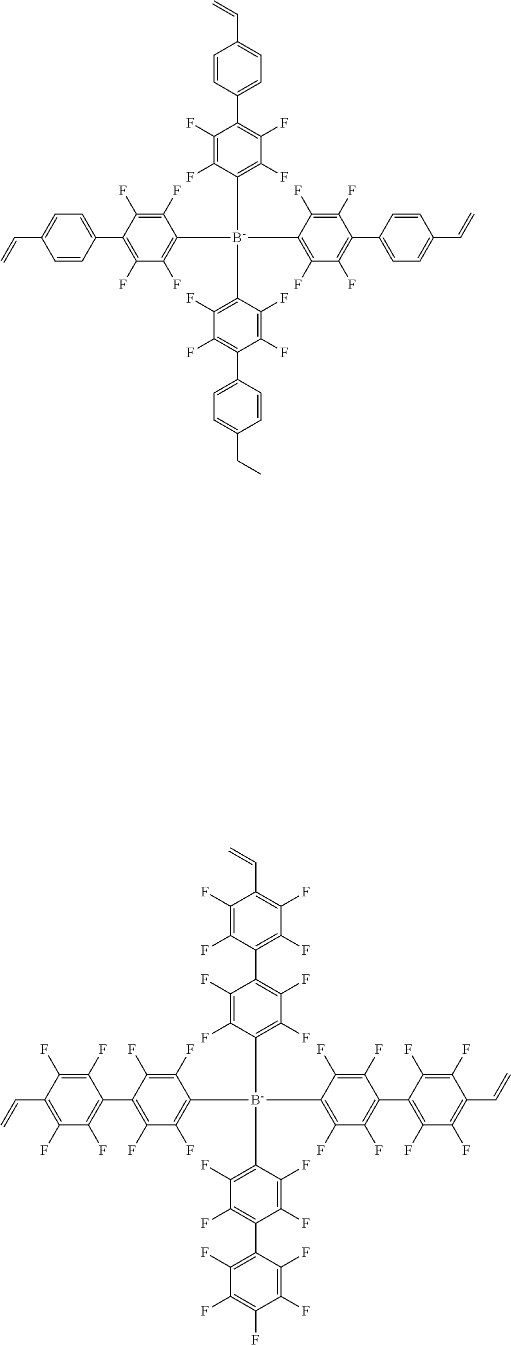

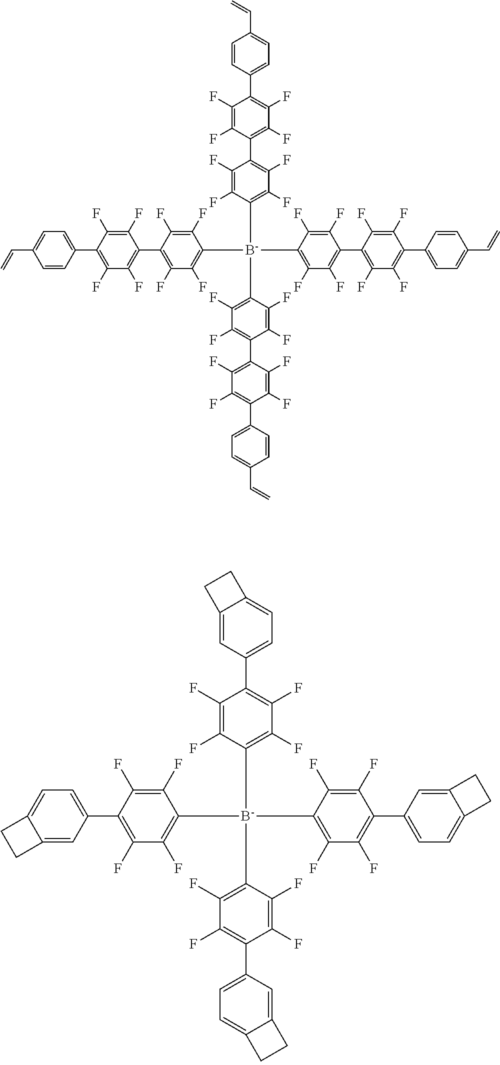

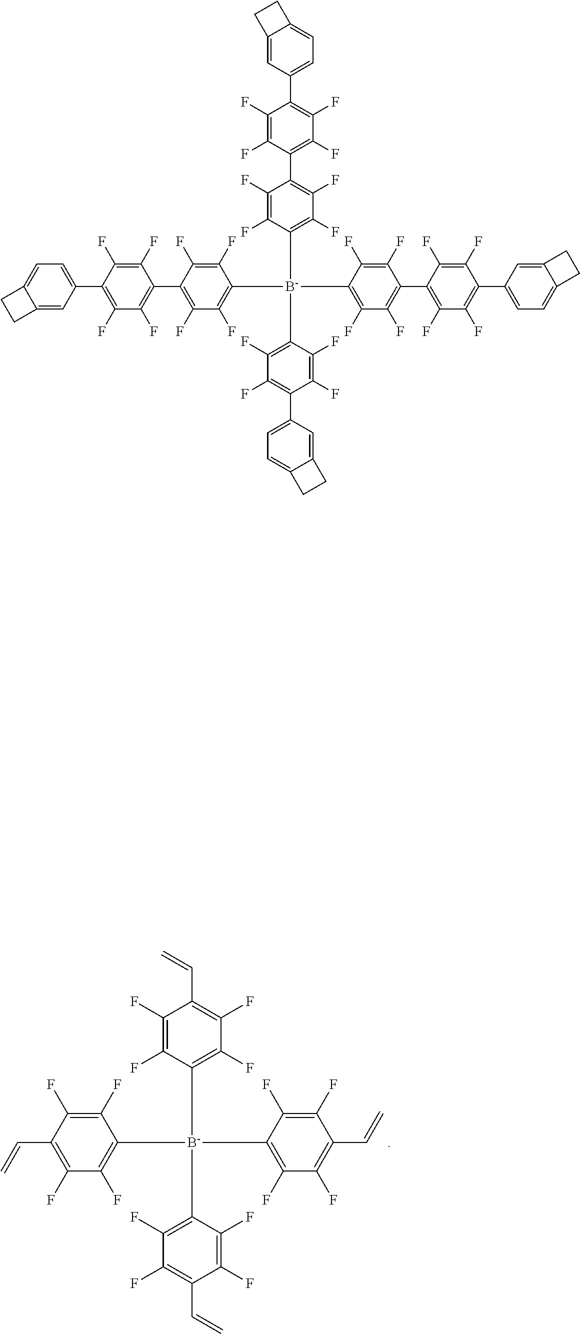 [SMILES: Fc1c(F)c(-c2c(F)c(F)c([B-](c3c(F)c(F)c(-c4ccc5c(c4)CC5)c(F)c3F)(c3c(F)c(F)c(-c4c(F)c(F)c(-c5ccc6c(c5)CC6)c(F)c4F)c(F)c3F)c3c(F)c(F)c(-c4c(F)c(F)c(-c5ccc6c(c5)CC6)c(F)c4F)c(F)c3F)c(F)c2F)c(F)c(F)c1-c1ccc2c(c1)CC2 ; C=Cc1c(F)c(F)c([B-](c2c(F)c(F)c(C=C)c(F)c2F)(c2c(F)c(F)c(C=C)c(F)c2F)c2c(F)c(F)c(C=C)c(F)c2F)c(F)c1F]

3. The composition according to any one of item 1 or 2, wherein the structural unit represented by Chemical Formula 1 is selected from Group (1-1) to Group (1-3):

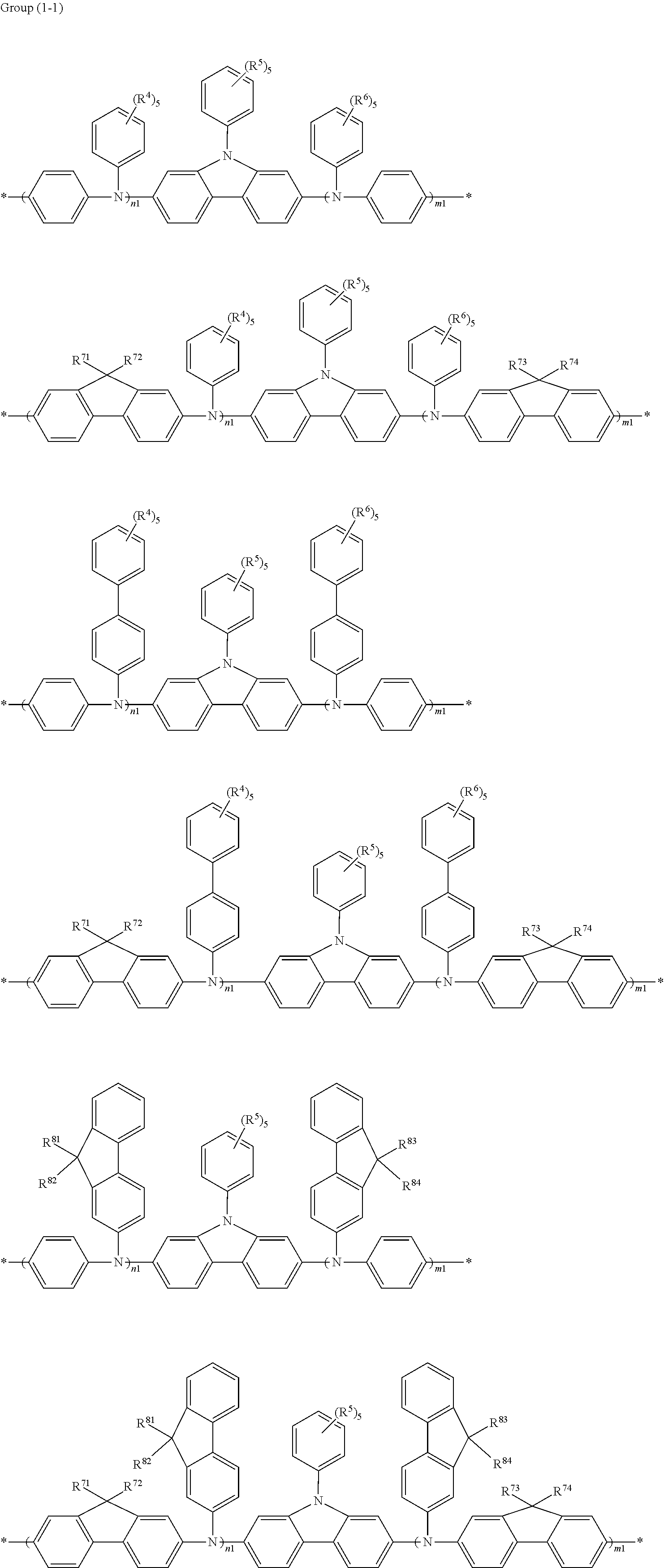

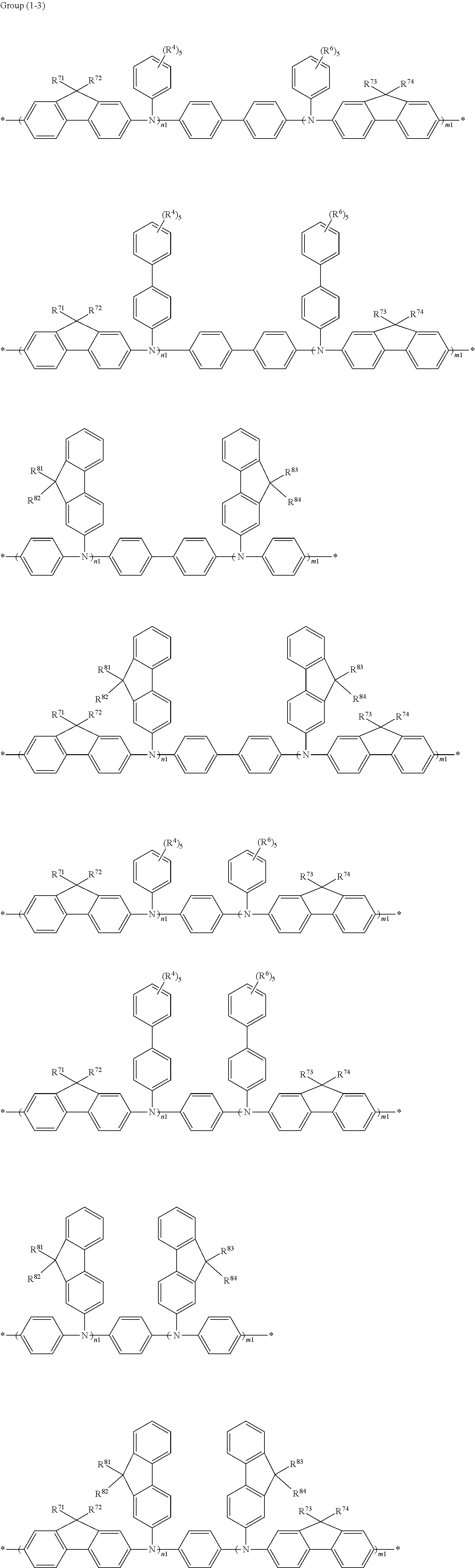

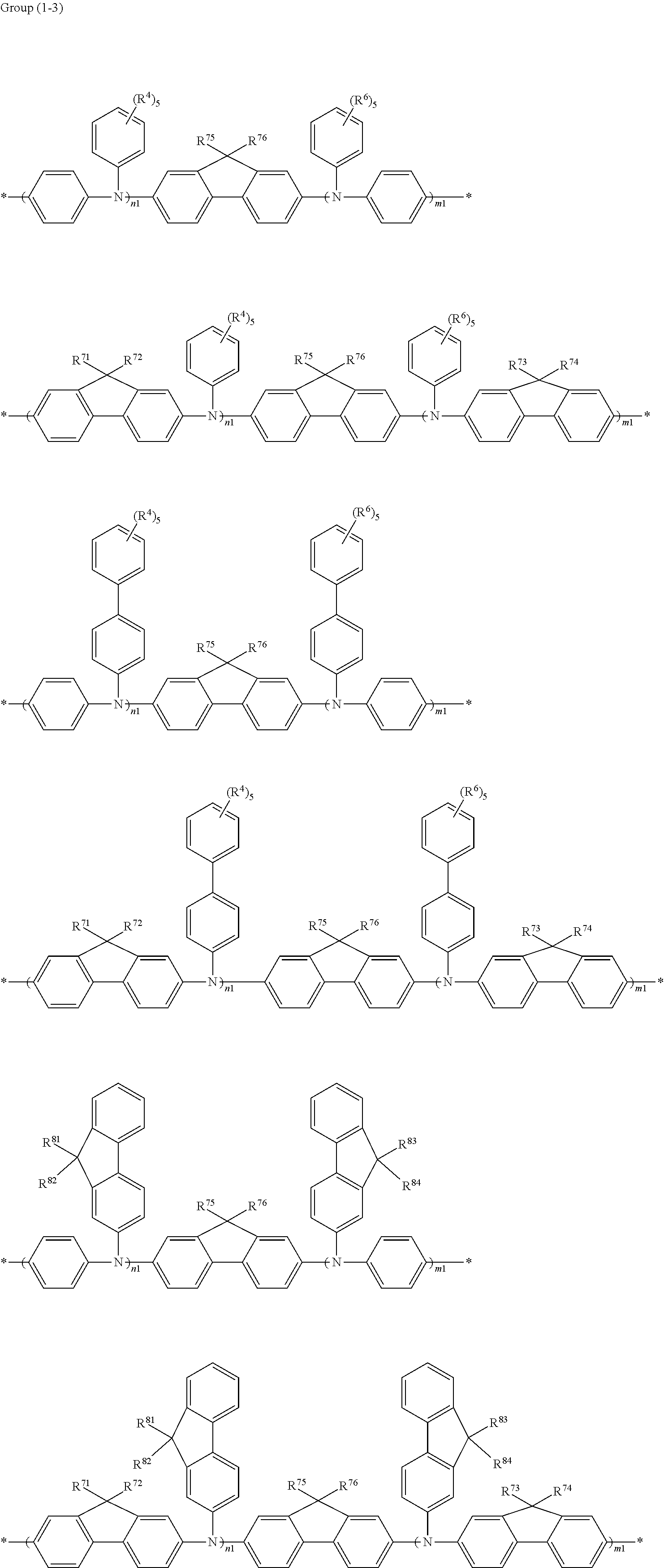

wherein in Group (1-1) to Group (1-3),
R⁴ to R⁶, R⁷¹ to R⁷⁶, and R⁸¹ to R⁸⁴ are, each independently, a hydrogen atom, or a hydrocarbon group having 1 to 20 carbon atoms,
each n1 represents an integer of greater than or equal to 1 and less than or equal to 3,
each m1 represents an integer of greater than or equal to 1 and less than or equal to 3, and
* is a bonding position to an adjacent atom.

4. The composition according to any one of items 1 to 3, wherein the Structural unit A represented by Chemical Formula 2 is selected from Group 2:

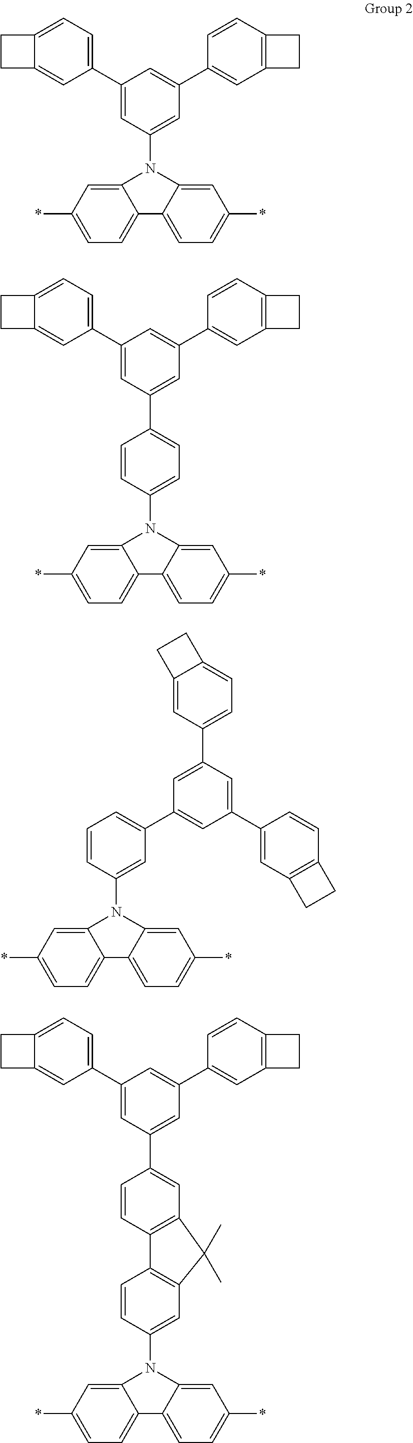

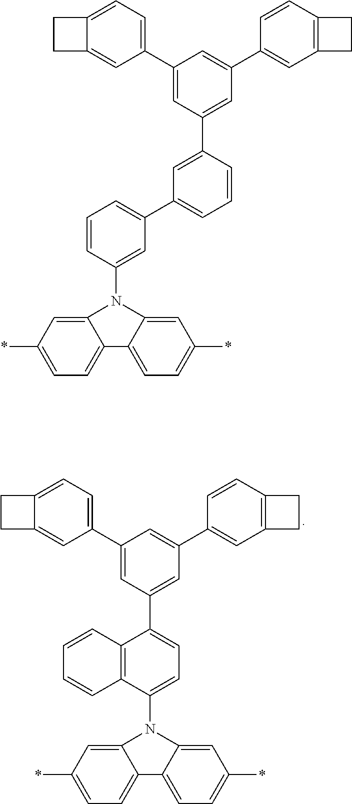

wherein the chemical formulae in Group 2, * is a bonding position to an adjacent atom.

5. The composition according to any one of items 1 to 4, wherein the Structural unit B represented by Chemical Formula 3 is selected from Group 3:

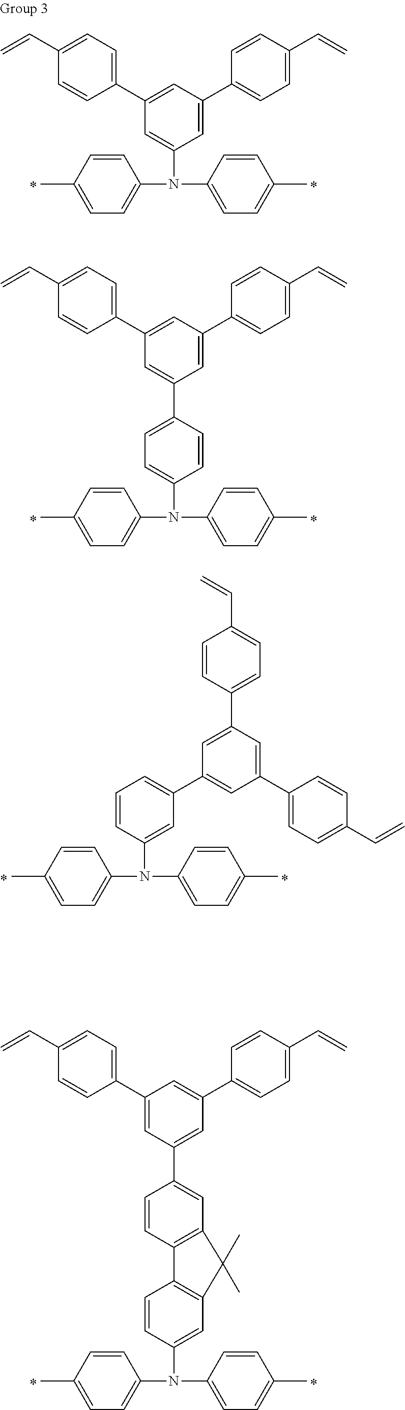

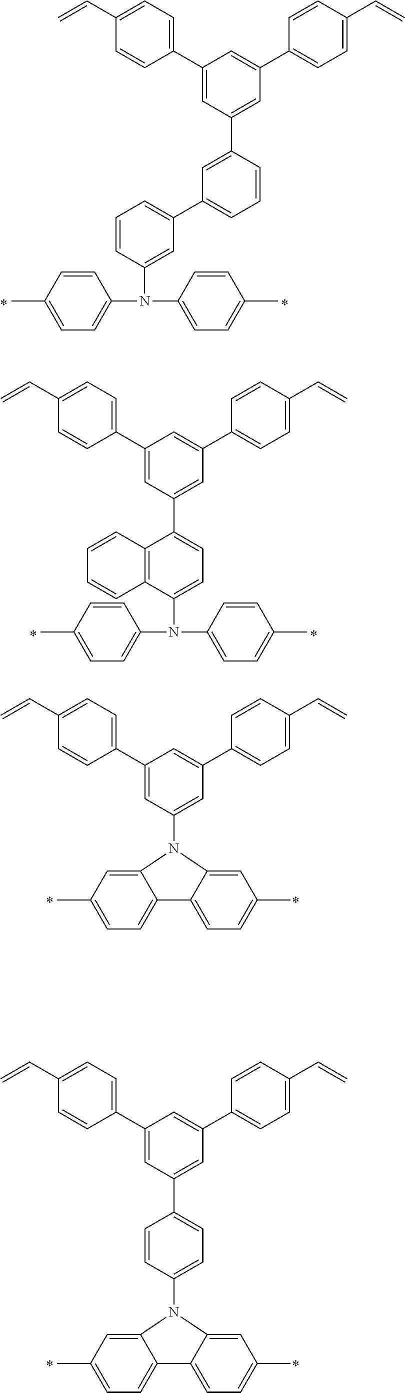

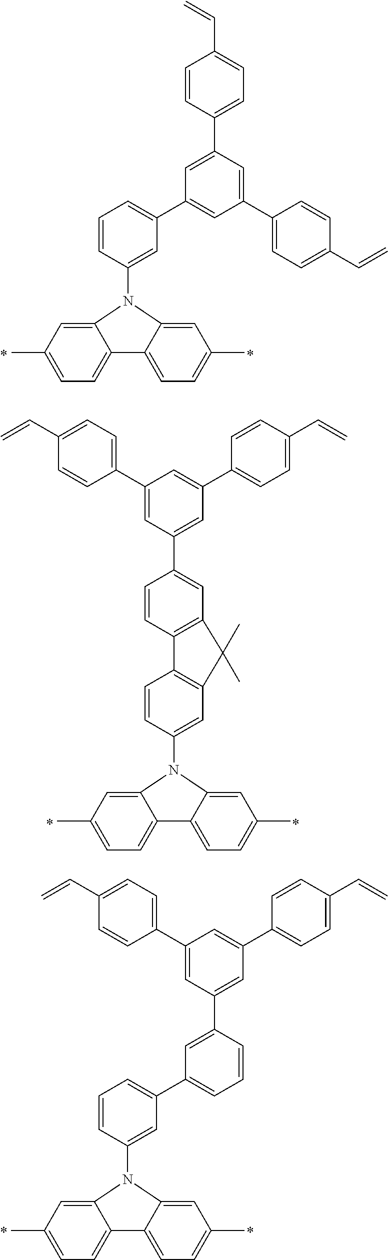

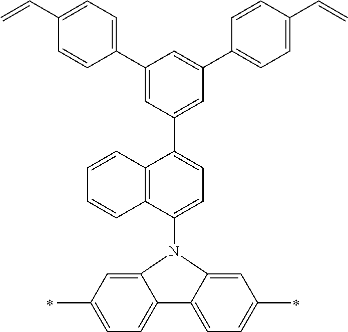

wherein the chemical formulae in Group 3, * is a bonding position to an adjacent atom.

6. The composition according to any one of items 1 to 5, wherein the copolymer is selected from the following chemical formulae:

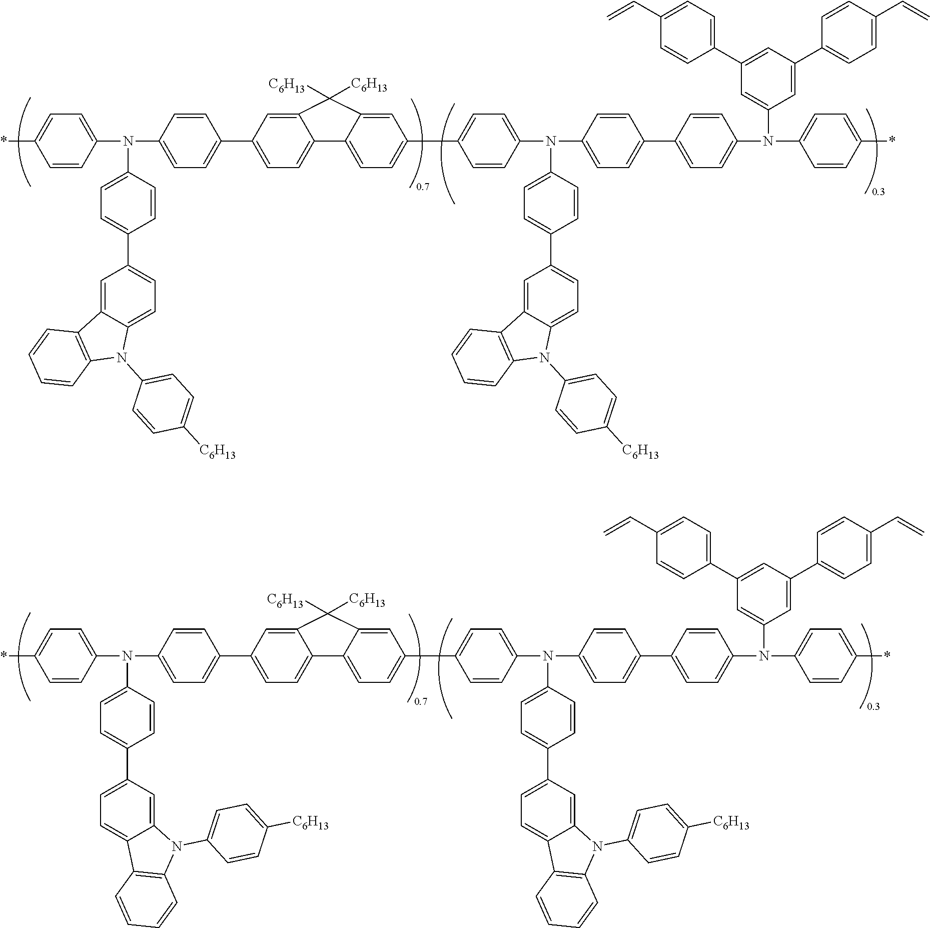

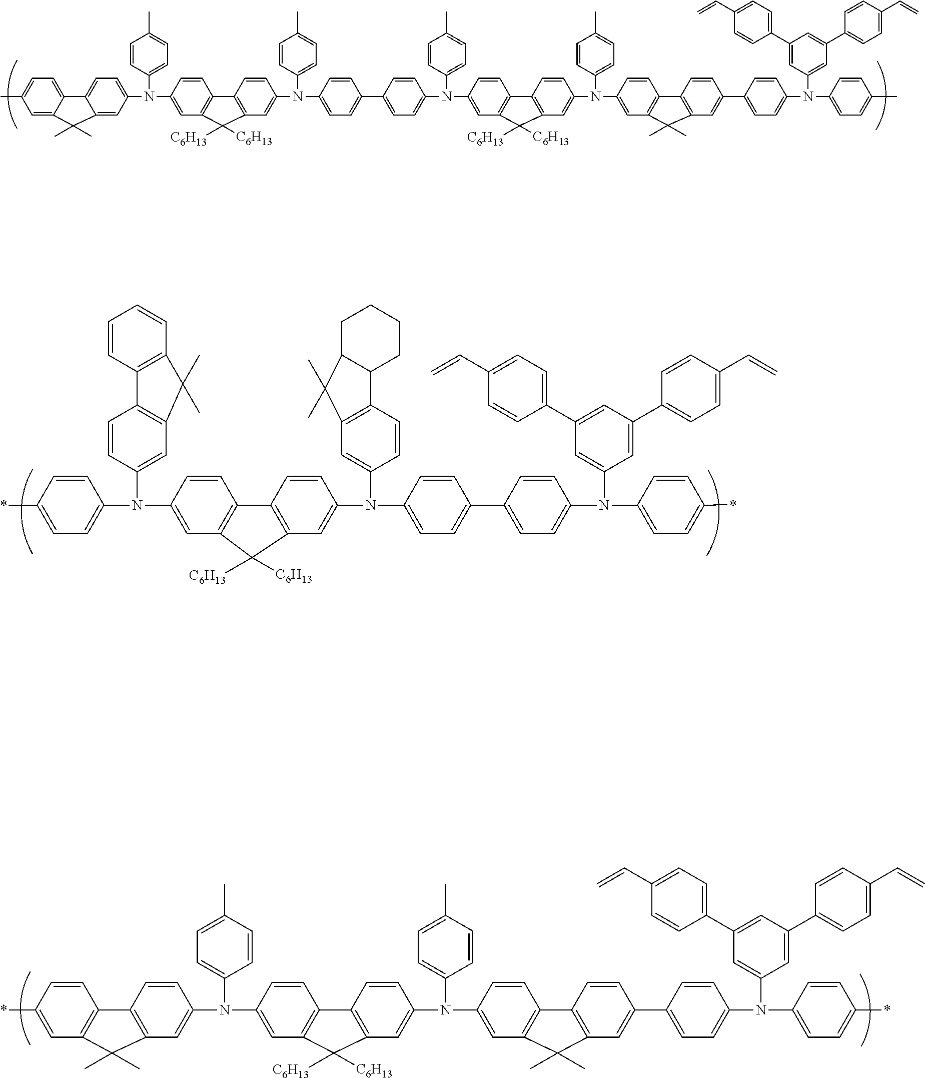

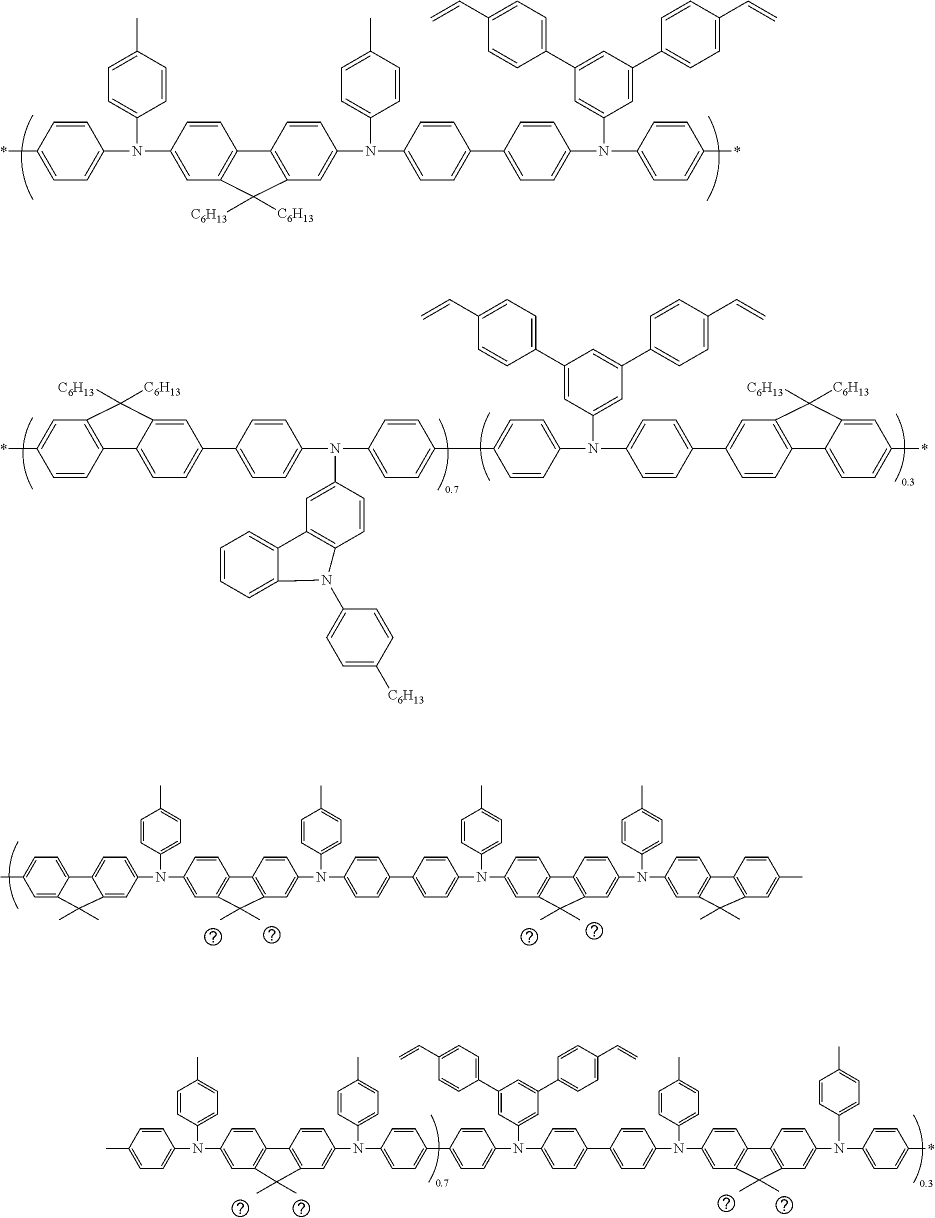

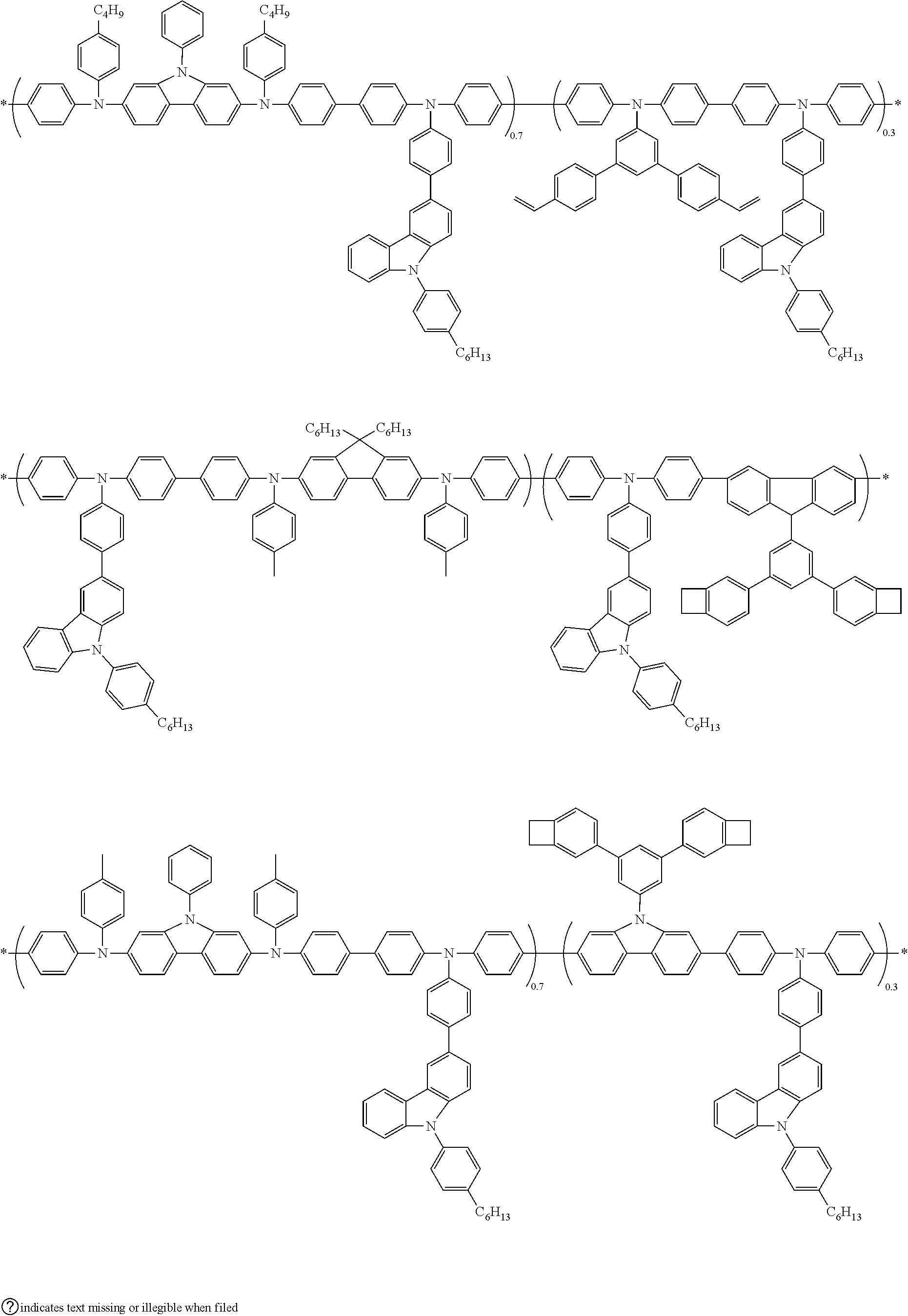

wherein in the chemical formulae, * is a bonding position to an adjacent atom.

7. The composition according to any one of items 1 to 6, wherein a mole ratio of the structural unit represented by Chemical Formula 1 is greater than or equal to about 20 mole % and less than or equal to about 99 mole %, based on a total number of moles of the structural unit represented by Chemical Formula 1, the Structural unit A represented by Chemical Formula 2, and the Structural unit B represented by Chemical Formula 3 in the copolymer.

8. The composition according to any one of items 1 to 7, wherein a mole ratio of the at least one of the Structural unit A represented by Chemical Formula 2 or the Structural unit B represented by Chemical Formula 3 is greater than or equal to about 1 mole % and less than or equal to about 80 mole %, based on a total number of moles of the structural unit represented by Chemical Formula 1, the Structural unit A represented by Chemical Formula 2, and the Structural unit B represented by Chemical Formula 3 in the copolymer.

9. The composition according to any one of items 1 to 8, wherein a weight average molecular weight (Mw) of the copolymer is greater than or equal to about 8,000 Da and less than or equal to about 500,000 Da, as determined by size exclusion chromatography.

10. The composition according to any one of items 1 to 9, wherein an amount of the salt compound in the composition is greater than or equal to about 1 wt % and less than or equal to about 70 wt %, based on a total weight of the copolymer and the salt compound.

11. The composition according to any one of items 1 to 10, wherein an electron affinity of the borate anion is greater than or equal to about 5.50 eV and less than or equal to about 6.50 eV.

12. The composition according to any one of items 1 to 11, wherein the iodonium cation is any one of a difuryliodonium cation, a dithienyliodonium cation, a bis(4,5-dimethyl-2-furyl) iodonium cation, a bis(5-chloro-2-thienyl) iodonium cation, a bis(5-cyano-2-furyl) iodonium cation, a bis(5-nitro-2-thienyl) iodonium cation, a bis(5-acetyl-2-furyl) iodonium cation, a bis(5-carboxy-2-thienyl) iodonium cation, a bis(5-methoxycarbonyl-2-furyl) iodonium cation, a bis(5-phenyl-2-furyl) iodonium cation, a bis(5-(p-methoxyphenyl)-2-thienyl) iodonium cation, a bis(5-vinyl-2-furyl) iodonium cation, a bis(5-ethynyl-2-thienyl) iodonium cation, a bis(5-cyclohexyl-2-furyl) iodonium cation, a bis(5-hydroxy-2-thienyl) iodonium cation, a bis(5-phenoxy-2-furyl) iodonium cation, a bis(5-mercapto-2-thienyl) iodonium cation, a bis(5-butylthio-2-thienyl) iodonium cation, a bis(5-phenylthio-2-thienyl) iodonium cation, a diphenyliodonium cation, a bis(p-tolyl) iodonium cation, a bis(p-octylphenyl) iodonium cation, a bis(p-octadecylphenyl) iodonium cation, a bis(p-octyloxyphenyl) iodonium cation, a bis(p-octadecyloxyphenyl) iodonium cation, a phenyl (p-octadecyloxyphenyl) iodonium cation, a 4-isopropyl-4′-methyldiphenyliodonium cation, a (4-isobutylphenyl)-p-tolyliodonium cation, a bis(1-naphthyl) iodonium cation, a bis(4-phenylsulfanylphenyl) iodonium cation, a phenyl (6-benzoyl-9-ethyl-9H-carbazol-3-yl) iodonium cation, a (7-methoxy-2-oxo-2H-chromen-3-yl)-4′-isopropylphenyliodonium cation, or a combination thereof.

13. The composition according to any one of items 1 to 12, wherein the ionization potential of the iodonium cation is greater than or equal to about 4.00 eV and less than or equal to about 4.95 eV.

14. The composition according to any one of items 1 to 13, wherein the salt compound further comprises a sulfonium cation, a sulfoxonium cation, a phosphonium cation, or a combination thereof.

15. An organic film including a cured material obtained by curing the composition according to any one of items 1 to 14, and a carboxyl-containing compound.

16. The organic film according to item 15, wherein the carboxyl-containing compound is acetic acid, propionic acid, butyric acid, valeric acid, caproic acid, malonic acid, succinic acid, glutaric acid, adipic acid, pimelic acid, (meth)acrylic acid, poly(meth)acrylic acid, benzoic acid, hexahydrobenzoic acid, terephthalic acid, 1,4-cyclohexanedicarboxylic acid, citric acid, malic acid, 3-isopropylmalic acid, itaconic acid, citraconic acid, or a combination thereof.

17. An electroluminescent device, including:
a first electrode supplying holes,
a second electrode supplying electrons, and
an organic layer disposed between the first electrode and the second electrode,
wherein at least one layer of the organic layer includes the organic film according to item 15 or item 16.

18. The electroluminescent device according to item 17, wherein the at least one layer of the organic layer including the organic film is a hole injection layer.

19. The electroluminescent device according to item 17 or item 18, wherein the organic layer includes a light emitting layer including semiconductor nanoparticles, an organometallic complex, or a combination thereof.

20. The electroluminescent device according to any one of items 17 to 19, wherein the organic layer includes a light emitting layer including semiconductor nanoparticles

### EXAMPLES

The present disclosure is described in further detail using the following examples and comparative examples. However, the technical range of the present disclosure is not limited to the following examples. In the following examples, unless specifically described, each operation was performed at room temperature (25° C.). In addition, unless specifically stated, “%” and “a part” mean “weight %” and “a part by weight”, respectively.

The ionization potential of the copolymer, electron affinity of the salt compound, and ionization potential of the iodonium cation were calculated as described below. Here, ΔE is produced by subtracting ionization potential of the copolymer from the electron affinity of the salt compound.

### Calculation Method

The ionization potential of the copolymer, the electron affinity of the salt compound, and the ionization potential of the iodonium cation were determined using Gaussian 16 (Gaussian Inc.) as a calculation software and as the functional B3LYP, and the basis function 6-31G(d,p) by Density Functional Theory (DFT).

### Synthesis Example 1: Synthesis of Compound M-1

Using the same method as the synthetic example 3 of Japanese Patent Laid-Open Publication No. 2021-138915, Compound M-1, represented by the following chemical formula, was synthesized.

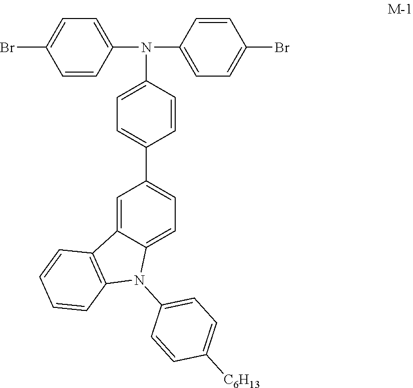

### Synthesis Example 2: Synthesis of Compound M-2

Compound M-2 represented by the following chemical formula was synthesized by the same method as Synthetic Example 4 of Japanese Patent Laid-Open Publication No. 2021-138915, except that 4-chloro-N-(4-chlorophenyl)-N-(4-(4,4,5,5-tetramethyl-1,3,2-dioxaboran-2-yl)phenyl) aniline was replaced with 4-bromo-N-(4-bromophenyl)-N-(4-(4,4,5,5-tetramethyl-1,3,2-dioxaboran-2-yl)phenyl)aniline.

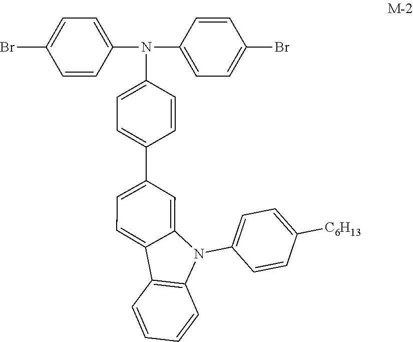

### Synthesis Example 3: Synthesis of Compound CL-1

### Compound CL-1 was Synthesized According to Reaction Scheme 1

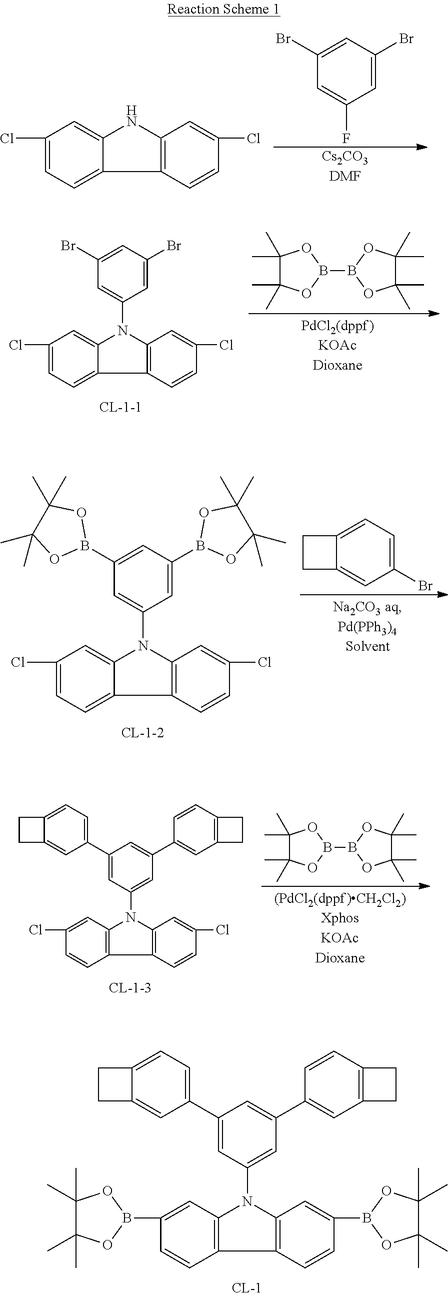

Into a 500 milliliter (mL), 4-neck flask substituted with argon, 2,7-dichloro-9H-carbazole (25.0 grams (g)), 1,3-dibromo-5-fluorobenzene (40.3 g), cesium carbonate (69.0 g), and N,N-dimethylformamide (DMF) (510 mL) were added and stirred at 170° C. (bath temperature) for 8 hours. After cooling to room temperature, the aqueous layer was separated, and the aqueous layer was extracted with toluene (200 mL×2). The organic layer was washed with water (200 mL×2) and dried over magnesium sulfate. The solvent was removed under reduced pressure, and the residue was recrystallized with toluene/ethanol to obtain Compound CL-1-1 (41.3 g).

Under an argon atmosphere, into a 1000 mL three-neck flask, were added the Compound CL-1-1 (40.0 g) obtained above, bis(pinacolato)diboron (86.4 g), potassium acetate (41.7 g), [1,1′-bis(diphenylphosphino)ferrocene]dichloropalladium(II) (PdCl₂(dppf)) (3.1 g), and 1,4-dioxane (400 mL), and the mixture was stirred at 110° C. (bath temperature) for 3 hours. The mixture was cooled to room temperature, and insolubles were removed by filtration using Celite as a filter aid. The solvent was removed under reduced pressure by distillation, and the residue was dissolved in a mixed solvent of toluene (100 mL) and hexane (100 mL), activated carbon (40.0 g) was added, and the mixture was refluxed for 30 minutes. Insolubles were filtered off using Celite as a filter aid. The solvent was removed under reduced pressure by distillation, and the obtained residue was crystallized by adding a toluene/ethanol mixed solvent and purified to obtain Compound CL-1-2 (32.6 g).

Into a 1000 mL, 4-neck flask substituted with argon, were added the compound CL-1-2 (30.0 g) obtained above, 3-bromocyclo[4.2.0]octa-1,3,5-triene (19.5 g), sodium carbonate (16.9 g), tetrakis(triphenylphosphine)palladium(0) (Pd(PPh₃)₄) (1.5 g), and solvents, i.e., toluene (300 mL), ethanol (120 mL), and water (120 mL), and the mixture was stirred at 100° C. (bath temperature) for 3 hours. After cooling to room temperature, the aqueous layer was separated and extracted with toluene (100 mL×2). The organic layer was washed with water (100 mL×2) and dried over magnesium sulfate. The solvent was removed under reduced pressure, and to the residue was added toluene (200 mL) and refluxed at 60° C. for 1 hour, after which the solids were filtered and dried. The solvent was removed under reduced pressure, and the obtained residue was recrystallized and purified by adding a toluene/ethanol mixed solvent to afford the Compound CL-1-3 (37.6 g).

In a 1000 mL, three-neck flask substituted with argon, the compound CL-1-3 (20.0 g) obtained above, bis(pinacolato)diboron (39.3 g), potassium acetate (13.3 g), [1,1′-bis(diphenylphosphino)ferrocene]dichloropalladium(II) dichloromethane adduct (PdCl₂(dppf)·CH₂Cl₂) (3.1 g), XPhos (2-dicyclohexylphosphino-2′,4′,6′-triisopropylbiphenyl) (1.84 g), and 1,4-dioxane (200 mL) were added and stirred at 110° C. (bath temperature) for 3 hours. The mixture was cooled to room temperature, and insoluble materials were removed using Celite as a filtration aid. The solvent was removed under reduced pressure by distillation, and the residue was dissolved in a mixed solvent of toluene (100 mL) and hexane (100 mL), followed by the addition of activated carbon (20.0 g) and refluxed for 30 minutes. Insoluble materials were filtered using Celite as a filtration aid. The solvent was removed under reduced pressure by distillation, and the obtained residue was recrystallized using a toluene/ethanol mixed solvent, purified, to afford Compound CL-1 (16.3 g).

### Synthesis Example 4: Synthesis of Compound CL-2

### Compound CL-2 was Synthesized According to Reaction Scheme 2

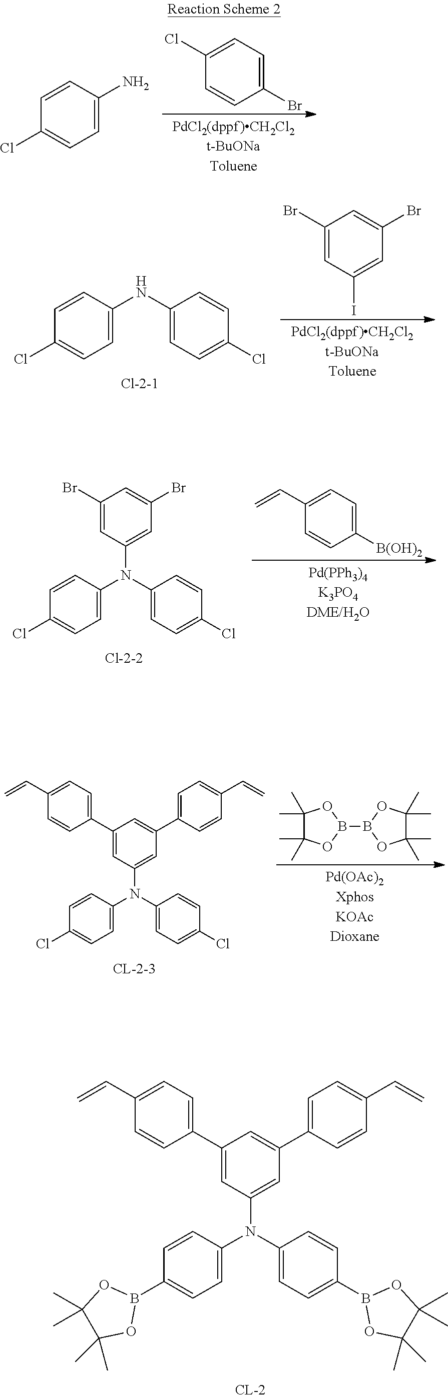

Into a 2000 mL, three-neck flask substituted with argon, 4-chloroaniline (60 g), 1-bromo-4-chlorobenzene (94.5 g), sodium tert-butoxide (t-BuONa) (67.8 g), and toluene (940 mL) were added and dispersed under a nitrogen atmosphere. Then, [1,1′-bis(diphenylphosphino)ferrocene]dichloropalladium(II) dichloromethane complex (PdCl₂(dppf)·CH₂Cl₂) (19.2 g) was added, and the mixture was stirred at 90° C. for 9 hours. After the reaction was completed, the mixture was cooled to room temperature, and the base material was filtered using Celite as a filtering aid. The obtained solution was concentrated and purified by silica gel column chromatography (eluents: toluene/hexane). The solid obtained after solvent removal was purified by recrystallization using a toluene/hexane mixed solvent. Then, the product was dried under reduced pressure (50° C., 16 hours) to obtain Compound CL-2-1 (79.7 g).

In a 2000 mL, three-neck flask substituted with argon, the obtained compound CL-2-1 (25.0 g), 1,3-dibromo-5-iodobenzene (57.0 g), sodium tert-butoxide (20.2 g), and toluene (525 mL) were added and dispersed under a nitrogen atmosphere. Next, [1,1′-bis(diphenylphosphino)ferrocene]dichloropalladium(II) dichloromethane complex (2.57 g) was added, and the mixture was stirred at 90° C. for 9 hours. After the reaction was complete, it was cooled to room temperature, and the base materials were filtered using Celite as a filtration aid. The resulting solution was concentrated and purified by silica gel column chromatography (eluents: toluene/hexane). The solvent was removed, and the obtained solid was purified by recrystallization using a toluene/methanol mixed solvent. Thereafter, the product was dried under reduced pressure (50° C., 16 hours) to obtain compound CL-2-2 (31.9 g).

In a 500 mL, three-neck flask substituted with argon, the compound CL-2-2 (15.0 g) obtained above, 4-vinylphenylboronic acid (14.1 g), and dimethoxyethane (159 mL) were added and dissolved. Next, an aqueous solution (80 mL) of potassium phosphate tribasic (95.34 mmol, 20.2 g) was added, and nitrogen was bubbled through the mixture for 30 minutes. Then, tetrakis(triphenylphosphine)palladium(0) (1.84 g) was added, and the mixture was stirred at 90° C. for 3 hours. After completion of the reaction, the contents were cooled to room temperature and partitioned with ethyl acetate and water. The organic layer was separated and dried over magnesium sulfate, and the solvent was removed. The resulting crude product was purified by silica gel column chromatography (eluents: toluene/hexane). The solid obtained after solvent removal was further purified by recrystallization using n-hexane. Subsequently, drying under reduced pressure (50° C., 16 hours) was performed to obtain Compound CL-2-3 (11.6 g).

Into a 500 mL, 3-neck flask substituted with argon, the Compound CL-2-3 (11.0 g) obtained above, bis(pinacolato)diboron (21.6 g), potassium acetate (112.2 g), and 1,4-dioxane (212 mL) were added and dissolved under a nitrogen atmosphere. Next, palladium acetate (0.48 g) and XPhos (1.01 g) were added, and the mixture was stirred under reflux for 6 hours. After the reaction was complete, the mixture was cooled to room temperature, and the base materials were filtered using Celite as a filtration aid. The resulting solution was concentrated and purified by silica gel column chromatography (eluents: toluene/ethanol). The crude product obtained after solvent removal was washed with acetonitrile. The solid recovered by filtration was further purified by recrystallization using a toluene/hexane mixed solvent. Subsequently, drying under reduced pressure was carried out (50° C., 16 hours) to obtain Compound CL-2 (8.7 g).

### Synthesis Example 5: Synthesis of Compound M-3

### Compound M-3 was Synthesized According to Reaction Scheme 3

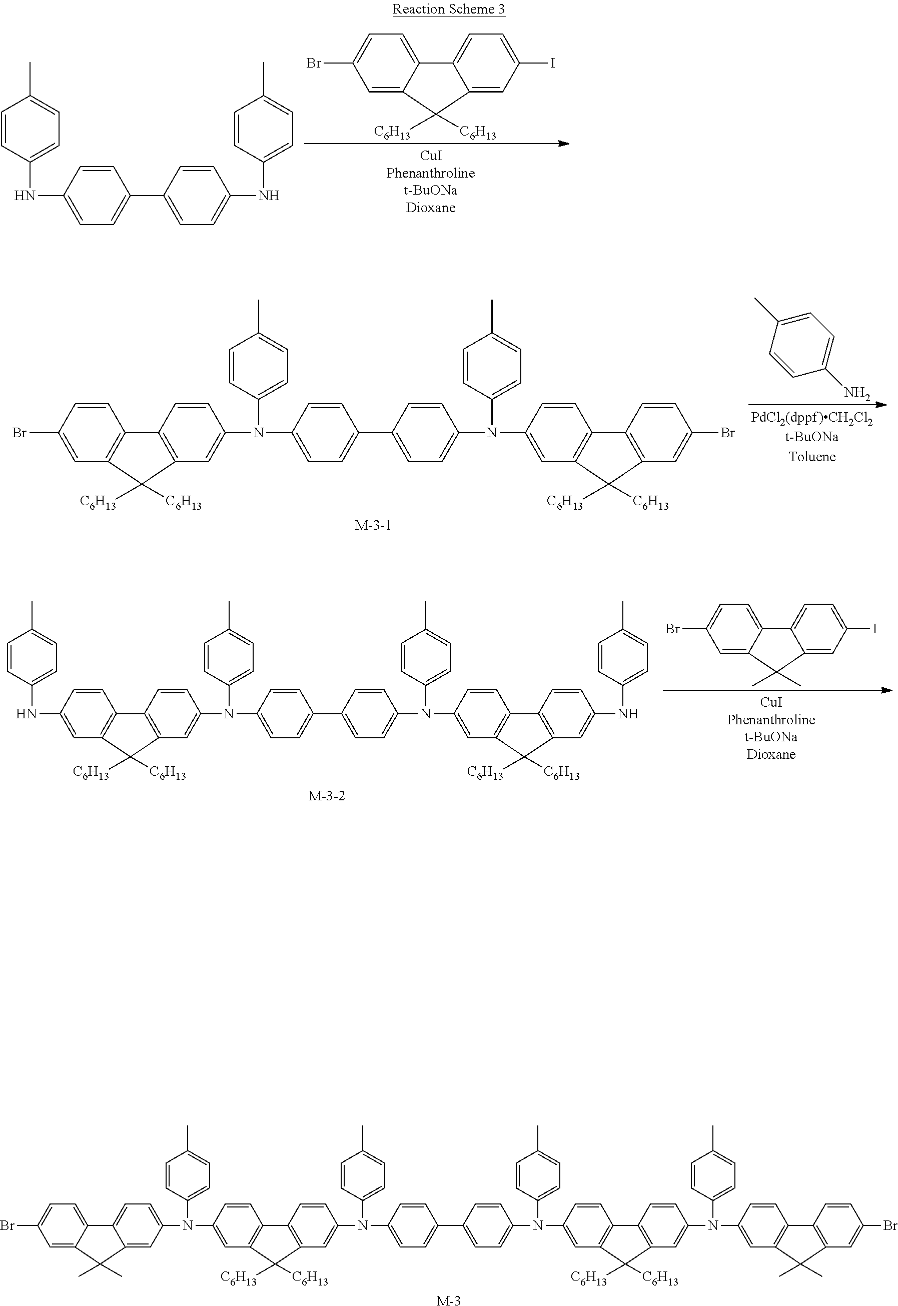

In a 200 mL, three-neck flask substituted with argon, N,N′-di(p-tolyl)benzidine (10.0 g), 2-bromo-9,9-dihexyl-7-iodo-9H-fluorene (31.1 g), copper(I) iodide (0.5 g), phenanthroline (1.5 g), sodium tert-butoxide (7.9 g), and 1,4-dioxane (30 mL) were added and stirred at 110° C. (bath temperature) for 3 hours. The mixture was cooled to room temperature, and insoluble materials were removed by filtration using Celite as a filter aid. The solvent was removed under reduced pressure by distillation, and the residue was dissolved in a mixed solvent of toluene (100 mL) and hexane (100 mL), activated carbon (20.0 g) was added, and the mixture was refluxed for 30 minutes. Insoluble materials were filtered off using Celite as a filter aid, the solvent was removed under reduced pressure by distillation, and the residue was purified by silica gel column chromatography (eluents: toluene/hexane) to obtain Compound M-3-1 (22.1 g).

Into a 500 mL, three-neck flask substituted with argon, were added the Compound M-3-1 (20.0 g) obtained above, p-toluidine (3.8 g), [1,1′-bis(diphenylphosphino)ferrocene]dichloropalladium(II) dichloromethane adduct (0.5 g), sodium tert-butoxide (4.8 g), and toluene (170 mL), and the mixture was stirred at 120° C. (bath temperature) for 12 hours. The mixture was cooled to room temperature, and insolubles were removed by filtration through Celite as a filter aid. The solvent was removed under reduced pressure by distillation, and the residue was purified by silica gel column chromatography (eluents: toluene/hexane) to obtain Compound M-3-2 (13.0 g).

Into a 100 mL, three-neck flask substituted with argon, the Compound M-3-2 (10.0 g) obtained above, 2-bromo-9,9-dimethyl-7-iodo-9H-fluorene (6.8 g), copper(I) iodide (0.2 g), phenanthroline (0.3 g), sodium tert-butoxide (2.3 g), and 1,4-dioxane (10 mL) were added, and the mixture was stirred at 110° C. (bath temperature) for 18 hours. After cooling to room temperature, the insoluble matter was removed by filtration using Celite as a filter aid. The solvent was removed under reduced pressure, and the residue was dissolved in a mixed solvent of toluene (100 mL) and hexane (100 mL), to which activated carbon (20.0 g) was added, and the contents were then heated at reflux for 30 minutes. After cooling to room temperature, the insoluble matter was filtered using Celite as a filter aid. The solvent was removed under reduced pressure, and the residue was purified by silica gel column chromatography (eluents: toluene/hexane) to obtain Compound M-3 (10.3 g).

### Synthesis Example 6: Synthesis of Compound M-4

### Compound M-4 was Synthesized According to Reaction Scheme 4

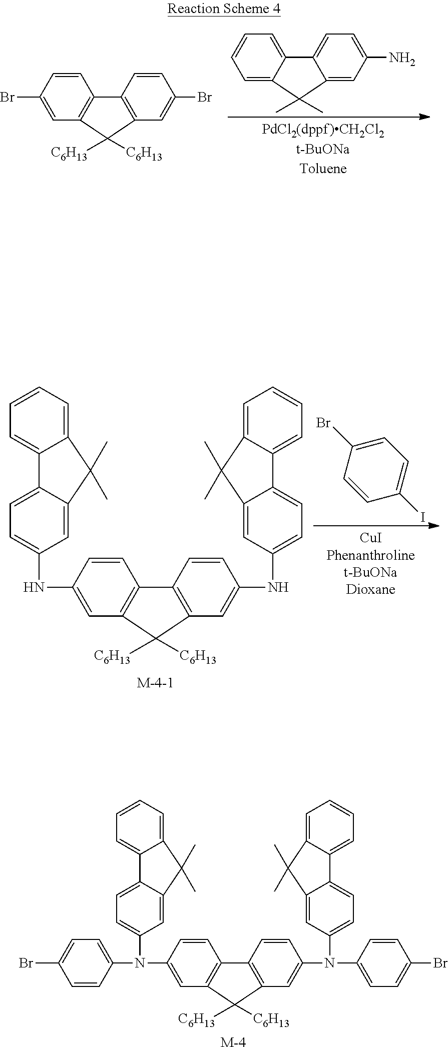

Into a 500 mL, three-neck flask replaced with argon, dibromo-9,9-dihexylfluorene (10.0 g), 9,9-dimethyl-9H-fluoren-2-amine (8.9 g), [1,1′-bis(diphenylphosphino)ferrocene]dichloropalladium(II) dichloromethane adduct (0.3 g), sodium tert-butoxide (5.9 g), and toluene (200 mL) were added, and the mixture was stirred at 120° C. (bath temperature) for 6 hours. The mixture was cooled to room temperature, and insoluble materials were removed by filtration using Celite as a filter aid. The solvent was removed under reduced pressure, and the residue was purified by silica gel column chromatography (eluents: toluene/hexane) to obtain Compound M-4-1 (19.8 g).

In a 100 mL, three-neck flask substituted with argon, Compound M-4-1 (15.0 g) obtained as above, 1-bromo-4-iodobenzene (11.9 g), copper(I) iodide (CuI) (0.4 g), phenanthroline (0.7 g), sodium tert-butoxide (5.7 g), and 1,4-dioxane (20 mL) were added and stirred at 110° C. (bath temperature) for 18 hours. The mixture was cooled to room temperature, and the insoluble matter was removed by filtration using Celite as the filter aid. The solvent was removed under reduced pressure, and the residue was dissolved in a mixed solvent of toluene (100 mL) and hexane (100 mL), and activated carbon (20.0 g) was added, and the resulting mixture was heated at reflux for 30 minutes. After cooling to room temperature, the insoluble matter was filtered using Celite as the filter aid. The solvent was removed under reduced pressure, and the residue was purified by silica gel column chromatography (eluents: toluene/hexane) to obtain Compound M-4 (10.6 g).

### Synthesis Example 7: Synthesis of Compound M-5

### Compound M-5 was Synthesized According to Reaction Scheme 5

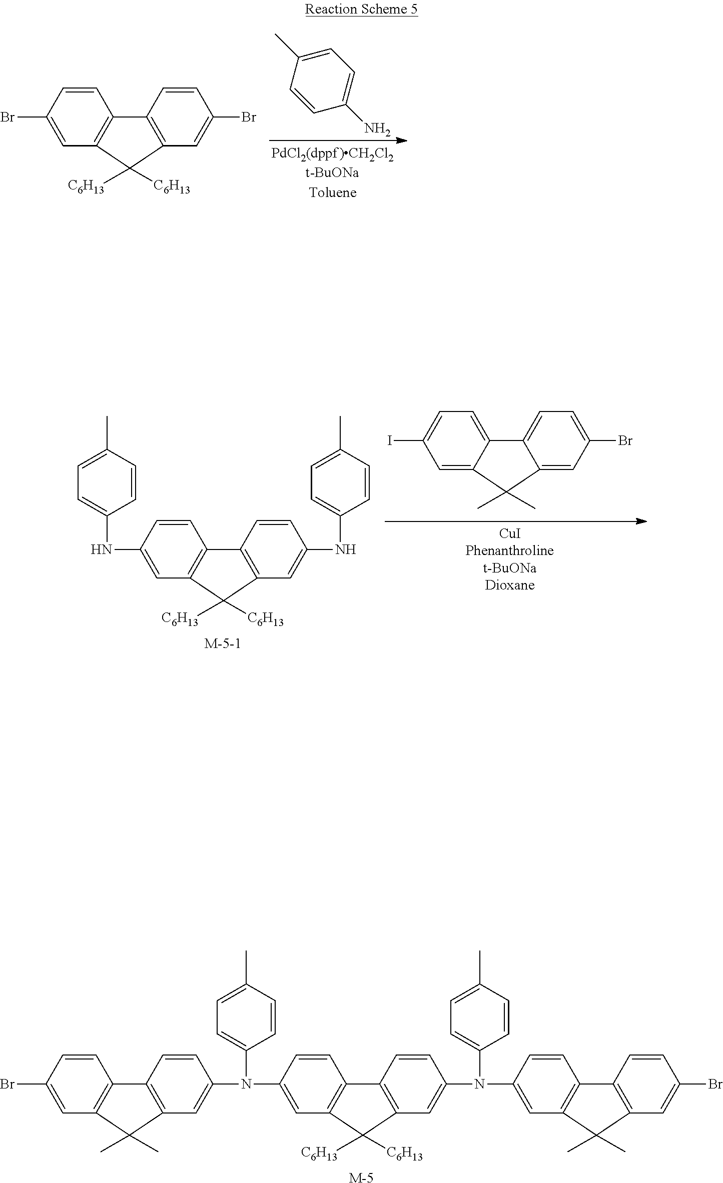

Into a 500 mL, three-neck flask exchanged with argon, dibromo-9,9-dihexylfluorene (20.0 g), p-toluidine (9.1 g), [1,1′-bis(diphenylphosphino)ferrocene]dichloropalladium(II) dichloromethane adduct (0.7 g), sodium tert-butoxide (11.7 g), and toluene (250 mL) were added, and the mixture was stirred at 120° C. (bath temperature) for 5 hours. The reaction was cooled to room temperature, and insoluble matter was removed by filtration using Celite as a filter aid. The solvent was removed under reduced pressure, and the residue was purified by silica gel column chromatography (eluents: toluene/hexane) to obtain Compound M-5-1 (15.1 g).

Into a 100 mL, three-neck flask substituted with argon, the Compound M-5-1 (10.0 g) obtained above, 2-bromo-9,9-dimethyl-7-iodo-9H-fluorene (14.0 g), copper(I) iodide (0.3 g), phenanthroline (0.6 g), sodium tert-butoxide (4.8 g), and 1,4-dioxane (20 mL) were added, and the mixture was stirred at 110° C. (bath temperature) for 18 hours. After cooling to room temperature, the insoluble matter was removed by filtration using Celite as a filter aid. The solvent was removed under reduced pressure, and the residue was dissolved in a mixed solvent of toluene (100 mL) and hexane (100 mL), to which activated carbon (20.0 g) was added, and the contents were heated at reflux for 30 minutes. The insoluble matter was filtered using Celite as a filter aid. The solvent was removed under reduced pressure, and the residue was purified by silica gel column chromatography (eluents: toluene/hexane) to obtain Compound M-5 (10.6 g).

### Synthesis Example 8: Synthesis of Compound M-6

### Compound M-6 was Synthesized According to Reaction Scheme 6

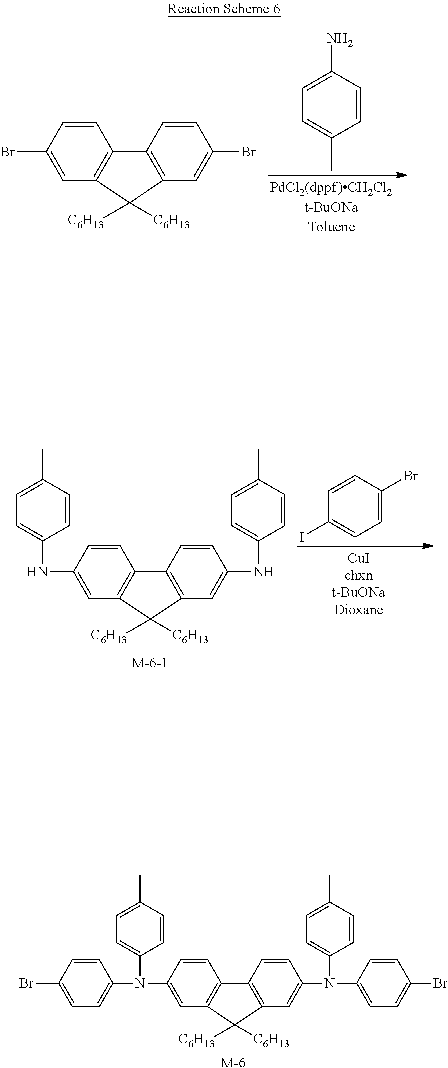

Into a 500 mL, three-neck flask substituted with argon, 2,7-dibromo-9,9-dihexyl-9H-fluorene (25.0 g), p-toluidine (11.4 g), and toluene (254 mL) were added and dissolved by stirring under a nitrogen atmosphere. Next, sodium tert-butoxide (14.6 g) and [1,1′-bis(diphenylphosphino)ferrocene]dichloropalladium(II) dichloromethane adduct (1.24 g) were added, and the mixture was stirred under reflux for 2 hours. After the reaction was completed, the mixture was cooled to room temperature, and the base material was filtered using Celite as the filtration aid. The obtained solution was concentrated and purified by silica gel column chromatography (eluents: toluene/hexane). The solid obtained after solvent removal was dissolved in hexane by heating at 65° C., slowly cooled, and purified by recrystallization. The obtained solid was dried under reduced pressure overnight to give Compound M-6-1 (22.0 g) as a white solid.

In a 200 mL, three-neck flask substituted with argon, the Compound M-6-1 (36.0 g) obtained above, 1-bromo-4-iodobenzene (56.1 g), sodium tert-butoxide (19.1 g), and 1,4-dioxane (66 mL) were added and dispersed, then purged with nitrogen. Next, copper(I) iodide (0.63 g) and trans-1,2-cyclohexanediamine (1.51 g) were added, and the contents were stirred under reflux for 21 hours. After completion of the reaction, toluene was added and cooled to room temperature, then the base material was filtered off using Celite as a filtering aid. The crude product was purified by silica gel column chromatography (eluent: toluene). The solid obtained after solvent removal was further purified by recrystallization (solvents: toluene/hexane). The obtained solid was dried under reduced pressure overnight to afford Compound M-6 (29.5 g) as a white solid.

### Synthesis Example 9: Synthesis of Compound M-7

### Compound M-7 was Synthesized According to Reaction Scheme 7

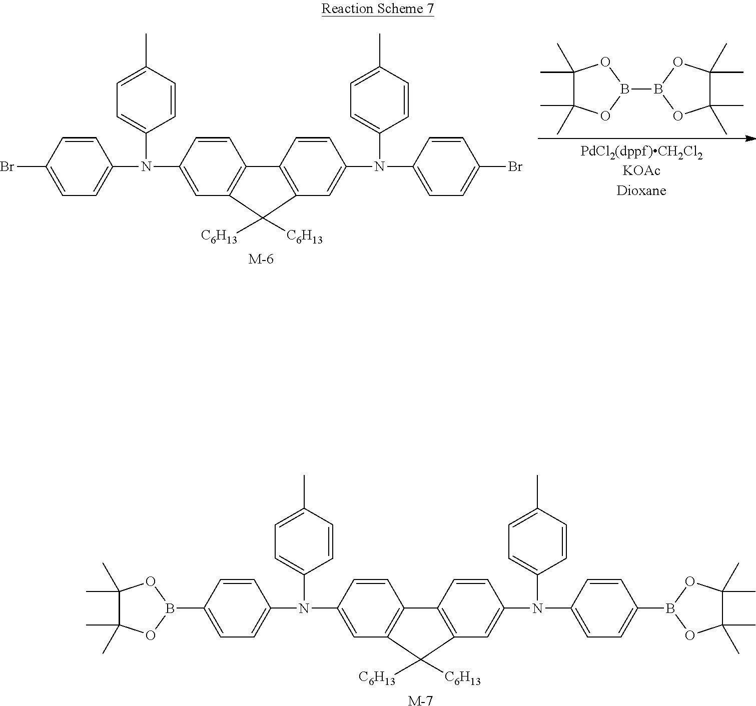

In a 200 mL, three-neck flask substituted with argon, Compound M-6 (13.6 g), bis(pinacolato)diboron (16.2 g), potassium acetate (6.25 g), and 1,4-dioxane (73 mL) were added and a nitrogen dissolved under atmosphere. Next, [1,1′-bis(diphenylphosphino)ferrocene]dichloropalladium(II) dichloromethane adduct (0.39 g) was added, and the mixture was stirred under reflux for 4 hours. After the reaction was complete, the mixture was cooled to room temperature, and the base material was filtered using Celite as a filtration aid. The resulting solution was concentrated and purified by silica gel column chromatography (eluent: toluene). The crude product obtained by solvent removal was washed with acetonitrile. The solid recovered by filtration was further purified by recrystallization (solvents: toluene/acetonitrile). The obtained solid was dried under reduced pressure (50° C., 16 hours) to give Compound M-7 (11.1 g).

### Synthesis Example 10: Synthesis of Compound M-8

### Compound M-8 was Synthesized According to Reaction Scheme 8

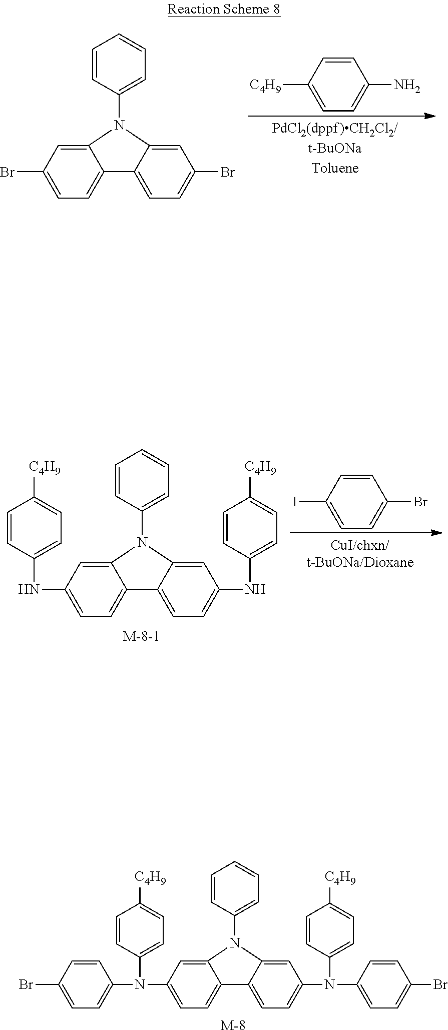

Into a 300 mL, four-neck flask substituted with argon, 2,7-dibromo-9-phenylcarbazole (4.73 (3.68 g), 4-butylaniline g), [1,1′-bis(diphenylphosphino)ferrocene]dichloropalladium(II) dichloromethane adduct (286 mg), sodium tert-butoxide (3.37 g), and toluene (50 mL) were added, and the mixture was heated and stirred at 110° C. under an argon atmosphere for 3 hours. The reaction mixture was allowed to stand and cool to room temperature, and insoluble materials were filtered through Celite as a filtering aid. The solvent was removed under reduced pressure, dissolved in toluene (100 mL), and purified by silica gel column chromatography (eluents: toluene/hexane) to obtain Compound M-8-1 (4.81 g).

In a 200 mL, 4-neck flask replaced with argon, the Compound M-8-1 (4.81 g) obtained above, 1-bromo-4-iodobenzene (7.33 g), copper(I) iodide (0.164 g), sodium tert-butoxide (2.48 g), trans-1,2-cyclohexanediamine (0.196 g), and 1,4-dioxane (55 mL) were added, and the mixture was heated and stirred at 100° C. for 30 hours. The mixture was left to cool to room temperature, then cooled further, and the insoluble materials were filtered using Celite as a filtering aid. The solvent was removed under reduced pressure, the product was dissolved in toluene (100 mL), and then purified by silica gel column chromatography (eluents: toluene/hexane) to obtain Compound M-8 (3.16 g).

### Synthesis Example 11: Synthesis of Compound M-9

### Compound M-9 was Synthesized According to Reaction Scheme 9

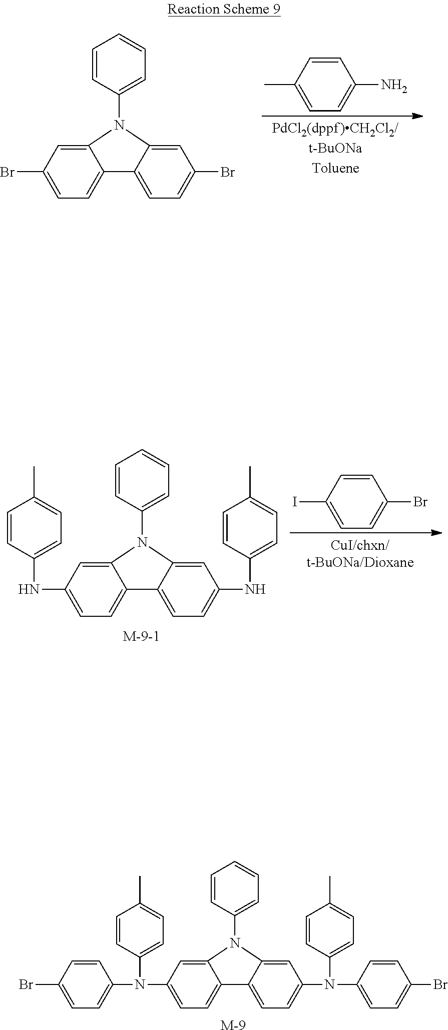

In a 200 mL, 4-neck flask substituted with argon, 2,7-dibromo-9-phenylcarbazole (5.50 g), 4-methylaniline (3.07 g), [1,1′-bis(diphenylphosphino)ferrocene]dichloropalladium(II) dichloromethane adduct (333 mg), sodium tert-butoxide (3.91 g), and toluene (58 mL) were added, and the mixture was heated and stirred at 110° C. for 3 hours under an argon atmosphere. The mixture was allowed to stand until room temperature was reached, cooled further, and the insoluble matter was filtered using Celite as a filtering aid. The solvent was removed under reduced pressure, the product was dissolved in toluene (100 mL), and then purified by silica gel column chromatography (eluents: toluene/hexane) to obtain Compound M-9-1 (5.02 g).

In a 200 mL, four-necked flask substituted with argon, the Compound M-9-1 (4.30 g) obtained above, 1-bromo-4-iodobenzene (8.03 g), copper(I) iodide (0.179 g), sodium tert-butoxide (2.71 g), trans-1,2-cyclohexanediamine (0.215 g), and 1,4-dioxane (60 mL) were added, and under an argon atmosphere, the mixture was heated and stirred at 100° C. for 30 hours. The mixture was left to reach room temperature, cooled further, and the insoluble materials were filtered through Celite as a filtering aid. The solvent was removed under reduced pressure, the product was dissolved in toluene (100 mL), and then purified by silica gel column chromatography (eluents: toluene/hexane) to give the Compound M-9 (3.16 g).

### Synthesis Example 12: Synthesis of Compound M-10

### Compound M-10 was Synthesized According to Reaction Scheme 10

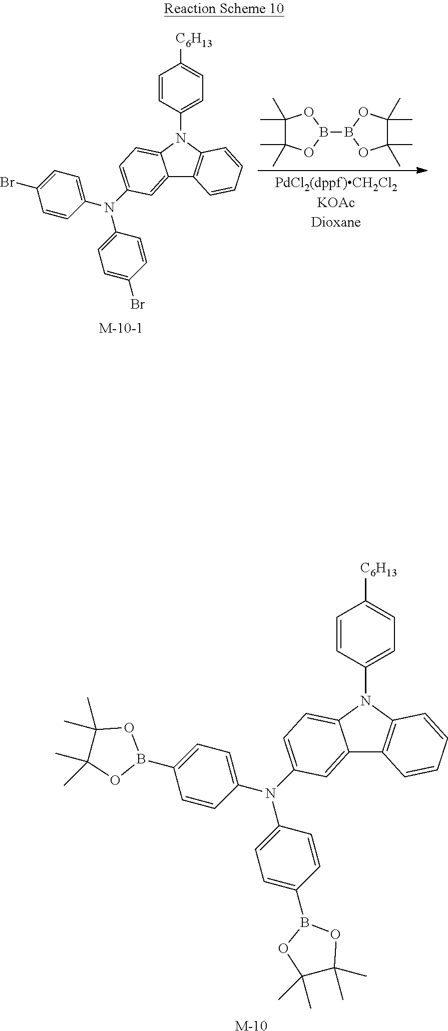

Compound M-10-1 was synthesized by the same method as the synthesis example 1 of Japanese Patent Laid-Open Publication No. 2021-138915.

Into a 100 mL, three-neck flask, Compound M-10-1 (14.0 g), bis(pinacolato)diboron (21.8 g), potassium acetate (8.25 g), and 1,4-dioxane (100 mL) were added and dissolved under a nitrogen atmosphere. Next, [1,1′-bis(diphenylphosphino)ferrocene]dichloropalladium(II) dichloromethane adduct (0.55 g) was added and the mixture was stirred under reflux for 2 hours. After completion of the reaction, the mixture was cooled to room temperature, and the base material was filtered using Celite as a filtration aid. The resulting solution was concentrated and purified by silica gel column chromatography (eluent: toluene). The crude product obtained by removing the solvent under reduced pressure was washed with acetonitrile. The solid recovered by filtration was further purified by recrystallization (solvents: toluene/acetonitrile). The resulting solid was dried under reduced pressure (50° C., 16 hours) to obtain Compound M-10 (7.5 g).

### Synthesis Example 13: Synthesis of Copolymer P-1

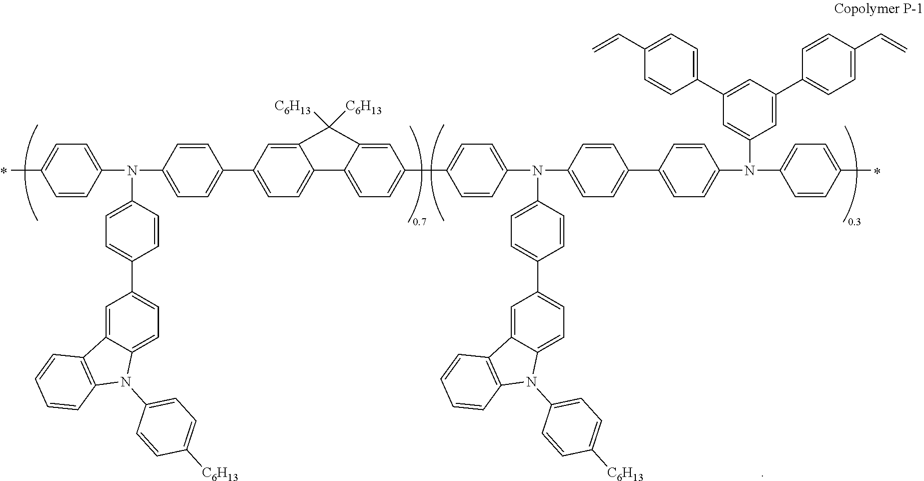

Under a nitrogen atmosphere, Compound M-1 (1.48 g), Compound CL-2 (0.27 g), dibromo-9,9-dihexylfluorene palladium acetate (3.3 mg), tris(2-methoxyphenyl)phosphine (31.6 mg), toluene (30 mL), and a 20 wt % aqueous solution of tetraethylammonium hydroxide (7.60 g) were added to a 4-neck flask and stirred at 85° C. for 6 hours. Then, phenylboronic acid (206 mg), bis(triphenylphosphine)palladium(II) dichloride (82.9 mg), and a 20 wt % aqueous solution of tetraethylammonium hydroxide (7.10 g) were added and stirred at 85° C. for 6 hours. After that, sodium N,N-diethyldithiocarbamate trihydrate (4.6 g) dissolved in ion-exchanged water (50 mL) was added and stirred at 85° C. for 2 hours. The organic layer was separated from the aqueous layer, the solvent in the organic layer was removed under reduced pressure, and the residue was dissolved and then precipitated with toluene/methanol. The precipitated solid was filtered, washed with water and methanol, and dried. The dry solid was dissolved in toluene (30 mL), and alumina (20.0 g) and Celite (5.0 g) were added, then the mixture was stirred at 90° C. for 1 hour. The alumina and Celite were removed by filtration, and 12 N hydrochloric acid (20 mL) was added to the filtrate and the mixture was stirred at room temperature for 12 hours. The aqueous layer was separated, and the organic layer was added dropwise into methanol. The precipitated solid was washed with methanol and water, and dried under reduced pressure to obtain the Copolymer P-1 (1.16 g). The weight-average molecular weight (Mw) and polydispersity (Mw/Mn) of the obtained Copolymer P-1 were measured by SEC. As a result, the weight-average molecular weight (Mw) and polydispersity (Mw/Mn) of the Copolymer P-1 were 28,300 Da and 2.24, respectively. Copolymer P-1 obtained in this manner is presumed to be a copolymer represented by the above chemical formula based on the monomer feed ratio. The ionization potential of Copolymer P-1 was 5.34 eV.

### Synthesis Example 14: Synthesis of Copolymer P-2

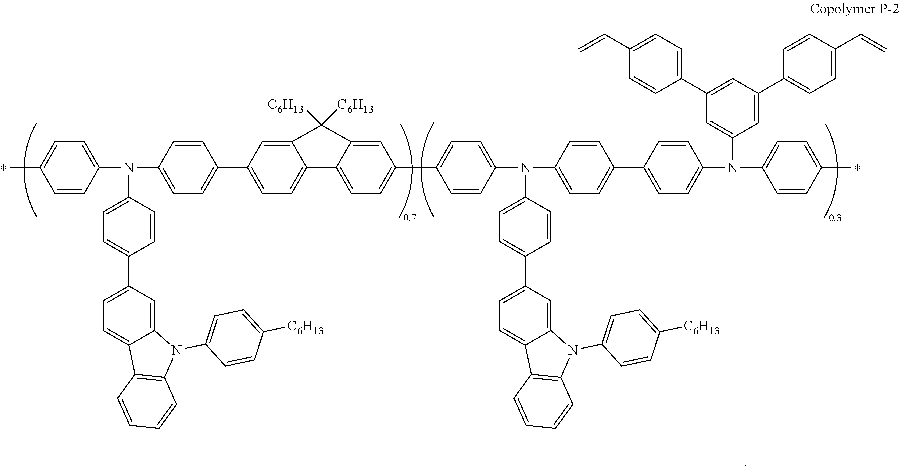

Under a nitrogen atmosphere, Compound M-2 (1.52 g), Compound CL-2 (0.34 g), dibromo-9,9-dihexylfluorene (0.64 g), palladium acetate (5.5 mg), tris(2-methoxyphenyl)phosphine (52.0 mg), toluene (37 mL), and 20 wt % aqueous tetraethylammonium hydroxide (8.90 g) were added to a four-neck flask and stirred at 85° C. for 6 hours. Then, phenylboronic acid (215 mg), bis(triphenylphosphine)palladium(II) dichloride (103.6 mg), and 20 wt % aqueous tetraethylammonium hydroxide (8.90 g) were added and stirred at 85° C. for 6 hours. Subsequently, sodium N,N-diethyldithiocarbamate trihydrate (5.8 g) dissolved in ion-exchanged water (70 mL) was added and stirred at 85° C. for 2 hours. After separating the organic layer from the aqueous layer, the solvent in the organic layer was removed under reduced pressure, and the residue was dissolved and then precipitated with toluene/methanol. The precipitated solid was filtered, washed with water and methanol, and dried. The dried solid was dissolved in toluene (40 mL), alumina (25.0 g) and Celite (5.0 g) were added, and the mixture was stirred at 90° C. for 1 hour. Alumina and Celite were removed by filtration, 12 N hydrochloric acid (30 mL) was added to the filtrate, and the mixture was stirred at room temperature for 12 hours. The aqueous layer was removed, and the organic layer was added dropwise to methanol. The precipitated solid was washed with methanol and water, and dried under reduced pressure to obtain the Copolymer P-2 (1.16 g). The weight-average molecular weight (Mw) and polydispersity (Mw/Mn) of the obtained Copolymer P-2 were measured by SEC. The weight-average molecular weight (Mw) and polydispersity (Mw/Mn) of Copolymer P-2 were 26,000 Da and 2.56, respectively. Copolymer P-2 obtained in this manner is estimated to be the copolymer represented by the above chemical formula based on the monomer feed ratio. The ionization potential of Copolymer P-2 was 5.41 eV.

### Synthesis Example 15: Synthesis of Copolymer P-3

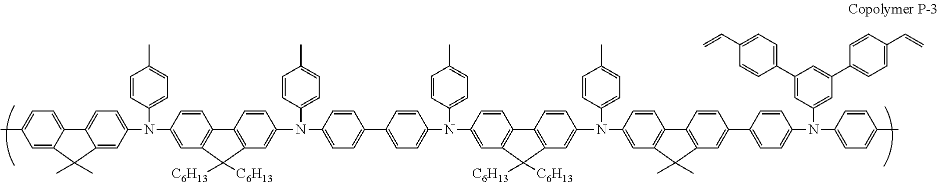

Under a nitrogen atmosphere, Compound M-3 (1.96 g), Compound CL-2 (0.67 g), palladium acetate (2.5 mg), tris(2-methoxyphenyl)phosphine (23.3 mg), toluene (53 mL), and 20 wt % tetraethylammonium hydroxide aqueous solution (5.68 g) were added to a 4-neck flask and stirred at 85° C. for 6 hours. Then, phenylboronic acid (196 mg), bis(triphenylphosphine)palladium(II) dichloride (46.4 mg), and 20 wt % tetraethylammonium hydroxide aqueous solution (5.68 g) were added and stirred at 85° C. for 6 hours. Thereafter, sodium trihydrate of N,N-diethyldithiocarbamic acid (3.7 g) dissolved in ion-exchanged water (70 mL) was added and stirred at 85° C. for 2 hours. After separating the organic layer from the aqueous layer, the solvent in the organic layer was removed under reduced pressure, the product was dissolved and precipitated with toluene/methanol. The precipitated solid was filtered, washed with water and methanol, and dried. The dry solid was dissolved in toluene (40 mL), alumina (20.0 g) and Celite (5.0 g) were added, and the mixture was stirred at 90° C. for 1 hour. The alumina and Celite were removed by filtration, 12 N hydrochloric acid (30 mL) was added to the filtrate, and the mixture was stirred at room temperature for 12 hours. The aqueous layer was removed, and the organic layer was added dropwise into methanol. The precipitated solid was washed with methanol and water, and dried under reduced pressure to obtain the Copolymer P-3 (1.01 g). The weight-average molecular weight (Mw) and polydispersity (Mw/Mn) of the obtained Copolymer P-3 were measured by SEC. The weight-average molecular weight (Mw) and polydispersity (Mw/Mn) of the Copolymer P-3 were 36,000 Da and 2.24, respectively. The Copolymer P-3 obtained in this manner is presumed to be the copolymer represented by the above chemical formula, based on the input ratio of the monomers. The ionization potential of Copolymer P-3 was 4.90 eV.

### Synthesis Example 16: Synthesis of Copolymer P-4

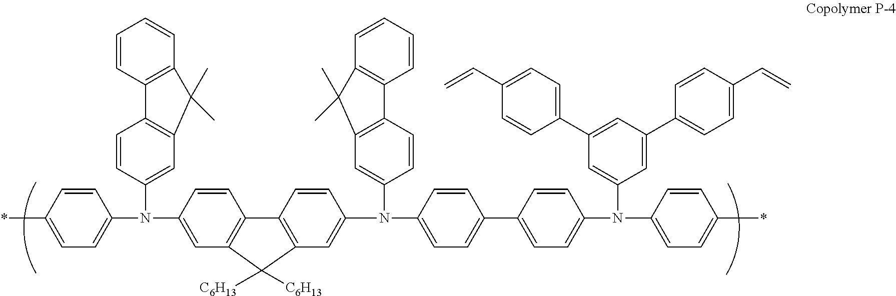

Under a nitrogen atmosphere, Compound M-4 (1.78 g), Compound CL-2 (1.18 g), palladium acetate (3.8 mg), tris(2-methoxyphenyl)phosphine (35.6 mg), toluene (59 mL), and 20 wt % tetrabutylammonium hydroxide aqueous solution (8.58 g) were added to a 4-neck flask and stirred at 85° C. for 6 hours. Phenylboronic acid (301 mg), bis(triphenylphosphine)palladium(II) dichloride (71.4 mg), and 20 wt % tetrabutylammonium hydroxide aqueous solution (8.58 g) were added and stirred at 85° C. for 6 hours. Then, sodium N,N-diethyldithiocarbamate trihydrate (5.7 g) dissolved in ion-exchanged water (60 mL) was added and stirred at 85° C. for 2 hours. After separating the organic layer from the aqueous layer, the solvent in the organic layer was removed under reduced pressure, and the residue was dissolved and then precipitated with toluene/methanol. The precipitated solid was filtered, washed with water and methanol, and dried. The dry solid was dissolved in toluene (40 mL), and alumina (20.0 g) and Celite (5.0 g) were added, and then the mixture was stirred at 90° C. for 1 hour. The alumina and Celite were removed by filtration, 12 N hydrochloric acid (30 mL) was added to the filtrate, and the mixture was stirred at room temperature for 12 hours. The aqueous layer was removed, and the organic layer was added dropwise into methanol. The precipitated solid was washed with methanol and water and dried under reduced pressure to obtain Copolymer P-4 (1.42 g). The weight-average molecular weight (Mw) and polydispersity (Mw/Mn) of the obtained Copolymer P-4 were measured by SEC. The weight-average molecular weight (Mw) and polydispersity (Mw/Mn) of Copolymer P-4 were 28,200 Da and 2.12, respectively. The Copolymer P-4 obtained in this manner is presumed to be the copolymer represented by the above chemical formula, based on the monomer feed ratio. The ionization potential of Copolymer P-4 was 5.02 eV.

### Synthesis Example 17: Synthesis of Copolymer P-5

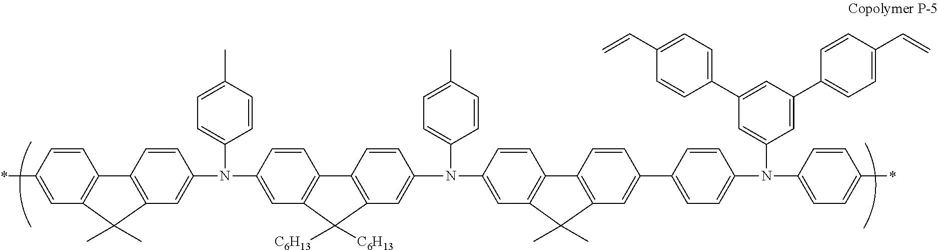

Under a nitrogen atmosphere, Compound M-5 (1.34 g), Compound CL-2 (0.87 g), palladium acetate (2.8 mg), tris(2-methoxyphenyl)phosphine (26.1 mg), toluene (45 mL), and 20 wt % tetraethylammonium hydroxide aqueous solution (6.36 g) were added to a 4-neck flask and stirred at 85° C. for 6 hours. Additionally, phenylboronic acid (220 mg), bis(triphenylphosphine)palladium(II) dichloride (52.0 mg), and 20 wt % tetraethylammonium hydroxide aqueous solution (6.36 g) were added and stirred at 85° C. for 6 hours. Then, sodium diethyldithiocarbamate trihydrate (4.2 g) dissolved in ion-exchanged water (45 mL) was added, and the mixture was stirred at 85° C. for 2 hours. After separating the organic layer from the aqueous layer, the solvent in the organic layer was removed under reduced pressure, and the residue was dissolved and precipitated with toluene/methanol. The precipitated solid was filtered, washed with water and methanol, and dried. The dry solid was dissolved in toluene (35 mL), and alumina (15.0 g) and Celite (5.0 g) were added, then the mixture was stirred at 90° C. for 1 hour. The alumina and Celite were removed by filtration, 12 N hydrochloric acid (30 mL) was added to the filtrate, and the mixture was stirred at room temperature for 12 hours. The aqueous layer was removed, and the organic layer was added dropwise into methanol. The precipitated solid was washed with methanol and water and dried under reduced pressure to obtain Copolymer P-5 (1.01 g). The weight-average molecular weight (Mw) and polydispersity (Mw/Mn) of the obtained Copolymer P-5 were measured by SEC. The weight-average molecular weight (Mw) and polydispersity (Mw/Mn) of Copolymer P-5 were 34,100 Da and 2.56, respectively. The Copolymer P-5 obtained in this manner is presumed, based on the monomer feed ratio, to be the copolymer represented by the above chemical formula. The ionization potential of Copolymer P-5 was 5.02 eV.

### Synthesis Example 18: Synthesis of Copolymer P-6

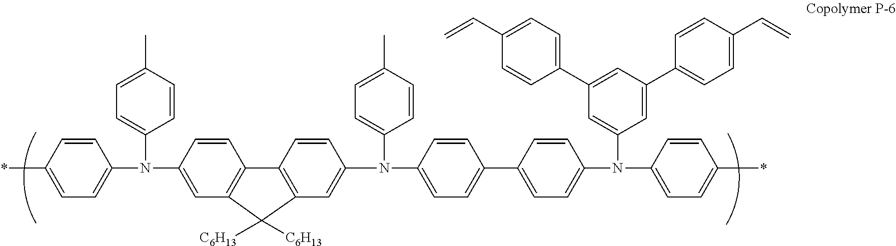

Under a nitrogen atmosphere, Compound M-6 (1.12 g), Compound CL-2 (0.92 g), palladium acetate (2.9 mg), tris(2-methoxyphenyl)phosphine (27.8 mg), toluene (41 mL), and 20 wt % aqueous tetraethylammonium hydroxide solution (6.77 g) were added to a 4-neck flask and stirred at 85° C. for 6 hours. Then, phenylboronic acid (234 mg), bis(triphenylphosphine)palladium(II) dichloride (55.3 mg), and 20 wt % aqueous tetraethylammonium hydroxide solution (6.77 g) were added and stirred at 85° C. for 6 hours. Afterwards, sodium diethyldithiocarbamate trihydrate (4.5 g) dissolved in ion-exchanged water (45 mL) was added and stirred at 85° C. for 2 hours. The organic layer was separated from the aqueous layer, then the solvent in the organic layer was removed under reduced pressure, and the residue was dissolved and then precipitated with toluene/methanol. The precipitated solid was filtered, washed with water and methanol, and dried. The dry solid was dissolved in toluene (35 mL), and alumina (15.0 g) and Celite (5.0 g) were added, followed by stirring the mixture at 90° C. for 1 hour. The alumina and Celite were removed by filtration, and 12 N hydrochloric acid (30 mL) was added to the filtrate, and the mixture was stirred at room temperature for 12 hours. The aqueous layer was removed, and the organic layer was added dropwise into methanol. The precipitated solid was washed with methanol and water, and then dried under reduced pressure, yielding the Copolymer P-6 (0.97 g). The weight-average molecular weight (Mw) and polydispersity (Mw/Mn) of the obtained Copolymer P-6 were measured by SEC. The weight-average molecular weight (Mw) and polydispersity (Mw/Mn) of the Copolymer P-6 were 20,300 Da and 2.10, respectively. The Copolymer P-6 obtained in this manner is presumed, from the monomer feed ratio, to be the copolymer represented by the above chemical formula. The ionization potential of Copolymer P-6 was 5.04 eV.

### Synthesis Example 19: Synthesis of Copolymer P-7

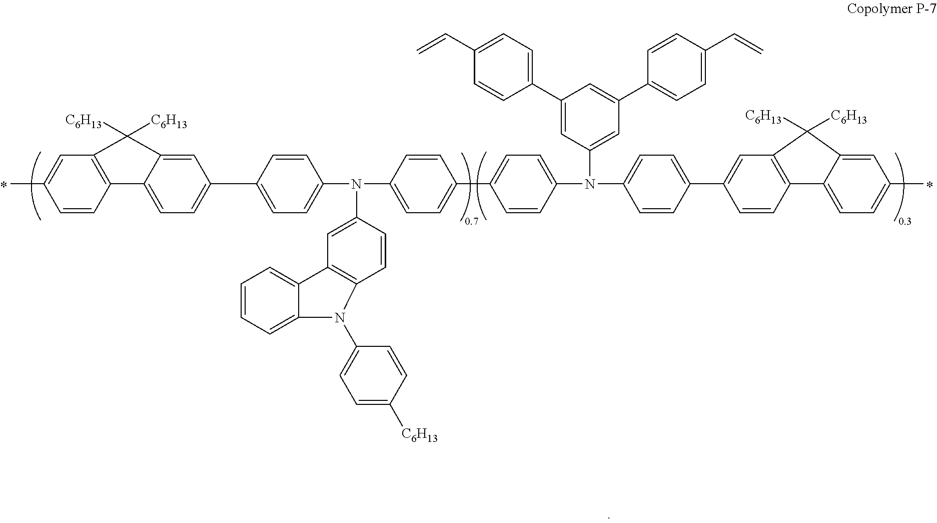

Under a nitrogen atmosphere, compound M-10 (0.69 g), compound CL-2 (0.28 g), dibromo-9,9-dihexylfluorene (1.12 g), palladium acetate (2.9 mg), tris(2-methoxyphenyl)phosphine (27.8 mg), toluene (41 mL), and 20 wt % aqueous tetraethylammonium hydroxide solution (6.77 g) were added to a four-neck flask and stirred at 85° C. for 6 hours. Additionally, phenylboronic acid (234 mg), bis(triphenylphosphine)palladium(II) dichloride (55.3 mg), and 20 wt % aqueous tetraethylammonium hydroxide solution (6.77 g) were added and stirred at 85° C. for 6 hours. Thereafter, sodium diethyldithiocarbamate trihydrate (4.5 g) dissolved in ion-exchanged water (45 mL) was added and stirred at 85° C. for 2 hours. After separating the organic layer from the aqueous layer, the solvent in the organic layer was removed under reduced pressure, and the residue was dissolved and precipitated with toluene/methanol. The precipitated solid was filtered, washed with water and methanol, and dried. The dried solid was dissolved in toluene (35 mL), alumina (15.0 g) and Celite (5.0 g) were added, and the mixture was stirred at 90° C. for 1 hour. The alumina and Celite were removed by filtration, 12 N hydrochloric acid (30 mL) was added to the filtrate, and the mixture was stirred at room temperature for 12 hours. The aqueous layer was removed, and the organic layer was added dropwise to methanol. The precipitated solid was washed with methanol and water, and dried under reduced pressure to obtain the Copolymer P-7 (0.77 g). The weight-average molecular weight (Mw) and polydispersity (Mw/Mn) of the obtained Copolymer P-7 were measured by SEC. The weight-average molecular weight (Mw) and polydispersity (Mw/Mn) of Copolymer P-7 were 27,100 Da and 2.43, respectively. The Copolymer P-7 obtained in this manner is estimated to be the copolymer represented by the above chemical formula based on the monomer feed ratio. The ionization potential of Copolymer P-7 was 5.27 eV.

### Synthesis Example 20: Synthesis of Copolymer P-8

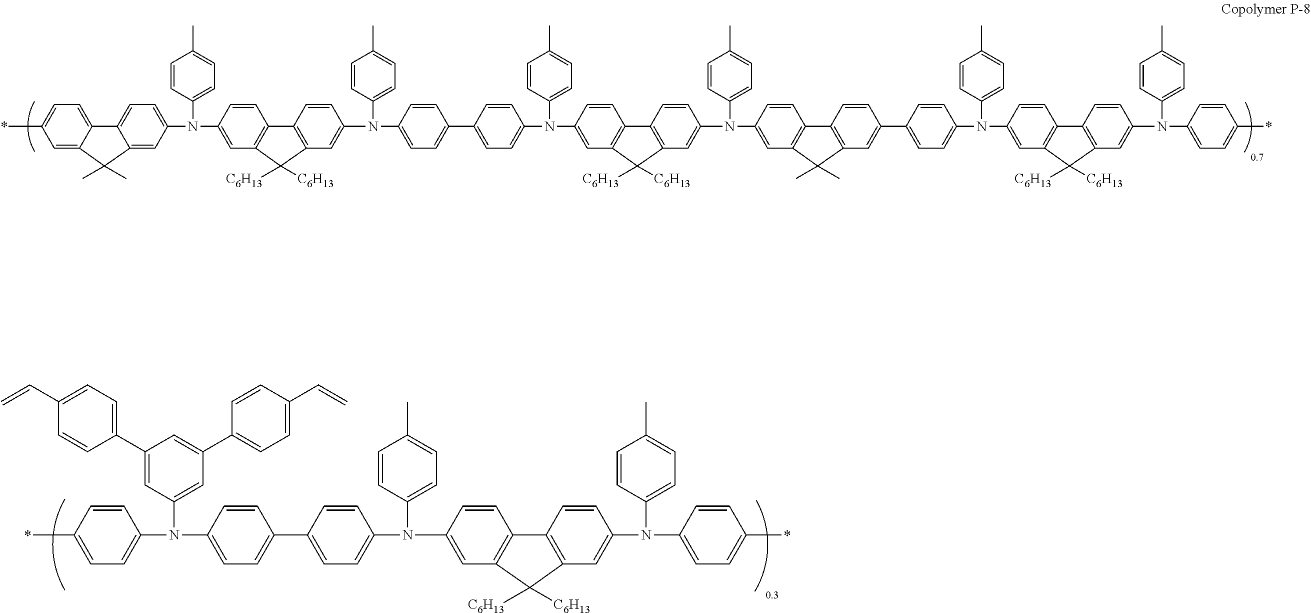

Under a nitrogen atmosphere, Compound M-3 (1.72 g), Compound CL-2 (0.20 g), Compound M-7 (0.64 g), palladium acetate (2.2 mg), tris(2-methoxyphenyl)phosphine (20.4 mg), toluene (39 mL), and 20 wt % tetraethylammonium hydroxide aqueous solution (4.98 g) were added to a four-neck flask and stirred at 85° C. for 6 hours. Additionally, phenylboronic acid (201 mg), bis(triphenylphosphine)palladium(II) dichloride (48.7 mg), and 20 wt % tetraethylammonium hydroxide aqueous solution (4.98 g) were added and stirred at 85° C. for 6 hours. Then, sodium N,N-diethyldithiocarbamate trihydrate (4.0 g) dissolved in ion-exchanged water (41 mL) was added and stirred at 85° C. for 2 hours. After separating the organic layer from the aqueous layer, the solvent in the organic layer was removed under reduced pressure, and the residue was dissolved and precipitated with toluene/methanol. The precipitated solid was filtered, washed with water and methanol, and dried. The dried solid was dissolved in toluene (35 mL), and alumina (13.0 g) and Celite (4.0 g) were added, and the mixture was stirred at 90° C. for 1 hour. The alumina and Celite were removed by filtration, 12 N hydrochloric acid (30 mL) was added to the filtrate, and the mixture was stirred at room temperature for 12 hours. The aqueous layer was removed, and the organic layer was added dropwise into methanol. The precipitated solid was washed with methanol and water, and dried under reduced pressure to obtain the Copolymer P-8 (1.03 g). The weight-average molecular weight (Mw) and polydispersity (Mw/Mn) of the obtained Copolymer P-8 were measured by SEC. The weight-average molecular weight (Mw) and polydispersity (Mw/Mn) of Copolymer P-8 were 36,000 Da and 2.24, respectively. The Copolymer P-8 obtained in this manner is estimated to be the copolymer represented by the above chemical formula based on the monomer feed ratio. The ionization potential of Copolymer P-8 was 4.86 eV.

### Synthesis Example 21: Synthesis of Copolymer P-9

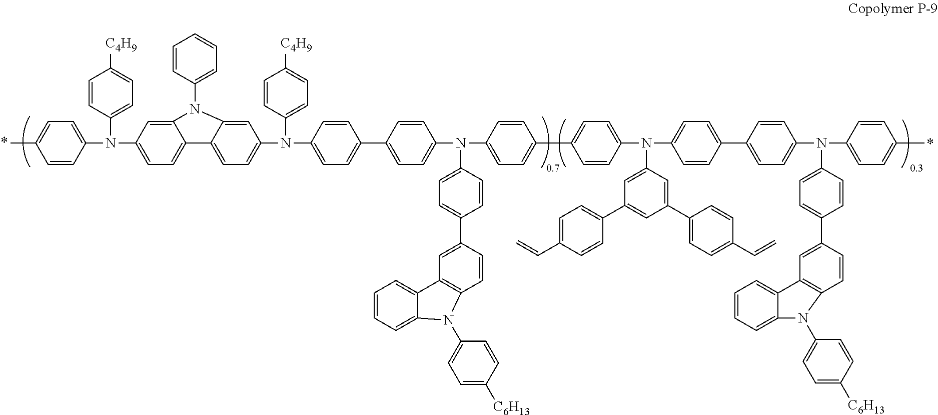

Under a nitrogen atmosphere, Compound M-8 (1.06 g), Compound CL-2 (0.35 g), Compound M-1 (1.23 g), palladium acetate (3.8 mg), tris(2-methoxyphenyl)phosphine (35.6 mg), toluene (39 mL), and 20 wt % aqueous tetraethylammonium hydroxide solution (8.68 g) were added to a four-neck flask and stirred at 85° C. for 6 hours. Additionally, phenylboronic acid (300 mg), bis(triphenylphosphine)palladium(II) dichloride (70.7 mg), and 20 wt % aqueous tetraethylammonium hydroxide solution (8.68 g) were added and stirred at 85° C. for 6 hours. Then, trihydrate sodium N,N-diethyldithiocarbamate dissolved in ion-exchanged water (60 mL, 6.7 g) was added and stirred at 85° C. for 2 hours. After separating the organic layer from the aqueous layer, the solvent in the organic layer was removed under reduced pressure, and the residue was dissolved and precipitated with toluene/methanol. The precipitated solid was filtered, washed with water and methanol, and dried. The dry solid was dissolved in toluene (45 mL), and alumina (20.0 g) and Celite (10.0 g) were added, followed by stirring the mixture at 90° C. for 1 hour. The alumina and Celite were removed by filtration, 12 N hydrochloric acid (40 mL) was added to the filtrate, and the mixture was stirred at room temperature for 12 hours. The aqueous layer was removed, and the organic layer was added dropwise into methanol. The precipitated solid was washed with methanol and water and then dried under reduced pressure to obtain the Copolymer P-9 (1.23 g). The weight-average molecular weight (Mw) and polydispersity (Mw/Mn) of the obtained Copolymer P-9 were measured by SEC. The weight-average molecular weight (Mw) and polydispersity (Mw/Mn) of the Copolymer P-9 were 50,000 Da and 2.42, respectively. The Copolymer P-9 obtained in this manner is presumed to be the copolymer represented by the above chemical formula, based on the monomer feed ratio. The ionization potential of Copolymer P-9 was 4.92 eV.

### Synthesis Example 22: Synthesis of Copolymer P-10

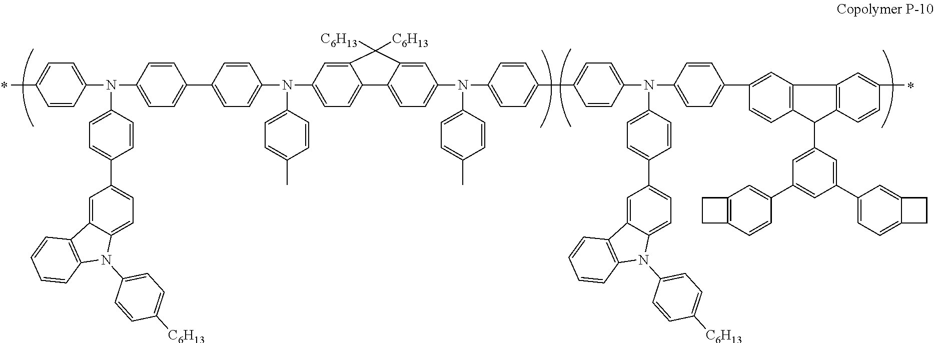

Under a nitrogen atmosphere, Compound M-7 (1.38 g), Compound CL-1 (0.11 g), Compound M-6 (1.38 g), palladium acetate (3.6 mg), tris(2-methoxyphenyl)phosphine (34.2 mg), toluene (58 mL), and 20 wt % aqueous tetraethylammonium hydroxide solution (8.34 g) were added to a four-neck flask and stirred at 85° C. for 6 hours. Additionally, phenylboronic acid (289 mg), bis(triphenylphosphine)palladium(II) dichloride (68.1 mg), and 20 wt % aqueous tetraethylammonium hydroxide solution (8.34 g) were added and stirred at 85° C. for 6 hours. Then, sodium N,N-diethyldithiocarbamate trihydrate (5.9 g) dissolved in ion-exchanged water (60 mL) was added, and the mixture was stirred at 85° C. for 2 hours. After separating the organic layer from the aqueous layer, the solvent in the organic layer was removed under reduced pressure, and the material was dissolved and precipitated with toluene/methanol. The precipitated solid was filtered, washed with water and methanol, and dried. The dry solid was dissolved in toluene (45 mL), and alumina (20.0 g) and Celite (10.0 g) were added, and then the mixture was stirred at 90° C. for 1 hour. The alumina and Celite were removed by filtration, and 12 N hydrochloric acid (40 mL) was added to the filtrate, followed by stirring at room temperature for 12 hours. The aqueous layer was removed, and the organic layer was added dropwise into methanol. The precipitated solid was washed with methanol and water and then dried under reduced pressure to obtain the Copolymer P-10 (1.12 g). The weight-average molecular weight (Mw) and polydispersity (Mw/Mn) of the obtained Copolymer P-10 were measured by SEC. The weight-average molecular weight (Mw) and polydispersity (Mw/Mn) of the Copolymer P-10 were 22,800 Da and 2.89, respectively. The Copolymer P-10 obtained in this manner is estimated to be the copolymer represented by the above chemical formula, based on the monomer feed ratio. The ionization potential of Copolymer P-10 was 5.00 eV.

### Synthesis Example 23: Synthesis of Copolymer P-11

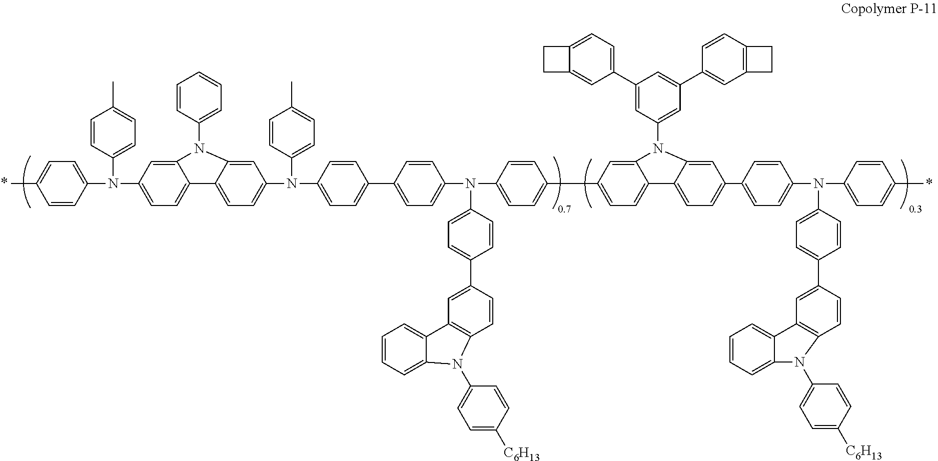

Under a nitrogen atmosphere, Compound M-9 (1.35 g), Compound CL-1 (0.12 g), Compound M-1 (1.29 g), palladium acetate (4.0 mg), tris(2-methoxyphenyl)phosphine (37.4 mg), toluene (55 mL), and 20 wt % tetraethylammonium hydroxide aqueous solution (9.13 g) were added to a 4-necked flask and stirred at 85° C. for 6 hours. Additionally, phenylboronic acid (316 mg), bis(triphenylphosphine)palladium(II) dichloride (70.7 mg), and 20 wt % tetraethylammonium hydroxide aqueous solution (9.13 g) were added and stirred at 85° C. for 6 hours. Then, sodium N,N-diethyldithiocarbamate trihydrate (6.7 g) dissolved in ion-exchange water (60 mL) was added, and the mixture was stirred at 85° C. for 2 hours. After separating the organic layer from the aqueous layer, the solvent in the organic layer was removed under reduced pressure, and the residue was dissolved and precipitated with toluene/methanol. The precipitated solid was filtered, washed with water and methanol, and dried. The dried solid was dissolved in toluene (45 mL), alumina (20.0 g) and Celite (10.0 g) were added, and the mixture was stirred at 90° C. for 1 hour. The alumina and Celite were removed by filtration, 12 N hydrochloric acid (40 mL) was added to the filtrate, and the mixture was stirred at room temperature for 12 hours. The aqueous layer was removed, and the organic layer was added dropwise into methanol. The precipitated solid was washed with methanol and water, and dried under reduced pressure to obtain the Copolymer P-11 (1.23 g). The weight-average molecular weight (Mw) and polydispersity (Mw/Mn) of the obtained Copolymer P-11 were measured by SEC. The weight-average molecular weight (Mw) and polydispersity (Mw/Mn) of Copolymer P-11 were 22,600 Da and 2.11, respectively. The Copolymer P-11 obtained in this manner is estimated to be the copolymer represented by the above chemical formula based on the monomer feed ratio. The ionization potential of Copolymer P-11 was 4.99 eV.

### Synthesis Example 24: Synthesis of Compound D-1

Compound D-1, which is a salt compound including a borate anion, was prepared according to Reaction Scheme 11.

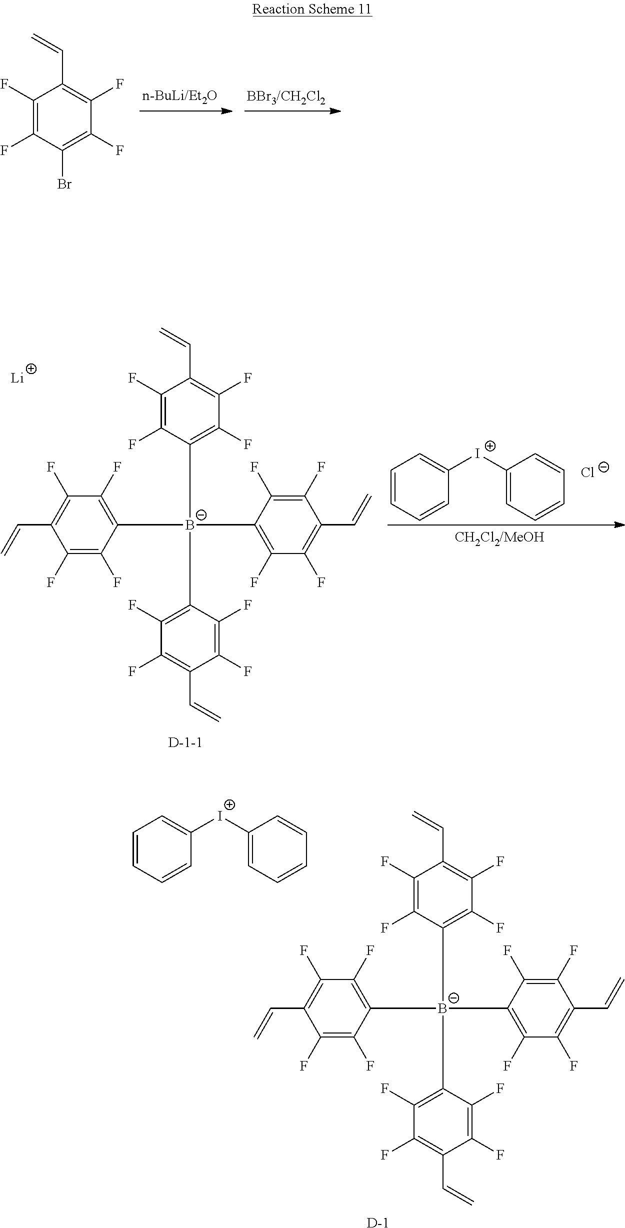

In a 100 mL, four-neck flask replaced with argon, 1-bromo-2,3,5,6-tetrafluoro-4-vinylbenzene (5.00 g) and diethyl ether (60 mL) were added, and the mixture was stirred under an argon atmosphere and cooled to −78° C. A hexane solution of n-butyllithium (1.6 M, 14.3 mL) was added dropwise, and the mixture was stirred at −78° C. for 30 minutes. Next, a dichloromethane solution of tribromoborane (1 M, 4.1 mL) was added dropwise to the reaction solution at −78° C., and the mixture was stirred overnight. Water (35 mL) was then added to the resulting reaction mixture, and a liquid-liquid extraction was performed. The obtained organic layer was concentrated under reduced pressure to afford an off-white solid (3.78 g). The obtained solid was purified by column chromatography (eluents: dichloromethane/acetonitrile), yielding Compound D-1-1 as a white solid (2.09 g). The obtained Compound D-1-1 and diphenyliodonium chloride (0.92 g) were dissolved in a mixed solvent of dichloromethane/methanol (dichloromethane:methanol=10:1 (v/v), 40 mL) and stirred for 1 hour. Water (35 mL) was added to the resulting mixed solution, and then the organic layer was washed. After removing the solvent under reduced pressure, purification was performed by column chromatography (eluents: dichloromethane/acetonitrile), yielding Compound D-1 (1.63 g). The electron affinity of the borate anion included in the Compound D-1 was 5.75 eV.

### Synthesis Example 25: Synthesis of Compound D-2

Compound D-2, which is a salt compound including a borate anion, was prepared according to Reaction Scheme 12.

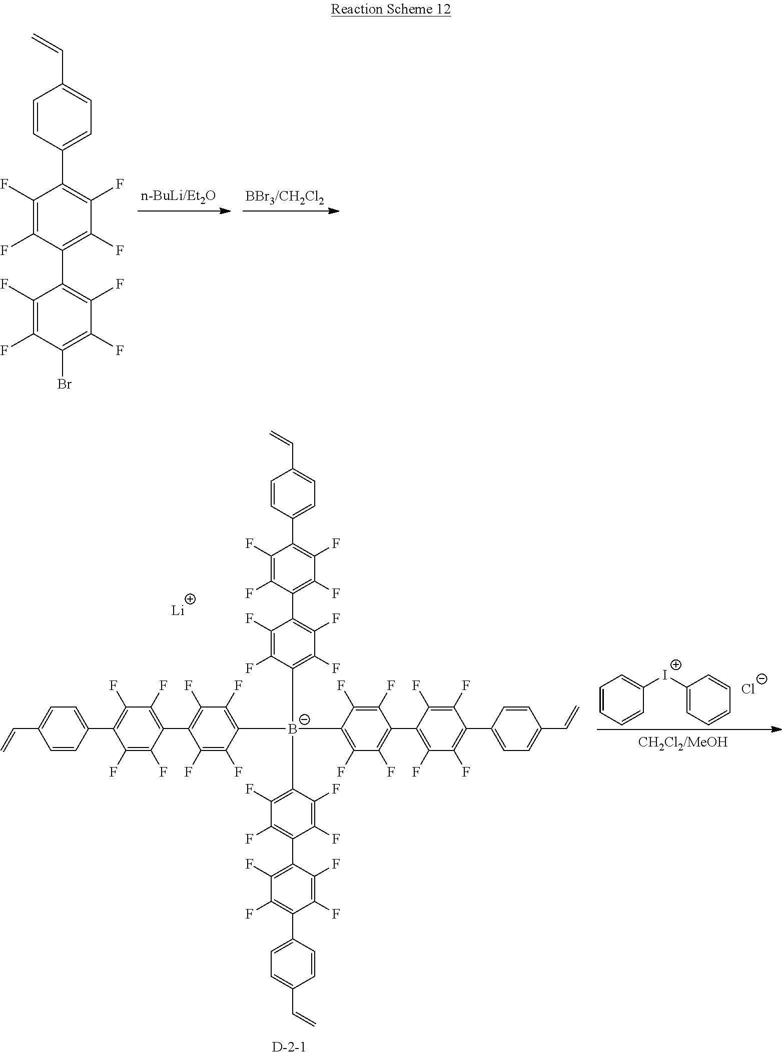 [SMILES: C=Cc1ccc(-c2c(F)c(F)c(-c3c(F)c(F)c(Br)c(F)c3F)c(F)c2F)cc1 ; C=Cc1ccc(-c2c(F)c(F)c(-c3c(F)c(F)c([B-](c4c(F)c(F)c(-c5c(F)c(F)c(-c6ccc(C=C)cc6)c(F)c5F)c(F)c4F)(c4c(F)c(F)c(-c5c(F)c(F)c(-c6ccc(C=C)cc6)c(F)c5F)c(F)c4F)c4c(F)c(F)c(-c5c(F)c(F)c(-c6ccc(C=C)cc6)c(F)c5F)c(F)c4F)c(F)c3F)c(F)c2F)cc1 ; [Li+] ; c1ccc([I+]c2ccccc2)cc1 ; [Cl-]]

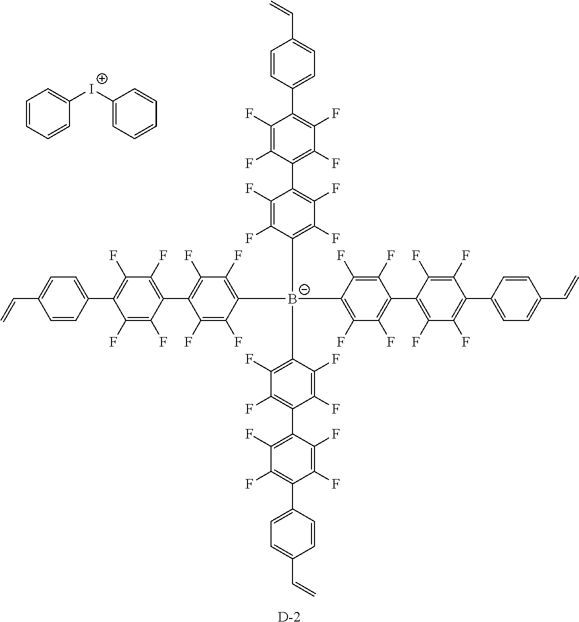

Into an 100 mL, 4-neck flask substituted with argon, 4-bromo-2,2′,3,3′,5,5′,6,6′-octafluoro-4″-vinyl-1,1′:4′,1″-terphenyl (2.20 g) and diethyl ether (60 mL) were added, and the mixture was stirred under an argon atmosphere while cooling to −78° C. A hexane solution of n-butyllithium (1.6 M, 3.20 mL) was added dropwise, and the mixture was stirred at −78° C. for 30 minutes. Then, a dichloromethane solution of tribromoborane (1 M, 0.99 mL) was added dropwise to the reaction solution at −78° C., and the mixture was stirred overnight. Afterwards, water (45 mL) was added to the resulting reaction solution, and a liquid-liquid extraction was performed. The obtained organic layer was concentrated under reduced pressure to afford an off-white solid. The solid was purified by column chromatography (eluents: dichloromethane/acetonitrile) to obtain Compound D-2-1 as a white solid (0.93 g). The obtained Compound D-2-1 and diphenyliodonium chloride (0.18 g) were dissolved in a mixed solvent of dichloromethane/methanol (dichloromethane:methanol=10:1 (v/v), 20 mL) and stirred for 1 hour. Water (20 mL) was then added to the resulting reaction solution, and the organic layer was washed. After removing the solvent under reduced pressure, the mixture was purified by column chromatography (eluents: dichloromethane/acetonitrile) to obtain Compound D-2 (0.40 g). The electron affinity of the borate anion included in the Compound D-2 was 6.08 eV.

### Synthesis Example 26: Synthesis of Compound D-3

Compound D-3, which is a salt compound including a borate anion, was prepared according to Reaction Scheme 13.

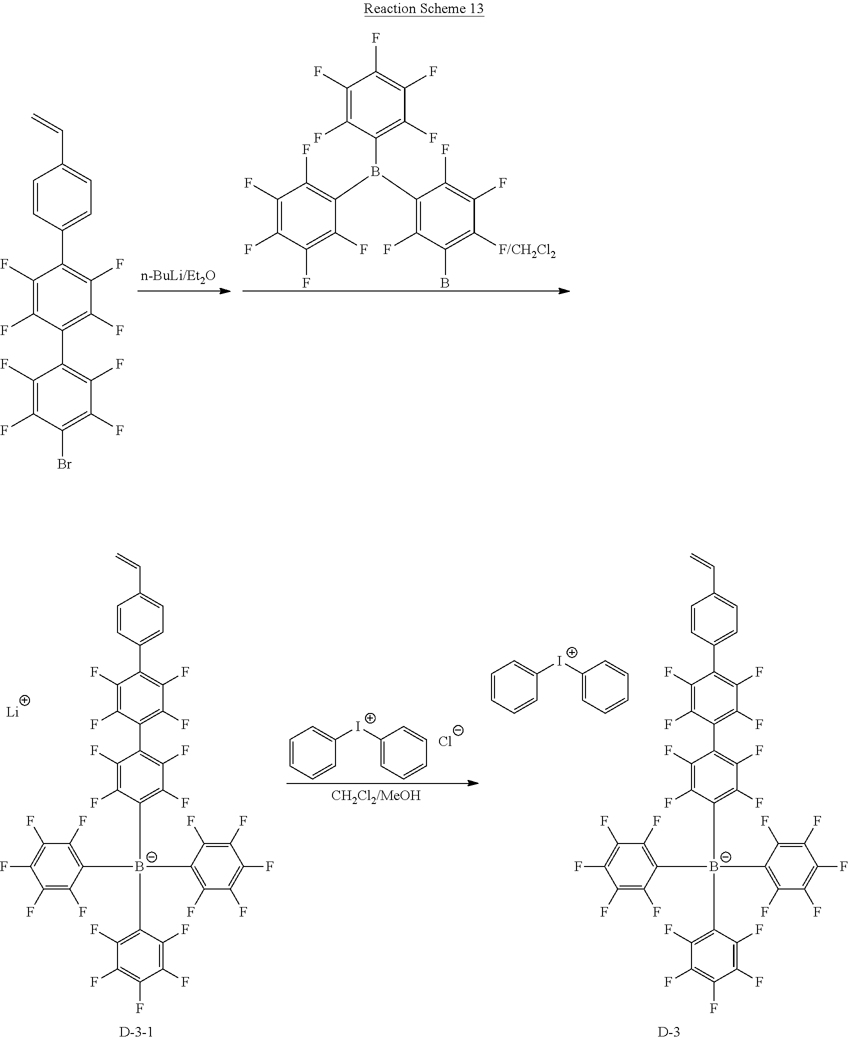

Into a 100 mL, 4-neck flask substituted with argon, 4-bromo-2,2′,3,3′,5,5′,6,6′-octafluoro-4″-vinyl-1,1′:4′,1″-terphenyl (1.00 g) and diethyl ether (27 mL) were added, and the mixture was stirred under an argon atmosphere and cooled to −78° C. A solution of n-butyllithium in hexane (1.6 M, 1.4 mL) was added dropwise, and the mixture was stirred at −78° C. for 30 minutes. Next, tris(pentafluorophenyl)borane (0.942 g) was dissolved in dichloromethane (3.8 mL), added dropwise at −78° C., and the mixture was stirred overnight. Thereafter, water (20 mL) was added to the resulting reaction solution, and a liquid-liquid extraction was performed. The obtained organic layer was concentrated under reduced pressure to yield an off-white solid. This solid was purified by column chromatography (eluents: dichloromethane/acetonitrile) to obtain Compound D-3-1 as a white solid (1.14 g). Next, the obtained Compound D-3-1 and diphenyliodonium chloride (0.58 g) were dissolved in a mixed solvent of dichloromethane/methanol (dichloromethane:methanol=10:1 (v/v), 20 mL) and stirred for 1 hour. Water (10 mL) was added to the resulting reaction solution, and then the organic layer was washed. After removing the solvent under reduced pressure, purification was carried out by column chromatography (eluents: dichloromethane/acetonitrile) to obtain Compound D-3 (1.14 g). The electron affinity of the borate anion included in the Compound D-3 was 6.22 eV.

### Synthesis Example 27: Synthesis of Compound D-4

Compound D-4, which is a salt compound including a borate anion, was prepared according to Reaction Scheme 14.

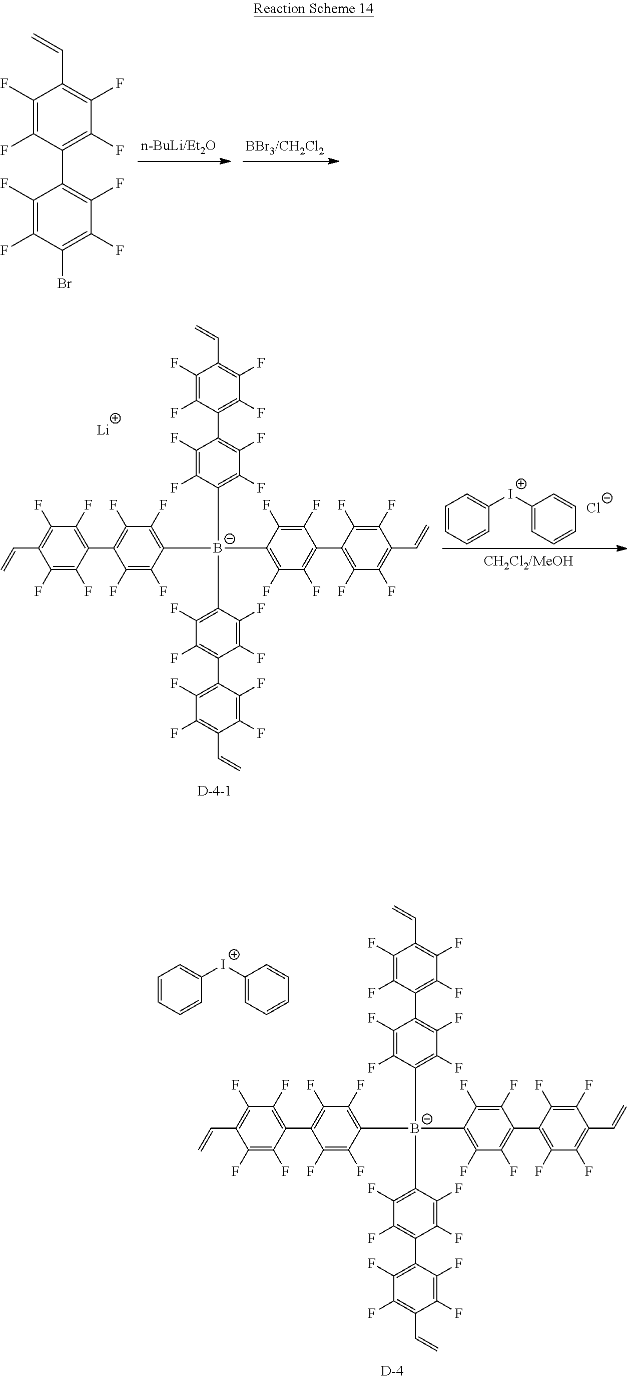

In a 100 mL, four-neck flask replaced with argon, 4-bromo-2,2′,3,3′,5,5′,6,6′-octafluoro-4″-vinyl-1,1′-biphenyl (5.00 g) and diethyl ether (45 mL) were added, and the mixture was stirred under an argon atmosphere while being cooled to −78° C. A hexane solution of n-butyllithium (1.6 M, 9.0 mL) was added dropwise, and the mixture was stirred at −78° C. for 30 minutes. Next, a dichloromethane solution of tribromoborane (1 M, 2.57 mL) was added dropwise at −78° C., and the mixture was stirred overnight. Afterwards, water (22 mL) was added to the obtained reaction solution, and the mixture was subjected to liquid-liquid extraction. The resulting organic layer was concentrated under reduced pressure to obtain an off-white solid. The obtained solid was purified by column chromatography (eluents: dichloromethane/acetonitrile) to give Compound D-4-1 as a white solid (2.21 g). Next, the Compound D-4-1 obtained and diphenyliodonium chloride (0.53 g) were dissolved in a mixed solvent of dichloromethane/methanol (dichloromethane:methanol=10:1 (v/v), 20 mL) and stirred for 1 hour. Water (10 mL) was added to the resulting reaction solution, and the organic layer was washed. After removing the solvent under reduced pressure, purification was carried out by column chromatography (eluents: dichloromethane/acetonitrile) to obtain Compound D-4 (1.73 g). The electron affinity of the borate anion included in the Compound D-4 was 6.17 eV.

### Synthesis Example 28: Synthesis of Compound D-5

Compound D-5, which is a salt compound including a borate anion, was prepared according to Reaction Scheme 15.

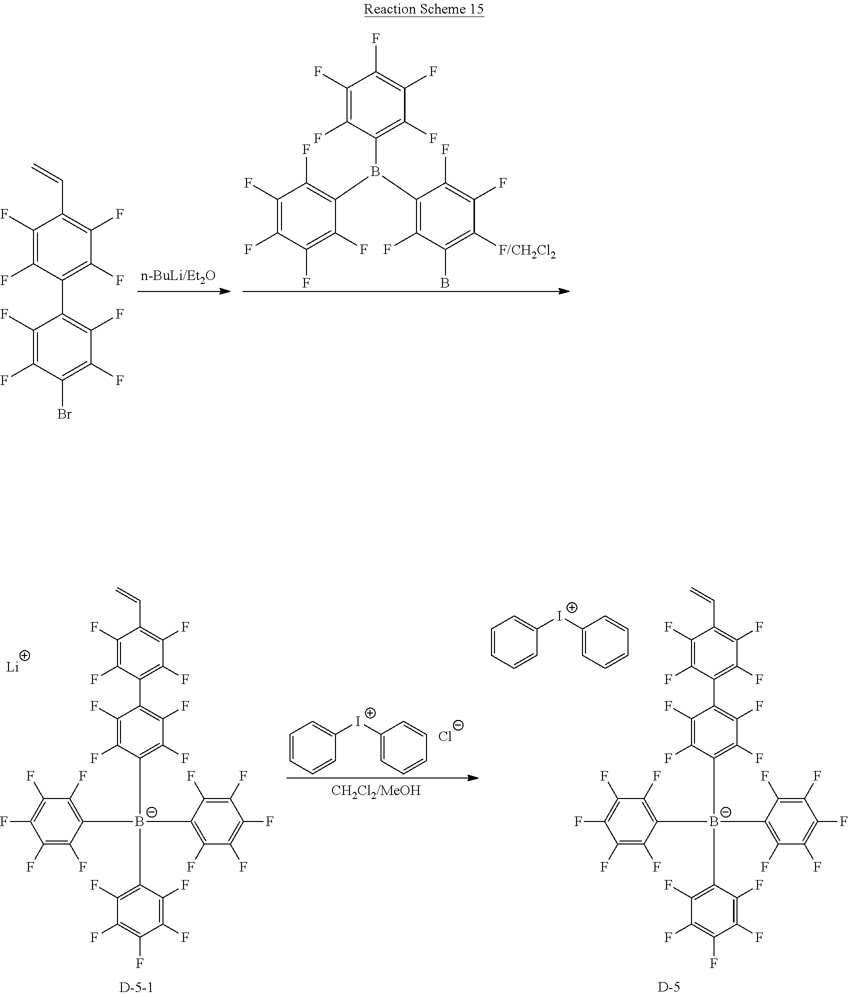

Into a 100 mL, four-neck flask replaced with argon, 4-bromo-2,2′,3,3′,5,5′,6,6′-octafluoro-4″-vinyl-1,1′-biphenyl (2.00 g) and diethyl ether (65 mL) were added, and the mixture was stirred under an argon atmosphere while cooling to −78° C. A solution of n-butyllithium in hexane (1.6 M, 3.3 mL) was added dropwise and stirred for about 30 minutes while maintaining the internal temperature of −78° C. Then, tris(pentafluorophenyl)borane (2.24 g) was dissolved in dichloromethane and added dropwise while maintaining the internal temperature of −78° C., and the mixture was stirred overnight. Next, water (30 mL) was added to the reaction mixture, a liquid-liquid extraction was performed, and the organic layer was concentrated under reduced pressure to obtain an off-white solid. The solid was purified by column chromatography using dichloromethane/acetonitrile as the eluents to give Compound D-5-1 (2.24 g) as a white solid. The white solid Compound D-5-1 and diphenyliodonium chloride (0.83 g) were dissolved in a mixed solvent of dichloromethane/methanol (dichloromethane:methanol=10/1 (v/v, 30 mL)) and stirred for 1 hour. Water (15 mL) was then added, and the organic layer was washed. After removing the solvent under reduced pressure, silica gel column chromatography (eluents: dichloromethane/acetonitrile) was performed to obtain Compound D-5 (1.68 g). The electron affinity of the borate anion included in Compound D-5 was 6.25 eV.

### Example 1

### Preparation of Composition 1, Fabrication of Electroluminescent Device 1, and Positive Aging

As a first electrode (anode), a glass substrate attached with a patterned indium tin oxide (ITO) film having a thickness of 150 nm was provided. The ITO attached glass substrate was washed with neutral detergent, deionized water, water, and isopropyl alcohol in order, and treated with UV-ozone processing.

The Copolymer P-1 prepared in Synthesis Example 13 was prepared by dissolving it at a concentration of 3 wt % in a mixed solvent of xylene and butyl benzoate (xylene:butyl benzoate=100:10 by volume). Separately, another solution was prepared by dissolving 4-isopropyl-4′-methyldiphenyliodonium tetrakis(pentafluorophenyl)borate (PIPB, manufactured by Tokyo Kasei Kogyo Kabushiki Kaisha), represented by the chemical formula below, at a concentration of 3 wt % in a mixed solvent of xylene and butyl benzoate (xylene:butyl benzoate=100:10 by volume). The two solutions were mixed so that the weight ratio of Copolymer 1 to PIPB was 90:10, thereby preparing Composition 1 (Coating Solution 1 for forming a hole injection layer). The electron affinity of the borate anion possessed by the above PIPB was 6.29 eV.

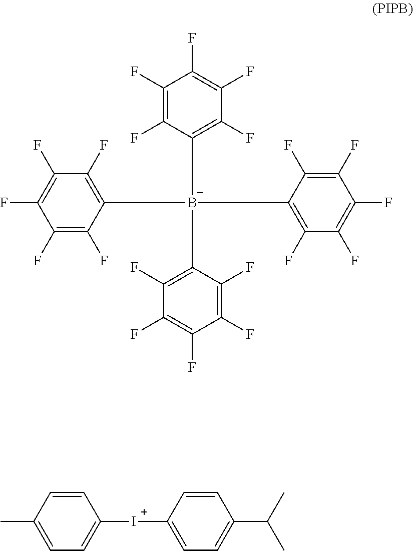 [SMILES: Fc1c(F)c(F)c([B-](c2c(F)c(F)c(F)c(F)c2F)(c2c(F)c(F)c(F)c(F)c2F)c2c(F)c(F)c(F)c(F)c2F)c(F)c1F ; Cc1ccc([I+]c2ccc(C(C)C)cc2)cc1]

Next, on the above-mentioned ITO-attached glass substrate, Composition 1 (a coating solution for forming a hole injection layer) was applied by a spin-coating method to a thickness (dry film thickness) of 100 nm, then heated at 230° C. for 30 minutes to form a hole injection layer with a thickness (dry film thickness) of 100 nm.

Subsequently, HTP-1 (the polymer compound P-3 described in Japanese Laid-open Publication No. 2021-138915), a hole transport material represented by the chemical formula below, was dissolved in xylene (solvent) at a concentration of 1 wt % to prepare a coating solution for forming a hole transport layer. On the hole injection layer formed above, the coating solution for forming the hole transport layer was applied by a spin-coating method to a thickness (dry film thickness) of 25 nm, then heated at 230° C. for 30 minutes to form a hole transport layer with a thickness (dry film thickness) of 25 nm.

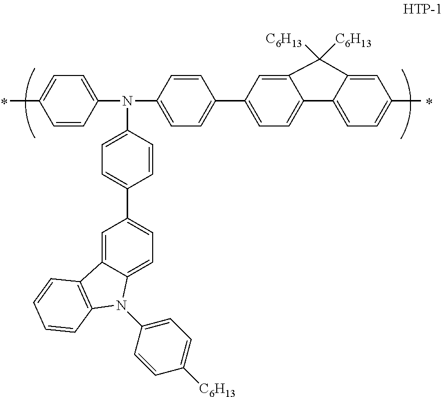

Next, blue quantum dots, ZnTeSe/ZnSe/ZnS (core/shell/shell; average diameter=10 nm), were dispersed in octane at a concentration of 1.0 wt % to prepare a quantum dot dispersion. This quantum dot dispersion was applied onto the hole transport layer by spin coating so that the dry film thickness would be 25 nm, and then dried. As a result, a light emitting layer with a thickness (dry film thickness) of 25 nm was formed on the hole transport layer. When ultraviolet light was irradiated onto the quantum dot dispersion, the emitted light had a peak wavelength of 462 nm and a full width at half maximum (FWHM) of 30 nm.

The light emitting layer was fully dried.

Next, a dispersion of ZnMgO (solvent: ethanol, concentration: 10 wt %) was spin-coated onto the thermally treated quantum dot emitting layer, and heat-treated at 80° C. to form an electron transport layer with a thickness of 20 nm. Aluminum (Al) was vacuum-deposited on the fabricated electron transport layer to form a second electrode with a thickness of 100 nm, creating a laminated structure and producing quantum dot electroluminescent device 1.

On the second electrode of the laminated structure, LOCTITE® AA366 (manufactured by Henkel, containing methacrylate ester, acrylic acid, methacrylic acid, etc.) was applied, and ultraviolet light (wavelength: 365 nm, cumulative dose: 10 mJ/cm²) was irradiated to form an acid compound layer (thickness: 1.5 μm), resulting in quantum dot electroluminescent device 1 before treatment (before positive aging treatment). This was placed in a constant temperature oven at 70° C. for 5 days to obtain quantum dot electroluminescent device 1 after treatment (after positive aging treatment).

### Fabricating MSM (Metal-Semiconductor-Metal) Device 1, and Positive Aging

As a first electrode (anode), a glass substrate attached with a patterned indium tin oxide (ITO) film having a thickness of 150 nm was provided. The ITO attached glass substrate was washed with neutral detergent, deionized water, water, and isopropyl alcohol in order, and treated with UV-ozone processing.

The Copolymer P-1 synthesized in Synthetic Example 13 was dissolved in a mixed solvent of xylene and butyl benzoate (xylene:butyl benzoate=100:10 by volume) at a concentration of 3 wt %. Separately, another solution was prepared by dissolving 4-isopropyl-4′-methyl diphenyliodonium tetrakis(pentafluorophenyl)borate (PIPB, manufactured by Tokyo Chemical Industry Co., Ltd., see the above chemical formula) in a mixed solvent of xylene and butyl benzoate (xylene:butyl benzoate=100:10 by volume) at a concentration of 3 wt %. The two solutions were mixed so that the weight ratio of the Copolymer 1 to PIPB was 90:10, thereby preparing Composition 1 (coating solution 1 for a hole injection layer).

Next, Composition 1 (coating solution for forming a hole injection layer) was applied onto the above-mentioned ITO-attached glass substrate by spin coating to a thickness (dry film thickness) of 100 nm, and then heated at 230° C. for 30 minutes, thereby forming a hole injection layer with a thickness (dry film thickness) of 100 nm.

Using a vacuum deposition device, a mixed film of silver and magnesium (hereinafter, also referred to as ‘AgMg’) was deposited by the vacuum deposition device on the hole injection layer formed above, forming a second electrode (cathode) with a thickness of 20 nm, thereby producing MSM device 1.

Next, on the second electrode of this laminated structure, LOCTITE® AA366 (manufactured by Henkel, containing methacrylic ester, acrylic acid, methacrylic acid, etc.) was applied, and ultraviolet light (wavelength: 365 nm, total irradiation: 10 mJ/cm²) was irradiated to form an acid compound layer (thickness: 1.5 μm), obtaining MSM device 1 before treatment (before positive aging treatment). This was then placed in a constant temperature oven at 70° C. for 5 days to obtain MSM device 1 after treatment (after positive aging treatment).

### Examples 2 to 11

Except for changing the types of the copolymers and salt compounds as listed in Table 1, the same procedure as in Example 1 was followed to fabricate Example compositions 2 to 11, quantum dot electroluminescent devices 2 to 11, quantum dot electroluminescent devices 2 to 11 before treatment, quantum dot electroluminescent devices 2 to 11 after treatment, MSM devices 2 to 11, MSM devices 2 to 11 before treatment, and MSM devices 2 to 11 after treatment, respectively.

### Comparative Example 1

Except for using the compound, TFB, i.e., poly[(9,9-dioctylfluorenyl-2,7-di-yl)-co-(4,4′-(N-(4-sec-butylphenyl)diphenylamine)] manufactured from Luminescence Technology Corp., shown below, instead of the Copolymer P-1, Comparative Composition 1, Comparative Electroluminescent Device 1, Comparative Pre-Treatment Electroluminescent Device 1, Comparative Post-Treatment Electroluminescent Device 1, Comparative MSM Device 1, Comparative Pre-Treatment MSM Device 1, and Comparative Post-Treatment MSM Device 1 were prepared in the same manner as in Example 1.

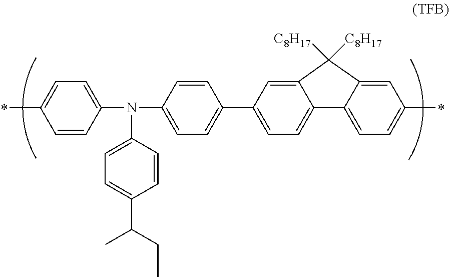

### Comparative Example 2

Except for using the Compound HT-1, shown below, instead of the Copolymer P-3, Comparative Composition 2, Comparative Electroluminescent Device 2, Comparative Pre-Treatment Electroluminescent Device 2, Comparative Post-Treatment Electroluminescent Device 2, Comparative MSM Device 2, Comparative Pre-Treatment MSM Device 2, and Comparative Post-Treatment MSM Device 2 were prepared in the same manner as in Example 4. The Compound HT-1 was synthesized with reference to the description in ACS Materials Lett. 2023, 5, pp. 3184-3191.

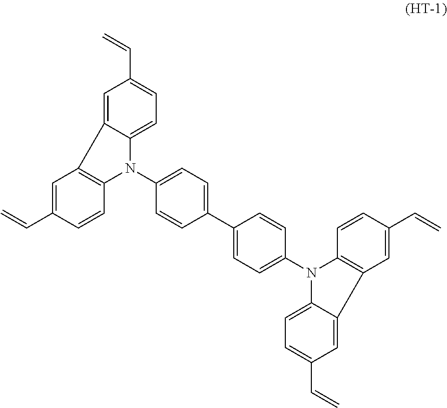 [SMILES: C=Cc1ccc2c(c1)c1cc(C=C)ccc1n2-c1ccc(-c2ccc(-n3c4ccc(C=C)cc4c4cc(C=C)ccc43)cc2)cc1]

### Comparative Example 3

Except for using the Copolymer HT-2 shown below, synthesized according to Synthesis Example 29, described below, instead of the Copolymer P-1, the same procedure as in Example 1 was followed to produce Comparative Composition 3, Comparative Electroluminescent Device 3, Comparative Pre-Treatment Electroluminescent Device 3, Comparative Post-Treatment Electroluminescent Device 3, Comparative MSM Device 3, Comparative Pre-Treatment MSM Device 3, and Comparative Post-Treatment MSM Device 3.

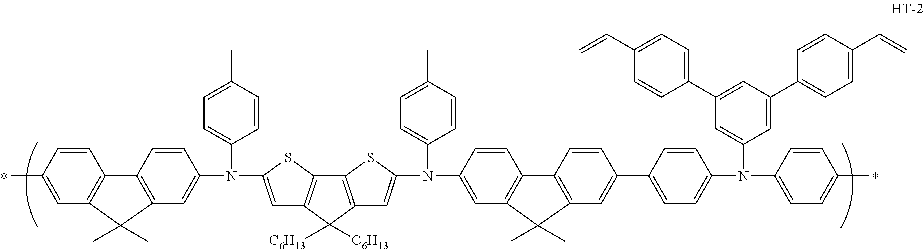

### Synthesis Example 29: Synthesis of Copolymer HT-2

The above Copolymer HT-2 was synthesized according to Reaction Scheme 16.

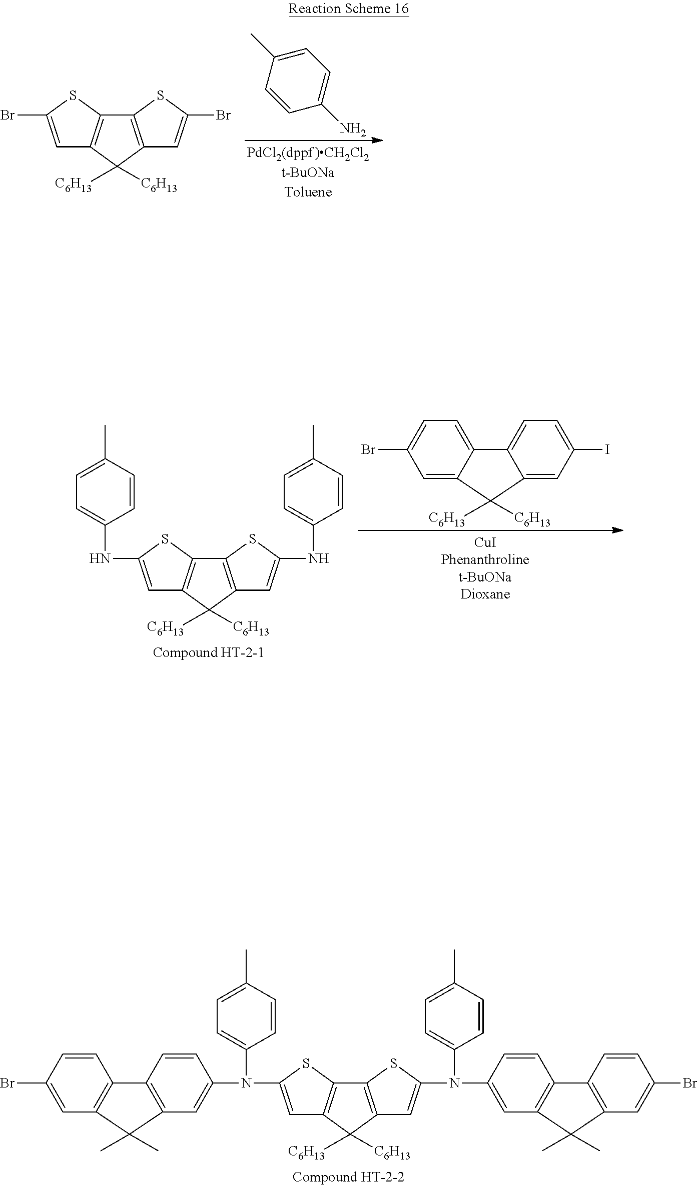

In a 300 mL, 3-neck flask substituted with argon, 2,6-dibromo-4,4-dihexyl-4H-cyclopenta[2,1-b:3,4-b′]dithiophene (10.0 g), p-toluidine (4.5 g), [1,1′-bis(diphenylphosphino)ferrocene]dichloropalladium(II) dichloromethane adduct (0.3 g), sodium tert-butoxide (5.7 g), and toluene (200 mL) were added and stirred at 120° C. (bath temperature) for 12 hours. After cooling to room temperature, the precipitate was removed by filtration using Celite as a filter aid. The solvent was removed under reduced pressure, and the residue was purified by silica gel column chromatography (eluents: toluene/hexane) to obtain Compound HT-2-1 (7.5 g).

In a 300 mL, three-neck flask substituted with argon, the Compound HT-2-1 (5.0 g) obtained above, 2-bromo-9,9-dimethyl-7-iodo-9H-fluorene (7.6 g), cuprous iodide (0.2 g), phenanthroline (0.3 g), sodium tert-butoxide (2.6 g), and 1,4-dioxane (10 mL) were added and stirred at 110° C. (bath temperature) for 18 hours. After cooling to room temperature, insoluble materials were removed using Celite as a filtration aid. The solvent was removed under reduced pressure, and the residue was dissolved in a mixed solvent of toluene (100 mL) and hexane (100 mL), activated charcoal (5.0 g) was added, and the mixture was heated at reflux for 30 minutes. The insoluble materials were filtered using Celite as a filtration aid. The solvent was removed under reduced pressure, and the residue was purified by silica gel column chromatography (eluent: toluene/hexane) to obtain compound HT-2-2 (8.3 g).

Into a four-neck flask under nitrogen atmosphere, were added the Compound HT-2-2 (1.79 g) obtained above, Compound CL-2 (1.14 g), palladium acetate (3.7 mg), tris(2-methoxypehnyl)phosphine (343. Mg), toluene (59 mL), and 20 wt % tetraethylammonium hydroxide aqueous solution (8.68 g), and the mixture was stirred at 85° C. for 6 hours. Additionally, phenylboronic acid (196 mg), bis(triphenylphosphine)palladium(II) dichloride (68.4 mg), and 20 wt % tetraethylammonium hydroxide aqueous solution (5.68 g) were added and stirred at 85° C. for 6 hours. Then, sodium N,N-diethyldithiocarbamate trihydrate (4.7 g) dissolved in ion-exchange water (70 mL) was added, and the mixture was stirred at 85° C. for 2 hours. After separating the organic layer from the aqueous layer, the solvent in the organic layer was removed under reduced pressure, and the residue was dissolved and precipitated with toluene/methanol. The precipitated solid was filtered, washed with water and methanol, and dried. The dried solid was dissolved in toluene (40 mL), alumina (20.0 g) and Celite (5.0 g) were added, and the mixture was stirred at 90° C. for 1 hour. The alumina and Celite were removed by filtration, 12 N hydrochloric acid (30 mL) was added to the filtrate, and the mixture was stirred at room temperature for 12 hours. The aqueous layer was removed, and the organic layer was added dropwise into methanol. The precipitated solid was washed with methanol and water, and dried under reduced pressure to obtain the Copolymer HT-2 (1.67 g). The weight-average molecular weight (Mw) and polydispersity (Mw/Mn) of the obtained Copolymer HT-2 were measured by SEC. The weight-average molecular weight (Mw) and polydispersity (Mw/Mn) of Copolymer HT-2 were 29,000 Da and 2.56, respectively. The Copolymer HT-2 obtained in this manner is estimated to be the copolymer represented by the above chemical formula based on the monomer feed ratio. The ionization potential of Copolymer HT-2 was 4.69 eV.

### Evaluation

### Evaluation of Solubility (Residual Film Rate)

The solubility of the copolymer included in the composition was evaluated by the following method. That is, the copolymer was dissolved in xylene as a solvent at a concentration of 1 wt % to prepare a copolymer coating solution. Next, the copolymer coating solution was applied onto a quartz substrate by spin coating, and then dried at 230° C. for 30 minutes to form a film with a dry thickness of 25 nm. Thereafter, the absorption spectrum of the formed film (before solvent immersion) was measured using a UV-Vis spectrophotometer (manufactured by Kabushiki Kaisha Shimadzu, UV-1800). The wavelength of the peak at the longest wavelength in the absorption spectrum was measured and set as the reference wavelength.

Next, the same film on the quartz substrate (the film before solvent immersion) was immersed in the solvent cyclohexylbenzene (CHB) for 20 minutes, then taken out of the solvent and dried at 230° C. for 30 minutes. The absorption spectrum of the dried film (the film after solvent immersion) was measured using the UV-Vis spectrophotometer in the same manner as above. For this absorption spectrum, the ratio of the intensity at the reference wavelength of the absorption spectrum after solvent immersion to the intensity at the reference wavelength of the absorption spectrum before solvent immersion {(“intensity at the reference wavelength of the absorption spectrum after solvent immersion”/“intensity at the reference wavelength of the absorption spectrum before solvent immersion”)×100(%)} was defined as the residual film rate (%). The obtained residual film rate (%) was evaluated according to the following criteria, and the uniformity of the coating was assessed:
o: greater than or equal to 80%
x: less than 80%

### [Measurement of Conductivity Retention Rate]

For each MSM device fabricated as described above, the conductivity retention rate was evaluated by the following method.

When a voltage is applied to the MSM device, current begins to flow at a certain voltage. Using a DC constant voltage power supply (manufactured by Kabushiki Kaisha Kikusui, source meter), a voltage was applied to the MSM device in increments of 0.2 V from 0 V to 10 V, and the corresponding current values were measured.

The current per unit area (current density) was calculated from the area of the MSM device, and the conductivity retention rate was calculated by dividing the current density of the processed MSM device by the current density of the unprocessed MSM device, and evaluated based on the following criteria:
⊚: greater than or equal to 80%
o: greater than or equal to 60% and less than 80%
X: less than 60%

The conductivity retention rate for Comparative Example 1 was not evaluated as it cannot be laminated due to being soluble in the solvent. Further, the conductivity retention rate for Comparative Example 3 was not evaluated as it cannot form a charge transport complex.

TABLE 1

| | | | Salt Compound | | | | | |
|---|---|---|---|---|---|---|---|---|
| | Copolymer | | | EA of | IP of | | | |
| | | Ioninc | | Borate | Iodonium | | | Conductivity |
| | | potential | | anion | cation | ΔE | Resistance | Retention |
| | Type | (IP) (eV) | Type | (eV) | (eV) | (eV) | to Solvent | Rate |
| Ex. 1 | P-1 | 5.34 | PIPB | 6.29 | 4.71 | 0.95 | ◯ | ◯ |
| Ex. 2 | P-2 | 5.41 | PIPB | 6.29 | 4.71 | 0.88 | ◯ | ◯ |
| Ex. 3 | P-3 | 4.90 | PIPB | 6.29 | 4.71 | 1.39 | ◯ | ⊚ |
| Ex. 4 | P-3 | 4.90 | D-1 | 5.75 | 4.84 | 0.85 | ◯ | ◯ |
| Ex. 5 | P-3 | 4.90 | D-2 | 6.08 | 4.84 | 1.18 | ◯ | ⊚ |
| Ex. 6 | P-3 | 4.90 | D-3 | 6.22 | 4.84 | 1.32 | ◯ | ⊚ |
| Ex. 7 | P-4 | 5.02 | PIPB | 6.29 | 4.71 | 1.27 | ◯ | ⊚ |
| Ex. 8 | P-5 | 5.02 | PIPB | 6.29 | 4.71 | 1.27 | ◯ | ⊚ |
| Ex. 9 | P-6 | 5.04 | PIPB | 6.29 | 4.71 | 1.25 | ◯ | ⊚ |
| Ex. 10 | P-6 | 5.04 | D-2 | 6.08 | 4.84 | 1.04 | ◯ | ⊚ |
| Ex. 11 | P-6 | 5.04 | D-3 | 6.22 | 4.84 | 1.18 | ◯ | ⊚ |
| Ex. 12 | P-7 | 5.27 | PIPB | 6.29 | 4.71 | 1.02 | ◯ | ⊚ |
| Ex. 13 | P-8 | 4.86 | PIPB | 6.29 | 4.71 | 1.43 | ◯ | ⊚ |
| Ex. 14 | P-8 | 4.86 | D-1 | 5.75 | 4.84 | 0.89 | ◯ | ◯ |
| Ex. 15 | P-8 | 4.86 | D-2 | 6.08 | 4.84 | 1.22 | ◯ | ⊚ |
| Ex. 16 | P-8 | 4.86 | D-3 | 6.22 | 4.84 | 1.36 | ◯ | ⊚ |
| Ex. 17 | P-8 | 4.86 | D-4 | 6.17 | 4.84 | 1.31 | ◯ | ⊚ |
| Ex. 18 | P-8 | 4.86 | D-5 | 6.25 | 4.84 | 1.39 | ◯ | ⊚ |
| Ex. 19 | P-9 | 4.92 | PIPB | 6.29 | 4.71 | 1.37 | ◯ | ⊚ |
| Ex. 20 | P-10 | 5.00 | PIPB | 6.29 | 4.71 | 1.29 | ◯ | ⊚ |
| Ex. 21 | P-11 | 4.99 | PIPB | 6.29 | 4.71 | 1.30 | ◯ | ⊚ |
| Comp. | TFB | 5.47 | PIPB | 6.29 | 4.71 | 0.82 | X | Impossible to |
| Ex. 1 | | | | | | | | evaluate |
| Comp. | HT-1 | 5.28 | D-1 | 5.75 | 4.84 | 0.47 | ◯ | X |
| Ex. 2 | | | | | | | | |
| Comp. | HT-2 | 4.69 | PIPB | 6.29 | 4.71 | 1.60 | ◯ | Impossible to |
| Ex. 3 | | | | | | | | dope |

EA: electron affinity

### Evaluation of Quantum Dots Electroluminescent Devices

With regard to the quantum dot electroluminescent device 13 manufactured in Example 13 and the comparative quantum dot electroluminescent device 2 manufactured in Comparative Example 2, the driving voltage (Op.V.: Operation Voltage), luminous efficiency (EQE (%)), and luminous lifespan (LT50 (hours)) were evaluated by the following method. The results are shown in Table 2 below.

### Operation Voltage (Op.V.)

When a voltage is applied to each quantum dot electroluminescent device using a DC constant voltage power supply (manufactured by Kabushikigaisha Kiensu, source meter), current begins to flow at a constant voltage, and the quantum dot electroluminescent device emits light. The voltage at a current density of 5 mA/cm² was used as the operating voltage “Op.V.”.

### Luminous Efficiency (EQE)

For each quantum dot electroluminescent device, when a voltage is applied, current begins to flow at a certain voltage, and the quantum dot electroluminescent device emits light. Using a DC constant voltage power supply (manufactured by Kabushiki Kaisha KENX, source meter), the voltage was gradually increased for each device, and the current value at that time was measured, and the luminance at the time of emission was measured using a luminance measurement device (manufactured by Kabushiki Kaisha Topcon Techno House, SR-3). Here, the measurement was stopped at the point when the luminance started to decay.

From the spectral radiance spectrum measured with the luminance measurement device, assuming Lambertian emission, the external quantum efficiency (EQE) at Op.V. was calculated.

### Luminous Lifespan (LT50)

Using a DC constant voltage power supply (manufactured by Kabushiki Kaisha Kenus, source meter) and applying a specified voltage to each quantum dot electroluminescent device, each quantum dot electroluminescent device was made to emit light. While measuring the emission of the quantum dot electroluminescent devices with a luminance measurement device (manufactured by Kabushiki Kaisha Topcon Technohouse, SR-3), the current was gradually increased, and when the luminance reached 650 nit (cd/m²), the current was kept constant and the devices were left to operate. As the luminance measured by the luminance measurement device gradually decreased, the time until it reached 50% of the initial luminance was defined as “LT50.”

EQE and LT50 are expressed as relative values with the value of comparative quantum dot electroluminescent device 2 set to 1.0.

TABLE 2

| | | | | Op. | | |
|---|---|---|---|---|---|---|
| | Device | | Salt | V. | Relative | Relative |
| | No. | Copolymer | Compound | (V) | EQE | LT50 |
| Ex. 13 | 13 | P-8 | PIPB | 2.8 | 1.1 | 1.1 |
| Comp. | Comp. | HT-1 | D-1 | 7.5 | 1.0 | 1.0 |
| Ex. 2 | 2 | | | | | |

As shown from Table 2, the operation voltage (Op.V.) of the quantum dot electroluminescent device 13 was lower than that of comparative quantum dot electroluminescent device 2, and the EQE and LT50 of the quantum dot electroluminescent device 13 were higher than those of comparative quantum dot electroluminescent device 2.

It should be understood that embodiments described herein should be considered in a descriptive sense only and not for purposes of limitation. Descriptions of features or aspects within each embodiment should be considered as available for other similar features or aspects in other embodiments.

While one or more embodiments have been described with reference to the FIGURE, it will be understood by those of ordinary skill in the art that various changes in form and details may be made therein without departing from the spirit and scope as defined by the following claims.

What is claimed is:

1. A composition comprising:
a copolymer comprising a structural unit represented by Chemical Formula 1, and at least one structural unit of Structural unit A represented by Chemical Formula 2 or Structural unit B represented by Chemical Formula 3, and
a salt compound comprising a borate anion represented by Chemical Formula 4, and an iodonium cation,
wherein an energy difference (ΔE) between an ionization potential of the copolymer and an electron affinity of the borate anion is greater than or equal to about 0.75 electron volts, and the ionization potential of the copolymer is deeper than an ionization potential of the iodonium cation: 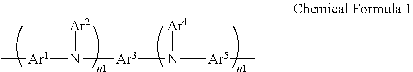
wherein in Chemical Formula 1,
Ar¹, Ar², Ar⁴, and Ar⁵ are, each independently, a substituted or unsubstituted aromatic hydrocarbon ring group, or a substituted or unsubstituted aromatic heterocyclic group,
Ar³ is a substituted or unsubstituted carbazole, a substituted or unsubstituted fluorene, a substituted or unsubstituted benzene, or a substituted or unsubstituted biphenylene group,
wherein, when Ar³ is a substituted or unsubstituted benzene, or a substituted or unsubstituted biphenylene group, then at least one of Ar¹ or Ar² is not a substituted or unsubstituted benzene, and at least one of Ar⁴ or Ar⁵ is not a substituted or unsubstituted benzene,
n1 is an integer of greater than or equal to 1 and less than or equal to 3,
m1 is an integer of greater than or equal to 1 and less than or equal to 3, and
* is a bonding position to an adjacent atom; 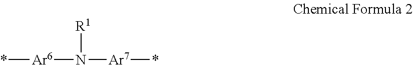
wherein in Chemical Formula 2,
Ar⁶ and Ar⁷ are, each independently, a substituted or unsubstituted aromatic hydrocarbon ring group, or a substituted or unsubstituted aromatic heterocyclic group, and Ar⁶ and Ar⁷ optionally form a ring together,
R¹ is a group represented by chemical formula (2-a), and
* is a bonding position to an adjacent atom, 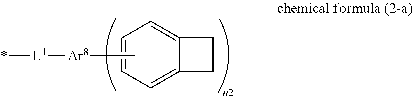
wherein in chemical formula (2-a),
L¹ is a single bond, or a group represented by chemical formula (2-b),
Ar⁸ is a substituted or unsubstituted aromatic hydrocarbon ring group, or a substituted or unsubstituted aromatic heterocyclic group,
wherein, when L¹ is a single bond, then at least one of Ar⁶, Ar⁷, or Ar⁸ is not a substituted or unsubstituted benzene group, or Ar⁸ forms a ring together with at least one of Ar⁶ or Ar⁷,
n2 is an integer of greater than or equal to 2 and less than or equal to 5, and
* is a bonding position to an adjacent atom, 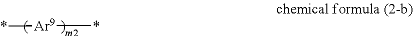
wherein in chemical formula (2-b),
Ar⁹ is a substituted or unsubstituted aromatic hydrocarbon ring group, or a substituted or unsubstituted aromatic heterocyclic group, or Ar⁹ optionally forms a ring together with at least one of Ar⁶ or Ar⁷,
m2 is an integer of greater than or equal to 1 and less than or equal to 5, wherein when m2 is an integer of greater than or equal to 2, each Ar⁹ are the same or different, and
* is a bonding position to an adjacent atom; 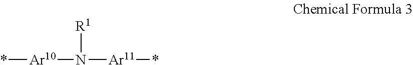
wherein in Chemical Formula 3,
Ar¹⁰ and Ar¹¹ are, each independently, a substituted or unsubstituted aromatic hydrocarbon ring group, or a substituted or unsubstituted aromatic heterocyclic group, and Ar¹⁰ and Ar¹¹ optionally form a ring together,
R² is a group represented by chemical formula (3-a) or chemical formula (3-b), and
* is a bonding position to an adjacent atom, 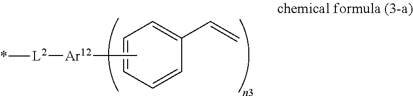
wherein in chemical formula (3-a),
L² is a single bond, or a group represented by chemical formula (3-c),
Ar¹² is a substituted or unsubstituted aromatic hydrocarbon ring group, or a substituted or unsubstituted aromatic heterocyclic group,
wherein, when L² is a single bond, Ar¹² optionally forms a ring together with at least one of Ar¹⁰ or Ar¹¹,
n3 is an integer of greater than or equal to 2 and less than or equal to 5, and
* is a bonding position to an adjacent atom; 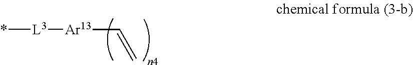
wherein in chemical formula (3-b),
L³ is a single bond, or a group represented by chemical formula (3-c),
Ar¹³ is a substituted or unsubstituted aromatic hydrocarbon ring group, or a substituted or unsubstituted aromatic heterocyclic group,
wherein, when L³ is a single bond, Ar¹³ optionally forms a ring together with at least one of Ar¹⁰ or Ar¹¹,
n4 is an integer of greater than or equal to 2 and less than or equal to 5, and
* is a bonding position to an adjacent atom; 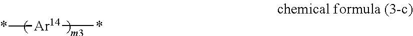
wherein in chemical formula (3-c),
Ar¹⁴ is a substituted or unsubstituted aromatic hydrocarbon ring group, or a substituted or unsubstituted aromatic heterocyclic group, or Ar¹⁴ optionally forms a ring together with at least one of Ar¹⁰ or Ar¹¹,
m3 is an integer of greater than or equal to 1 and less than or equal to 5, and when m3 is an integer of greater than or equal to 2, each Ar¹⁴ is the same or different, and
* is a bonding position to an adjacent atom; 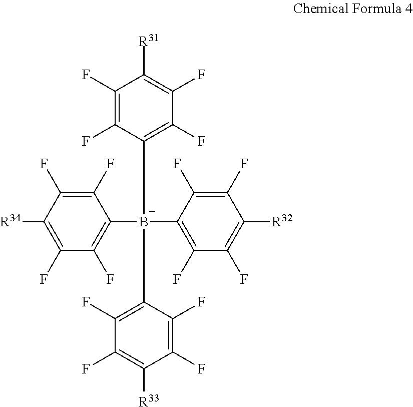
wherein in Chemical Formula 4,
R³¹ to R³⁴ are, each independently, a hydrogen atom, a fluorine atom, or a group represented by chemical formula (4-a):
*-L⁴-(Ar¹⁵)ₙ₆—(X)ₙ₅ chemical formula (4-a)
wherein in chemical formula (4-a),
L⁴ is a single bond, or a group represented by chemical formula (4-b),
Ar¹⁵ is a substituted or unsubstituted aromatic hydrocarbon ring group, or a substituted or unsubstituted aromatic heterocyclic group,
X is a fluorine atom, or a group selected from Group (4-1),
n5 is an integer of greater than or equal to 1 and less than or equal to 5,
n6 is an integer of 0 or 1, wherein,
when multiple groups represented by chemical formula (4-a) are present, each L⁴ is the same or different,
when multiple groups represented by chemical formula (4-a) are present, each Ar¹⁵ is the same or different,
when multiple groups represented by chemical formula (4-a) are present, each X is the same or different,
when multiple groups represented by chemical formula (4-a) are present, each n5 is the same or different,
when multiple groups represented by chemical formula (4-a) are present, each n6 is the same or different,
when n5 is an integer of greater than or equal to 2, each X is the same or different, and
* is a bonding position to an adjacent atom, 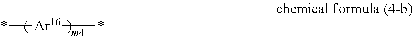
wherein in chemical formula (4-b),
Ar¹⁶ is a substituted or unsubstituted aromatic hydrocarbon ring group, or a substituted or unsubstituted aromatic heterocyclic group,
m4 is an integer of greater than or equal to 1 and less than or equal to 5, and when m4 is greater than or equal to 2, each Ar¹⁶ is the same or different, and
* is a bonding position to an adjacent atom, 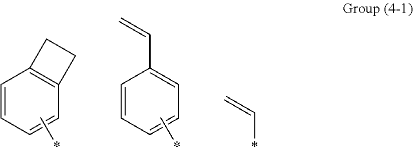
in Group (4-1),
* is a bonding position to an adjacent atom.

2. The composition of claim 1, wherein the borate anion is selected from the groups represented below:

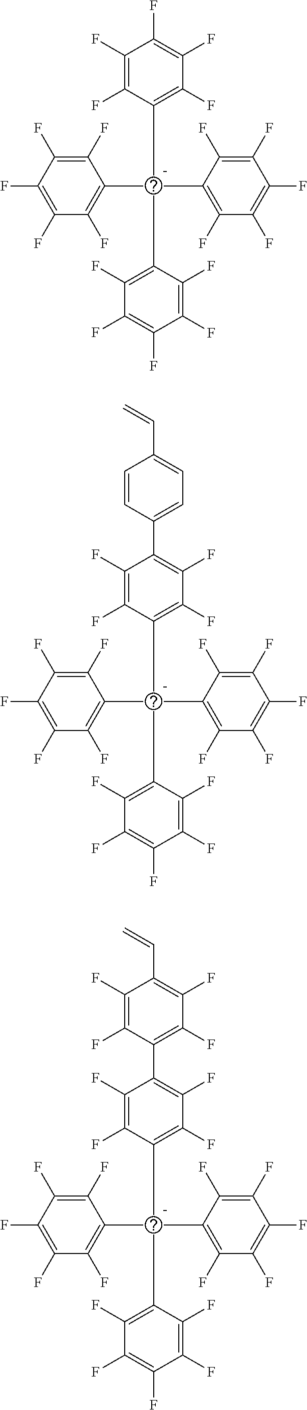 [SMILES: Fc1c(F)c(F)c(C(c2c(F)c(F)c(F)c(F)c2F)(c2c(F)c(F)c(F)c(F)c2F)c2c(F)c(F)c(F)c(F)c2F)c(F)c1F ; C=Cc1ccc(-c2c(F)c(F)c(C(c3c(F)c(F)c(F)c(F)c3F)(c3c(F)c(F)c(F)c(F)c3F)c3c(F)c(F)c(F)c(F)c3F)c(F)c2F)cc1 ; C=Cc1c(F)c(F)c(-c2c(F)c(F)c(C(c3c(F)c(F)c(F)c(F)c3F)(c3c(F)c(F)c(F)c(F)c3F)c3c(F)c(F)c(F)c(F)c3F)c(F)c2F)c(F)c1F]

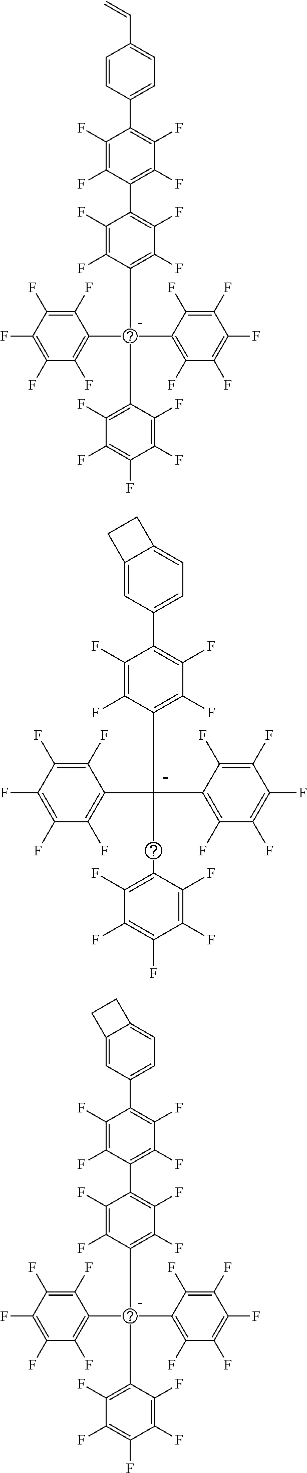

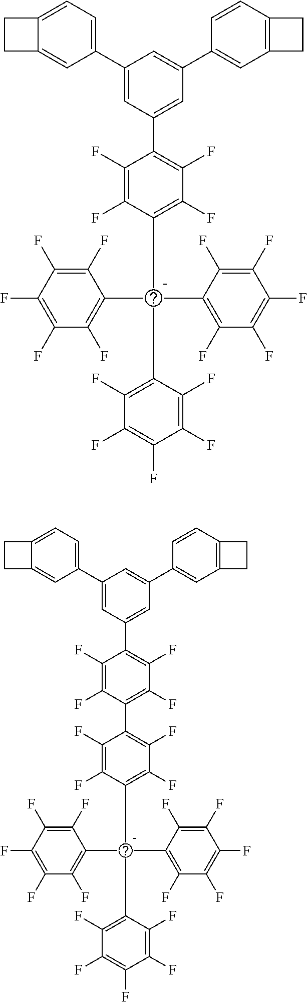

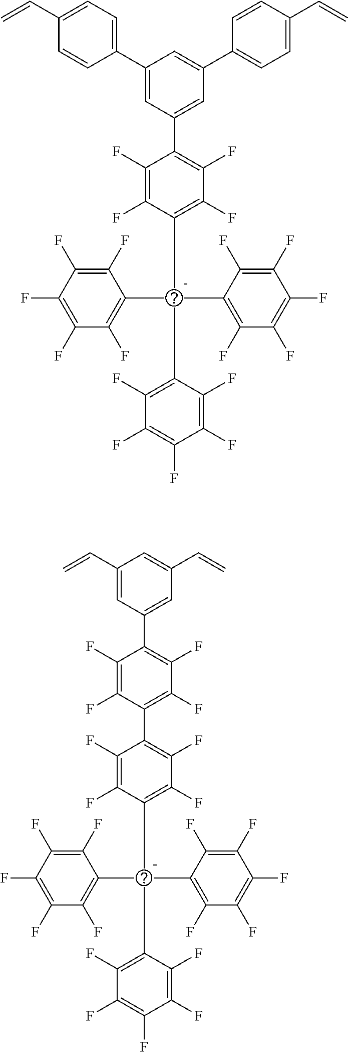 [SMILES: C=Cc1ccc(-c2cc(-c3ccc(C=C)cc3)cc(-c3c(F)c(F)c(C(c4c(F)c(F)c(F)c(F)c4F)(c4c(F)c(F)c(F)c(F)c4F)c4c(F)c(F)c(F)c(F)c4F)c(F)c3F)c2)cc1 ; C=Cc1cc(C=C)cc(-c2c(F)c(F)c(-c3c(F)c(F)c(C(c4c(F)c(F)c(F)c(F)c4F)(c4c(F)c(F)c(F)c(F)c4F)c4c(F)c(F)c(F)c(F)c4F)c(F)c3F)c(F)c2F)c1]

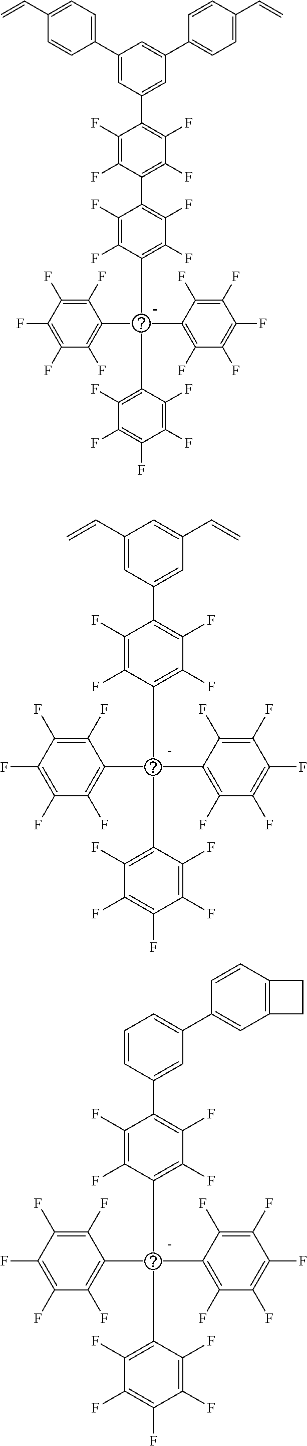 [SMILES: C=Cc1ccc(-c2cc(-c3ccc(C=C)cc3)cc(-c3c(F)c(F)c(-c4c(F)c(F)c(C(c5c(F)c(F)c(F)c(F)c5F)(c5c(F)c(F)c(F)c(F)c5F)c5c(F)c(F)c(F)c(F)c5F)c(F)c4F)c(F)c3F)c2)cc1 ; C=Cc1cc(C=C)cc(-c2c(F)c(F)c(C(c3c(F)c(F)c(F)c(F)c3F)(c3c(F)c(F)c(F)c(F)c3F)c3c(F)c(F)c(F)c(F)c3F)c(F)c2F)c1 ; Fc1c(F)c(F)c(C(c2c(F)c(F)c(F)c(F)c2F)(c2c(F)c(F)c(F)c(F)c2F)c2c(F)c(F)c(-c3cccc(-c4ccc5c(c4)CC5)c3)c(F)c2F)c(F)c1F]

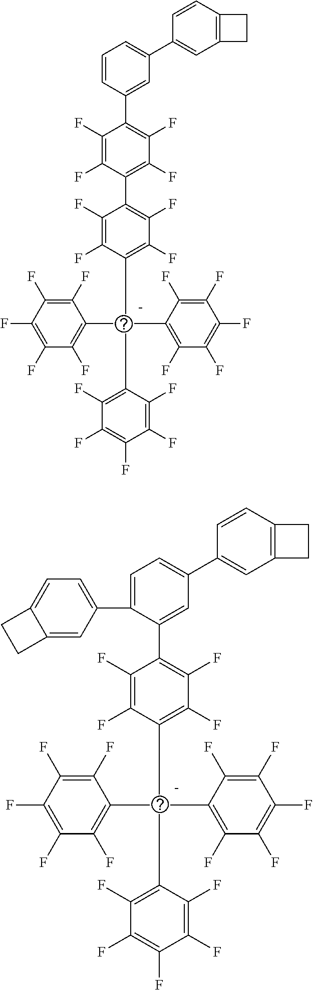 [SMILES: Fc1c(F)c(F)c(C(c2c(F)c(F)c(F)c(F)c2F)(c2c(F)c(F)c(F)c(F)c2F)c2c(F)c(F)c(-c3c(F)c(F)c(-c4cccc(-c5ccc6c(c5)CC6)c4)c(F)c3F)c(F)c2F)c(F)c1F ; Fc1c(F)c(F)c(C(c2c(F)c(F)c(F)c(F)c2F)(c2c(F)c(F)c(F)c(F)c2F)c2c(F)c(F)c(-c3cc(-c4ccc5c(c4)CC5)ccc3-c3ccc4c(c3)CC4)c(F)c2F)c(F)c1F]

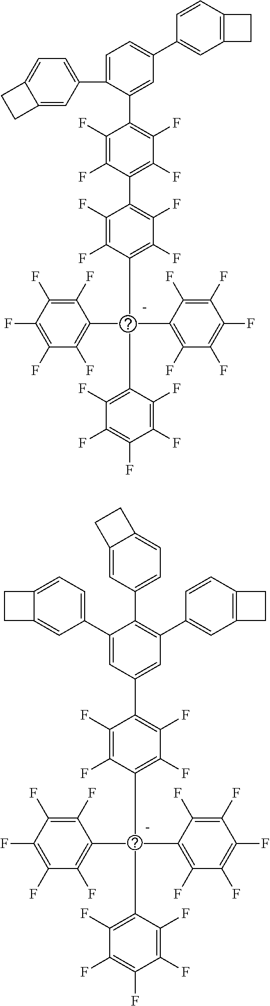

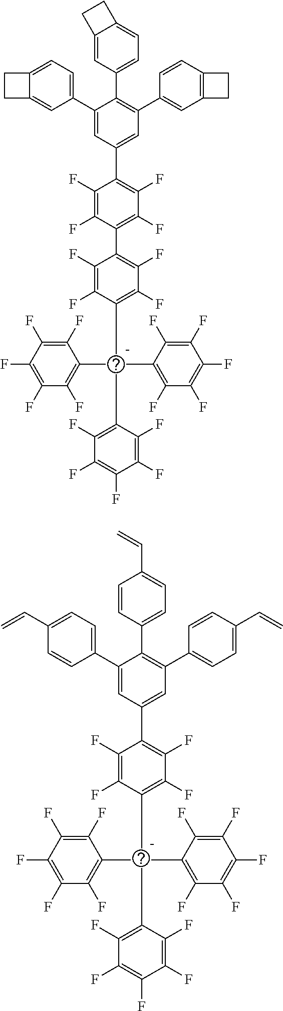

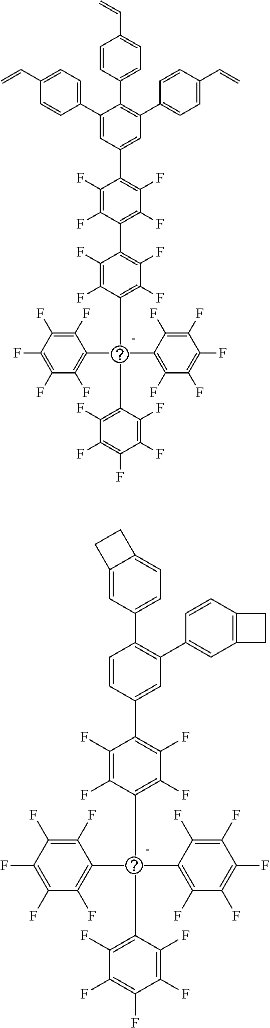 [SMILES: C=Cc1ccc(-c2cc(-c3c(F)c(F)c(-c4c(F)c(F)c(C(c5c(F)c(F)c(F)c(F)c5F)(c5c(F)c(F)c(F)c(F)c5F)c5c(F)c(F)c(F)c(F)c5F)c(F)c4F)c(F)c3F)cc(-c3ccc(C=C)cc3)c2-c2ccc(C=C)cc2)cc1 ; Fc1c(F)c(F)c(C(c2c(F)c(F)c(F)c(F)c2F)(c2c(F)c(F)c(F)c(F)c2F)c2c(F)c(F)c(-c3ccc(-c4ccc5c(c4)CC5)c(-c4ccc5c(c4)CC5)c3)c(F)c2F)c(F)c1F]

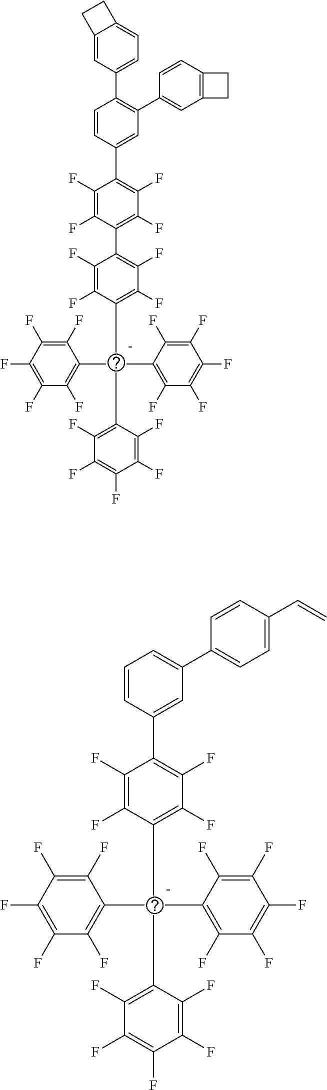 [SMILES: Fc1c(F)c(F)c(C(c2c(F)c(F)c(F)c(F)c2F)(c2c(F)c(F)c(F)c(F)c2F)c2c(F)c(F)c(-c3c(F)c(F)c(-c4ccc(-c5ccc6c(c5)CC6)c(-c5ccc6c(c5)CC6)c4)c(F)c3F)c(F)c2F)c(F)c1F ; C=Cc1ccc(-c2cccc(-c3c(F)c(F)c(C(c4c(F)c(F)c(F)c(F)c4F)(c4c(F)c(F)c(F)c(F)c4F)c4c(F)c(F)c(F)c(F)c4F)c(F)c3F)c2)cc1]

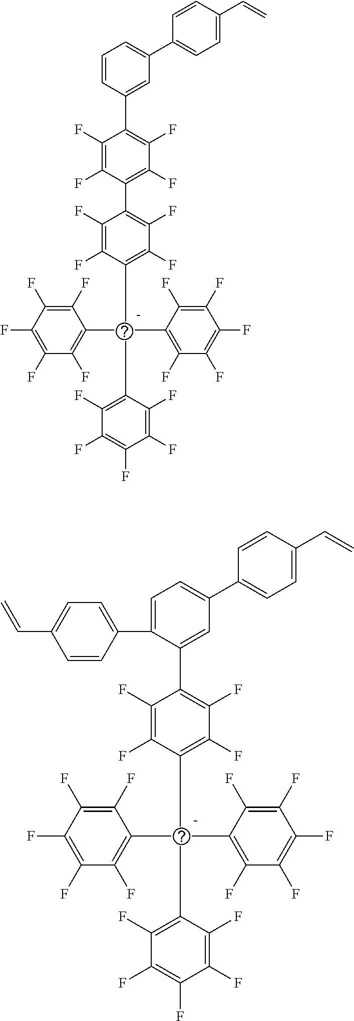

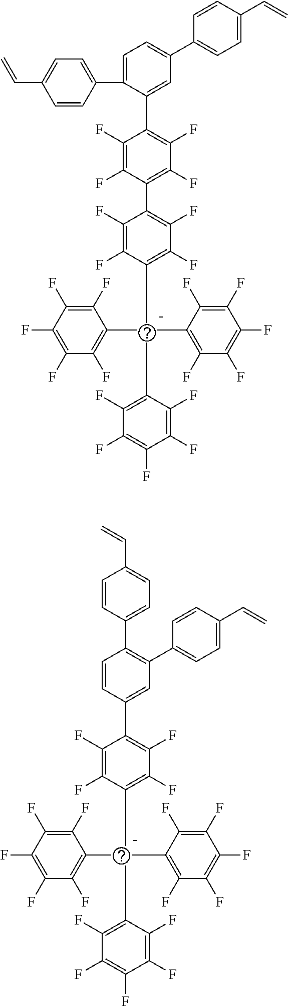 [SMILES: C=Cc1ccc(-c2ccc(-c3ccc(C=C)cc3)c(-c3c(F)c(F)c(-c4c(F)c(F)c(C(c5c(F)c(F)c(F)c(F)c5F)(c5c(F)c(F)c(F)c(F)c5F)c5c(F)c(F)c(F)c(F)c5F)c(F)c4F)c(F)c3F)c2)cc1 ; C=Cc1ccc(-c2ccc(-c3c(F)c(F)c(C(c4c(F)c(F)c(F)c(F)c4F)(c4c(F)c(F)c(F)c(F)c4F)c4c(F)c(F)c(F)c(F)c4F)c(F)c3F)cc2-c2ccc(C=C)cc2)cc1]

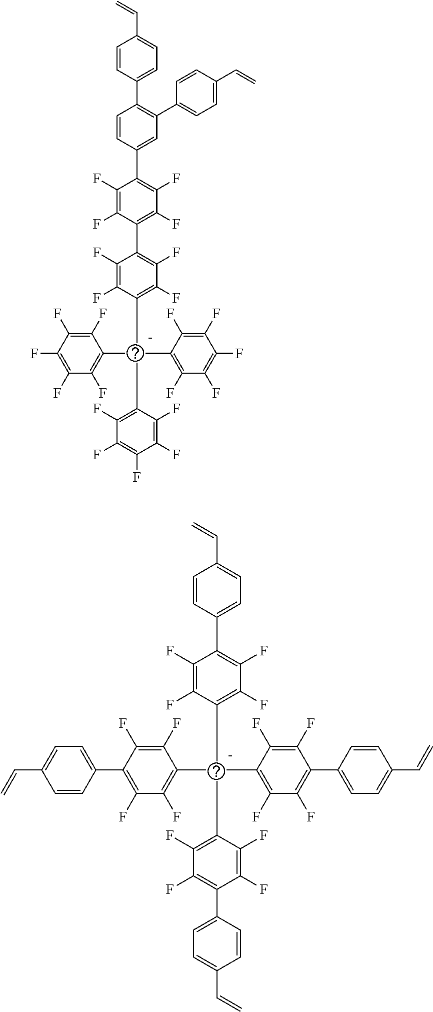 [SMILES: C=Cc1ccc(-c2ccc(-c3c(F)c(F)c(-c4c(F)c(F)c(C(c5c(F)c(F)c(F)c(F)c5F)(c5c(F)c(F)c(F)c(F)c5F)c5c(F)c(F)c(F)c(F)c5F)c(F)c4F)c(F)c3F)cc2-c2ccc(C=C)cc2)cc1 ; C=Cc1ccc(-c2c(F)c(F)c(C(c3c(F)c(F)c(-c4ccc(C=C)cc4)c(F)c3F)(c3c(F)c(F)c(-c4ccc(C=C)cc4)c(F)c3F)c3c(F)c(F)c(-c4ccc(C=C)cc4)c(F)c3F)c(F)c2F)cc1]

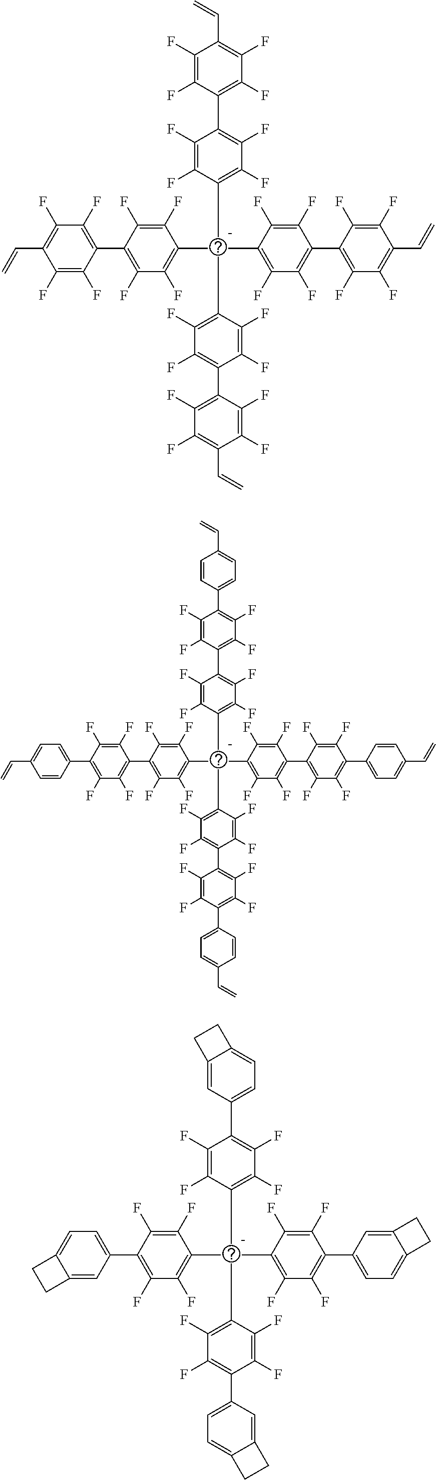

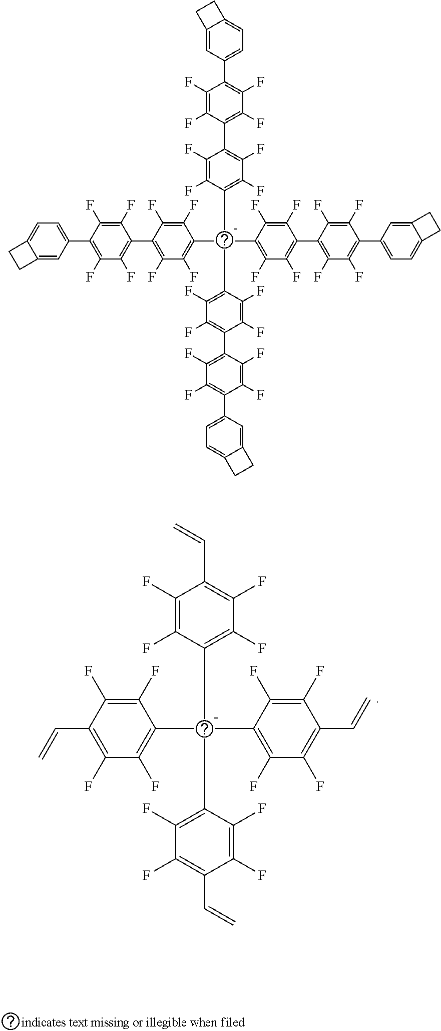 [SMILES: Fc1c(F)c(-c2c(F)c(F)c(C(c3c(F)c(F)c(-c4c(F)c(F)c(-c5ccc6c(c5)CC6)c(F)c4F)c(F)c3F)(c3c(F)c(F)c(-c4c(F)c(F)c(-c5ccc6c(c5)CC6)c(F)c4F)c(F)c3F)c3c(F)c(F)c(-c4c(F)c(F)c(-c5ccc6c(c5)CC6)c(F)c4F)c(F)c3F)c(F)c2F)c(F)c(F)c1-c1ccc2c(c1)CC2 ; C=Cc1c(F)c(F)c(C(c2c(F)c(F)c(C=C)c(F)c2F)(c2c(F)c(F)c(C=C)c(F)c2F)c2c(F)c(F)c(C=C)c(F)c2F)c(F)c1F]

3. The composition of claim 1, wherein the structural unit represented by Chemical Formula 1 is selected from Group (1-1) to Group (1-3): 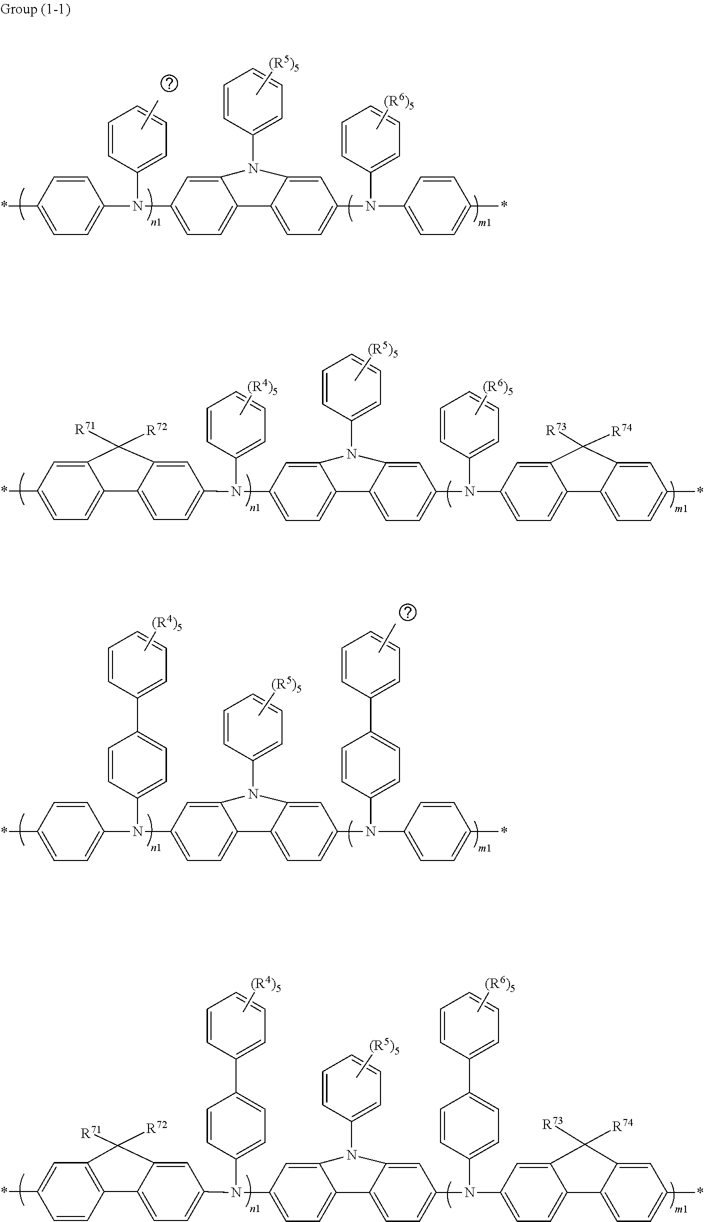 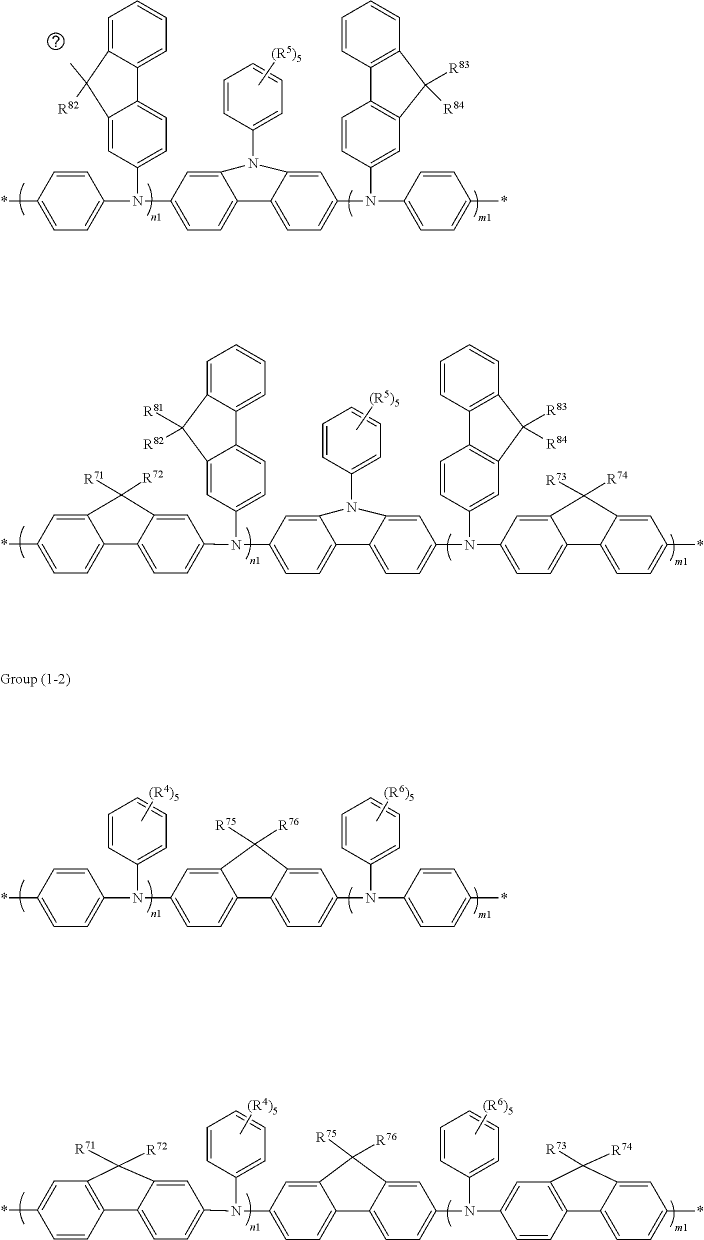 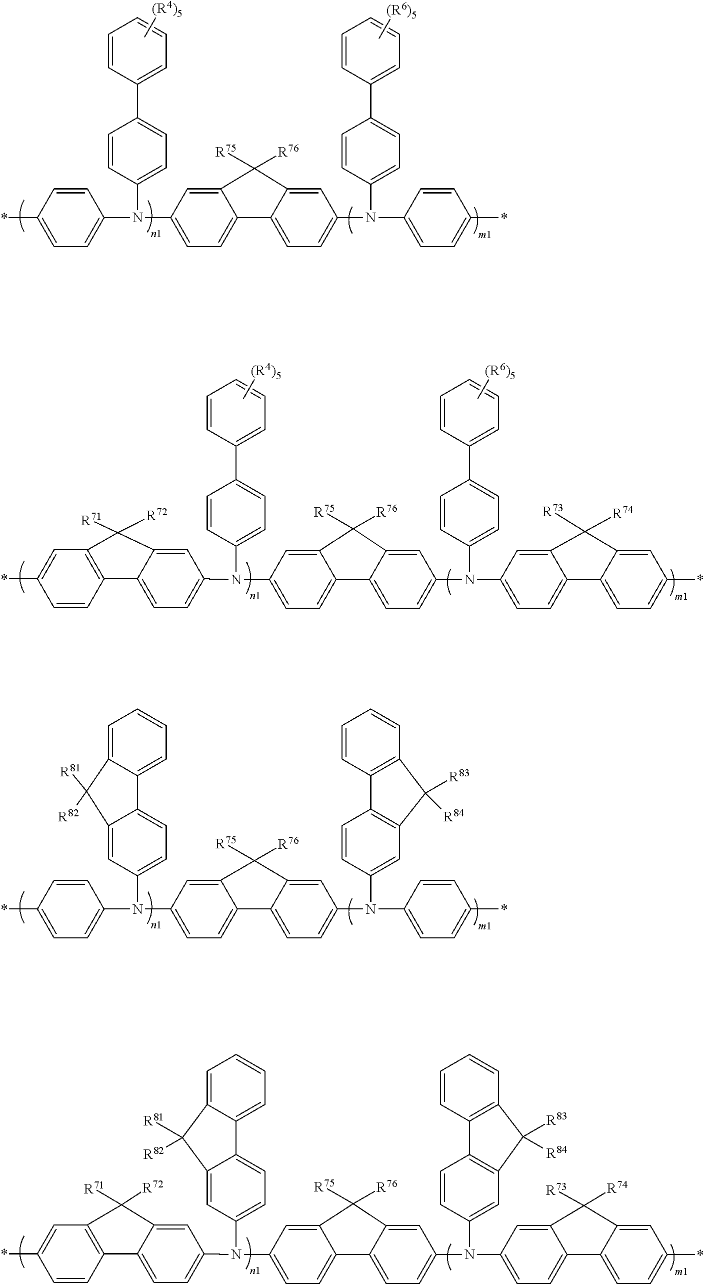 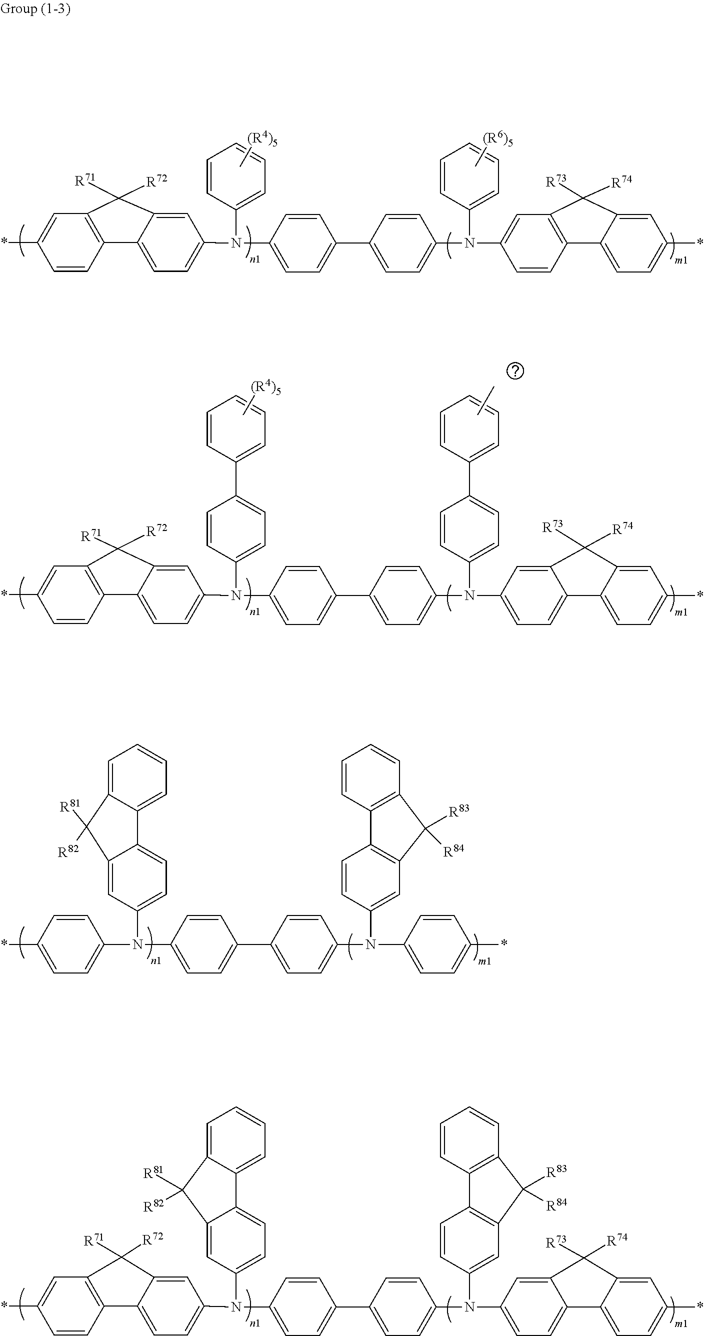 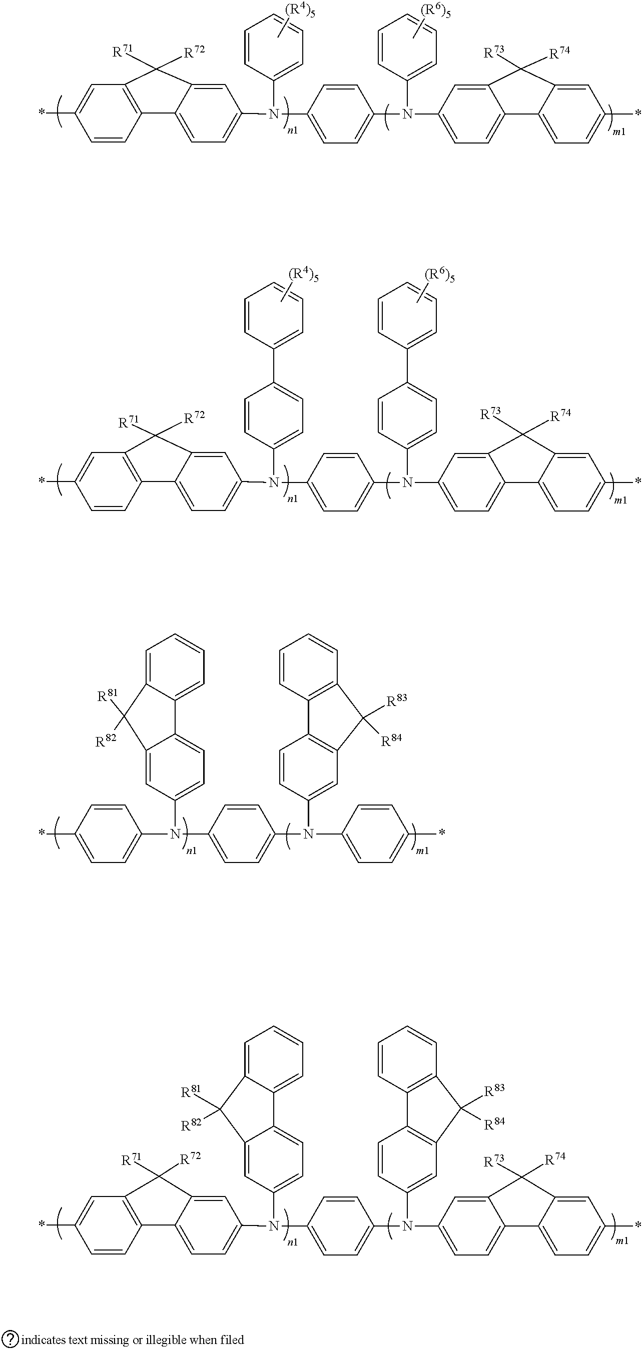
wherein in Group (1-1) to Group (1-3),
R⁴ to R⁶, R⁷¹ to R⁷⁶, and R⁸¹ to R⁸⁴, are, each independently, a hydrogen atom, or a hydrocarbon group having 1 to 20 carbon atoms,
each n1 represents an integer of greater than or equal to 1 and less than or equal to 3,
each m1 represents an integer of greater than or equal to 1 and less than or equal to 3, and
* is a bonding position to an adjacent atom.

4. The composition of claim 1, wherein the Structural unit A represented by Chemical Formula 2 is selected from Group 2: 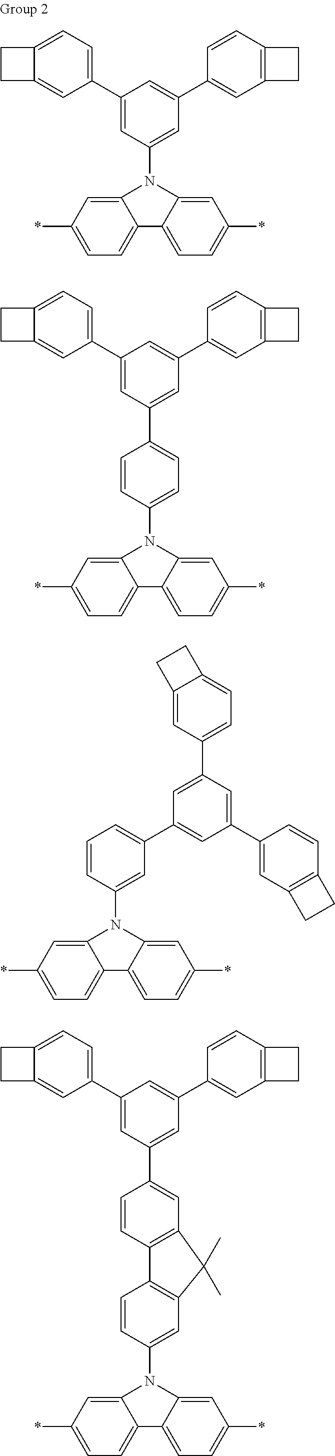 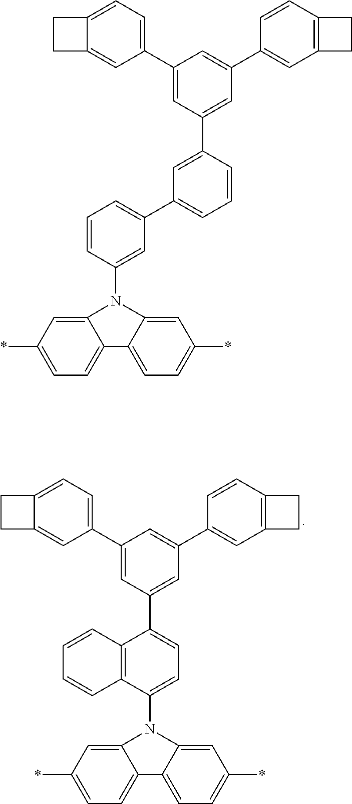
wherein in the chemical formulae in Group 2, * is a bonding position to an adjacent atom.

5. The composition of claim 1, wherein the Structural unit B represented by Chemical Formula 3 is selected from Group 3: 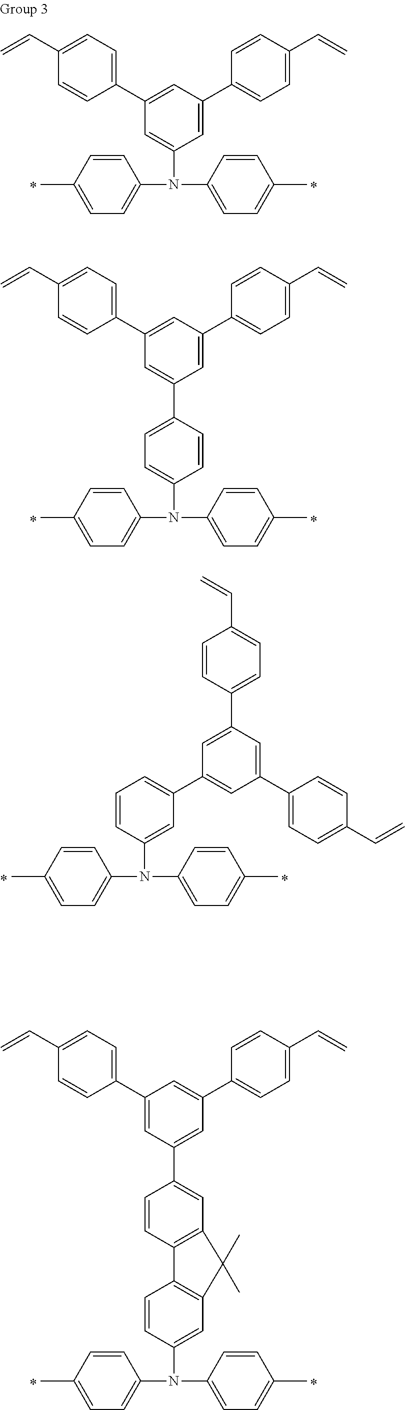 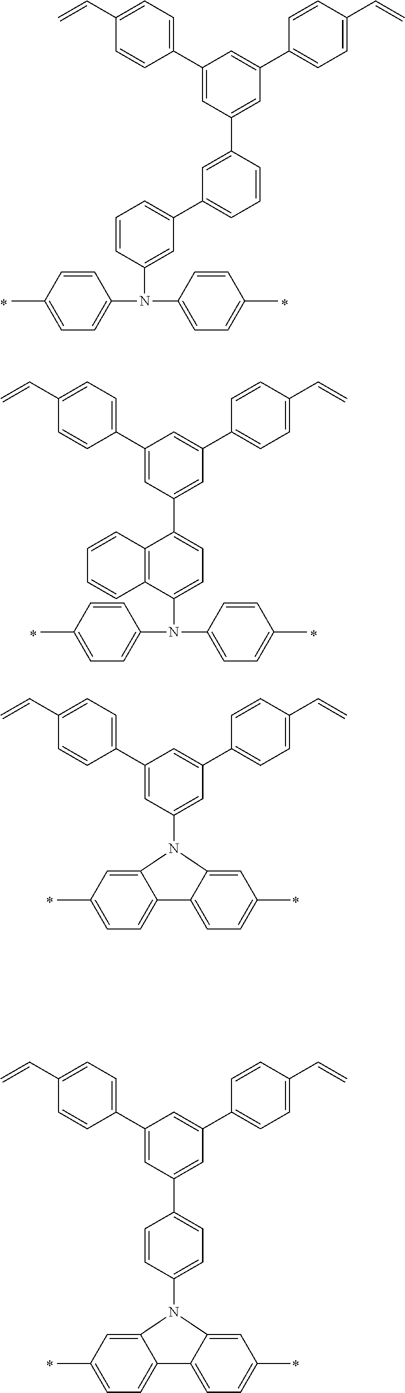 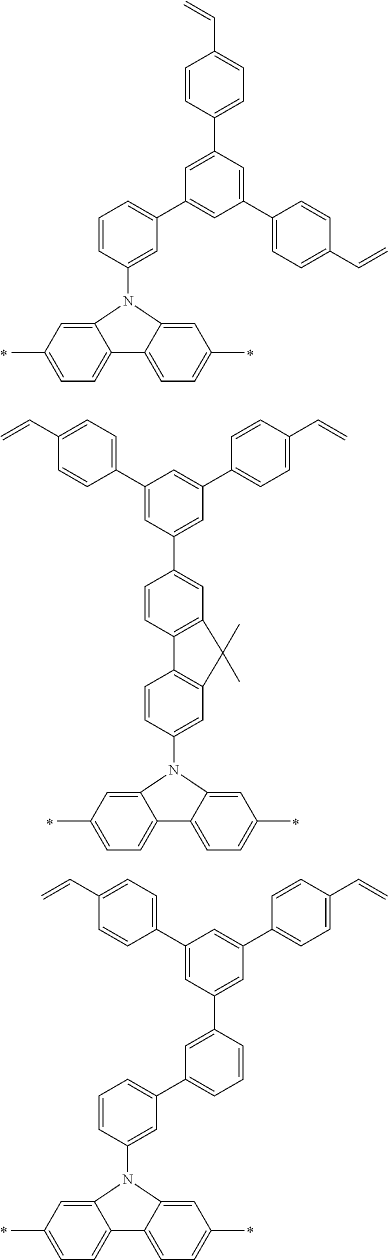 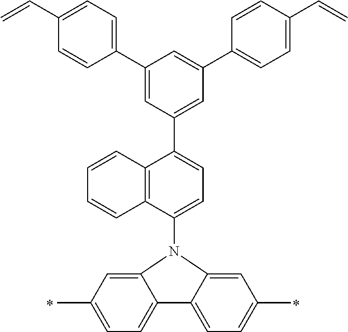
wherein in the chemical formulae in Group 3, * is a bonding position to an adjacent atom.

6. The composition of claim 1, wherein the copolymer is selected from the following chemical formulae: 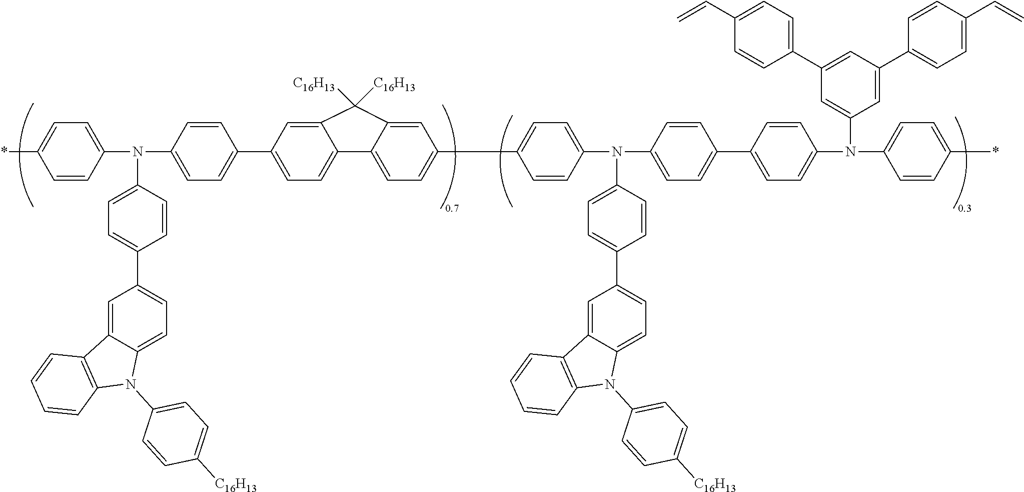 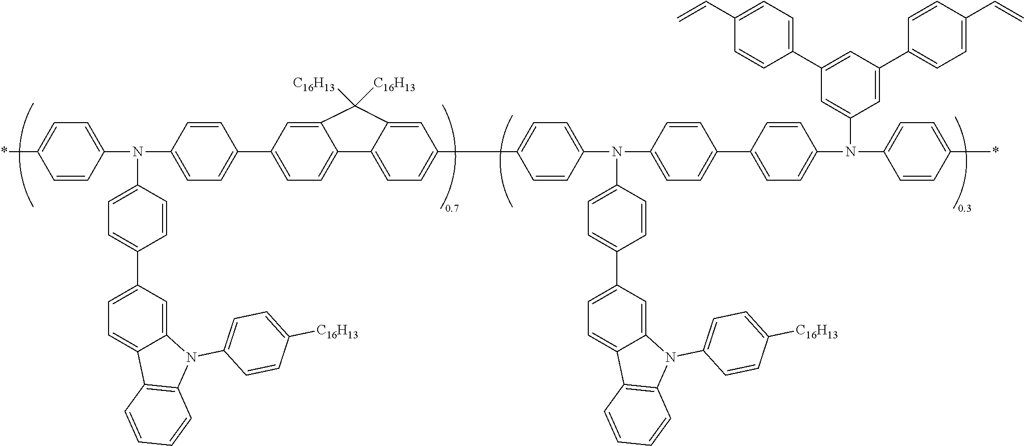 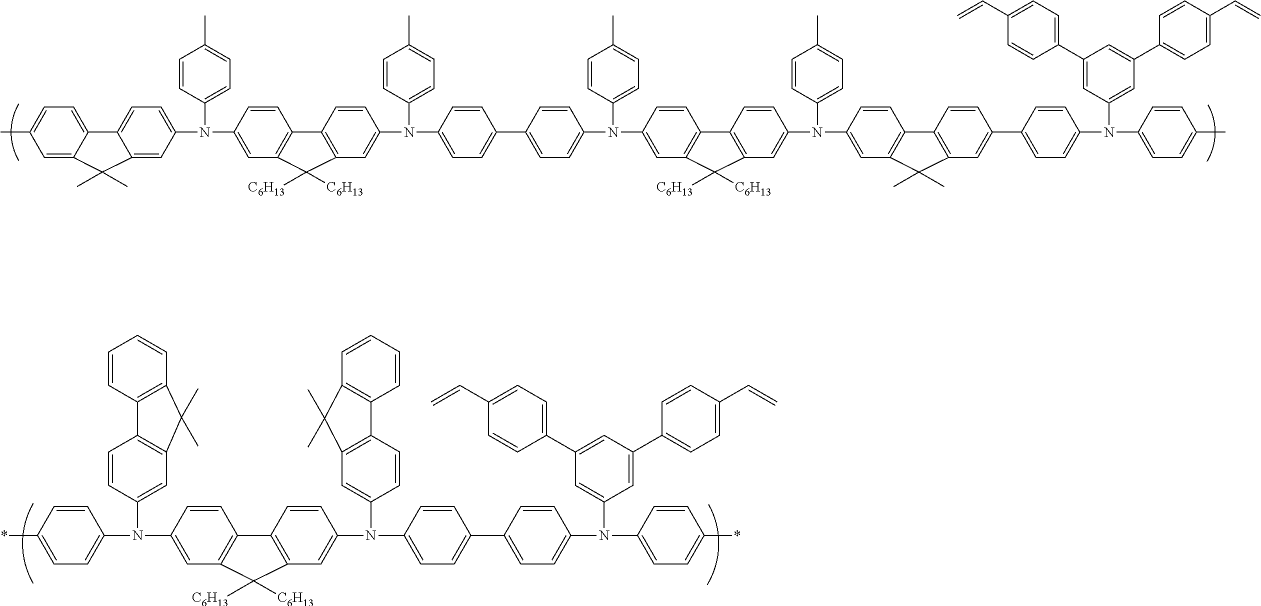 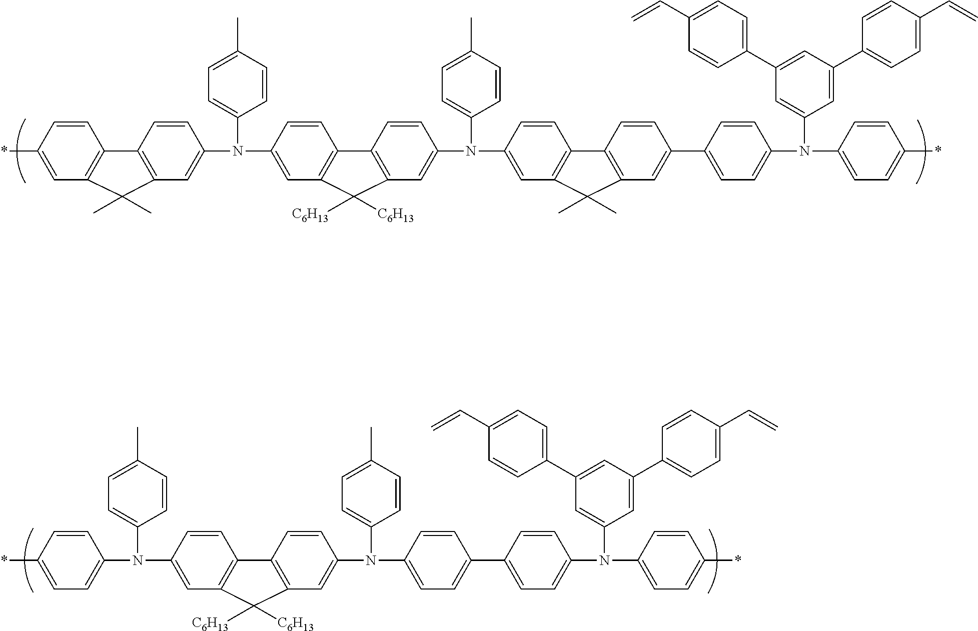 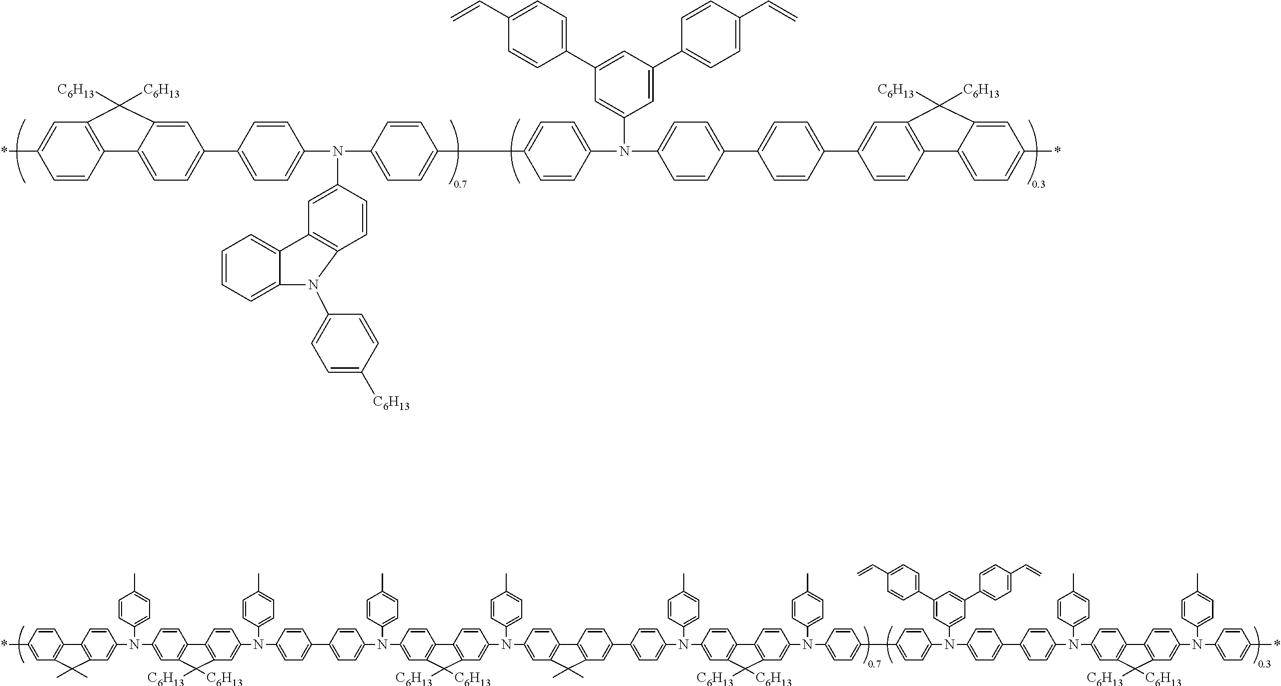 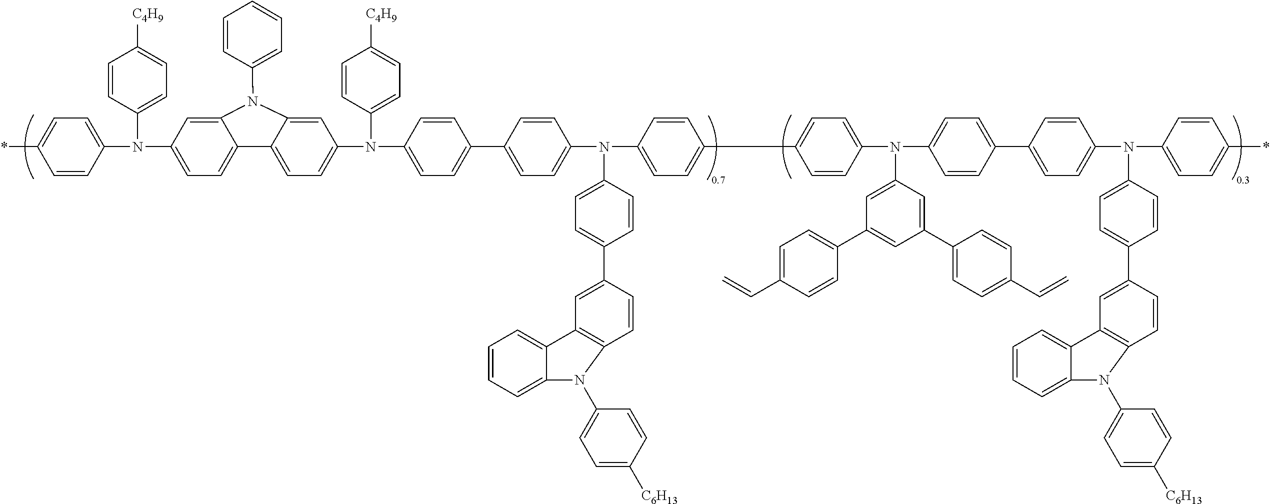 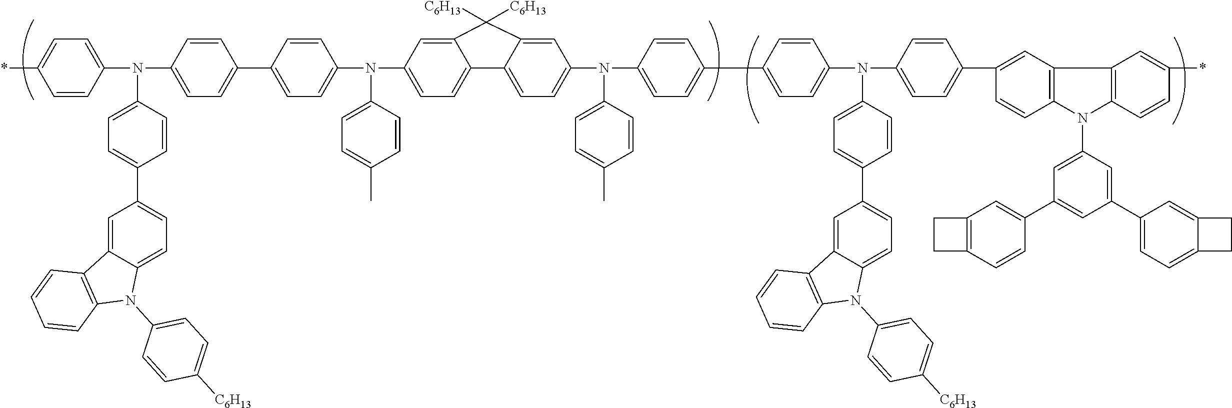 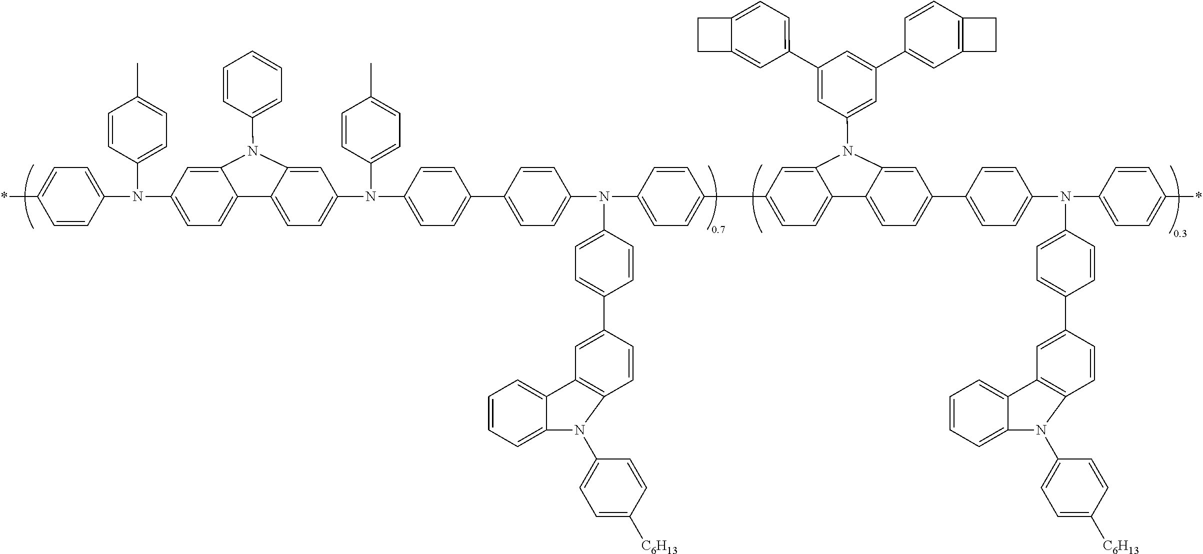
wherein in the chemical formulae, * is a bonding position to an adjacent atom.

7. The composition of claim 1, wherein a mole ratio of the structural unit represented by Chemical Formula 1 is greater than or equal to about 20 mole % and less than or equal to about 99 mole %, based on a total number of moles of the structural unit represented by Chemical Formula 1, the Structural unit A represented by Chemical Formula 2, and the Structural unit B represented by Chemical Formula 3 in the copolymer.

8. The composition of claim 1, wherein a mole ratio of the structural unit represented by Chemical Formula 1 is greater than or equal to about 50 mole % and less than or equal to about 95 mole %, based on a total number of moles of the structural unit represented by Chemical Formula 1, the Structural unit A represented by Chemical Formula 2, and the Structural unit B represented by Chemical Formula 3 in the copolymer.

9. The composition according to claim 1, wherein a weight average molecular weight (Mw) of the copolymer is greater than or equal to about 8,000 Dalton and less than or equal to about 500,000 Dalton.

10. The composition of claim 1, wherein an amount of the salt compound in the composition is greater than or equal to about 1 weight percent and less than or equal to about 70 weight percent, based on a total weight of the copolymer and the salt compound.

11. The composition of claim 1, wherein the electron affinity of the borate anion is greater than or equal to about 5.50 electron volts and less than or equal to about 6.50 electron volts.

12. The composition of claim 1, wherein the iodonium cation is a difuryliodonium cation, a dithienyliodonium cation, a bis(4,5-dimethyl-2-furyl) iodonium cation, a bis(5-chloro-2-thienyl) iodonium cation, a bis(5-cyano-2-furyl) iodonium cation, a bis(5-nitro-2-thienyl) iodonium cation, a bis(5-acetyl-2-furyl) iodonium cation, a bis(5-carboxy-2-thienyl) iodonium cation, a bis(5-methoxycarbonyl-2-furyl) iodonium cation, a bis(5-phenyl-2-furyl) iodonium cation, a bis(5-(p-methoxyphenyl)-2-thienyl) iodonium cation, a bis(5-vinyl-2-furyl) iodonium cation, a bis(5-ethynyl-2-thienyl) iodonium cation, a bis(5-cyclohexyl-2-furyl) iodonium cation, a bis(5-hydroxy-2-thienyl) iodonium cation, a bis(5-phenoxy-2-furyl) iodonium cation, a bis(5-mercapto-2-thienyl) iodonium cation, a bis(5-butylthio-2-thienyl) iodonium cation, a bis(5-phenylthio-2-thienyl) iodonium cation, a diphenyliodonium cation, a bis(p-tolyl)iodonium cation, a bis(p-octylphenyl) iodonium cation, a bis(p-octadecylphenyl) iodonium cation, a bis(p-octyloxyphenyl) iodonium cation, a bis(p-octadecyloxyphenyl) iodonium cation, a phenyl (p-octadecyloxyphenyl) iodonium cation, a 4-isopropyl-4′-methyldiphenyliodonium cation, a (4-isobutylphenyl)-p-tolyliodonium cation, a bis(1-naphthyl) iodonium cation, a bis(4-phenylsulfanylphenyl) iodonium cation, a phenyl (6-benzoyl-9-ethyl-9H-carbazol-3-yl) iodonium cation, a (7-methoxy-2-oxo-2H-chromen-3-yl)-4′-isopropylphenyliodonium cation, or a combination thereof.

13. The composition of claim 1, wherein the ionization potential of the iodonium cation is greater than or equal to about 4.00 electron volts and less than or equal to about 4.95 electron volts.

14. The composition of claim 1, wherein the salt compound further comprises a sulfonium cation, a sulfoxonium cation, a phosphonium cation, or a combination thereof.

15. An organic film comprising a cured material obtained by curing the composition of claim 1, and a carboxyl-containing compound.

16. The organic film according to claim 15, wherein the carboxyl-containing compound is acetic acid, propionic acid, butyric acid, valeric acid, caproic acid, malonic acid, succinic acid, glutaric acid, adipic acid, pimelic acid, (meth)acrylic acid, poly(meth)acrylic acid, benzoic acid, hexahydrobenzoic acid, terephthalic acid, 1,4-cyclohexanedicarboxylic acid, citric acid, malic acid, 3-isopropylmalic acid, itaconic acid, citraconic acid, or a combination thereof.

17. An electroluminescent device, comprising:
a first electrode supplying holes,
a second electrode supplying electrons, and
an organic layer disposed between the first electrode and the second electrode,
wherein at least one layer of the organic layer comprises the organic film of claim 15.

18. The electroluminescent device according to claim 17, wherein the at least one layer of the organic layer comprising the organic film is a hole injection layer.

19. The electroluminescent device according to claim 17, wherein the organic layer comprises a light emitting layer comprising semiconductor nanoparticles, an organometallic complex, or a combination thereof.

20. The electroluminescent device according to claim 17, wherein the organic layer comprises a light emitting layer comprising semiconductor nanoparticles.
